(19) United States
(12) Patent Application Publication
(10) Pub. No.: US 2025/0344568 A1
(43) Pub. Date: Nov. 6, 2025

(54) LIGHT-EMITTING ELEMENT, POLYCYCLIC COMPOUND FOR THE SAME, AND DISPLAY DEVICE AND ELECTRONIC DEVICE INCLUDING THE SAME

(71) Applicant: Samsung Display Co., Ltd., Yongin-si (KR)

(72) Inventors: MUN-KI SIM, Yongin-si (KR); Hirokazu MIYASHITA, Yongin-si (KR); TAEIL KIM, Yongin-si (KR); SUN YOUNG PAK, Yongin-si (KR); MinJae SUNG, Yongin-si (KR); MINJUNG JUNG, Yongin-si (KR); Seonhyoung HUR, Yongin-si (KR)

(21) Appl. No.: 19/185,162

(22) Filed: Apr. 21, 2025

(30) Foreign Application Priority Data
Apr. 24, 2024 (KR) 10-2024-0054964

(51) Int. Cl. H10K 50/12; H10K 59/38; H10K 85/30; H10K 85/40; H10K 85/60; H10K 101/20; H10K 102/00

(52) U.S. Cl. CPC H10K 50/12; H10K 59/38; H10K 85/342; H10K 85/346; H10K 85/40; H10K 85/626; H10K 85/633; H10K 85/636; H10K 85/654; H10K 85/6572; H10K 85/6574; H10K 85/6576; H10K 85/658; H10K 2101/20; H10K 2102/331

(57) ABSTRACT

A light-emitting element including a first electrode, a second electrode arranged on the first electrode, and an emission layer arranged between the first electrode and the second electrode is provided. The emission layer includes a first compound represented by Formula 1.

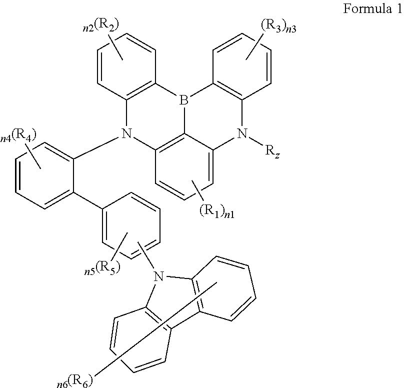

### CROSS-REFERENCE TO RELATED APPLICATION

This application claims priority to and the benefit of Korean Patent Application No. 10-2024-0054964, filed on Apr. 24, 2024, in the Korean Intellectual Property Office, the entire content of which is incorporated herein by reference.

### BACKGROUND

### 1. Field

One or more aspects of embodiments of the present disclosure relate to a light-emitting element, a polycyclic compound used for the light-emitting element, a display device including the light-emitting element, and an electronic device including the light-emitting element.

### 2. Background

Recently, significant advancements have been made in organic electroluminescence display devices, which are actively being developed as image display devices. Unlike liquid crystal display devices, these so-called “self-luminous” display devices recombine holes and electrons in an emission layer, injected respectively from a first electrode and a second electrode. This recombination causes an emission material, such as a light-emitting element containing an organic compound, to emit light and display images

In the application of organic light-emitting elements to display devices, improvements in luminous efficiency and long lifespan are desired or required.

Therefore, ongoing development focuses on materials for organic light-emitting elements that may reliably and stably meet or achieve these requirements.

Recently, to achieve high-efficiency light-emitting elements, technologies such as phosphorescent emission, which uses energy in triplet states, and fluorescent emission using triplet-triplet annihilation (TTA)—a phenomenon where a singlet exciton is generated by the collision of triplet excitons—have been developed. Additionally, there is the active development of materials for thermally activated delayed fluorescence (TADF), which utilizes a delayed fluorescence phenomenon.

### SUMMARY

One or more aspects of embodiments of the present disclosure are directed toward a light-emitting element with (e.g., having) enhanced (e.g., improved) luminous efficiency and lifespan.

One or more aspects of embodiments of the present disclosure are directed toward a polycyclic compound with (e.g., having) enhanced (e.g., improved) material lifespan.

One or more aspects of embodiments of the present disclosure are directed toward a display device including the light-emitting element with (e.g., having) enhanced (e.g., improved) luminous efficiency and lifespan to thereby have excellent or suitable display quality.

One or more aspects of embodiments of the present disclosure an electronic device that includes a light-emitting element with improved luminous efficiency and lifespan, thereby ensuring excellent display quality.

Additional aspects will be set forth in part in the description which follows and, in part, will be apparent from the description, or may be learned by practice of the presented embodiments of the disclosure.

O ne or more embodiments of the present disclosure provide a light-emitting element including a first electrode, a second electrode arranged on the first electrode, and an emission layer arranged between the first electrode and the second electrode and including (e.g., containing) a first compound represented by Formula 1.

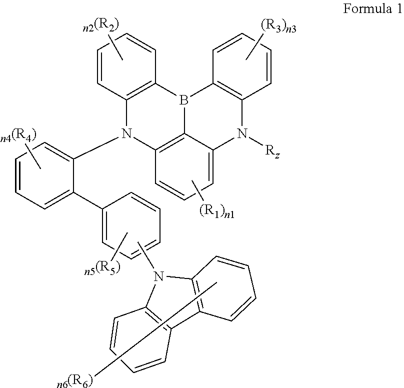

In Formula 1, R₁ to R₃, R₆ and Rz may each independently be a hydrogen atom, a deuterium atom, a cyano group, a substituted or unsubstituted alkyl group having 1 to 30 carbons, a substituted or unsubstituted aryl group having 6 to 60 ring-forming carbons, or a substituted or unsubstituted heteroaryl group having 2 to 60 ring-forming carbons. R₄ and R₅ may each independently be a hydrogen atom, a deuterium atom, a cyano group, a hydroxyl group, a substituted or unsubstituted thio group, a substituted or unsubstituted oxy group, a substituted or unsubstituted amine group, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, or a substituted or unsubstituted heteroaryl group having 2 to 30 ring-forming carbons, and/or may each be bonded to an adjacent group to form a ring. n1 may be an integer of 0 to 3, n2 to n5 may each independently be an integer of 0 to 4, and n6 may be an integer of 0 to 8.

In one or more embodiments, Formula 1 may be represented by Formula 2.

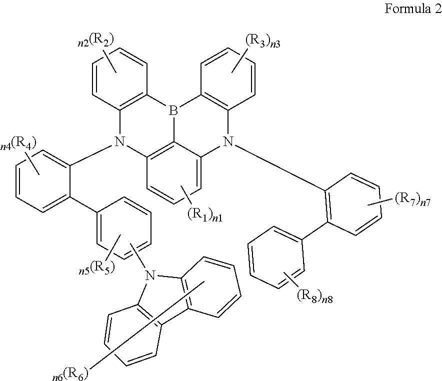

In Formula 2, R₇ and R₈ may each independently be a hydrogen atom, a deuterium atom, a cyano group, a hydroxyl group, a substituted or unsubstituted thio group, a substituted or unsubstituted oxy group, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, or a substituted or unsubstituted heteroaryl group having 2 to 30 ring-forming carbons, and/or may each be bonded to an adjacent group to form a ring. n7 may be an integer of 0 to 4, n8 may be an integer of 0 to 5, and R₁ to R₆, and n1 to n6 may be as defined in Formula 1.

In one or more embodiments, Formula 1 may be represented by Formula 2-A or Formula 2-B.

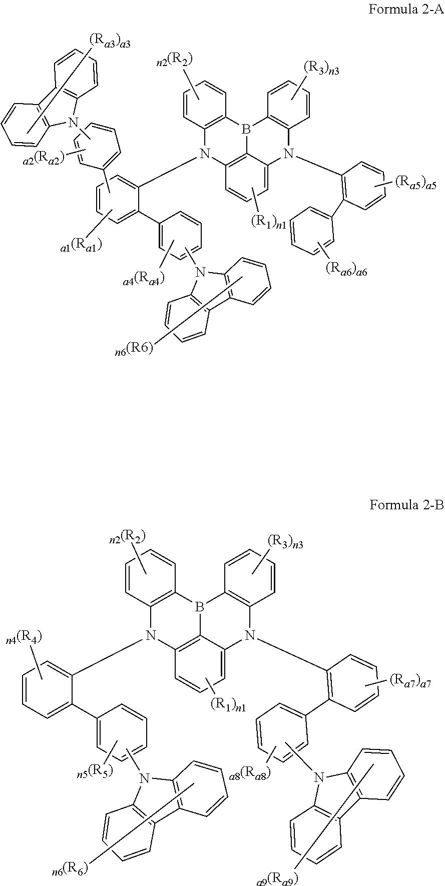

In Formula 2-A and Formula 2-B, Rₐ₁ to Rₐ₆, and Rₐ₉ may each independently be a hydrogen atom, a deuterium atom, a substituted or unsubstituted alkyl group having 1 to 30 carbons, a substituted or unsubstituted aryl group having 6 to 30 ring-forming carbons, or a substituted or unsubstituted heteroaryl group having 2 to 30 ring-forming carbons, Rₐ₇ and Rₐ₈ may each independently be a hydrogen atom, a deuterium atom, a cyano group, a hydroxyl group, a substituted or unsubstituted thio group, a substituted or unsubstituted oxy group, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, or a substituted or unsubstituted heteroaryl group having 2 to 30 ring-forming carbons, and/or may each be bonded to an adjacent group to form a ring. a1 may be an integer of 0 to 3, a2, a4, a5, a7 and a8 may each independently be an integer of 0 to 4, a3 and a9 may each independently be an integer of 0 to 8, a6 may be an integer of 0 to 5, and R₁ to R₆ and n1 to n6 may each independently be the same as defined in Formula 1.

In one or more embodiments, Formula 1 may be represented by Formula 3-1 or Formula 3-2.

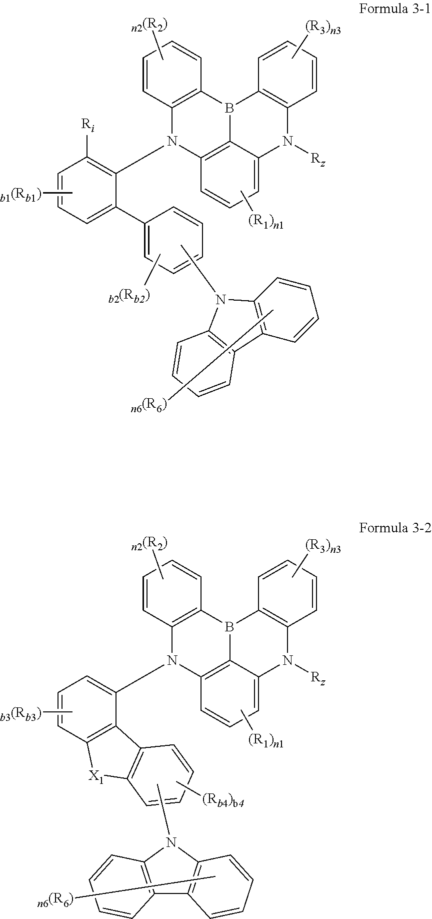

In Formula 3-2, X₁ may be O, S, NRₓ₁ or CRₓ₂Rₓ₃, and

Rₓ₁ to Rₓ₃ may each independently be a hydrogen atom, a deuterium atom, a substituted or unsubstituted alkyl group having 1 to 10 carbons, a substituted or unsubstituted aryl group having 6 to 15 ring-forming carbons. In Formula 3-1 and Formula 3-2 Rᵢ, and R_{b1} to R_{b4} may each independently be a hydrogen atom, a deuterium atom, a substituted or unsubstituted alkyl group having 1 to 30 carbons, or a substituted or unsubstituted aryl group having 6 to 30 ring-forming carbons. b1, b3 and b4 may each independently be an integer of 0 to 3, b2 is an integer of 0 to 4, and R₁ to R₃, R₆, Rz, n1 to n3, and n6 may each independently be as defined in Formula 1.

In one or more embodiments, Formula 3-1 may be represented by Formula 3-1-A:

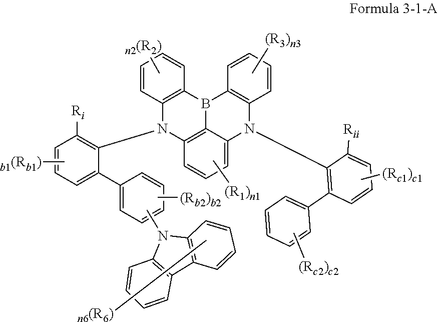

In Formula 3-1-A, Rᵢᵢ, R_{c1}, and R_{c2} may each independently be a hydrogen atom, a deuterium atom, a substituted or unsubstituted alkyl group having 1 to 30 carbons, a substituted or unsubstituted aryl group having 6 to 30 ring-forming carbons, or a substituted or unsubstituted heteroaryl group having 2 to 30 ring-forming carbons. c1 may be an integer of 0 to 3, c2 may be an integer of 0 to 5, and R₁ to R₃, R₆, Rᵢ, R_{b1}, R_{b2}, n1 to n3, n6, b1 and b2 may each independently be as defined in Formula 1 and Formula 3-1.

In one or more embodiments, Formula 3-2 may be represented by Formula 3-2-A.

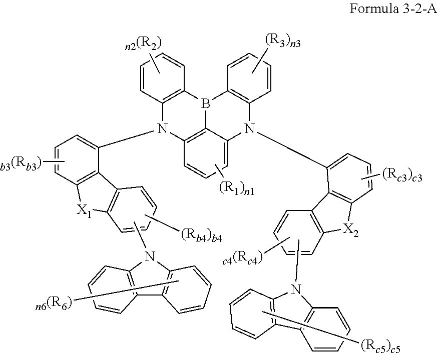

In Formula 3-2-A, X₂ may be O, S, NRₓ₄, or CRₓ₅Rₓ₆, Rₓ₄ to Rₓ₆ may each independently be a hydrogen atom, a deuterium atom, a substituted or unsubstituted alkyl group having 1 to 10 carbons, or a substituted or unsubstituted aryl group having 6 to 15 ring-forming carbons. R_{c3} to R_{c5} may each independently be a hydrogen atom, a deuterium atom, a substituted or unsubstituted alkyl group having 1 to 30 carbons, or a substituted or unsubstituted aryl group having 6 to 30 ring-forming carbons. c3 and c4 may each independently be an integer of 0 to 3, c5 may be an integer of 0 to 8, and X₁, R₁ to R₃, R₆, R_{b3}, R_{b4}, n1 to n3, n6, b3, and b4 may each independently be as defined in Formula 1 and Formula 3-2.

In one or more embodiments, Formula 1 may be represented by Formula 4:

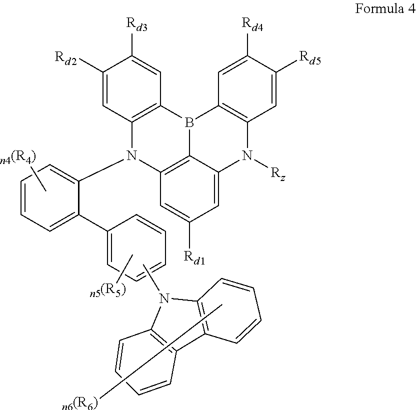

In Formula 4, R_{d1} may be a substituted or unsubstituted alkyl group having 1 to 10 carbons, a substituted or unsubstituted aryl group having 6 to 30 ring-forming carbons, or a substituted or unsubstituted heteroaryl group having 2 to 30 ring-forming carbons. At least one selected from among R_{d2} and R_{d3}, and at least one selected from among R_{d4} and R_{d5} may each independently be a substituted or unsubstituted aryl group having 6 to 30 ring-forming carbons, or a substituted or unsubstituted heteroaryl group having 2 to 30 ring-forming carbons, and any remaining R_{d2}, R_{d3}, R_{d4}, and R_{d5} may each independently be a hydrogen atom, or a deuterium atom, and Rz, R₄ to R₆, and n4 to n6 may each independently be as defined in Formula 1.

In one or more embodiments, at least one among (e.g., selected from among) hydrogen atoms of the first compound represented by Formula 1 may be substituted with a deuterium atom.

In one or more embodiments, the emission layer may be to emit blue light.

In one or more embodiments, the emission layer may further include (e.g., contain) at least one of (e.g., among) a second compound represented by Formula HT-1, a third compound represented by Formula ET-1, or a fourth compound represented by Formula D-1.

In one or more embodiments of the disclosure, a polycyclic compound is represented by Formula 1.

In one or more embodiments of the disclosure, an electric device may comprise a display device. The display device may include a base layer; a circuit layer arranged on the base layer; and a display element layer arranged on the circuit layer and including a light-emitting element, the light-emitting element may include a first electrode, a second electrode opposite to (e.g., facing) the first electrode, and an emission layer arranged between the first electrode and the second electrode and represented by Formula 1.

### BRIEF DESCRIPTION OF THE DRAWINGS

The accompanying drawings are included to provide a further understanding of the preceding and other advantages of the disclosure, and are incorporated in and constitute a part of this specification. The drawings illustrate embodiments of the disclosure and, together with the description, serve to explain principles of the disclosure. In the drawings:

FIG. 1 is a plan view illustrating a display device according to one or more embodiments;

FIG. 2 is a cross-sectional view illustrating a section taken along the line I-I′ in FIG. 1;

FIG. 3 is a cross-sectional view schematically illustrating a light-emitting element according to one or more embodiments;

FIG. 4 is a cross-sectional view schematically illustrating a light-emitting element according to one or more embodiments;

FIG. 5 is a cross-sectional view schematically illustrating a light-emitting element according to one or more embodiments;

FIG. 6 is a cross-sectional view schematically illustrating a light-emitting element according to one or more embodiments;

FIG. 7 is a cross-sectional view schematically illustrating a light-emitting element according to one or more embodiments;

FIG. 8A-8C are each a 3D structure of a polycyclic compound according to one or more embodiments;

FIG. 9 is a cross-sectional view illustrating a display device according to one or more embodiments;

FIG. 10 is a cross-sectional view illustrating a display device according to one or more embodiments;

FIG. 11 is a cross-sectional view illustrating a display device according to one or more embodiments;

FIG. 12 is a cross-sectional view illustrating a display device according to one or more embodiments; and

FIG. 13 is a view illustrating an inside of a vehicle in which a display device according to one or more embodiments is arranged.

### DETAILED DESCRIPTION

The present disclosure may be modified in one or more suitable manners and have many forms, and thus specific embodiments will be exemplified in the drawings and described in more detail in the detailed description of present disclosure. It should be understood, however, that it is not intended to limit the disclosure to the particular forms disclosed, but rather, is intended to cover all modifications, equivalents, and alternatives falling within the spirit and scope of the disclosure.

When explaining each of drawings, like reference numbers are used for referring to like elements, and duplicative descriptions thereof may not be provided. In the accompanying drawings, the dimensions of each structure are exaggeratingly illustrated for clarity of the present disclosure. It will be understood that, although the terms “first,” “second,” and/or the like, may be used herein to describe one or more suitable components, these components should not be limited by these terms. These terms are only used to distinguish one component from another. For example, a first component could be termed a second component, and, similarly, a second component could be termed a first component, without departing from the scope of example embodiments of the disclosure. As used herein, the singular forms, “a,” “an,” and “the” are intended to include the plural forms as well, unless the context clearly indicates otherwise.

In the present application, it will be understood that the terms “comprises,” “comprising,” “comprise,” “includes,” “including “include,” “have” and/or the like specify the presence of features, numbers, steps, operations, component, parts, and/or one or more (e.g., any suitable) combinations thereof disclosed in the specification, but do not exclude the possibility of presence or addition of one or more other features, numbers, steps, operations, component, parts, and/or one or more (e.g., any suitable) combinations thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof. In this context, “consisting essentially of” indicates that any additional components will not materially affect the chemical, physical, optical or electrical properties of the semiconductor film.

In the present application, if (e.g., when) a layer, a film, a region, or a plate is referred to as being “on” or “in an upper portion of” another layer, film, region, or plate, it may be not only “directly on” the layer, film, region, or plate, but intervening layers, films, regions, or plates may also be present. On the contrary to this, if (e.g., when) a layer, a film, a region, or a plate is referred to as being “below”, “in a lower portion of” another layer, film, region, or plate, it can be not only directly under the layer, film, region, or plate, but intervening layers, films, regions, or plates may also be present. In some embodiments, it will be understood that if (e.g., when) a part is referred to as being “on” another part, it can be arranged above the other part, or arranged under the other part as well.

Spatially relative terms, such as “beneath”, “below”, “lower”, “above”, “upper” and/or the like, may be used herein for ease of description to describe one element or feature's relationship to another elements or features as shown in the drawings. It will be understood that the spatially relative terms are intended to encompass different orientations of the device in use or operation in addition to the orientation depicted in the drawings. For example, if the device in the drawings is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

As used herein, the term “and/or” may include any and all combinations of one or more of the associated listed items.

Expressions such as “at least one of,” “one of,” “selected from,” and “selected from among,” when preceding a list of elements, modify the entire list of elements and do not modify the individual elements of the list. For example, throughout the disclosure, the expression “at least one of a, b or c” indicates only a, only b, only c, both (e.g., simultaneously) a and b, both (e.g., simultaneously) a and c, both (e.g., simultaneously) b and c, all of a, b, and c, or variations thereof.

Unless otherwise defined, all terms including chemical, technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

Hereinafter, embodiments of the present disclosure will be described with reference to accompanying drawings in which one or more embodiments of present disclosure are shown. An aspect and a characteristic of the disclosure, and a method of accomplishing these will be apparent referring to one or more embodiments described with reference to the drawings. In this specification, phrases such as “on a plane,” “plan view,” and/or the like indicate viewing a target portion from the top, and the phrase “on a cross-section” indicates viewing a cross-section formed by vertically cutting a target portion from the side.

### Definitions

In the specification, the term “substituted or unsubstituted” may refer to substituted or unsubstituted with at least one substituent selected from among the group consisting of a deuterium atom, a halogen atom, a cyano group, a nitro group, an amino group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In some embodiments, each of the substituents exemplified above may be substituted or unsubstituted. For example, a biphenyl group may be interpreted as an aryl group or a phenyl group substituted with a phenyl group.

In the specification, the phrase “bonded to an adjacent group to form a ring” may refer to that a group is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle.

The hydrocarbon ring and the heterocycle may be monocyclic or polycyclic. In some embodiments, the rings formed by being bonded to each other may be connected to another ring to form a spiro structure.

In the specification, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In some embodiments, two methyl groups in 4,5-dimethylphenanthrene may be interpreted as “adjacent groups” to each other.

In the specification, examples of the halogen atom may include a fluorine atom, a chlorine atom, a bromine atom, or an iodine atom.

In the specification, the alkyl group may be linear or branched. The number of carbons in the alkyl group is 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like, but one or more embodiments of the disclosure are not limited thereto.

In the specification, a cycloalkyl group may refer to a cyclic alkyl group. The number of carbons in the cycloalkyl group is 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and/or the like, but one or more embodiments of the disclosure are not limited thereto.

In the specification, an alkenyl group refers to a hydrocarbon group including at least one carbon double bond in the middle or terminal of an alkyl group having 2 or more carbon atoms. The alkenyl group may be linear or branched. The number of carbon atoms in the alkenyl group is not specifically limited, but is 2 to 30, 2 to 20, or 2 to 10. Examples of the alkenyl group include a vinyl group, a 1-butenyl group, a 1-pentenyl group, a 1,3-butadienyl group, a styrenyl group, a styryl vinyl group, and/or the like, but one or more embodiments of the disclosure are not limited thereto.

In the specification, an alkynyl group refers to a hydrocarbon group including at least one carbon triple bond in the middle or terminal of an alkyl group having 2 or more carbon atoms. The alkynyl group may be linear or branched. Although the number of carbon atoms is not specifically limited, it is 2 to 30, 2 to 20, or 2 to 10.

Specific examples of the alkynyl group may include an ethynyl group, a propynyl group, and/or the like, but are not limited thereto.

In the specification, the hydrocarbon ring group refers to any functional group or substituent derived from an aliphatic hydrocarbon ring. The hydrocarbon ring group may be a saturated hydrocarbon ring group having 5 to 30 or 5 to 20 ring-forming carbon atoms.

In the specification, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 60, 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and/or the like, but one or more embodiments of the disclosure are not limited thereto.

In the specification, the fluorenyl group may be substituted, and two substituents may be bonded to each other to form a spiro structure. Examples of the substituted fluorenyl group are as follows. However, one or more embodiments of the disclosure are not limited thereto.

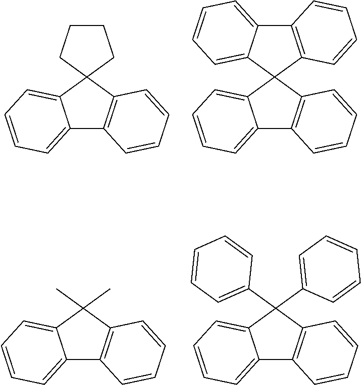

The heterocyclic group herein refers to any functional group or substituent derived from a ring containing at least one of B, O, N, P, Si, S or Se as a heteroatom. The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

In the specification, the heterocyclic group may contain at least one of B, O, N, P, Si, S or Se as a heteroatom. If the heterocyclic group contains two or more heteroatoms, the two or more heteroatoms may be the same as or different from each other. The heterocyclic group may be a monocyclic heterocyclic group or a polycyclic heterocyclic group, and includes a heteroaryl group. The number of ring-forming carbon atoms in the heterocyclic group may be 2 to 60, 2 to 30, 2 to 20, or 2 to 10.

In the specification, the aliphatic heterocyclic group may include at least one of B, O, N, P, Si, S, or Se as a heteroatom. The number of ring-forming carbon atoms in the aliphatic heterocyclic group may be 2 to 60, 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and/or the like, but one or more embodiments of the disclosure are not limited thereto.

In the specification, the heteroaryl group may contain at least one of B, O, N, P, Si, S, or Se as a heteroatom. If the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 60, 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and/or the like, but one or more embodiments of the disclosure are not limited thereto.

In the specification, the description of the aryl group may be applied to an arylene group except that the arylene group is a divalent group. The description of the heteroaryl group may be applied to a heteroarylene group except that the heteroarylene group is a divalent group.

In the specification, the silyl group includes an alkylsilyl group and an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and/or the like, but one or more embodiments of the disclosure are not limited thereto.

In the specification, the number of ring-forming carbon atoms in the carbonyl group is not specifically limited, but may be 1 to 40, 1 to 30, or 1 to 20. For example, the carbonyl group may have the following structures, but one or more embodiments of the disclosure are not limited thereto.

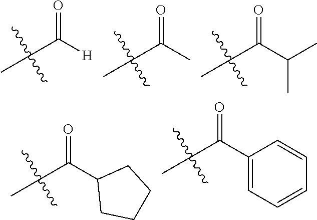

In the specification, the number of carbon atoms in the sulfinyl group and the sulfonyl group is not particularly limited, but may be 1 to 30. The sulfinyl group may include an alkyl sulfinyl group and an aryl sulfinyl group. The sulfonyl group may include an alkyl sulfonyl group and an aryl sulfonyl group.

In the specification, the thio group may include an alkylthio group and an arylthio group. The thio group may refer to that a sulfur atom is bonded to the alkyl group or the aryl group as defined. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but one or more embodiments of the disclosure are not limited thereto.

In the specification, an oxy group may refer to that an oxygen atom is bonded to the alkyl group or the aryl group as defined. The oxy group may include an alkoxy group and an aryl oxy group. The alkoxy group may be a linear chain, a branched chain or a ring chain. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, and/or the like, but one or more embodiments of the disclosure are not limited thereto.

The boron group herein may refer to that a boron atom is bonded to the alkyl group or the aryl group as defined. The boron group includes an alkyl boron group and an aryl boron group. Examples of the boron group may include a dimethylboron group, a trimethylboron group, a t-butyldimethylboron group, a diphenylboron group, a phenylboron group, and/or the like, but one or more embodiments of the disclosure are not limited thereto.

In the specification, the number of carbon atoms in an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, and/or the like, but one or more embodiments of the disclosure are not limited thereto.

In the specification, the alkyl group among an alkylthio group, an alkylsulfoxy group, an alkylaryl group, an alkylamino group, an alkyl boron group, an alkyl silyl group, and an alkyl amine group is the same as the examples of the alkyl group described.

In the specification, the aryl group among an aryloxy group, an arylthio group, an arylsulfoxy group, an arylamino group, an arylboron group, an arylsilyl group, an arylamine group is the same as the examples of the aryl group described.

In the specification, a direct linkage may refer to a single bond.

In one or more embodiments, in the specification,

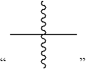

and “-*” refer to a position to be connected.

Hereinafter, embodiments of the disclosure will be described with reference to the accompanying drawings.

### Display Device

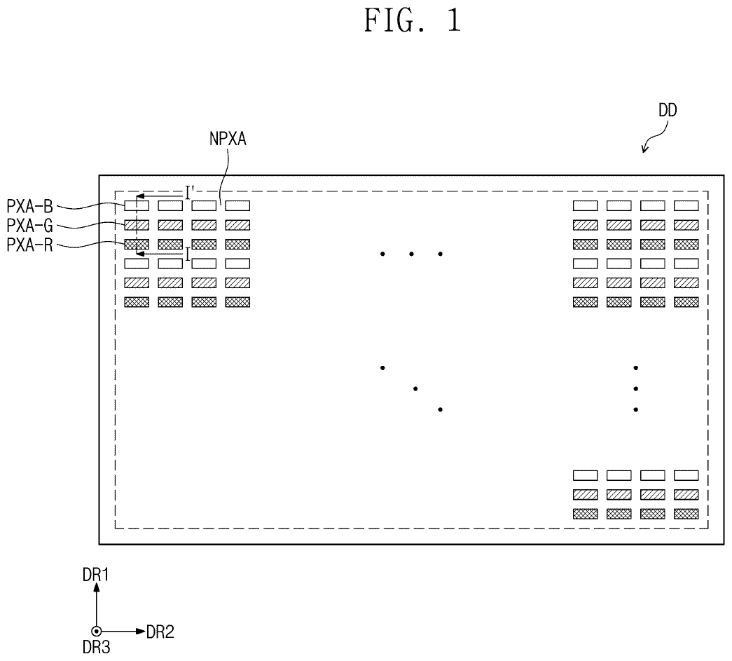

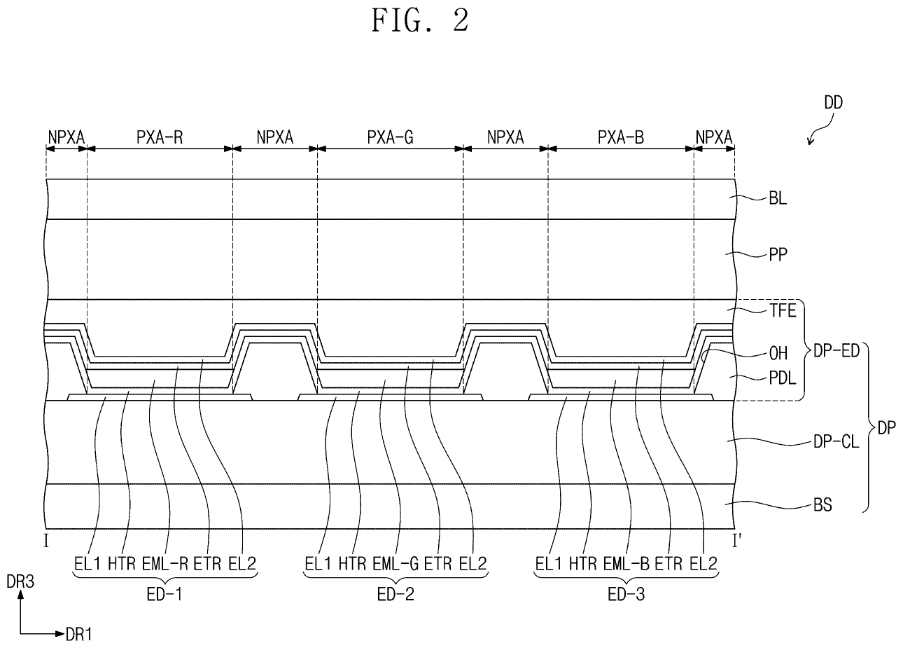

FIG. 1 is a plan view illustrating one or more embodiments of a display device DD. FIG. 2 is a cross-sectional view of the display device DD of the embodiment. FIG. 2 is a cross-sectional view illustrating a part taken along the line I-I′ of FIG. 1.

The display device DD may include a display panel DP and an optical layer PP arranged on the display panel DP. The display panel DP includes light-emitting elements ED-1, ED-2, and ED-3. The display device DD may include a plurality of light-emitting elements ED-1, ED-2, and ED-3. The optical layer PP may be arranged on the display panel DP to control reflected light in the display panel DP due to external light. The optical layer PP may include, for example, a polarization layer or a color filter layer. In one or more embodiments, the optical layer PP may not be provided from the display device DD of one or more embodiments.

A base substrate BL may be arranged on the optical layer PP. The base substrate BL may be a member which provides a base surface on which the optical layer PP arranged. The base substrate BL may be a glass substrate, a metal substrate, a plastic substrate, and/or the like. However, one or more embodiments of the disclosure are not limited thereto, and the base substrate BL may be an inorganic layer, an organic layer, or a composite material layer. In some embodiments, unlike the configuration illustrated, in one or more embodiments, the base substrate BL may not be provided.

The display device DD according to one or more embodiments may further include a filling layer. The filling layer may be arranged between a display device layer DP-ED and the base substrate BL. The filling layer may be an organic material layer.

The filling layer may include at least one of an acrylic-based resin, a silicone-based resin, or an epoxy-based resin.

The display panel DP may include a base layer BS, a circuit layer DP-CL provided on the base layer BS, and the display device layer DP-ED. The display device layer DP-ED may include a pixel defining film PDL, the light-emitting elements ED-1, ED-2, and ED-3 arranged between portions of the pixel defining film PDL, and an encapsulation layer TFE arranged on the light-emitting elements ED-1, ED-2, and ED-3.

The base layer BS may be a member which provides a base surface on which the display device layer DP-ED is arranged. The base layer BS may be a glass substrate, a metal substrate, a plastic substrate, and/or the like. However, one or more embodiments is not limited thereto, and the base layer BS may be an inorganic layer, an organic layer, or a composite material layer.

In one or more embodiments, the circuit layer DP-CL is arranged on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light-emitting elements ED-1, ED-2, and ED-3 of the display device layer DP-ED.

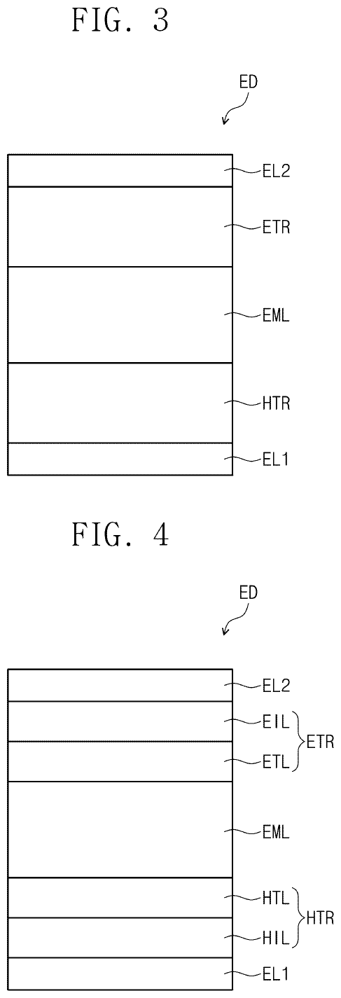

Each of the light-emitting elements ED-1, ED-2, and ED-3 may have a structure of each light-emitting element ED of embodiments according to FIGS. 3 to 6, which will be described in more detail later. Each of the light-emitting elements ED-1, ED-2, and ED-3 may include a first electrode EL1, a hole transport region HTR, emission layers EML-R, EML-G, and EML-B, an electron transport region ETR, and a second electrode EL2.

FIG. 2 illustrates one or more embodiments in which the emission layers EML-R, EML-G, and EML-B of the light-emitting elements ED-1, ED-2, and ED-3 are arranged in openings OH defined in the pixel defining film PDL, and the hole transport region HTR, the electron transport region ETR, and the second electrode EL2 are provided as a common layer in the entire light-emitting elements ED-1, ED-2, and ED-3. However, one or more embodiments of the disclosure are not limited thereto, and unlike the configuration illustrated in FIG. 2, the hole transport region HTR and the electron transport region ETR in one or more embodiments may be provided by being patterned inside the openings OH defined in the pixel defining film PDL. For example, the hole transport region HTR, the emission layers EML-R, EML-G, and EML-B, and the electron transport region ETR of the light-emitting element ED-1, ED-2, and ED-3 in one or more embodiments may be provided by being patterned in an inkjet printing method.

The encapsulation layer TF E may cover the light-emitting elements ED-1, ED-2 and ED-3. The encapsulation layer TF E may seal the display device layer DP-ED. The encapsulation layer TF E may be a thin film encapsulation layer. The encapsulation layer TF E may be formed by laminating one layer or a plurality of layers. The encapsulation layer TF E includes at least one insulation layer. The encapsulation layer TFE according to one or more embodiments may include at least one inorganic film (hereinafter, an encapsulation-inorganic film). The encapsulation layer TFE according to one or more embodiments may also include at least one organic film (hereinafter, an encapsulation-organic film) and at least one encapsulation-inorganic film.

The encapsulation-inorganic film protects the display device layer DP-ED from moisture/oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, and/or the like, but one or more embodiments of the disclosure are not particularly limited thereto. The encapsulation-organic film may include an acrylic-based compound, an epoxy-based compound, and/or the like. The encapsulation-organic film may include a photopolymerizable organic material, but one or more embodiments of the disclosure are not particularly limited thereto.

The encapsulation layer TF E may be arranged on the second electrode EL2 and may be arranged filling the opening OH.

Referring to FIGS. 1 and 2, the display device DD may include one or more non-light emitting region(s) NPXA and also include light emitting regions PXA-R, PXA-G, and PXA-B. The light emitting regions PXA-R, PXA-G, and PXA-B may be regions in which light generated by the respective light-emitting elements ED-1, ED-2, and ED-3 is emitted. The light emitting regions PXA-R, PXA-G, and PXA-B may be spaced and/or apart (e.g., spaced apart or separated) from each other on a plane.

Each of the light emitting regions PXA-R, PXA-G, and PXA-B may be a region divided by the pixel defining film PDL. The non-light emitting regions NPXA may be regions between the adjacent light emitting regions PXA-R, PXA-G, and PXA-B, which correspond to the pixel defining film PDL. In one or more embodiments, in the specification, the light emitting regions PXA-R, PXA-G, and PXA-B may respectively correspond to pixels. The pixel defining film PDL may divide light-emitting elements ED-1, ED-2, and ED-3. The emission layers EML-R, EML-G, and EML-B of the light-emitting elements ED-1, ED-2, and ED-3 may be arranged in openings OH defined in the pixel defining film PDL and separated from each other.

The light emitting regions PXA-R, PXA-G, and PXA-B may be divided into a plurality of groups according to the color of light generated from the light-emitting elements ED-1, ED-2, and ED-3. In the display device DD of one or more embodiments illustrated in FIGS. 1 and 2, three light emitting regions PXA-R, PXA-G, and PXA-B, which emit red light, green light, and blue light, respectively, are exemplarily illustrated. For example, the display device DD of one or more embodiments may include the red light emitting region PXA-R, the green light emitting region PXA-G, and the blue light emitting region PXA-B that are separated from each other.

In the display device DD according to one or more embodiments, the plurality of light-emitting elements ED-1, ED-2 and ED-3 may be to emit light beams having wavelengths different from each other. For example, in one or more embodiments, the display device DD may include a first light-emitting element ED-1 that emits red light, a second light-emitting element ED-2 that emits green light, and a third light-emitting element ED-3 that emits blue light. For example, the red light emitting region PXA-R, the green light emitting region PXA-G, and the blue light emitting region PXA-B of the display device DD may correspond to the first light-emitting element ED-1, the second light-emitting element ED-2, and the third light-emitting element ED-3, respectively.

However, one or more embodiments of the disclosure are not limited thereto, and the first to third light-emitting elements ED-1, ED-2, and ED-3 may be to emit light beams in substantially the same wavelength range or at least one light-emitting element may be to emit a light beam in a wavelength range different from the others. For example, the first to third light-emitting elements ED-1, ED-2, and ED-3 may all emit blue light.

The light emitting regions PXA-R, PXA-G, and PXA-B in the display device DD according to one or more embodiments may be arranged in a stripe form. Referring to FIG. 1, the plurality of red light emitting regions PXA-R may be arranged with each other along a second directional axis DR2, the plurality of green light emitting regions PXA-G may be arranged with each other along the second directional axis DR2, and the plurality of blue light emitting regions PXA-B each may be arranged along the second directional axis DR 2. In some embodiments, the red light emitting region PXA-R, the green light emitting region PXA-G, and the blue light emitting region PXA-B may be alternately arranged in this order along a first directional axis DR1.

FIGS. 1 and 2 illustrate that all the light emitting regions PXA-R, PXA-G, and PXA-B have similar area, but one or more embodiments of the disclosure are not limited thereto. Thus, the light emitting regions PXA-R, PXA-G, and PXA-B may have different areas from each other according to the wavelength range of the emitted light. In this case, the areas of the light emitting regions PXA-R, PXA-G, and PXA-B may refer to areas if (e.g., when) viewed on a plane defined by the first directional axis DR1 and the second directional axis DR2 (e.g., in a plan view). A third directional axis DR3 may be perpendicular to a plane defined by the first directional axis DR1 and the second directional axis DR2.

In one or more embodiments, an arrangement form of the light emitting regions PXA-R, PXA-G, and PXA-B are not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality desired or required in the display device DD. For example, the arrangement form of the light emitting regions PXA-R, PXA-G, and PXA-B may be a pentile (PENTILE®) arrangement form or a diamond (Diamond Pixel®) arrangement form (PENTILE® and Diamond Pixel® are registered trademarks owned by Samsung Display Co., Ltd.).

In some embodiments, the areas of the light emitting regions PXA-R, PXA-G, and PXA-B may be different from each other. For example, in one or more embodiments, the area of the green light emitting region PXA-G may be smaller than that of the blue light emitting region PXA-B, but one or more embodiments of the disclosure are not limited thereto.

Hereinafter, FIG. 3 to FIG. 7 are cross-sectional views schematically showing light-emitting elements according to one or more embodiments. The light-emitting element ED of one or more embodiments may include a first electrode EL1, a hole transport region HTR, an emission layer EML, an electron transport region ETR, and a second electrode EL2 stacked in order (e.g., stacked sequentially).

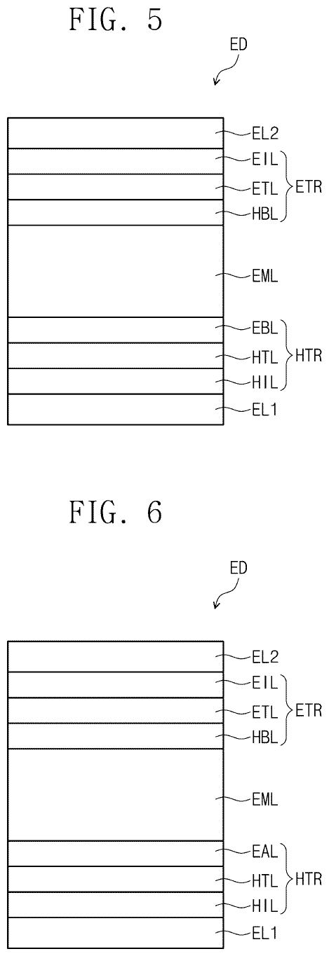

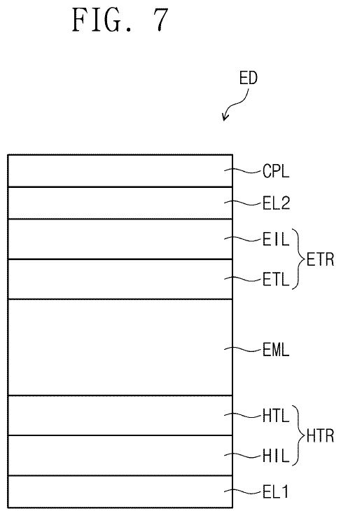

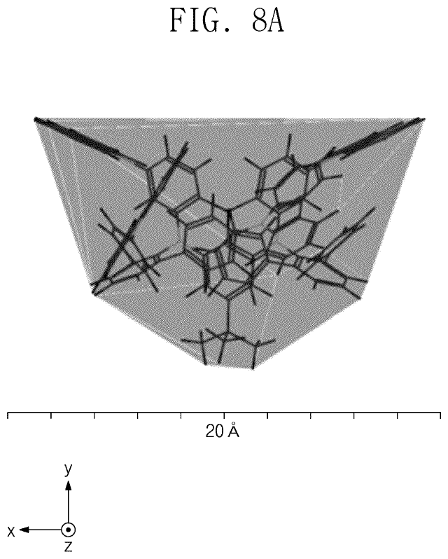

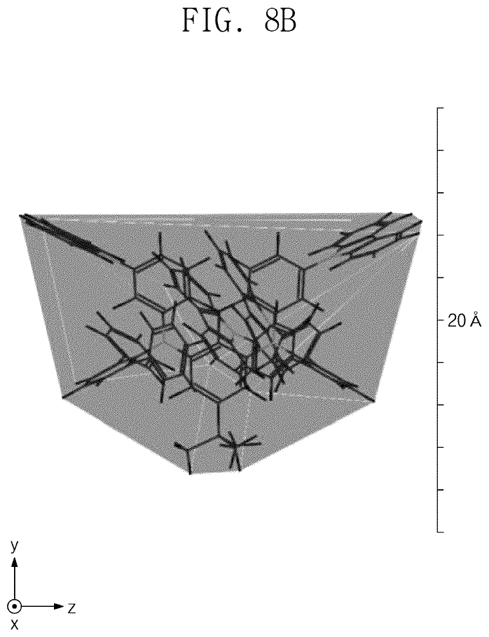

Compared with FIG. 3, FIG. 4 illustrates a cross-sectional view of a light-emitting element ED of one or more embodiments, in which a hole transport region HTR includes a hole injection layer HIL and a hole transport layer HTL, and an electron transport region ETR includes an electron injection layer EIL and an electron transport layer ETL. In some embodiments, compared with FIG. 3, FIG. 5 illustrates a cross-sectional view of a light-emitting element ED of one or more embodiments, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. FIG. 6 illustrates, compared to FIG. 3, a cross-sectional view of a light-emitting element ED in which a hole transport region HTR includes a hole injection layer HIL, a hole transport layer HTL, and an emission auxiliary layer EAL, and an electron transport region ETR includes an electron injection layer EIL, an electron transport layer ETL, and a hole blocking layer HBL. Compared with FIG. 4, FIG. 7 illustrates a cross-sectional view of a light-emitting element ED of one or more embodiments including a capping layer CPL arranged on a second electrode EL2.

The first electrode EL1 has conductivity (e.g., is a conductor). The first electrode EL1 may be formed of a metal material, a metal alloy, or a conductive compound. The first electrode EL1 may be an anode or a cathode. However, one or more embodiments of the disclosure are not limited thereto. In some embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from among these, a mixture of two or more selected from among these, or an oxide thereof.

If the first electrode EL1 is the transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound or mixture thereof (e.g., a mixture of Ag and Mg). In one or more embodiments, the first electrode EL1 may have a multilayer structure including a reflective film or a transflective film formed of the herein-described materials, and a transparent conductive film formed of ITO, IZO, ZnO, ITZO, and/or the like. For example, the first electrode EL1 may have a three-layer structure of ITO/Ag/ITO, but one or more embodiments of the disclosure are not limited thereto. In one or more embodiments of the disclosure, the first electrode EL1 may include the herein-described metal materials, combinations of at least two metal materials of the herein-described metal materials, oxides of the herein-described metal materials, and/or the like. The thickness of the first electrode EL1 may be from about 700 angstrom (Å) to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, a buffer layer or an emission-auxiliary layer, or an electron blocking layer E BL. The thickness of the hole transport region HTR may be, for example, from about 50 Å to about 15,000 Å.

The hole transport region HTR may have a single layer formed of a single material, a single layer formed of a plurality of different materials, or a multilayer structure including a plurality of layers formed of a plurality of different materials.

For example, the hole transport region HTR may have a single layer structure of the hole injection layer HIL or the hole transport layer HTL, or may have a single layer structure formed of a hole injection material and a hole transport material. In some embodiments, the hole transport region HTR may have a single layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order from the first electrode EL1, but one or more embodiments of the disclosure are not limited thereto.

The hole transport region HTR may be formed using one or more suitable methods such as a vacuum deposition method, a spin coating method, a cast method, a Langmuir-Blodgett (LB) method, an inkjet printing method, a laser printing method, and a laser induced thermal imaging (LITI) method.

The hole transport region HTR may include a compound represented by Formula H-1i

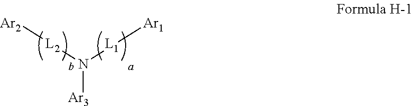

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In one or more embodiments, if (e.g., when) a or b is an integer of 2 or greater, a plurality of L₁'s and L₂'s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-1, Ar₃ may be a substituted or unsubstituted aryl group having 6 to 30 ring-forming carbon atoms, or a substituted or unsubstituted heteroaryl group having 2 to 30 ring-forming carbon atoms.

The compound represented by Formula H-1 may be a monoamine compound. In one or more embodiments, the compound represented by Formula H-1 may be a diamine compound in which at least one among (e.g., selected from among) Ar₁ to Ar₃ includes the amine group as a substituent. In some embodiments, the compound represented by Formula H-1 may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be represented by any one of (e.g., selected from among) the compounds in Compound Group H. However, the compounds listed in Compound Group H are examples, and the compounds represented by Formula H-1 are not limited to those represented by Compound Group H:

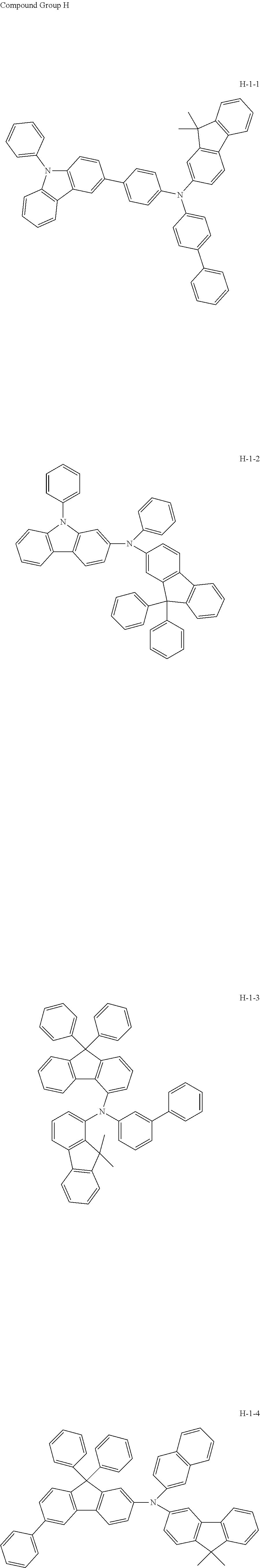 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

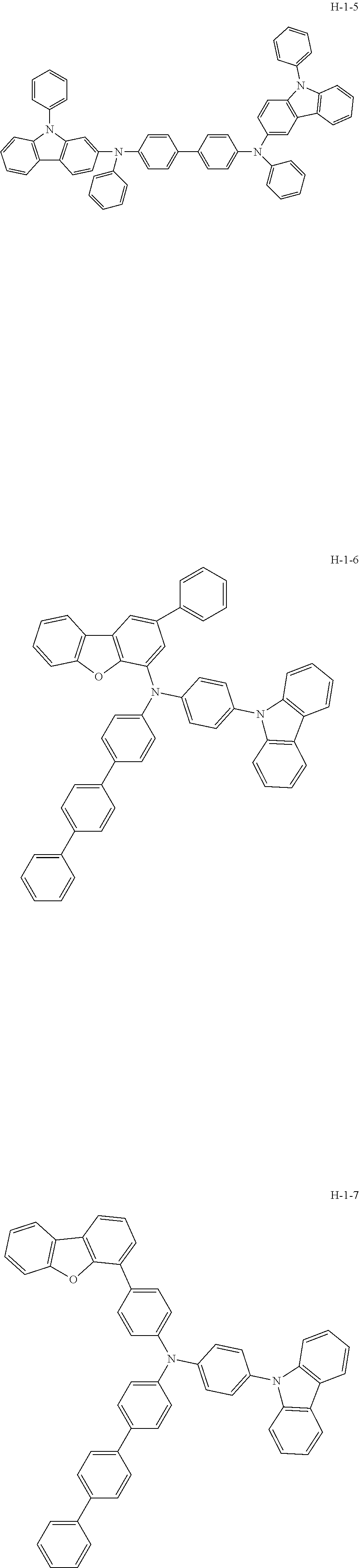 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

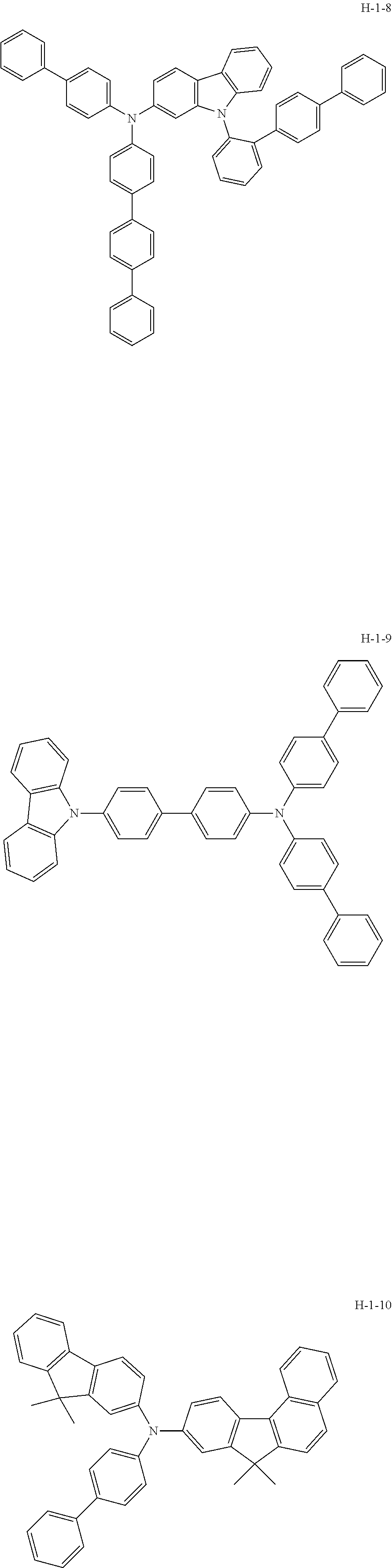 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

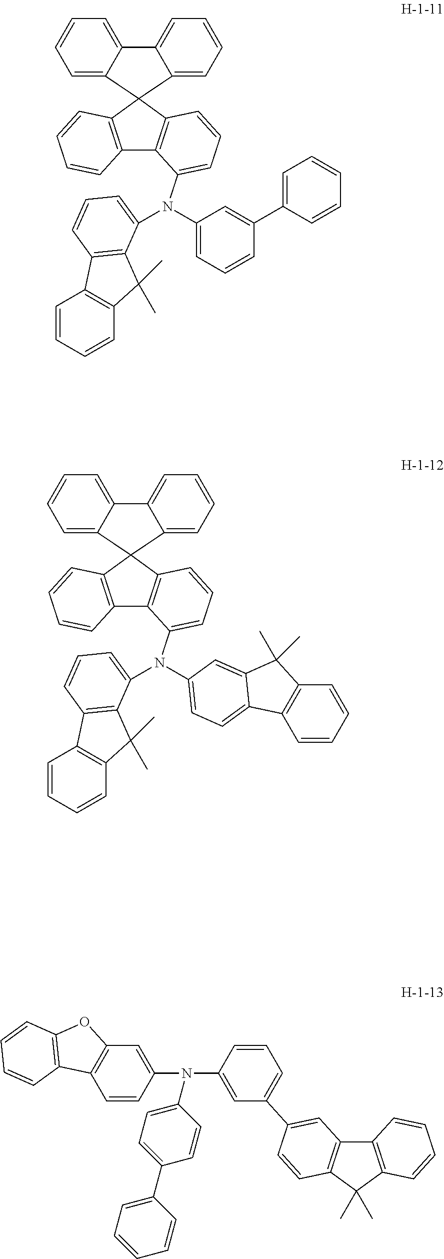 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

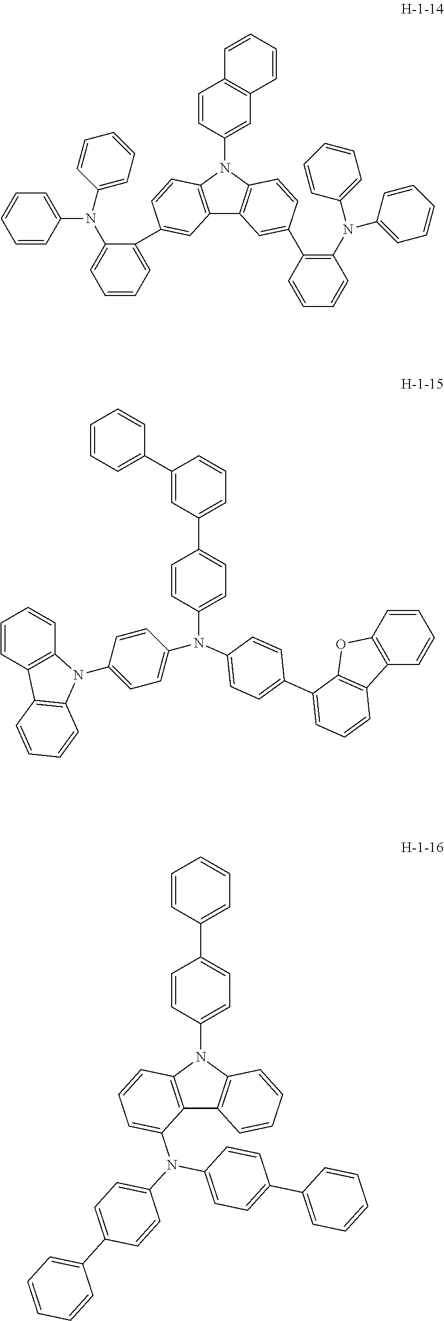 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

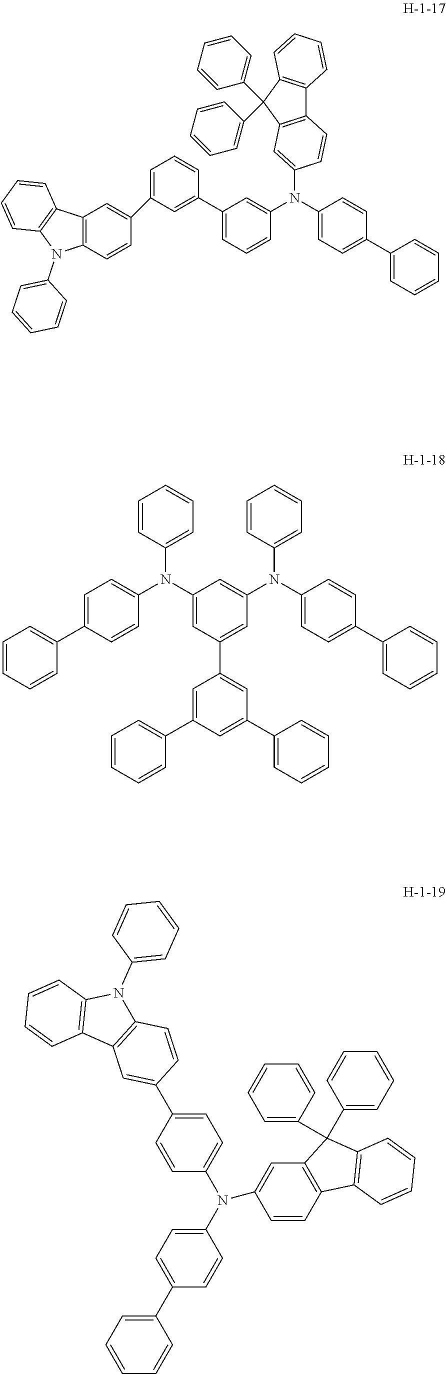 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region H TR may include a phthalocyanine compound such as copper phthalocyanine, N¹,N¹⁺-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N-(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (N PB), triphenylamine-containing polyetherketone (TPAPEQK) 4-isopropyl-4′-methyldiphenyliodonium [tetrakis(pentafluorophenyl)borate], dipyrazino[2,3-f:2′,3′-h]quinoxaline-2,3,6,7,10,11-hexacarbonitrile (HAT-CN), and/or the like.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 1,3-bis(N-carbazolyl)benzene (mCP), and/or the like.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and/or the like.

The hole transport region HTR may include the herein-described compounds of the hole transport region HTR in at least one of a hole injection layer HIL, a hole transport layer HTL, or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 250 Å to about 1,000 Å. For example, if (e.g., when) the hole transport region HTR includes the electron blocking layer EBL, the electron blocking layer EBL may have a thickness of about 10 Å to about 1,000 Å. If the thicknesses of the hole transport region HTR, the hole injection layer HIL, the hole transport layer HTL and the electron blocking layer E BL satisfy the herein-described ranges, satisfactory hole transport properties may be achieved without a substantial increase in driving voltage.

The hole transport region HTR may further include a charge generating material to increase conductivity in addition to the herein-described materials. The charge generating material may be dispersed uniformly (e.g., substantially uniformly) or non-uniformly (e.g., substantially non-uniformly) in the hole transport region HTR. The charge generating material may be, for example, a p-dopant. The p-dopant may include at least one of a halogenated metal compound, a quinone derivative, a metal oxide, or a cyano group-containing compound, but one or more embodiments of the disclosure are not limited thereto. For example, the p-dopant may include a metal halide compound such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like, but one or more embodiments of the disclosure are not limited thereto.

As described herein, the hole transport region HTR may further include, in addition to the hole injection layer HIL and the hole transport layer HTL, at least one among (e.g., selected from among) an emission auxiliary layer EAL and an electron blocking layer E BL. The emission auxiliary layer EAL may compensate for a resonance distance according to a wavelength of emitted light and may adjust a hole charge balance to increase luminous efficiency. In some embodiments, the emission auxiliary layer EAL may contain materials that may be contained in the hole transport region HTR. The electron blocking layer EBL may serve to prevent or reduce electrons from being injected into the hole transport region HTR.

In the light-emitting element ED according to one or more embodiments, the emission layer EML may contain a polycyclic compound according to one or more embodiments. In the light-emitting element ED according to one or more embodiments, the emission layer EML may contain at least one compound among a first compound, which is a polycyclic compound according to one or more embodiments, a second compound, and a third compound. In some embodiments, in the light-emitting element ED according to one or more embodiments, the emission layer EML may further contain a fourth compound. The second compound may include a three-membered fused ring containing a nitrogen atom as a ring-forming atom. The third compound may include a six-membered ring group containing at least one nitrogen atom as a ring-forming atom. The fourth compound may contain an organic metal complex. The second and fourth compounds will be described in more detail later in more detail.

In this specification, the first compound may be referred to as a polycyclic compound according to one or more embodiments. The polycyclic compound according to one or more embodiments includes, as a core structure, a five-membered fused ring containing two nitrogen (N) atoms and one boron (B) atom as ring-forming atoms. In some embodiments, the polycyclic compound according to one or more embodiments may include a biphenyl derivative bonded to the five-membered fused core structure, and a carbazole moiety bonded to the biphenyl derivative. The biphenyl derivative, to which the carbazole moiety is bonded, is a bulky three-dimensional protective substituent and may be bonded to at least one among (e.g., selected from among) the two nitrogen atoms in the five-membered fused core structure. In the polycyclic compound according to one or more embodiments, in which the biphenyl derivative to which the carbazole moiety is bonded to the five-membered fused ring core, host materials and a highest occupied molecular orbital (HOMO) energy level are easily matched, which may contribute to improvements in efficiency and lifespan of the light-emitting element ED. In this specification, the biphenyl derivative includes a biphenyl group substituted with other substituents, a substituted or unsubstituted fluorenyl group, a substituted or unsubstituted carbazole group, a substituted or unsubstituted dibenzofuran group, and a substituted or unsubstituted dibenzothiophene group as well as an unsubstituted biphenyl group

The polycyclic compound according to one or more embodiments includes a bulky substituent and/or the like, and thus may have a three-dimensional molecular shape close to a sphere form. Due to characteristics of the three-dimensional shape of the polycyclic compound according to one or more embodiments, intermolecular aggregation and interaction between the polycyclic compound decreases, and thus the polycyclic compound may exhibit excellent or suitable material stability.

In the polycyclic compound according to one or more embodiments, the five-membered fused ring core structure may be protected by the substituent and/or the like, and thus stability of the polycyclic compound according to one or more embodiments may be improved. For example, in the polycyclic compound according to one or more embodiments, the five-membered fused ring core structure may have a protected molecular form by being surrounded with a bulky substituent and/or the like, and because p-orbitals of a boron (B) atom, in which a bulky substituent and/or the like form the five-membered fused ring core structure, may be well protected, material stability may increase.

In some embodiments, due to the three-dimensional structural characteristics of the polycyclic compound according to one or more embodiments, in which the bulky substituents are connected to the five-membered fused ring core structure, the five-membered fused ring core corresponding to a multi-resonance core where a luminescence-related transition occurs may be protected. In some embodiments, in the polycyclic compound according to one or more embodiments, molecular planarity thereof may be reduced due to the three-dimensional structural characteristics, thus distances between neighboring molecules increase to thereby reduce Dexter energy transition, and a side reaction that is not transition for emission and involves an intermolecular interaction, and/or the like such as triplet annihilation (TTA) and triplet exciton-polaron quenching (TPQ) may decrease to thereby having excellent or suitable stability.

The light-emitting element ED according to one or more embodiments may include the polycyclic compound according to one or more embodiments. The polycyclic compound according to one or more embodiments may be represented by Formula 1.

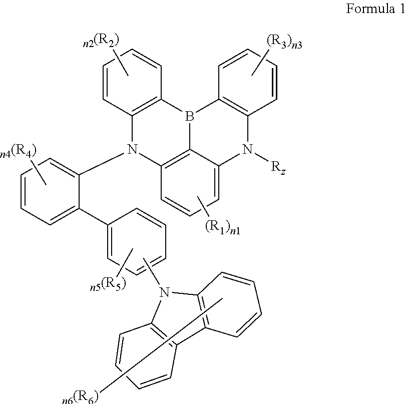

In Formula 1, R₁ to R₃, R₆ and R_{z} may each independently be a hydrogen atom, a deuterium atom, a cyano group, a substituted or unsubstituted alkyl group having 1 to 30 carbons, a substituted or unsubstituted aryl group having 6 to 60 ring-forming carbons, or a substituted or unsubstituted heteroaryl group having 2 to 60 ring-forming carbons.

In one or more embodiments, R₁ to R₃, and R₆ may each independently be a hydrogen atom, a deuterium atom, a substituted or unsubstituted alkyl group having 1 to 10 carbons, a substituted or unsubstituted aryl group having 6 to 30 ring-forming carbons, or a substituted or unsubstituted heteroaryl group having 2 to 30 ring-forming carbons. For example, R₁ to R₃, and R₆ may each independently be a hydrogen atom, a deuterium atom, a substituted or unsubstituted t-butyl group, a substituted or unsubstituted phenyl group, a substituted or unsubstituted biphenyl group, a substituted or unsubstituted terphenyl group, a substituted or unsubstituted carbazole group, a substituted or unsubstituted dibenzofuran group, and/or the like, but the present disclosure is not limited thereto.

In one or more embodiments, R_{z} may be a substituted or unsubstituted aryl group having 6 to 60 ring-forming carbons, or a substituted or unsubstituted heteroaryl group having 2 to 30 ring-forming carbons. For example, R_{z} may be a substituted or unsubstituted biphenyl group, a substituted or unsubstituted terphenyl group, a substituted or unsubstituted quarterphenyl group, a substituted or unsubstituted quinquephenyl group, a substituted or unsubstituted fluorenyl group, a substituted or unsubstituted carbazole group, a substituted or unsubstituted dibenzofuran group, or a substituted or unsubstituted dibenzothiophene group, and/or the like. However, one or more embodiments of the disclosure are not limited thereto.

In Formula 1, a biphenyl group connected to R₄ and R₅ may correspond to the biphenyl derivative described previously. The biphenyl group connected to R₄ and R₅ may be referred to as a first biphenyl derivative.

In Formula 1, R₄ and R₅ may each independently be a hydrogen atom, a deuterium atom, a cyano group, a hydroxyl group, a substituted or unsubstituted thio group, a substituted or unsubstituted oxy group, a substituted or unsubstituted amine group, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, or a substituted or unsubstituted heteroaryl group having 2 to 30 ring-forming carbons, or may be bonded to an adjacent group to form a ring. For example, R₄ and R₅ may each independently be a hydrogen atom, a deuterium atom, a substituted or unsubstituted alkyl group 1 to 10 carbons, or a substituted or unsubstituted aryl group having 6 to 30 ring-forming carbons. For example, R₄ and R₅ may each independently be a hydrogen atom, a deuterium atom, a substituted or unsubstituted t-butyl group, a substituted or unsubstituted phenyl group, or a substituted or unsubstituted biphenyl group. In some embodiments, R₄ and R₅ may be bonded to each other to form a hydrocarbon ring or a hetero ring.

In Formula 1, n1 may be an integer of 0 to 3. If n1 is 0, the polycyclic compound according to one or more embodiments may be unsubstituted with R₁. In Formula 1, if n1 is 3 and three R₁s are all hydrogen atoms may be the same as the case where n1 in Formula 1 is 0. If n1 is an integer of at least 2, R₁s provided in plural may be all the same or at least one among (e.g., selected from among) the plurality of R₁s may be different.

In Formula 1, n2 to n5 may each independently be an integer of 0 to 4. If n2 to n5 are each 0, the polycyclic compound according to one or more embodiments may be unsubstituted with each of R₂ to R₅. In Formula 1, a case where each of n2 to n5 is 4 and each of R₂ to R₅ is a hydrogen atom may be the same as the case where each of n2 to n5 is 0 in Formula 1. If each of n2 to n5 is an integer of at least 2, at least one among (e.g., selected from among) R₂ to R₅ provided in the plurality may be different.

In the polycyclic compound according to one or more embodiments represented by Formula 1, at least one of hydrogen atoms may be substituted with a deuterium atom. For example, in the polycyclic compound represented by Formula 1, in addition to a hydrogen atom of a fused core, a biphenyl derivative, and a carbazole moiety connected to the biphenyl derivative, a hydrogen atom in a substituent substituted for each of the same may be substituted with a deuterium atom.

The polycyclic compound according to one or more embodiments may have a structure in which two biphenyl derivatives are bonded to the five-membered fused ring core structure. The two biphenyl derivatives may be bonded to two nitrogen atoms, respectively. In one or more embodiments, the polycyclic compound represented by Formula 1 may be represented by Formula 2.

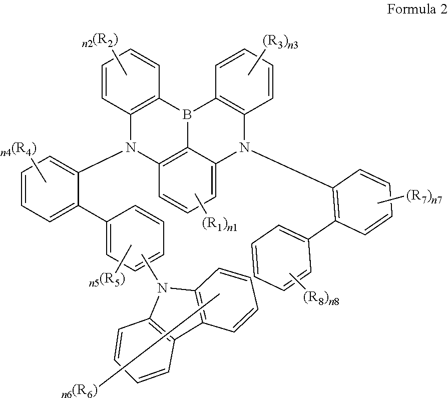

In Formula 2, R₇ and R₈ may each independently be a hydrogen atom, a deuterium atom, a cyano group, a hydroxyl group, a substituted or unsubstituted thio group, a substituted or unsubstituted oxy group, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, or a substituted or unsubstituted heteroaryl group having 2 to 30 ring-forming carbons, or may be bonded to each other to form a ring.

For example, R₇ and R₈ may each independently be a hydrogen atom, a deuterium atom, a substituted or unsubstituted alkyl group having 1 to 10 carbons, a substituted or unsubstituted aryl group having 6 to 20 ring-forming carbons, or a substituted or unsubstituted heteroaryl group having 2 to 20 ring-forming carbons. For example, R₇ and R₈ may each independently be a hydrogen atom, a deuterium atom, a substituted or unsubstituted-t-butyl group, a substituted or unsubstituted phenyl group, a substituted or unsubstituted biphenyl group, or a substituted or unsubstituted carbazole group. In some embodiments, R₇ and R₈ may be bonded to each other to form a hydrocarbon ring, or a hetero ring.

In Formula 2, n7 may be an integer of 0 to 4. If n7 is 0, the polycyclic compound according to one or more embodiments may be unsubstituted with R₇. A case where n7 is 4 and four R₇s are each a hydrogen atom in Formula 2 may be the same as the case where n7 in Formula 2 is 0. If n7 is an integer of at least 2, R₇s provided in the plurality may be the same or at least one among (e.g., selected from among) the plurality of R₇s may be different.

In Formula 2, n8 may be an integer of 0 to 5. If n8 is 0, the polycyclic compound according to one or more embodiments may be unsubstituted with Rs. A case where n8 is 5 and five R₈s are each a hydrogen atom in Formula 2 may be the same as the case where n8 in Formula 2 is 0. If n8 is an integer of at least 2, R₈s provided in the plurality may be the same or at least one among (e.g., selected from among) the plurality of R₈s may be different.

The same descriptions of R₁ to R₆, and n1 to n6 in Formula 1 may be similarly applied to Formula 2.

In one or more embodiments, the polycyclic compound represented by Formula 2 may be represented by Formula 2-A or Formula 2-B. The same descriptions of R₁ to R₆, and n1 to n6 in Formula 1 may be similarly applied to Formula 2-A and Formula 2-B. For example, the same descriptions of R₁ to R₃, R₆, n1 to n3, and n6 in Formula 1 may be similarly applied to Formula 2-A. The same descriptions of R₁ to R₆, and n1 to n6 in Formula 1 may be similarly applied to Formula 2-B.

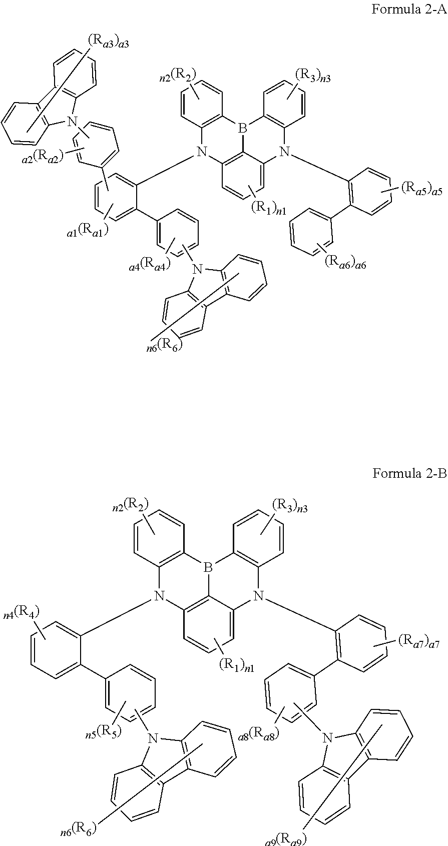

In Formula 2-A and Formula 2-B, Rₐ₁ to Rₐ₆, and Rₐ₉ may each independently be a hydrogen atom, a deuterium atom, a substituted or unsubstituted alkyl group having 1 to 30 carbons, a substituted or unsubstituted aryl group having 6 to 30 ring-forming carbons, or a substituted or unsubstituted heteroaryl group having 2 to 30 ring-forming carbons. For example, Rₐ₁ to Rₐ₆, and Rₐ₉ may each independently be a hydrogen atom, a deuterium atom, a substituted or unsubstituted t-butyl group, a substituted or unsubstituted phenyl group, a substituted or unsubstituted biphenyl group, or a substituted or unsubstituted carbazole group, but the present disclosure is not limited thereto.

In Formula 2-B, Rₐ₇ and Rₐ₈ may each independently be a hydrogen atom, a deuterium atom, a cyano group, a hydroxyl group, a substituted or unsubstituted thio group, a substituted or unsubstituted oxy group, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, or a substituted or unsubstituted heteroaryl group having 2 to 30 ring-forming carbons, or may be bonded to an adjacent group to form a ring. For example, Rₐ₇ and Ras may each independently be a hydrogen atom, a deuterium atom, a substituted or unsubstituted alkyl group having 1 to 10 alkyl group, or a substituted or unsubstituted aryl group having 6 to 20 ring-forming carbons. For example, Rₐ₇ and Rₐ₈ may each independently be a hydrogen atom, a deuterium atom, a substituted or unsubstituted t-butyl group, a substituted or unsubstituted phenyl group, or a substituted or unsubstituted biphenyl group. In some embodiments, Rₐ₇ and Rₐ₈ may be bonded to each other to form a hydrocarbon ring or a hetero ring.

In Formula 2-A and Formula 2-B, a1 may be an integer of 0 to 3, a2, a4, a5, a7 and a8 may each independently be an integer of 0 to 4, a3 and a9 may each independently be an integer of 0 to 8, and a6 may be an integer of 0 to 5.

If each of a1 to a9 is 0, the polycyclic compound according to one or more embodiments may be unsubstituted with each of Rₐ₁ to Rₐ₉. A case where a1 is 3 and three Rₐ₁ are hydrogen atoms may be the same as the case where a1 is 0. Cases where each of a2, a4, a5, a7 and a8 is 4 and four Rₐ₂, four Rₐ₄, four Rₐ₅, four Rₐ₇, and four Ras are hydrogen atoms may be the same as the cases where each of a2, a4, a5, a7 and a8 is 0, respectively. Cases where each of a3 and a9 is 8 and eight Rₐ₃ and eight Rₐ₉ are each hydrogen atoms may be the same as the cases where each of a3 and a9 is 0, respectively. A case where a6 is 5 and five Rₐ₆ are hydrogen atoms may be the same as the case where a6 is 0. If each of a1 to a9 is an integer of at least 2, each of Rₐ₁ to Rₐ₉ provided in plurality may be the same, or at least one among (e.g., selected from among) the plurality of Rₐ₁ to Rₐ₉ may be different.

In one or more embodiments, the polycyclic compound represented by Formula 1 may be represented by Formula 3-1 or Formula 3-2. the same descriptions of R₁ to R₃, R₆, R_{z}, n1 to n3, and n6 in Formula 1 may be similarly applied in Formula 3-1 and Formula 3-2.

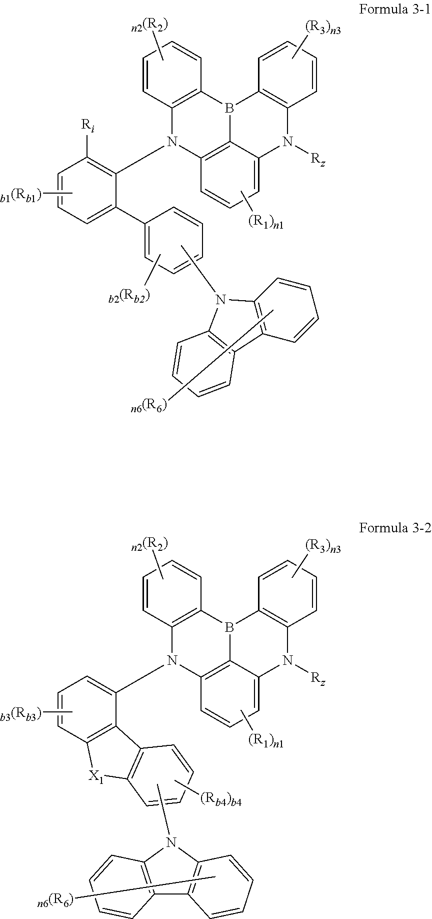

In Formula 3-2, X₁ may be O, S, NRₓ₁ or CRₓ₂Rₓ₃. Rₓ₁ to Rₓ₃ may each independently be a hydrogen atom, a deuterium atom, a substituted or unsubstituted alkyl group having 1 to 10 carbons, or a substituted or unsubstituted aryl group having 6 to 15 ring-forming carbons. In one or more embodiments, Rₓ₁ may be a hydrogen atom, a deuterium atom, or a substituted or unsubstituted aryl group having 6 to 15 ring-forming carbons. For example, Rₓ₁ may be a substituted or unsubstituted phenyl group, but one or more embodiments of the disclosure are not limited thereto. In one or more embodiments, Rₓ₂ and Rₓ₃ may each independently be a hydrogen atom, a deuterium atom, or a substituted or unsubstituted alkyl group having 1 to 10 carbons. For example, Rₓ₂ and Rₓ₃ may each independently be methyl group, but the present disclosure is not limited thereto.

In Formula 3-1 and Formula 3-2, Rᵢ, and R_{b1} to R_{b4} may each independently be a hydrogen atom, a deuterium atom, a substituted or unsubstituted alkyl group having 1 to 30 carbons, or a substituted or unsubstituted aryl group having 6 to 30 ring-forming carbons. In one or more embodiments, R₁ may be a hydrogen atom, a deuterium atom, or a substituted or unsubstituted aryl group having 6 to 20 ring-forming carbons. For example, R₁ may be a hydrogen atom, a deuterium atom, or an unsubstituted phenyl group, a phenyl group substituted with a carbazole group, but the present disclosure is not limited thereto.

In one or more embodiments, R_{b1} to R_{b4} may each independently be a hydrogen atom, a deuterium atom, a substituted or unsubstituted alkyl group having 1 to 10 carbons, or a substituted or unsubstituted aryl group having a ring-forming carbons of 6 to 20. For example, R_{b1} to R_{b4} may each independently be a hydrogen atom, a deuterium atom, a substituted or unsubstituted t-butyl group, a substituted or unsubstituted phenyl group, and/or the like, but the present disclosure is not limited thereto.

In Formula 3-1 and Formula 3-2, b1, b3, and b4 may each independently be an integer of 0 to 3, b2 may be an integer of 0 to 4. If each of b1 to b4 is 0, the polycyclic compound according to one or more embodiments may be unsubstituted with each of R_{b1} to R_{b4}. Cases where each b1, b3, and b4 are 3 and three R_{b1}, three R_{b3}, and three R_{b4} are all hydrogen atoms may be the same as the cases where b1, b3, and b4 are each 0. A case where b2 are 4 and four R_{b2} are all hydrogen atoms may be the same as the case where b2 is 0. If each of b1 to b4 is an integer of at least 2, each of R_{b1} to R_{b4} provided in plurality may be the same, or at least one among (e.g., selected from among) the plurality of R_{b1} to R_{b4} may be different.

In one or more embodiments, the polycyclic compound represented by Formula 3-1 may be represented by Formula 3-1-A. In Formula 3-1-A, the same descriptions of R₁ to R₃, R₆, Rᵢ, R_{b1}, R_{b2}, n1 to n3, n6, b1 and b2 in Formula 1 and Formula 3-1 may be similarly applied to Formula 3-1-A.

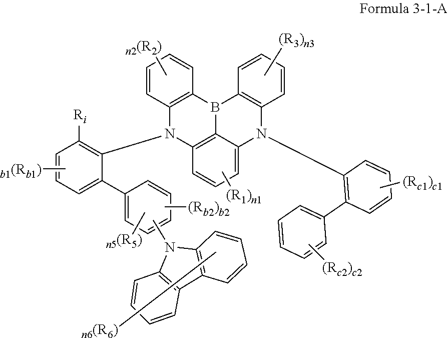

In Formula 3-1-A, Rᵢᵢ, R_{c1}, and R_{c2} may each independently be a hydrogen atom, a deuterium atom, a substituted or unsubstituted alkyl group having 1 to 30 carbons, a substituted or unsubstituted aryl group having 6 to 30 ring-forming carbons, or a substituted or unsubstituted heteroaryl group having 2 to 30 ring-forming carbons. In one or more embodiments, Rᵢᵢ may be a hydrogen atom, a deuterium atom, a substituted or unsubstituted aryl group having 6 to 20 ring-forming carbons. For example, Rᵢᵢ may be a hydrogen atom, a deuterium atom, an unsubstituted phenyl group, a phenyl group substituted with a carbazole group, and/or the like, but one or more embodiments of the disclosure are not limited thereto.

In one or more embodiments, R_{c1} and R_{c2} may each independently be a hydrogen atom, a deuterium atom, a substituted or unsubstituted alkyl group having 1 to 10 carbons, a substituted or unsubstituted aryl group having 6 to 20 ring-forming carbons, or a substituted or unsubstituted heteroaryl group having 2 to 20 ring-forming carbons. For example, R_{c1} and R_{c2} may each independently be a hydrogen atom, a deuterium atom, a substituted or unsubstituted t-butyl group, a substituted or unsubstituted phenyl group, a substituted or unsubstituted carbazole group, and/or the like, but the present disclosure is not limited thereto.

In Formula 3-1-A, c1 may be an integer of 0 to 3, c2 may be an integer of 0 to 5. If c1 and c2 are each 0, the polycyclic compound according to one or more embodiments may be unsubstituted with each of R_{c1} and R_{c2}. A case c1 is 3 and three R_{c1} are all hydrogen atoms may be the same as the case where c1 is 0. A case c2 is 5 and five R_{c2} are all hydrogen atoms may be the same as the case where c2 is 0.

In one or more embodiments, the polycyclic compound represented by Formula 3-2 may be represented by Formula 3-2-A. The same descriptions of X₁, R₁ to R₃, R₆, R_{b3}, R_{b4}, n1 to n3, n6, b3 and b4 in Formula 1 and Formula 3-2 may be similarly applied to Formula 3-2-A.

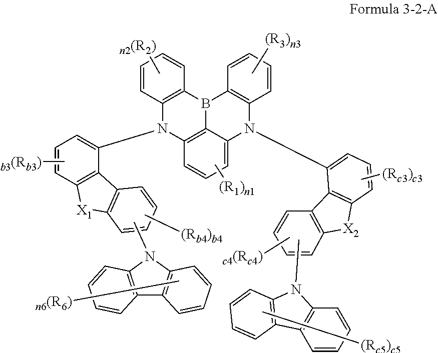

In Formula 3-2-A, X₂ may be O, S, NRₓ₄, or CRₓ₅Rₓ₆. X₂ may be the same as X₁, or may be different from each other.

In Formula 3-2-A, Rₓ₄ to Rₓ₆ may each independently be a hydrogen atom, a deuterium atom, a substituted or unsubstituted alkyl group having 1 to 10 carbons, or a substituted or unsubstituted aryl group having 6 to 15 ring-forming carbons. In one or more embodiments, Rₓ₄ may be a hydrogen atom, a deuterium atom, or a substituted or unsubstituted aryl group having 6 to 15 ring-forming carbons. For example, Rₓ₄ may be a substituted or unsubstituted phenyl group, but one or more embodiments of the disclosure are not limited thereto. In one or more embodiments, Rₓ₅ and Rₓ₆ may each independently be a hydrogen atom, a deuterium atom, or a substituted or unsubstituted alkyl group having 1 to 10 carbons. For example, Rₓ₅ and Rₓ₆ may each independently be an unsubstituted methyl group, but one or more embodiments of the disclosure are not limited thereto.

In Formula 3-2-A, R_{c3} to R_{c5} may each independently be a hydrogen atom, a deuterium atom, a substituted or unsubstituted alkyl group having 1 to 30 carbons, or a substituted or unsubstituted aryl group having 6 to 30 ring-forming carbons. For example, R_{c3} to R_{c5} may each independently be a hydrogen atom or a deuterium atom, but one or more embodiments of the disclosure are not limited thereto.

In Formula 3-2-A, c3 and c4 may each independently be an integer of 0 to 3, and c5 may be an integer of 0 to 8. If each of c3 to c5 is 0, the polycyclic compound according to one or more embodiments may be unsubstituted with each of R_{c3} to R_{c5}. Cases where each of c3 and c4 is 3, and three R_{c3} and three R_{c4} are all hydrogen atoms, respectively, may be the same as the cases where each of c3 and c4 is 0. A case where c5 is 8, and eight R_{c5} are all hydrogen atoms may be the same as the case where c5 is 0. If each of c3 and c5 is an integer of at least 2, R_{c3} to R_{c5} provided in plurality may be the same or at least one among (e.g., selected from among) the plurality of R_{c3} to R_{c5} may be different.

In one or more embodiments, the polycyclic compound represented by Formula 1 may be represented by Formula 4. The same descriptions of R_{z}, R₄ to R₆, and n4 to n6 in Formula 1 may be applied in Formula 4.

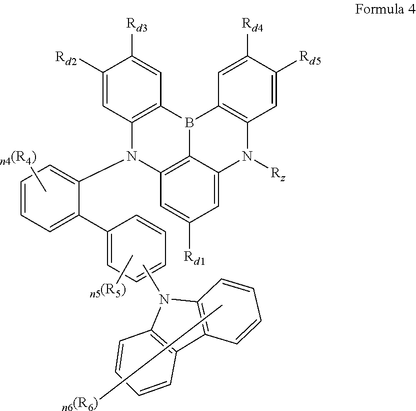

In Formula 4, R_{d1} may be a substituted or unsubstituted alkyl group having 1 to 10 carbons, a substituted or unsubstituted aryl group having 6 to 30 ring-forming carbons, or a substituted or unsubstituted heteroaryl group having 2 to 30 ring-forming carbons. F or example, R_{d1} may be a substituted or unsubstituted t-butyl group, a substituted or unsubstituted phenyl group, a substituted or unsubstituted carbazole group, or a substituted or unsubstituted dibenzofuran group.

In Formula 4, at least one among (e.g., selected from among) R_{d2} and R_{d3}, and at least one among (e.g., selected from among) R_{d4} and R_{d5} may be a substituted or unsubstituted aryl group having 6 to 30 ring-forming carbons, or a substituted or unsubstituted heteroaryl group having 2 to 30 ring-forming carbons, and the remaining may each independently be a hydrogen atom or a deuterium atom. In one or more embodiments, at least one among (e.g., selected from among) R_{d2} and R_{d3} may be a substituted or unsubstituted aryl group having 6 to 30 ring-forming carbons, or a substituted or unsubstituted heteroaryl group having 2 to 30 ring-forming carbons, and the other among R_{d2} and R_{d3} may be a hydrogen atom or a deuterium atom. In some embodiments, one among (e.g., selected from among) R_{d4} and R_{d5} may be a substituted or unsubstituted aryl group having 6 to 30 ring-forming carbons, or a substituted or unsubstituted heteroaryl group having 2 to 30 ring-forming carbons, and the other among R_{d4} and R_{d5} may be a hydrogen atom or a deuterium atom.

For example, R_{d2} and R_{d5} may each independently be a substituted or unsubstituted aryl group having 6 to 30 ring-forming carbons, or a substituted or unsubstituted heteroaryl group having 2 to 30 ring-forming carbons. R_{d2} and R_{d5} may be the same as or may be different from each other. R_{d2} and R_{d5} may each independently be a substituted or unsubstituted phenyl group, a substituted or unsubstituted biphenyl group, a substituted or unsubstituted terphenyl group, or a substituted or unsubstituted carbazole group. R_{d3} and R_{d4} may each independently be a hydrogen atom, or a deuterium atom. R_{d3} and R_{d4} may be the same as or may be different from each other.

For example, R_{d3} and R_{d5} may each independently be a substituted or unsubstituted aryl group having 6 to 30 ring-forming carbons, or a substituted or unsubstituted heteroaryl group having 2 to 30 ring-forming carbons. R_{d3} and R_{d5} may be the same as or may be different from each other. R_{d3} and R_{d5} may each independently be a substituted or unsubstituted phenyl group, a substituted or unsubstituted biphenyl group, a substituted or unsubstituted terphenyl group, or a substituted or unsubstituted carbazole group. R_{d2} and R_{d4} may each independently be a hydrogen atom, or a deuterium atom. R_{d2} and R_{d4} may be the same as or may be different from each other.

The polycyclic compound represented by Formula 1 and/or the like may include at least one biphenyl derivative to which a carbazole moiety is bonded, and thus the five-membered fused ring core may be protected. In the polycyclic compound according to one or more embodiments, a biphenyl derivative may be bonded to at least one among (e.g., selected from among) two nitrogen atoms of the five-membered fused ring core, because the carbazole moiety may be additionally bonded to the biphenyl derivative, thereby including a bulky substituent, which results in a decrease in an intermolecular interaction between the polycyclic compounds, and thus excellent or suitable material stability may be exhibited. Due to this, the polycyclic compound according to one or more embodiments may contribute to implement of improvements in high efficiency and long lifespan of the light-emitting element ED.

The polycyclic compound according to one or more embodiments may be represented by any one among (e.g., selected from among) compounds present in Compound Group 1. The light-emitting element ED may include at least one among (e.g., selected from among) compounds among Compound Group 1. The light-emitting element ED may include at least one among (e.g., selected from among) the compounds in Compound Group 1 in the emission layer EML. In Compound Group 1, D is a deuterium atom.

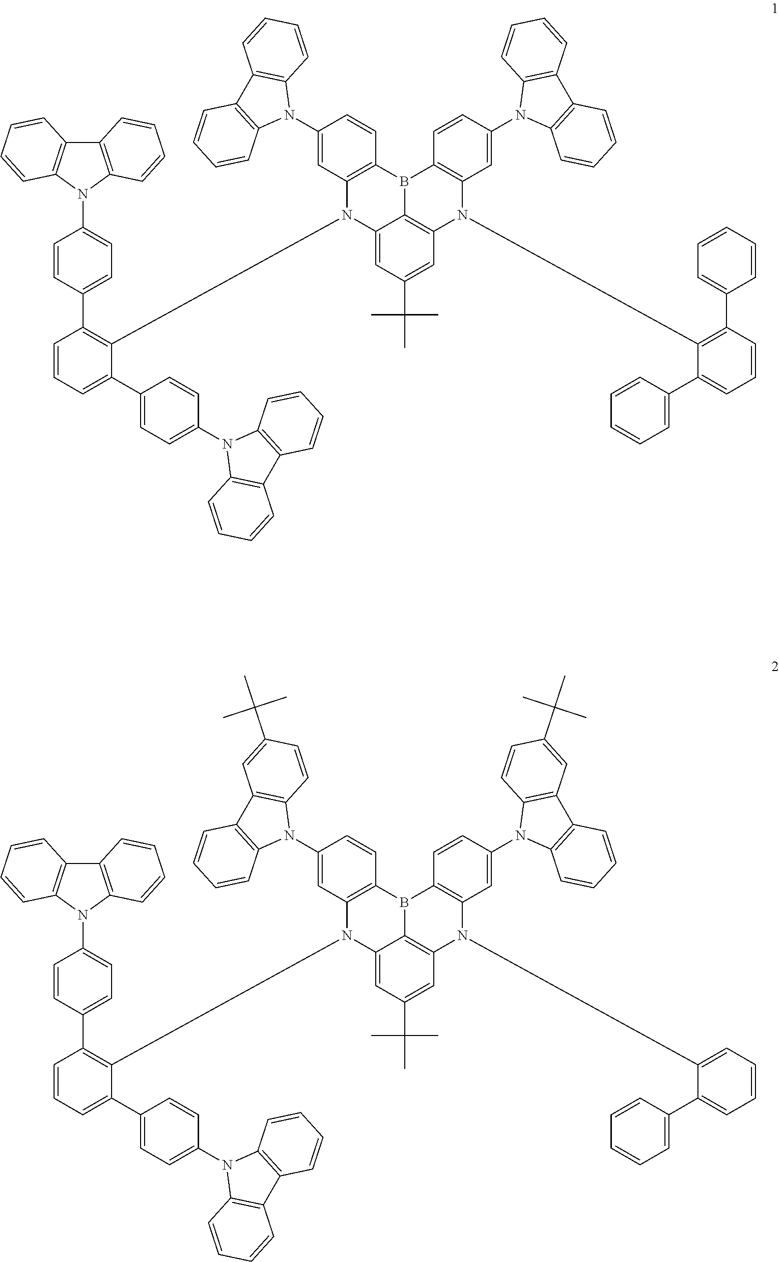 [SMILES: CC(C)(C)c1cc2c3c(c1)N(c1c(-c4ccc(-n5c6ccccc6c6ccccc65)cc4)cccc1-c1ccc(-n4c5ccccc5c5ccccc54)cc1)c1cc(-n4c5ccccc5c5ccccc54)ccc1B3c1ccc(-n3c4ccccc4c4ccccc43)cc1N2c1c(-c2ccccc2)cccc1-c1ccccc1 ; CC(C)(C)c1cc2c3c(c1)N(c1c(-c4ccc(-n5c6ccccc6c6ccccc65)cc4)cccc1-c1ccc(-n4c5ccccc5c5ccccc54)cc1)c1cc(-n4c5ccccc5c5cc(C(C)(C)C)ccc54)ccc1B3c1ccc(-n3c4ccccc4c4cc(C(C)(C)C)ccc43)cc1N2c1ccccc1-c1ccccc1]

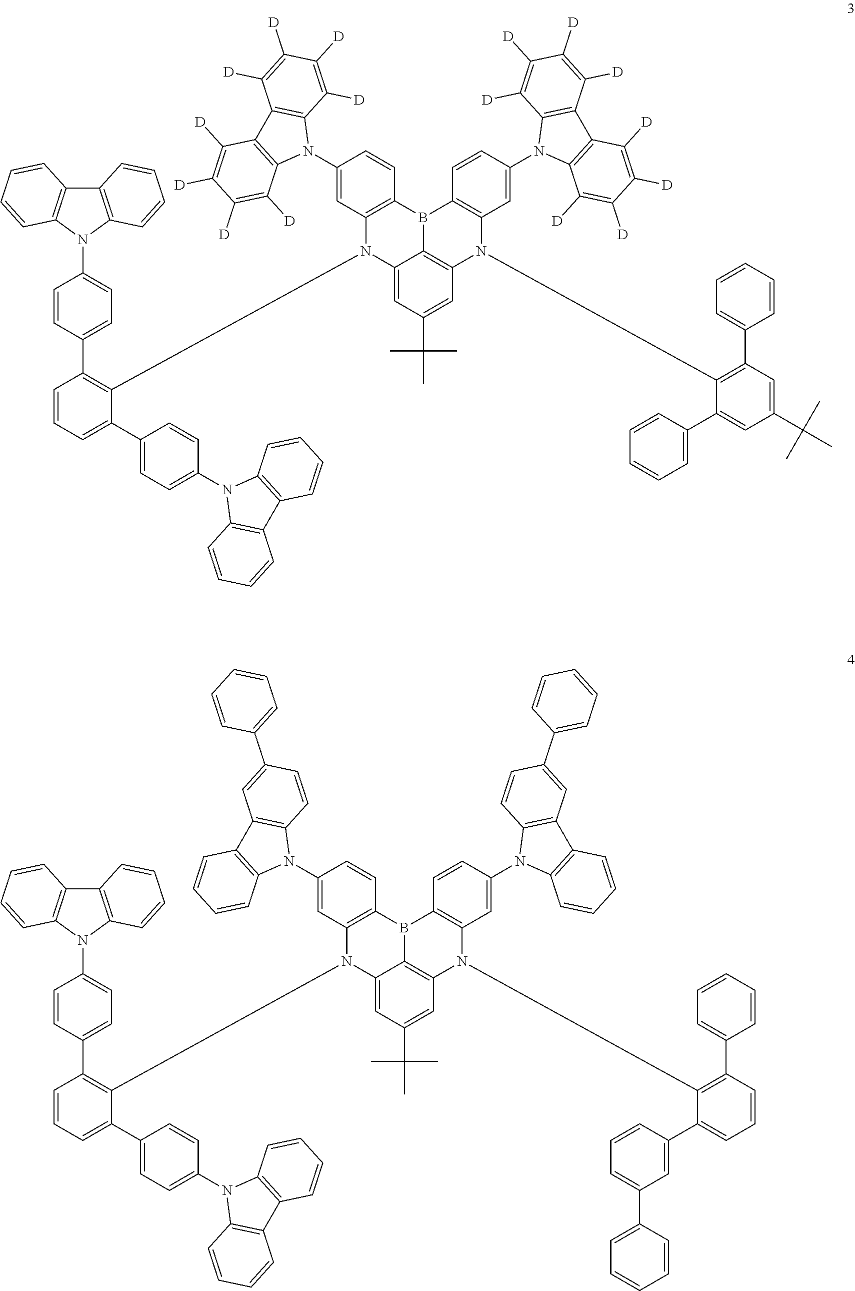

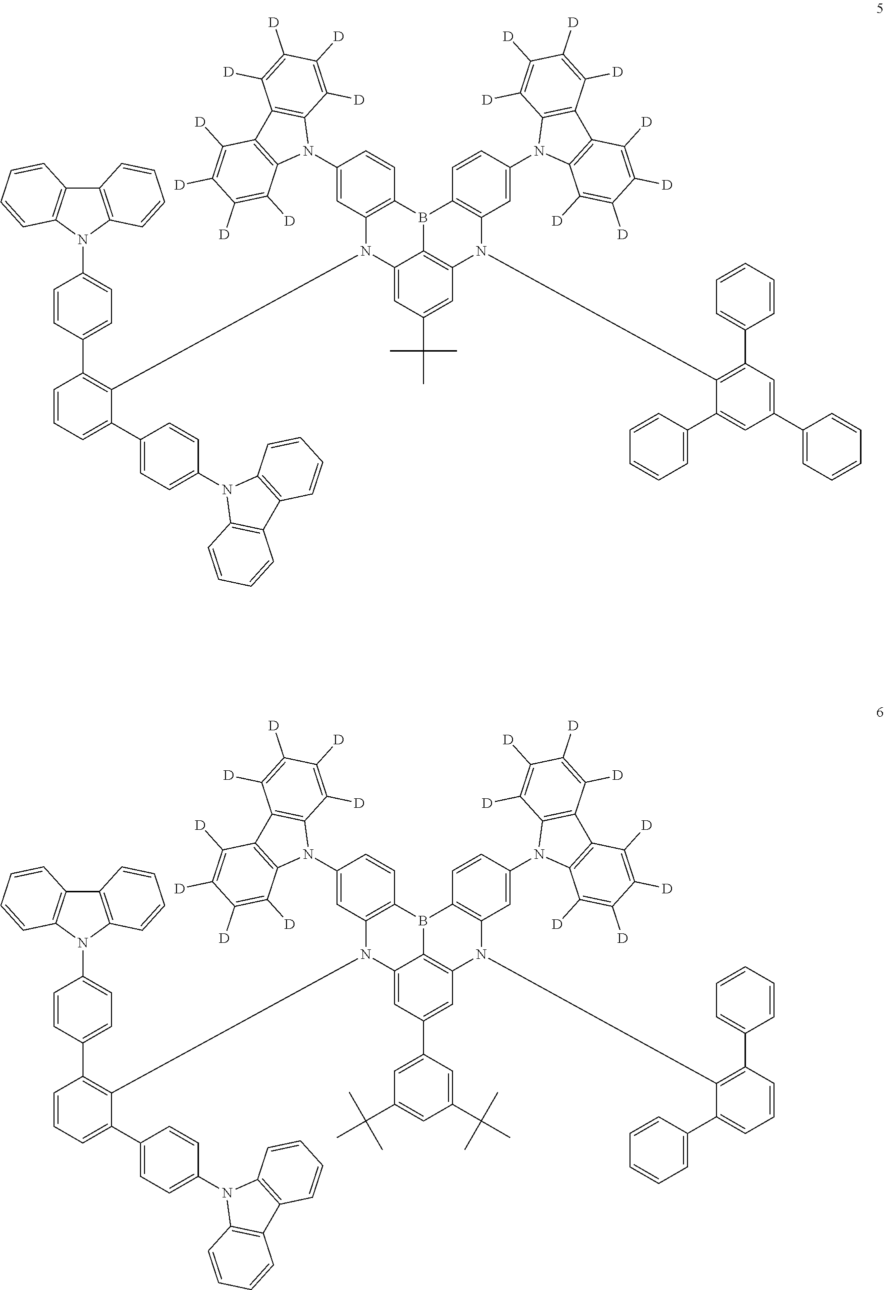

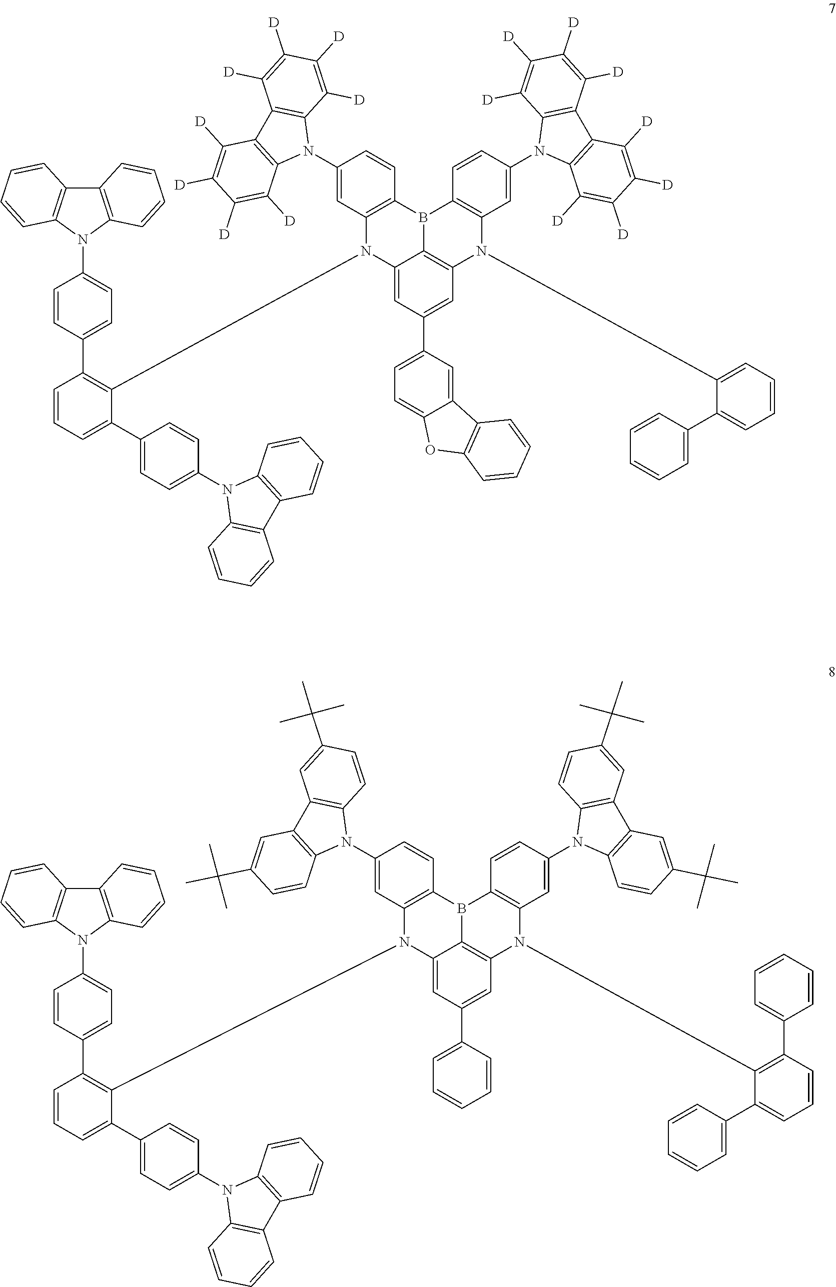

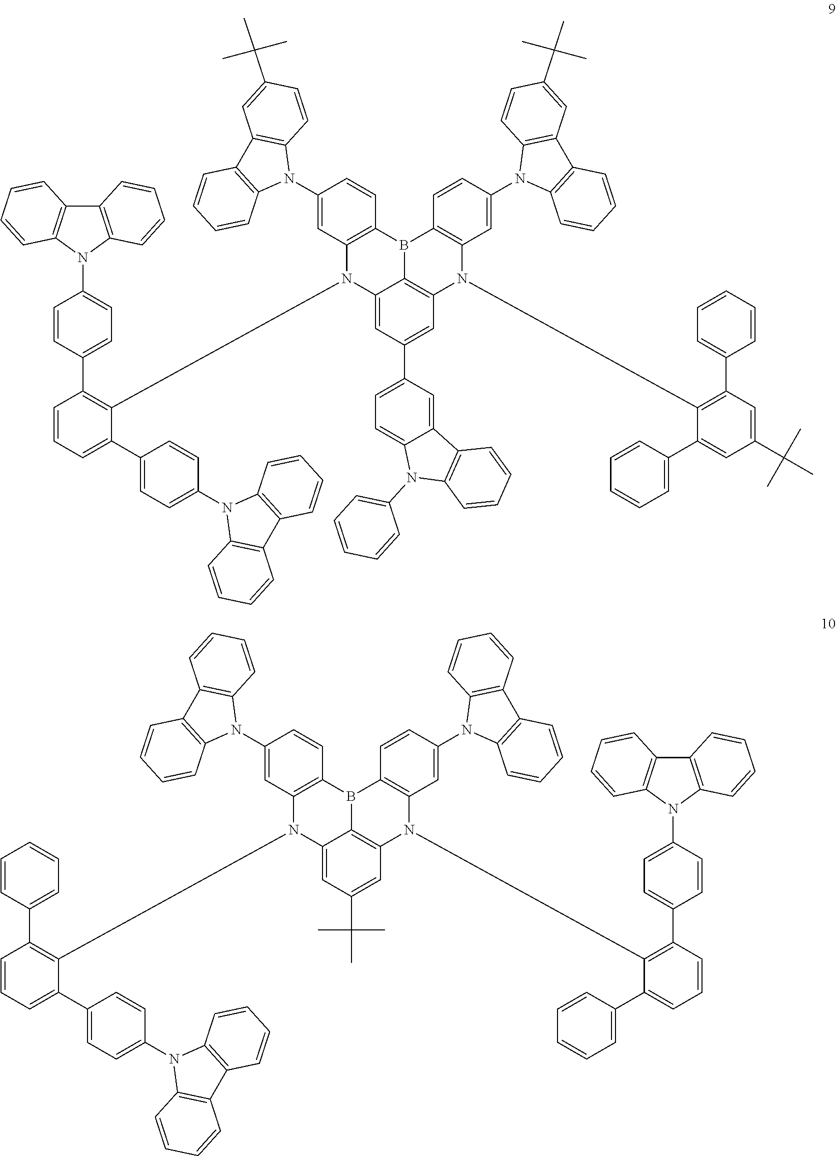

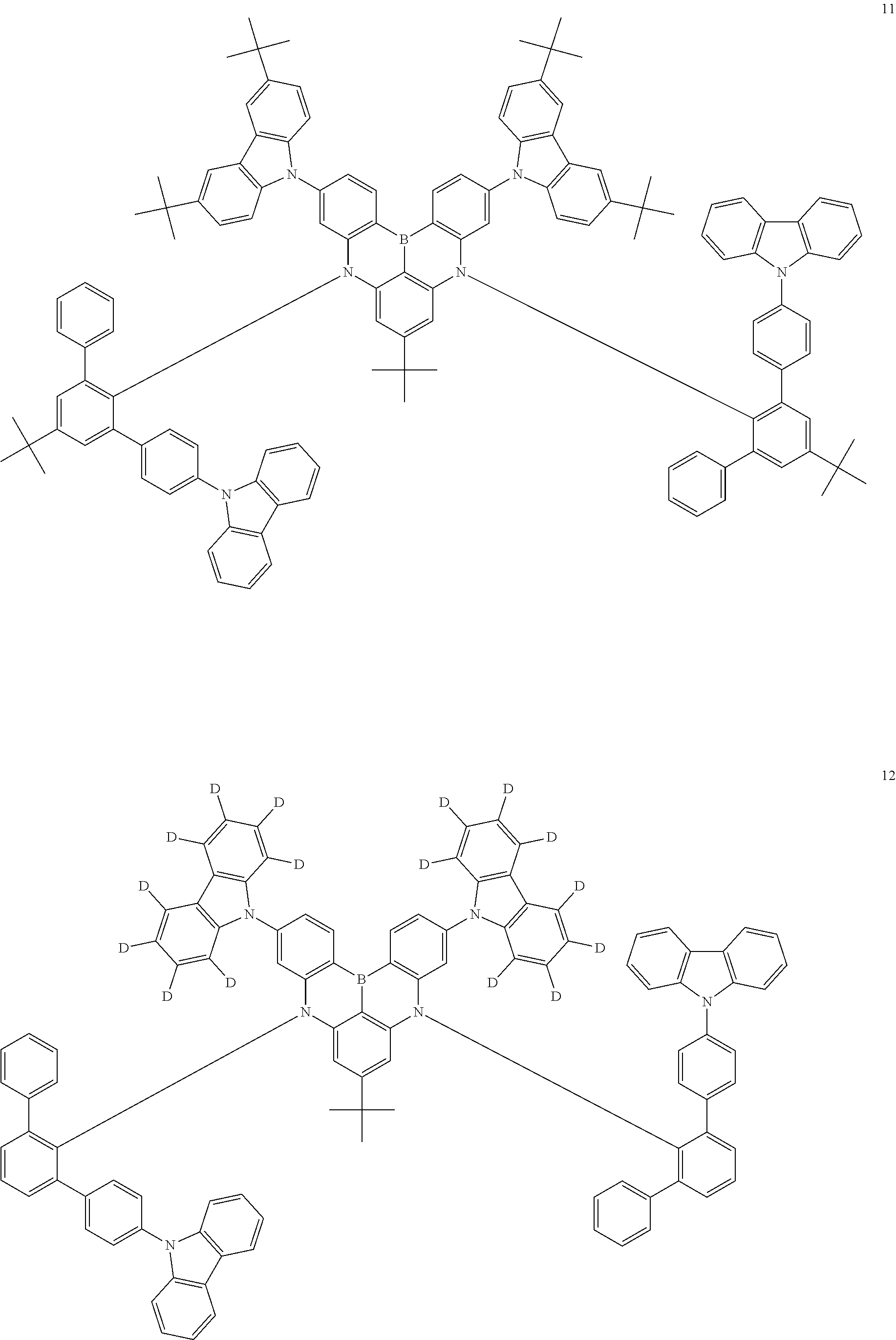

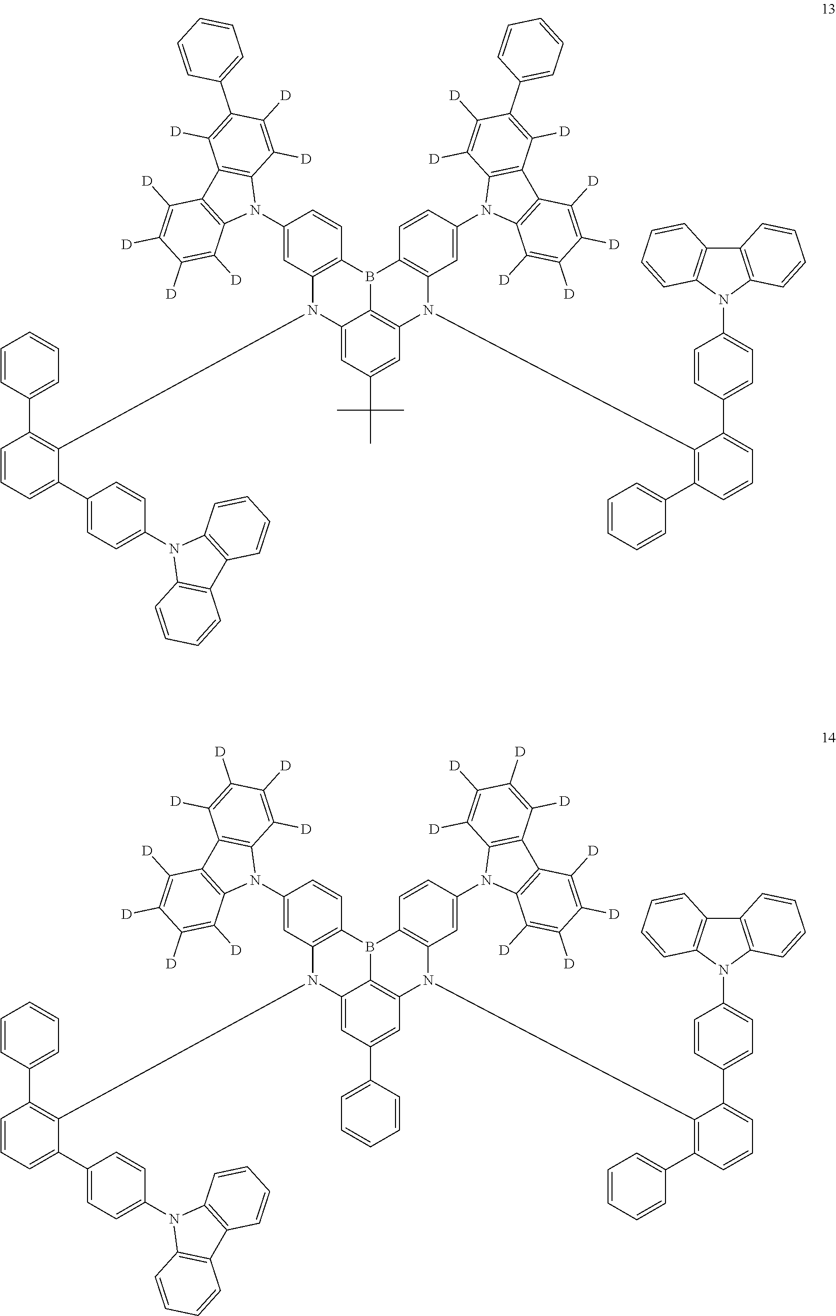

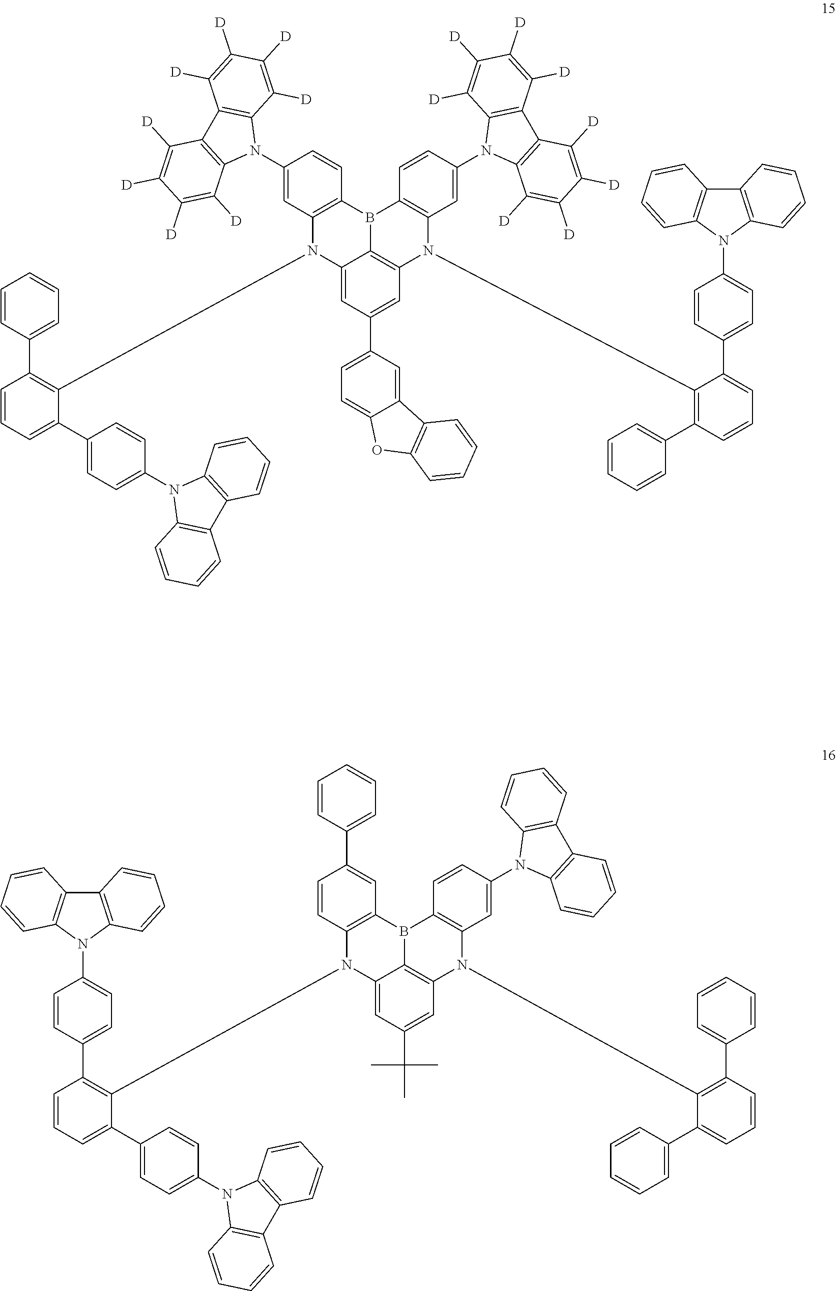 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccc(-n3c4ccccc4c4ccccc43)cc1)c1cc(-c3ccc4oc5ccccc5c4c3)cc3c1B2c1ccc(-n2c4c([2H])c([2H])c([2H])c([2H])c4c4c([2H])c([2H])c([2H])c([2H])c42)cc1N3c1c(-c2ccccc2)cccc1-c1ccc(-n2c3ccccc3c3ccccc32)cc1 ; CC(C)(C)c1cc2c3c(c1)N(c1c(-c4ccccc4)cccc1-c1ccccc1)c1cc(-n4c5ccccc5c5ccccc54)ccc1B3c1cc(-c3ccccc3)ccc1N2c1c(-c2ccc(-n3c4ccccc4c4ccccc43)cc2)cccc1-c1ccc(-n2c3ccccc3c3ccccc32)cc1]

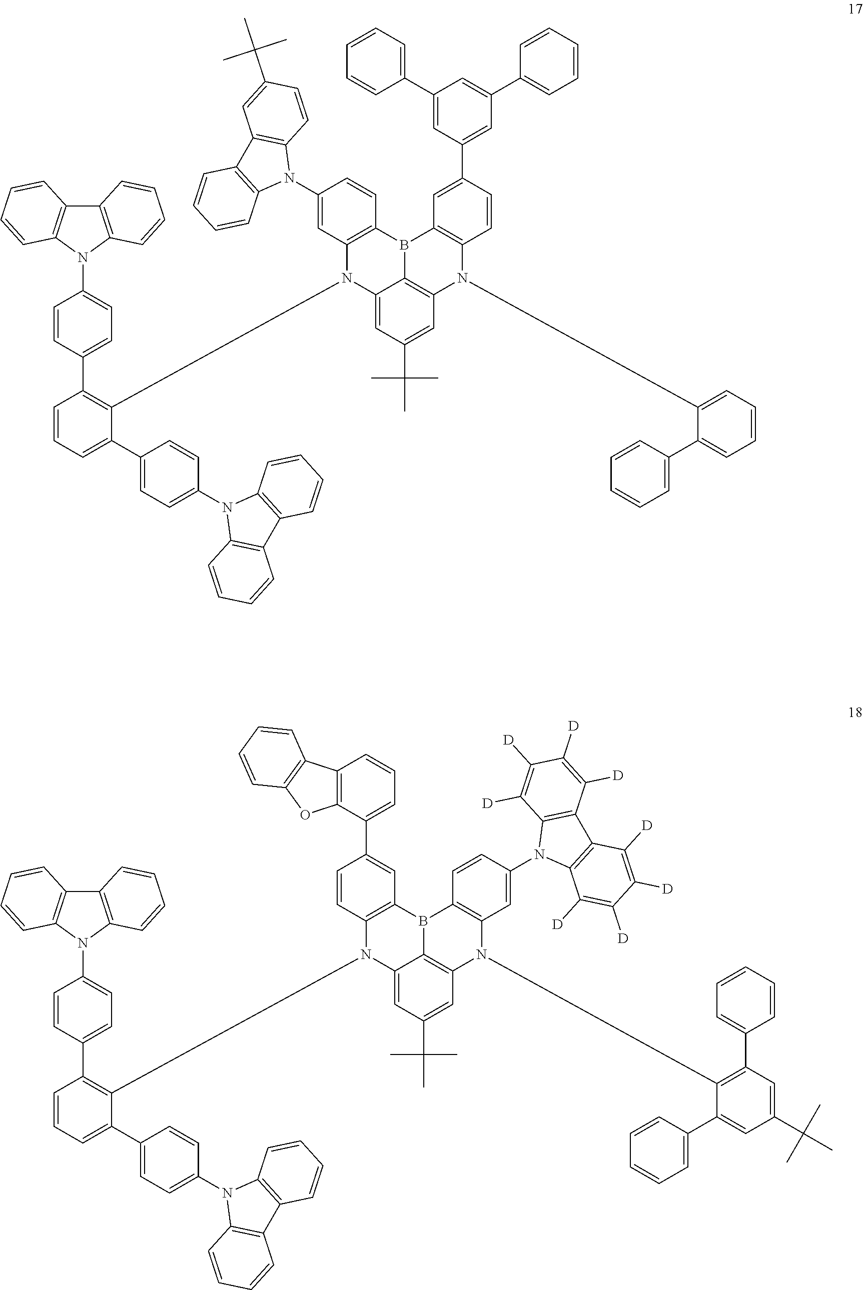 [SMILES: CC(C)(C)c1cc2c3c(c1)N(c1c(-c4ccc(-n5c6ccccc6c6ccccc65)cc4)cccc1-c1ccc(-n4c5ccccc5c5ccccc54)cc1)c1cc(-n4c5ccccc5c5cc(C(C)(C)C)ccc54)ccc1B3c1cc(-c3cc(-c4ccccc4)cc(-c4ccccc4)c3)ccc1N2c1ccccc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1cc(-c2cccc4c2oc2ccccc24)ccc1N3c1c(-c2ccc(-n3c4ccccc4c4ccccc43)cc2)cccc1-c1ccc(-n2c3ccccc3c3ccccc32)cc1]

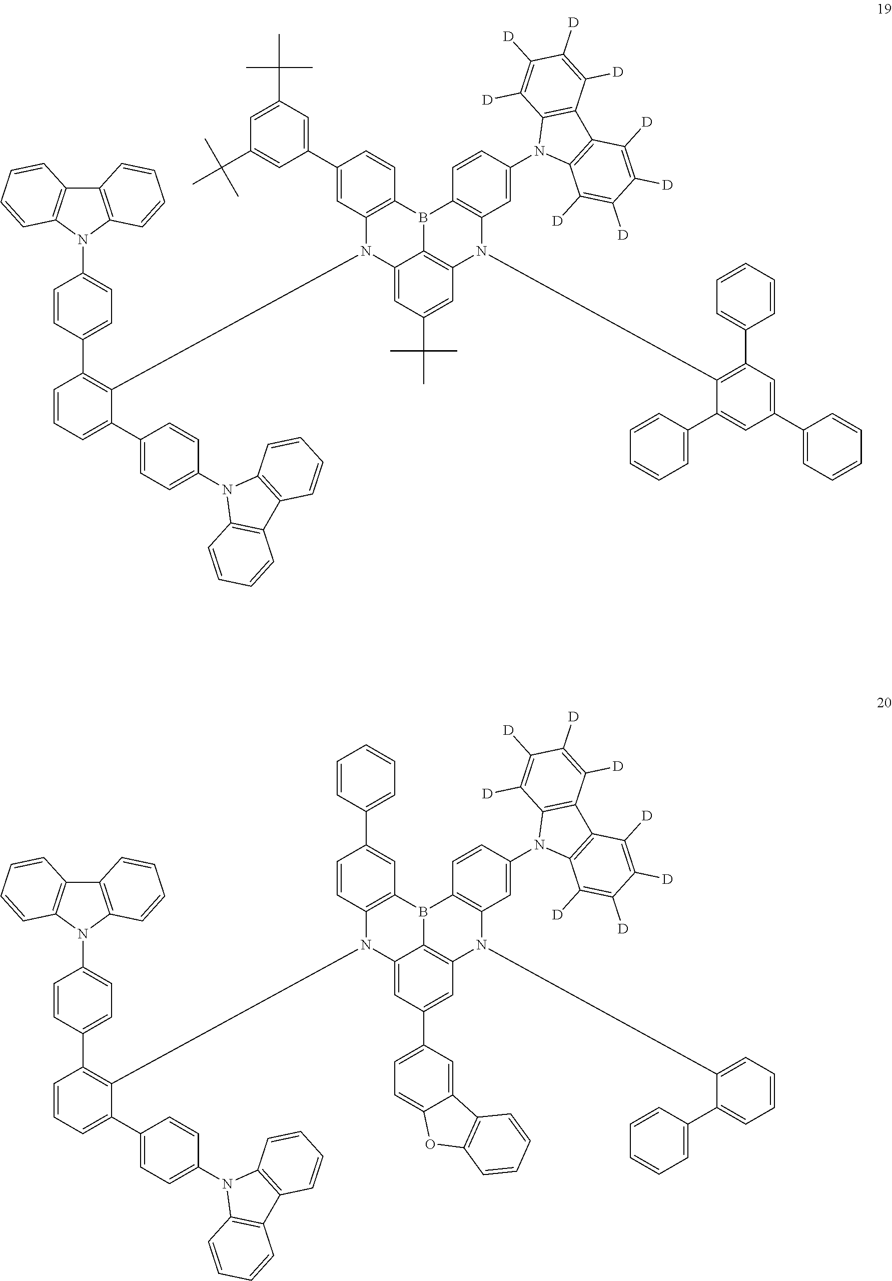 [SMILES: [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1ccccc1)c1cc(C(C)(C)C)cc3c1B2c1ccc(-c2cc(C(C)(C)C)cc(C(C)(C)C)c2)cc1N3c1c(-c2ccc(-n3c4ccccc4c4ccccc43)cc2)cccc1-c1ccc(-n2c3ccccc3c3ccccc32)cc1 ; [2H]c1c([2H])c([2H])c2c(c1[2H])c1c([2H])c([2H])c([2H])c([2H])c1n2-c1ccc2c(c1)N(c1ccccc1-c1ccccc1)c1cc(-c3ccc4oc5ccccc5c4c3)cc3c1B2c1cc(-c2ccccc2)ccc1N3c1c(-c2ccc(-n3c4ccccc4c4ccccc43)cc2)cccc1-c1ccc(-n2c3ccccc3c3ccccc32)cc1]

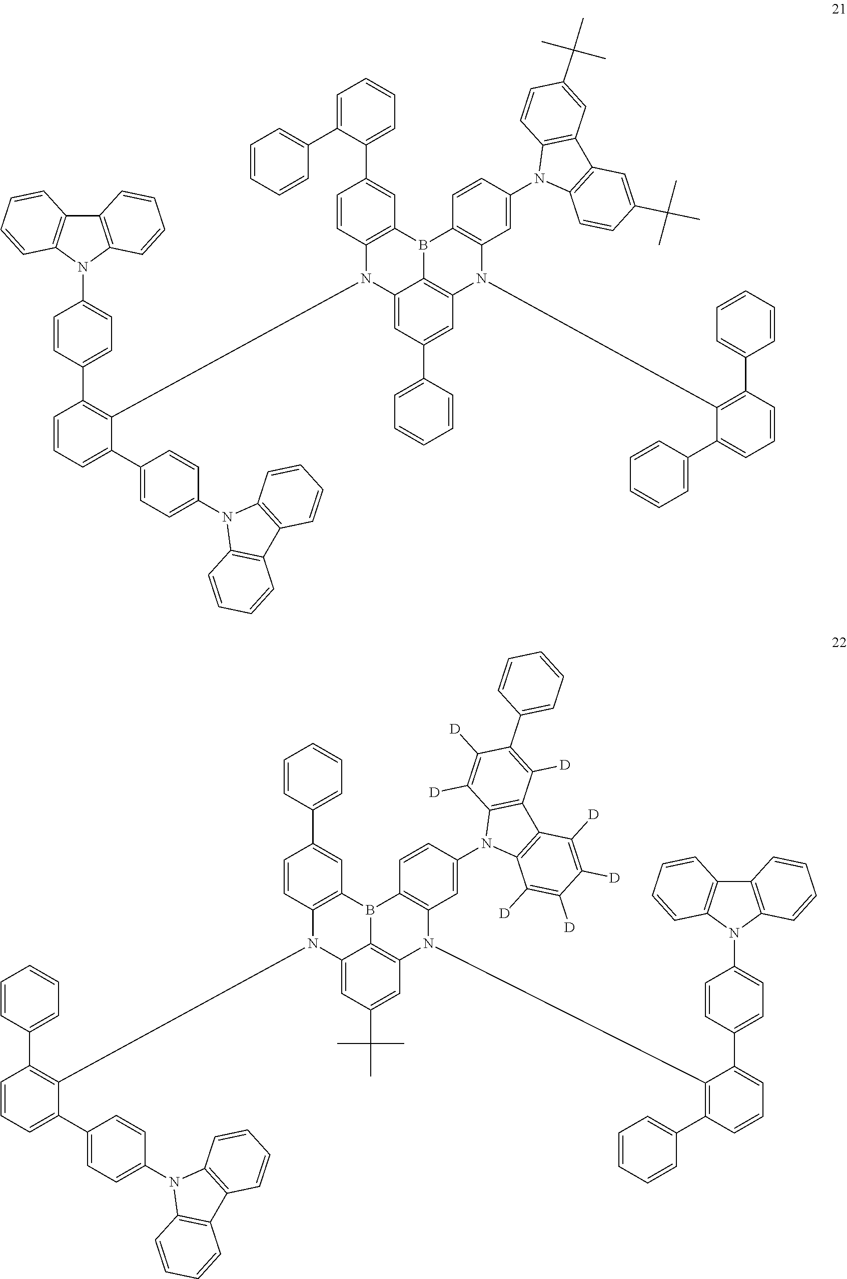 [SMILES: CC(C)(C)c1ccc2c(c1)c1cc(C(C)(C)C)ccc1n2-c1ccc2c(c1)N(c1c(-c3ccccc3)cccc1-c1ccccc1)c1cc(-c3ccccc3)cc3c1B2c1cc(-c2ccccc2-c2ccccc2)ccc1N3c1c(-c2ccc(-n3c4ccccc4c4ccccc43)cc2)cccc1-c1ccc(-n2c3ccccc3c3ccccc32)cc1 ; [2H]c1c([2H])c([2H])c2c(c1[2H])c1c([2H])c(-c3ccccc3)c([2H])c([2H])c1n2-c1ccc2c(c1)N(c1c(-c3ccccc3)cccc1-c1ccc(-n3c4ccccc4c4ccccc43)cc1)c1cc(C(C)(C)C)cc3c1B2c1cc(-c2ccccc2)ccc1N3c1c(-c2ccccc2)cccc1-c1ccc(-n2c3ccccc3c3ccccc32)cc1]

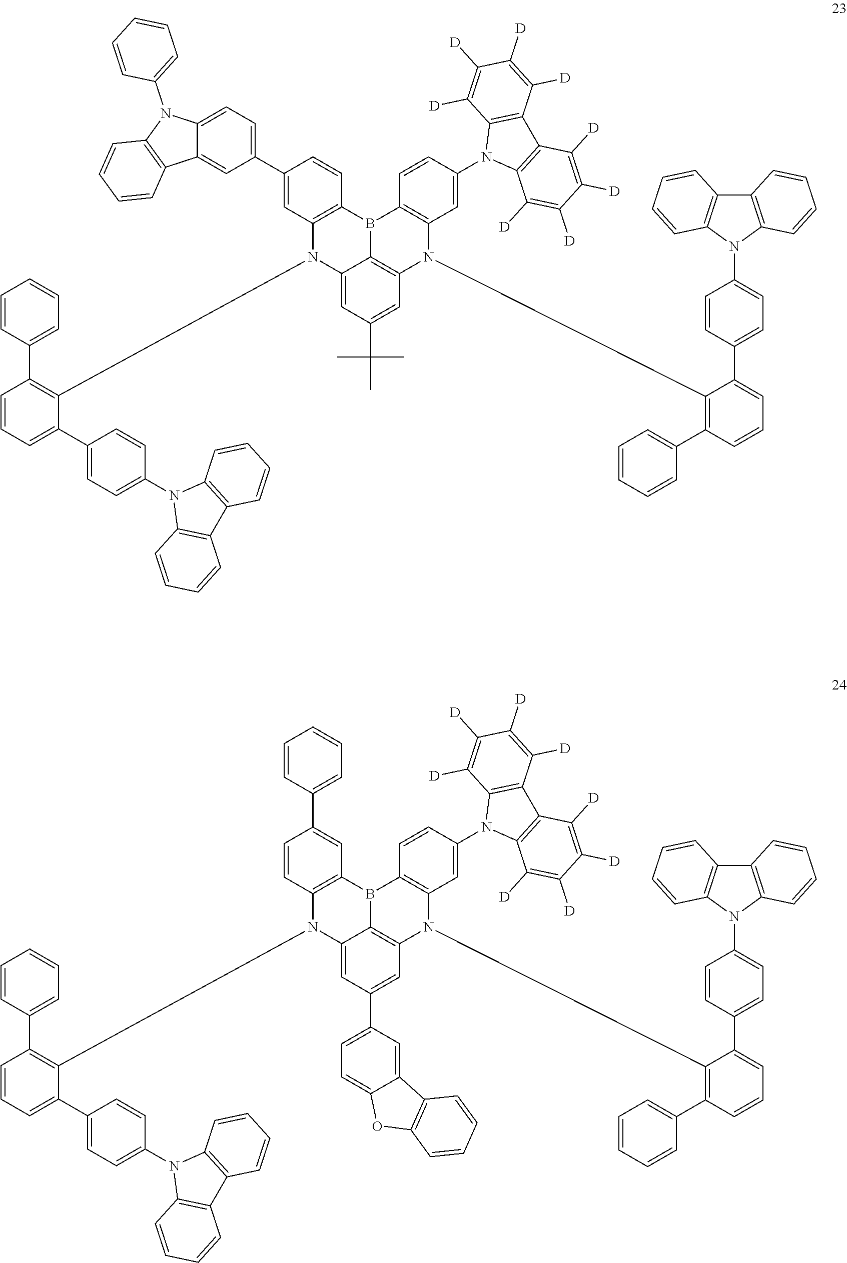 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccc(-n3c4ccccc4c4ccccc43)cc1)c1cc(C(C)(C)C)cc3c1B2c1ccc(-c2ccc4c(c2)c2ccccc2n4-c2ccccc2)cc1N3c1c(-c2ccccc2)cccc1-c1ccc(-n2c3ccccc3c3ccccc32)cc1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccc(-n3c4ccccc4c4ccccc43)cc1)c1cc(-c3ccc4oc5ccccc5c4c3)cc3c1B2c1cc(-c2ccccc2)ccc1N3c1c(-c2ccccc2)cccc1-c1ccc(-n2c3ccccc3c3ccccc32)cc1]

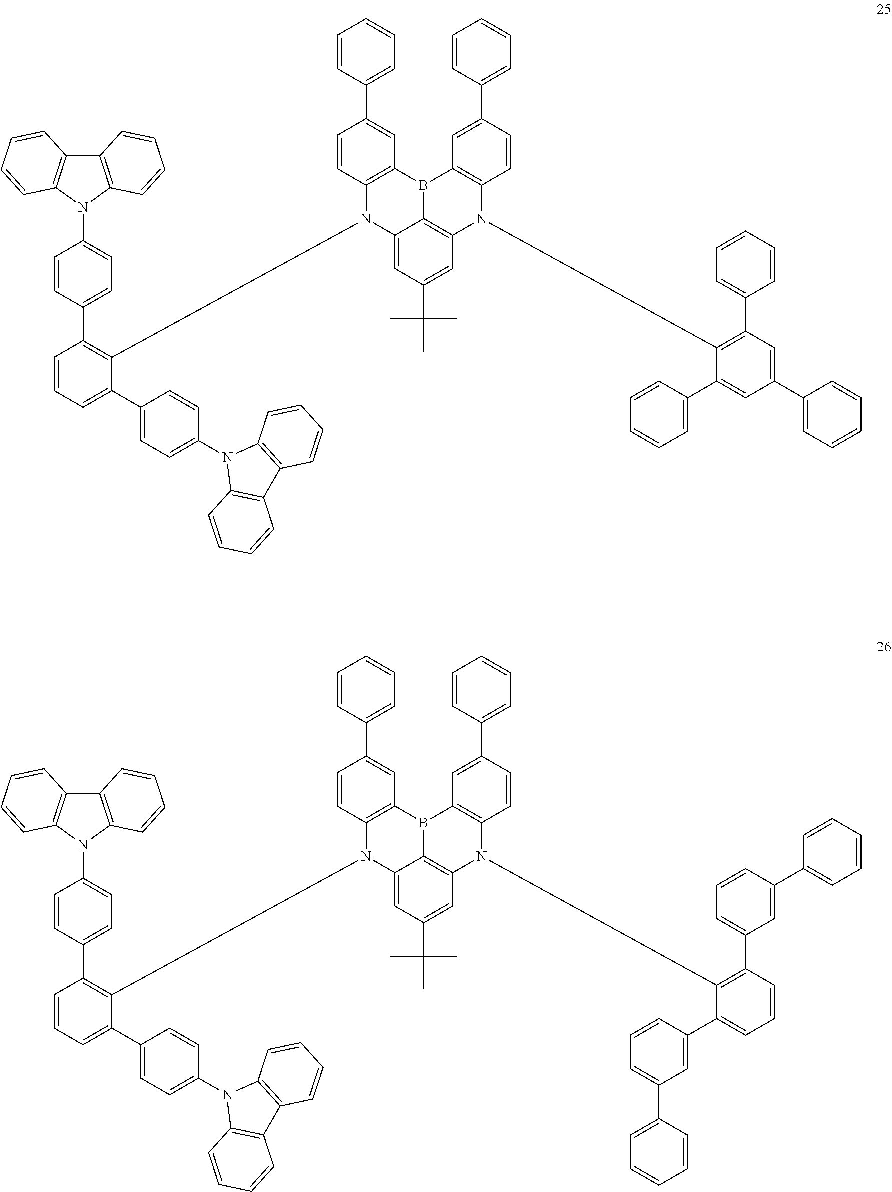 [SMILES: CC(C)(C)c1cc2c3c(c1)N(c1c(-c4ccccc4)cc(-c4ccccc4)cc1-c1ccccc1)c1ccc(-c4ccccc4)cc1B3c1cc(-c3ccccc3)ccc1N2c1c(-c2ccc(-n3c4ccccc4c4ccccc43)cc2)cccc1-c1ccc(-n2c3ccccc3c3ccccc32)cc1 ; CC(C)(C)c1cc2c3c(c1)N(c1c(-c4cccc(-c5ccccc5)c4)cccc1-c1cccc(-c4ccccc4)c1)c1ccc(-c4ccccc4)cc1B3c1cc(-c3ccccc3)ccc1N2c1c(-c2ccc(-n3c4ccccc4c4ccccc43)cc2)cccc1-c1ccc(-n2c3ccccc3c3ccccc32)cc1]

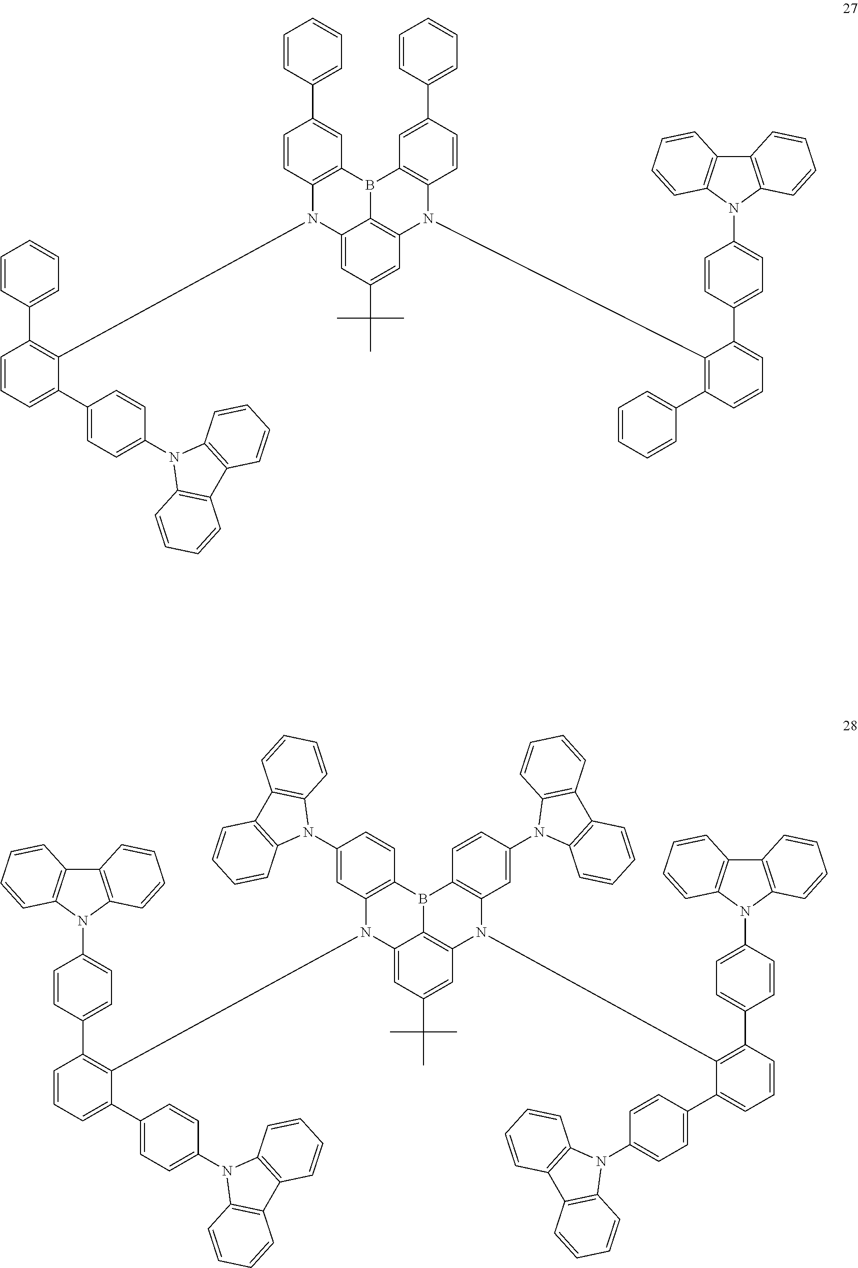 [SMILES: CC(C)(C)c1cc2c3c(c1)N(c1c(-c4ccccc4)cccc1-c1ccc(-n4c5ccccc5c5ccccc54)cc1)c1ccc(-c4ccccc4)cc1B3c1cc(-c3ccccc3)ccc1N2c1c(-c2ccccc2)cccc1-c1ccc(-n2c3ccccc3c3ccccc32)cc1 ; CC(C)(C)c1cc2c3c(c1)N(c1c(-c4ccc(-n5c6ccccc6c6ccccc65)cc4)cccc1-c1ccc(-n4c5ccccc5c5ccccc54)cc1)c1cc(-n4c5ccccc5c5ccccc54)ccc1B3c1ccc(-n3c4ccccc4c4ccccc43)cc1N2c1c(-c2ccc(-n3c4ccccc4c4ccccc43)cc2)cccc1-c1ccc(-n2c3ccccc3c3ccccc32)cc1]

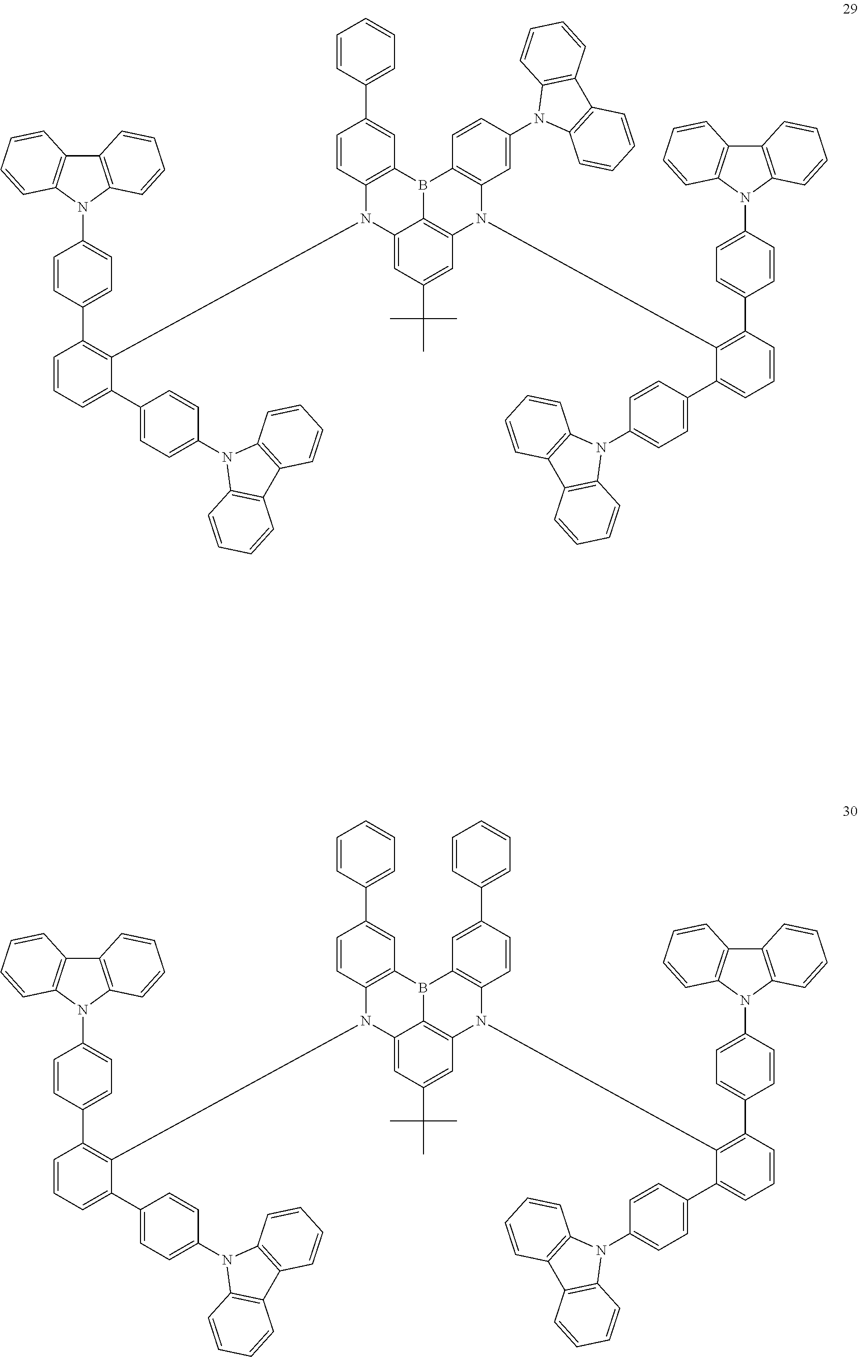 [SMILES: CC(C)(C)c1cc2c3c(c1)N(c1c(-c4ccc(-n5c6ccccc6c6ccccc65)cc4)cccc1-c1ccc(-n4c5ccccc5c5ccccc54)cc1)c1cc(-n4c5ccccc5c5ccccc54)ccc1B3c1cc(-c3ccccc3)ccc1N2c1c(-c2ccc(-n3c4ccccc4c4ccccc43)cc2)cccc1-c1ccc(-n2c3ccccc3c3ccccc32)cc1 ; CC(C)(C)c1cc2c3c(c1)N(c1c(-c4ccc(-n5c6ccccc6c6ccccc65)cc4)cccc1-c1ccc(-n4c5ccccc5c5ccccc54)cc1)c1ccc(-c4ccccc4)cc1B3c1cc(-c3ccccc3)ccc1N2c1c(-c2ccc(-n3c4ccccc4c4ccccc43)cc2)cccc1-c1ccc(-n2c3ccccc3c3ccccc32)cc1]

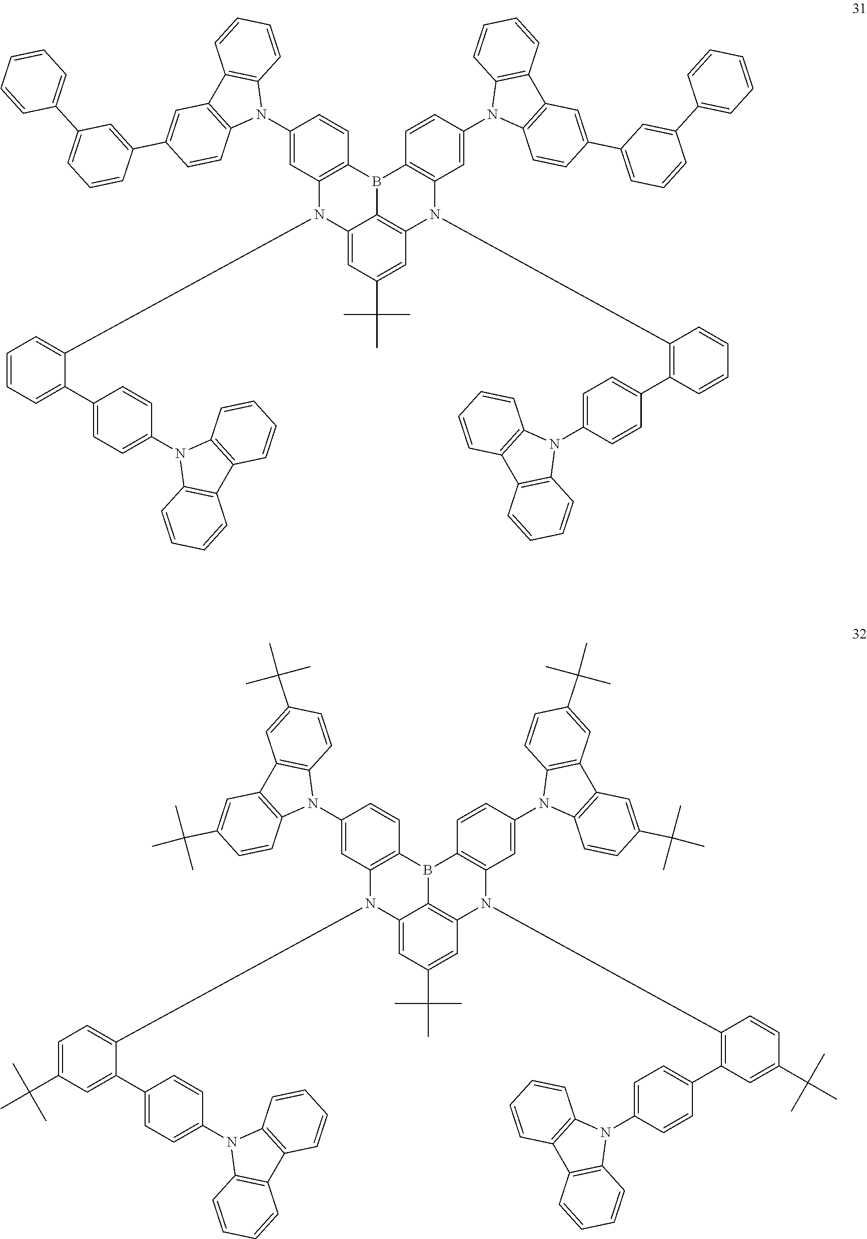 [SMILES: CC(C)(C)c1cc2c3c(c1)N(c1ccccc1-c1ccc(-n4c5ccccc5c5ccccc54)cc1)c1cc(-n4c5ccccc5c5cc(-c6cccc(-c7ccccc7)c6)ccc54)ccc1B3c1ccc(-n3c4ccccc4c4cc(-c5cccc(-c6ccccc6)c5)ccc43)cc1N2c1ccccc1-c1ccc(-n2c3ccccc3c3ccccc32)cc1 ; CC(C)(C)c1ccc(N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4ccc(C(C)(C)C)cc4-c4ccc(-n5c6ccccc6c6ccccc65)cc4)c4cc(C(C)(C)C)cc2c43)c(-c2ccc(-n3c4ccccc4c4ccccc43)cc2)c1]

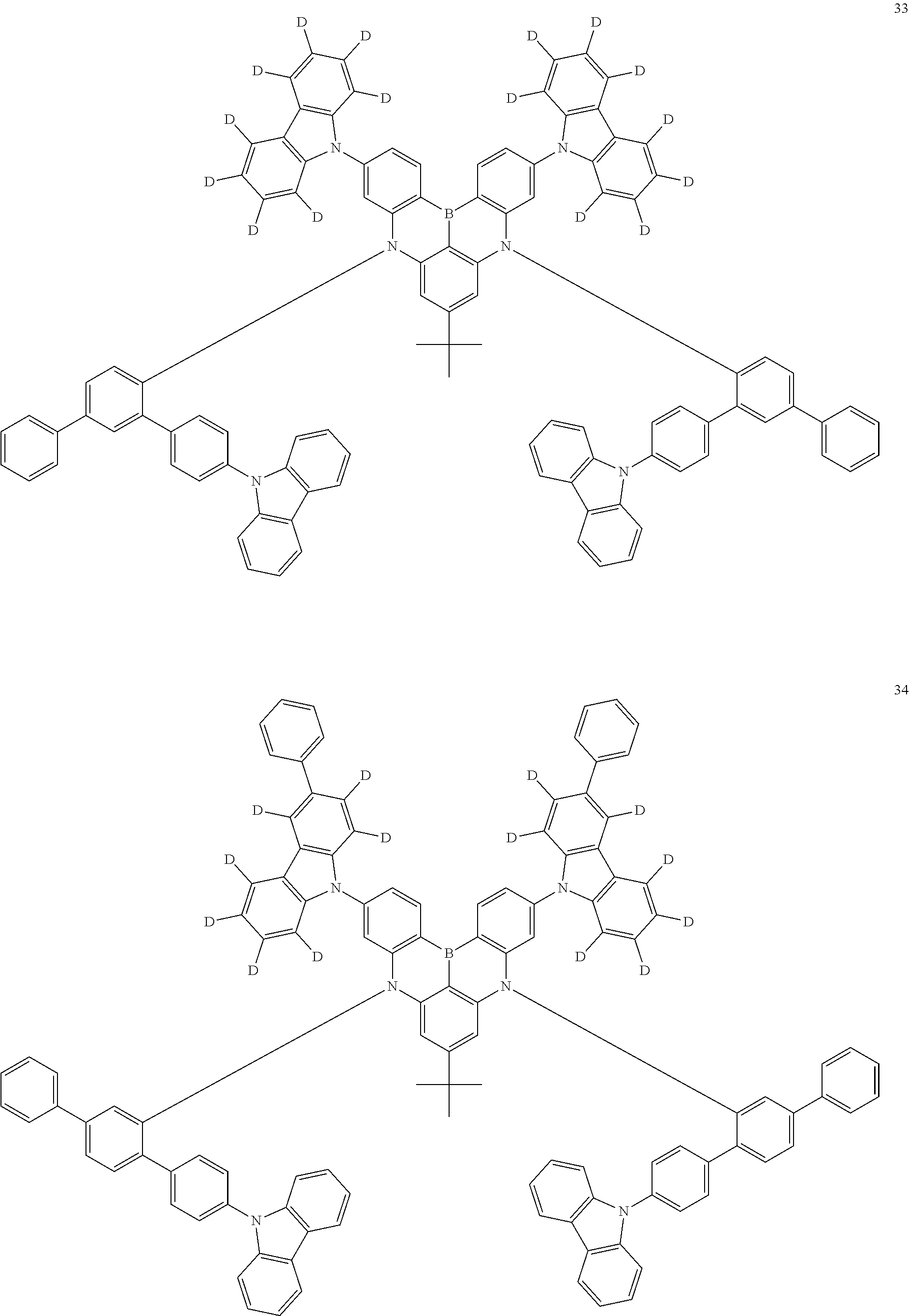

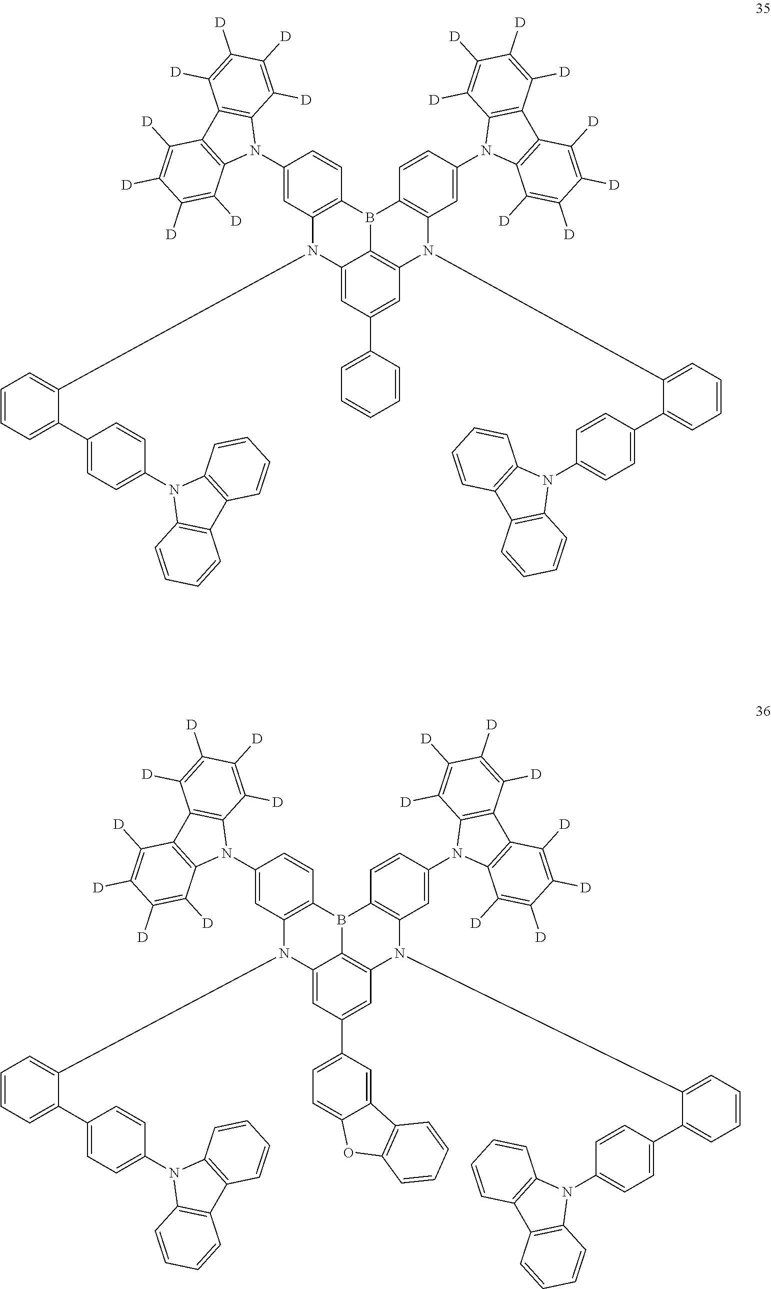

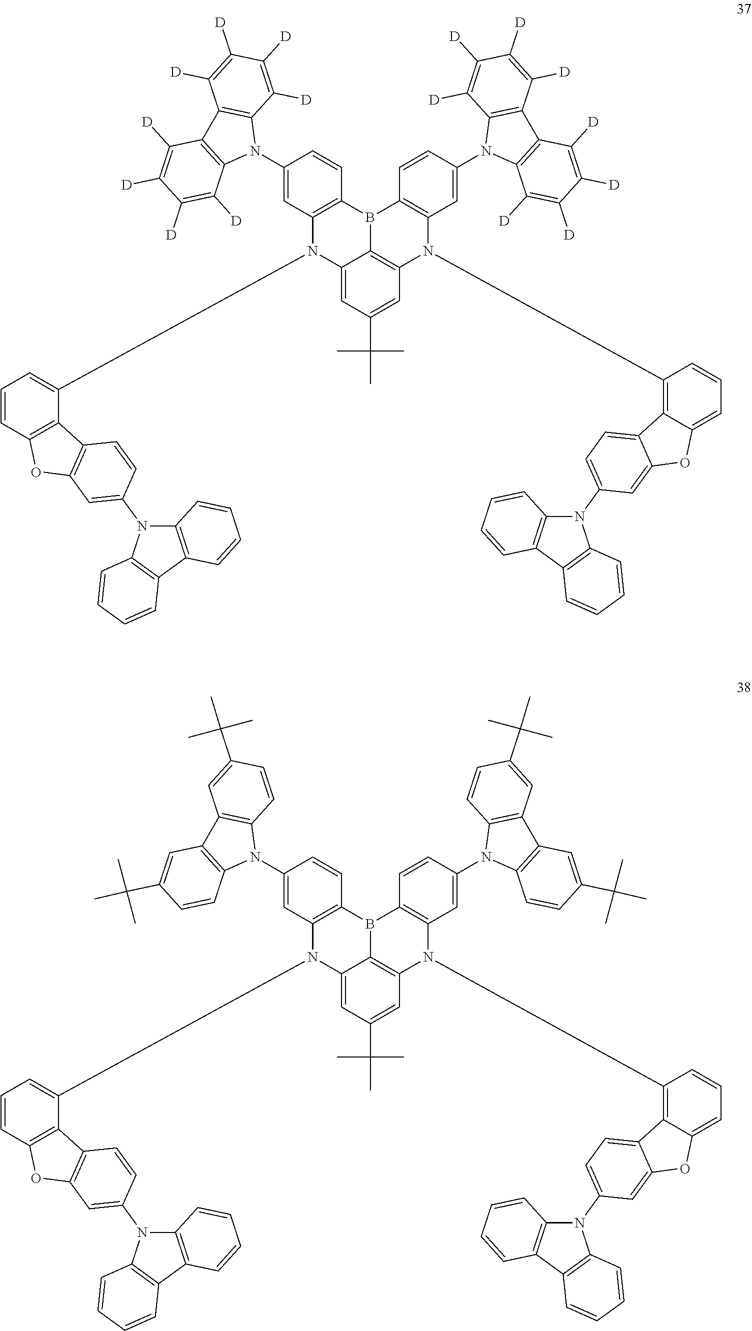 [SMILES: [2H]c1c([2H])c([2H])c2c(c1[2H])c1c([2H])c([2H])c([2H])c([2H])c1n2-c1ccc2c(c1)N(c1cccc3oc4cc(-n5c6ccccc6c6ccccc65)ccc4c13)c1cc(C(C)(C)C)cc3c1B2c1ccc(-n2c4c([2H])c([2H])c([2H])c([2H])c4c4c([2H])c([2H])c([2H])c([2H])c42)cc1N3c1cccc2oc3cc(-n4c5ccccc5c5ccccc54)ccc3c12 ; CC(C)(C)c1cc2c3c(c1)N(c1cccc4oc5cc(-n6c7ccccc7c7ccccc76)ccc5c14)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1N2c1cccc2oc3cc(-n4c5ccccc5c5ccccc54)ccc3c12]

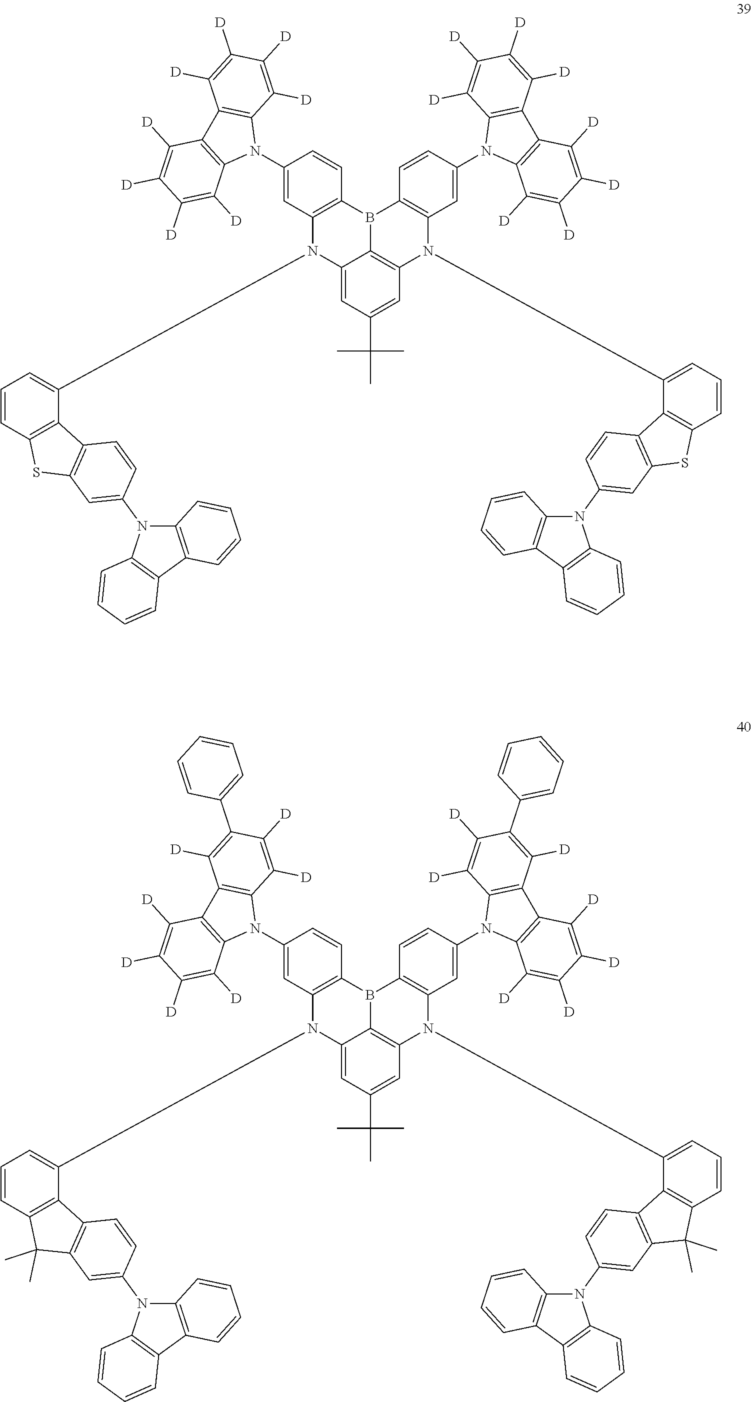

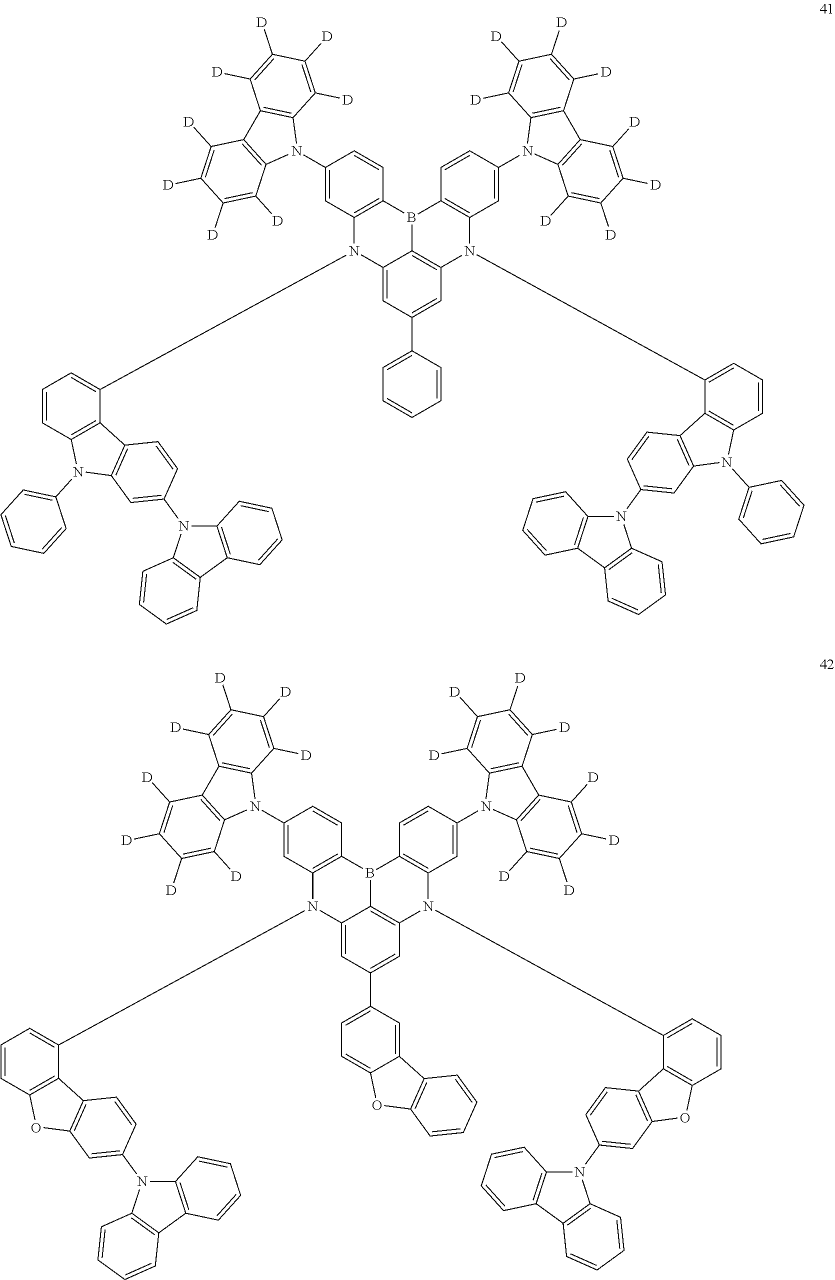

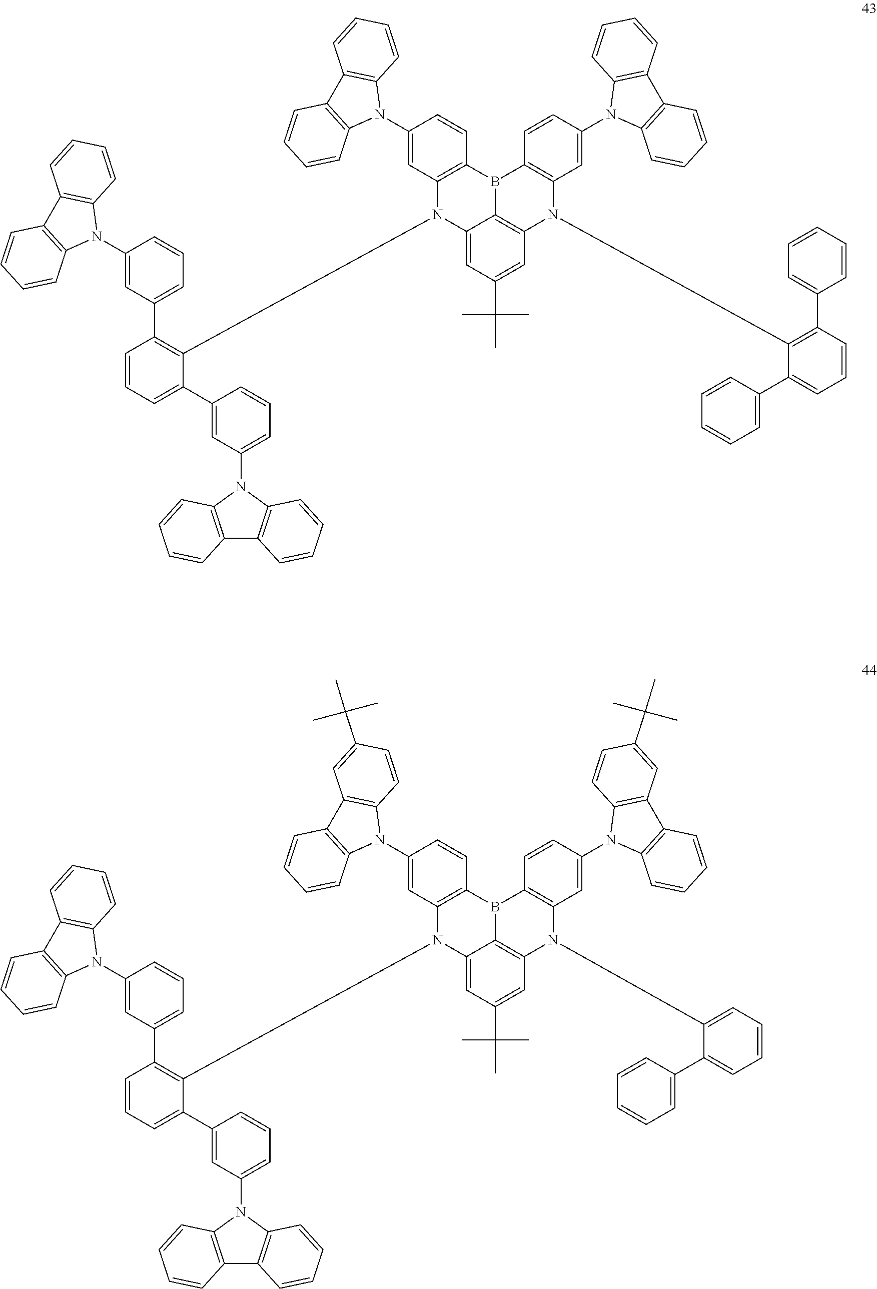 [SMILES: CC(C)(C)c1cc2c3c(c1)N(c1c(-c4cccc(-n5c6ccccc6c6ccccc65)c4)cccc1-c1cccc(-n4c5ccccc5c5ccccc54)c1)c1cc(-n4c5ccccc5c5ccccc54)ccc1B3c1ccc(-n3c4ccccc4c4ccccc43)cc1N2c1c(-c2ccccc2)cccc1-c1ccccc1 ; CC(C)(C)c1cc2c3c(c1)N(c1c(-c4cccc(-n5c6ccccc6c6ccccc65)c4)cccc1-c1cccc(-n4c5ccccc5c5ccccc54)c1)c1cc(-n4c5ccccc5c5cc(C(C)(C)C)ccc54)ccc1B3c1ccc(-n3c4ccccc4c4cc(C(C)(C)C)ccc43)cc1N2c1ccccc1-c1ccccc1]

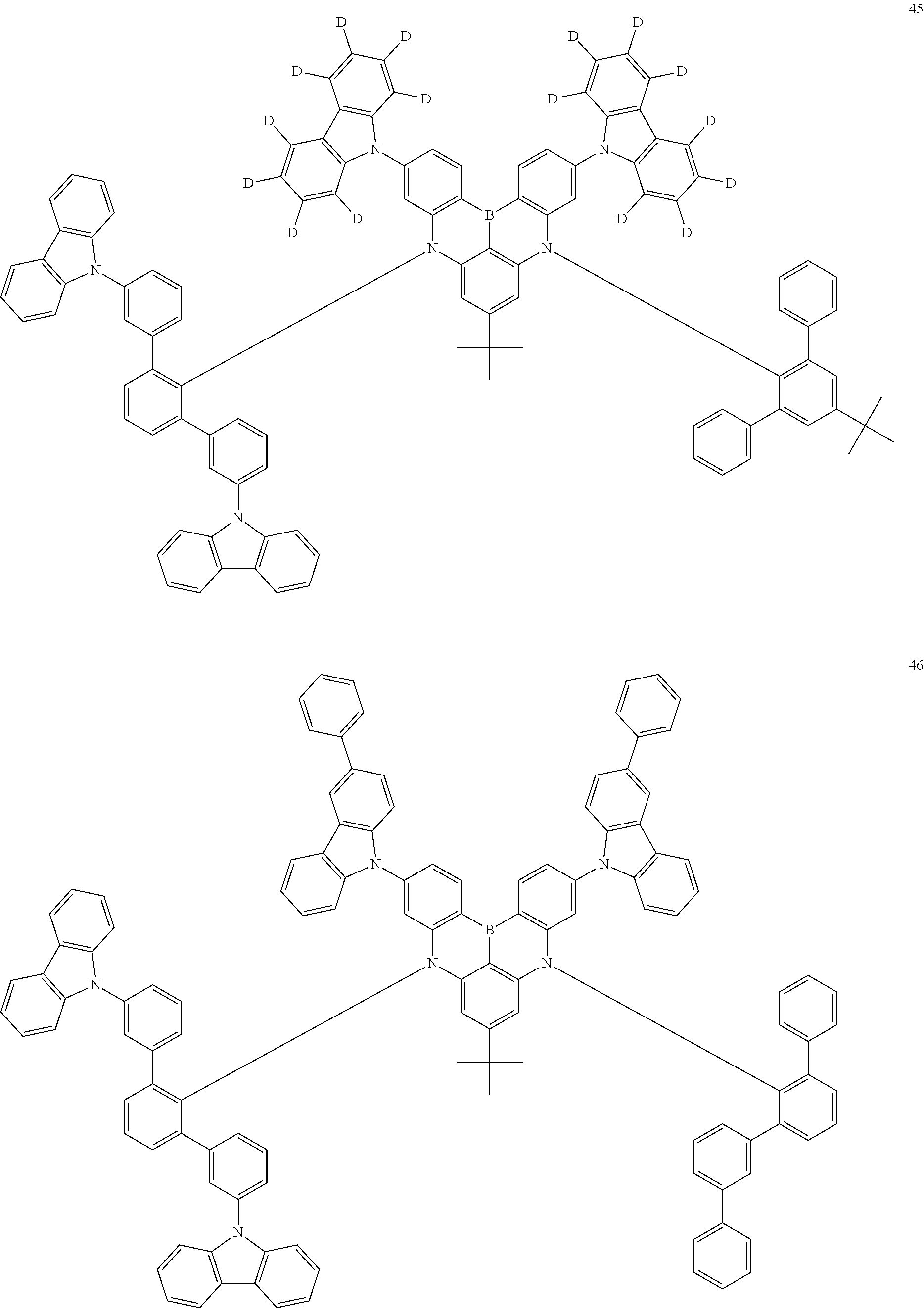

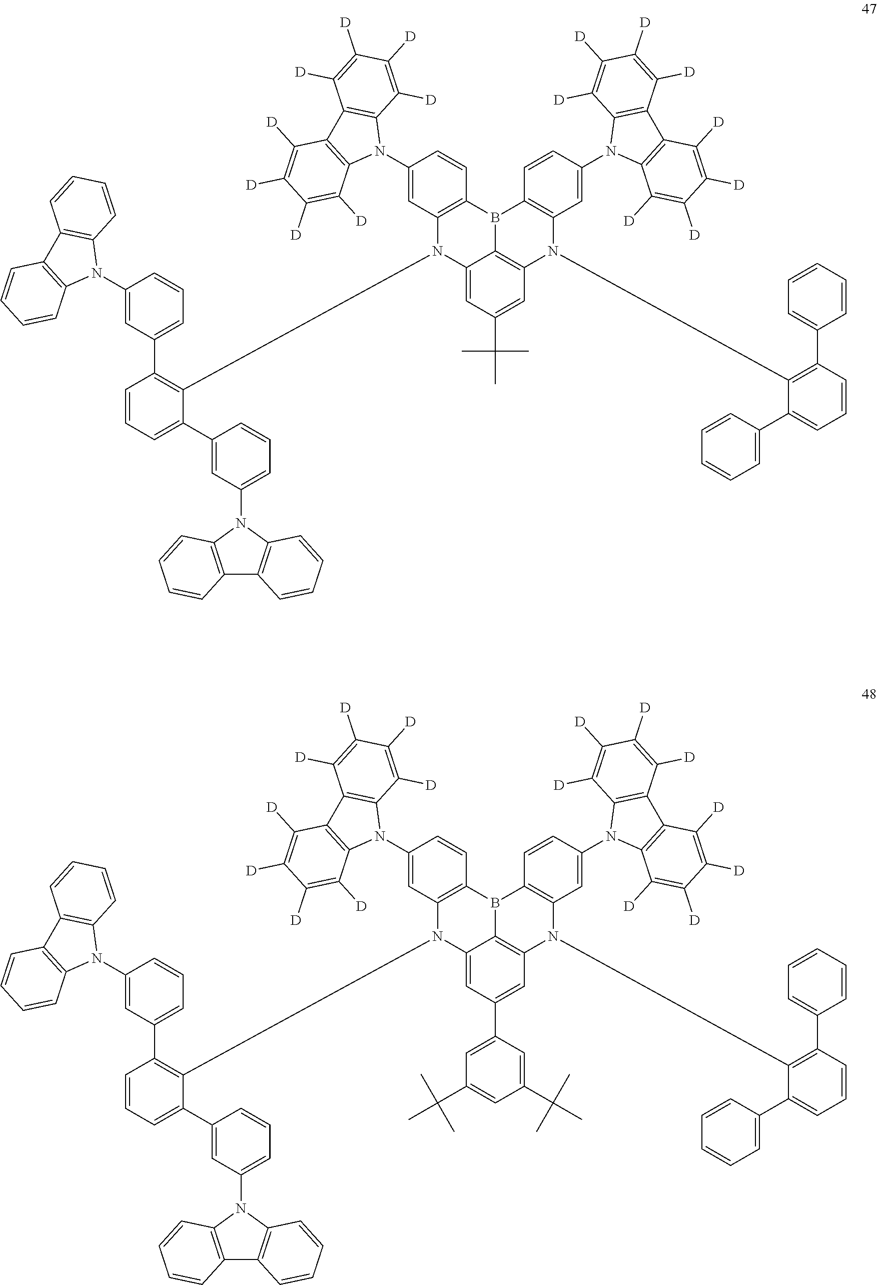

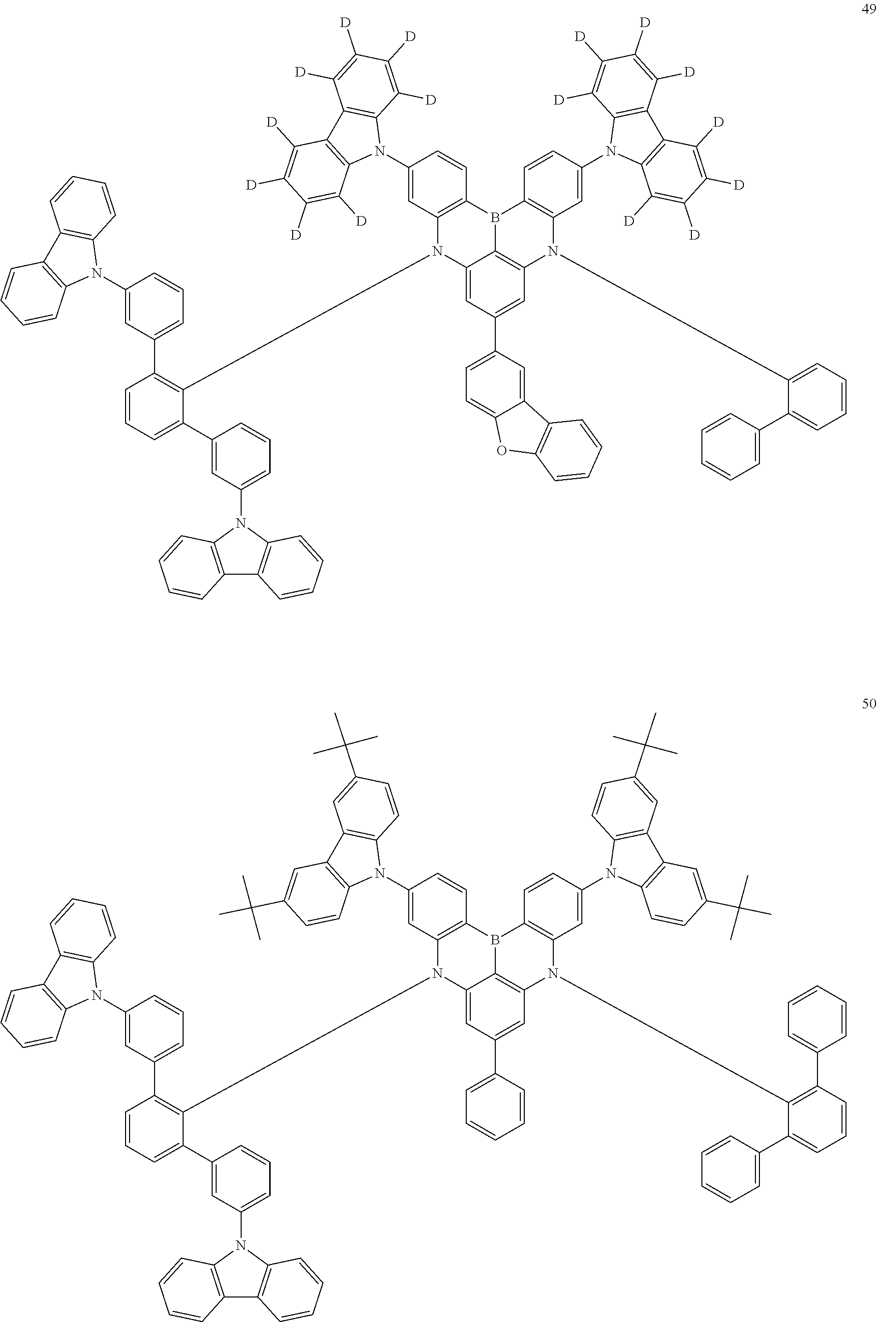

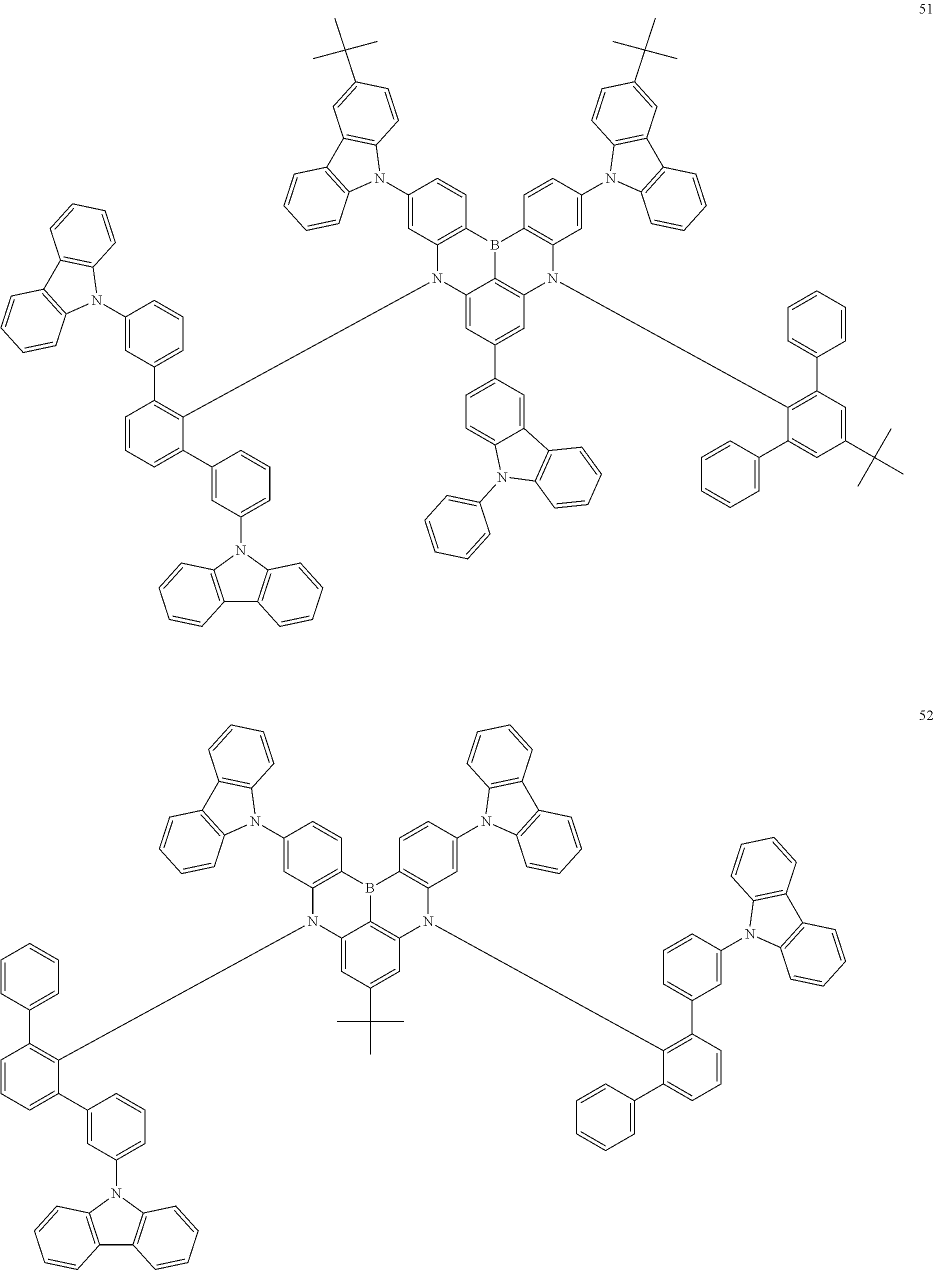 [SMILES: CC(C)(C)c1cc(-c2ccccc2)c(N2c3cc(-n4c5ccccc5c5cc(C(C)(C)C)ccc54)ccc3B3c4ccc(-n5c6ccccc6c6cc(C(C)(C)C)ccc65)cc4N(c4c(-c5cccc(-n6c7ccccc7c7ccccc76)c5)cccc4-c4cccc(-n5c6ccccc6c6ccccc65)c4)c4cc(-c5ccc6c(c5)c5ccccc5n6-c5ccccc5)cc2c43)c(-c2ccccc2)c1 ; CC(C)(C)c1cc2c3c(c1)N(c1c(-c4ccccc4)cccc1-c1cccc(-n4c5ccccc5c5ccccc54)c1)c1cc(-n4c5ccccc5c5ccccc54)ccc1B3c1ccc(-n3c4ccccc4c4ccccc43)cc1N2c1c(-c2ccccc2)cccc1-c1cccc(-n2c3ccccc3c3ccccc32)c1]

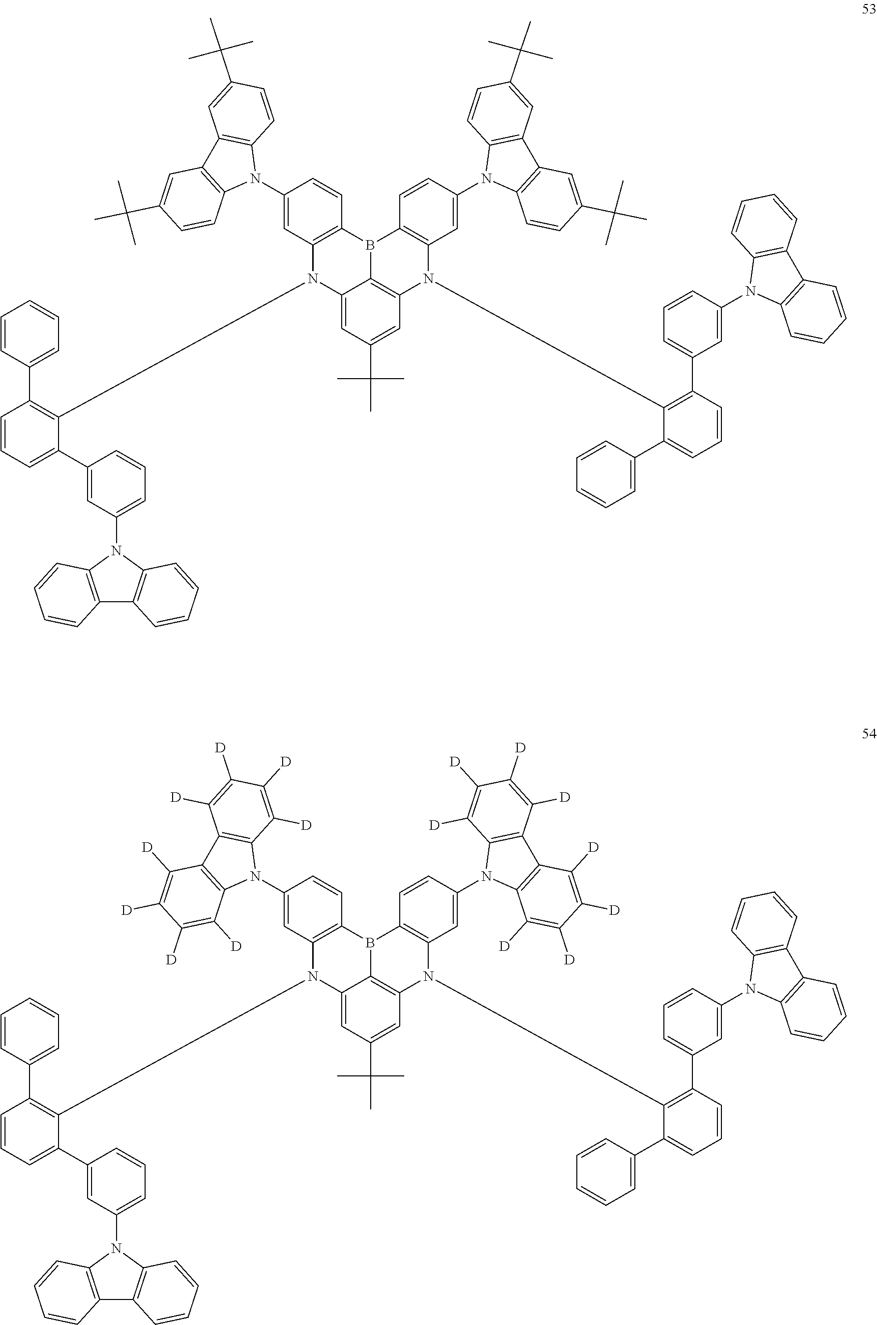

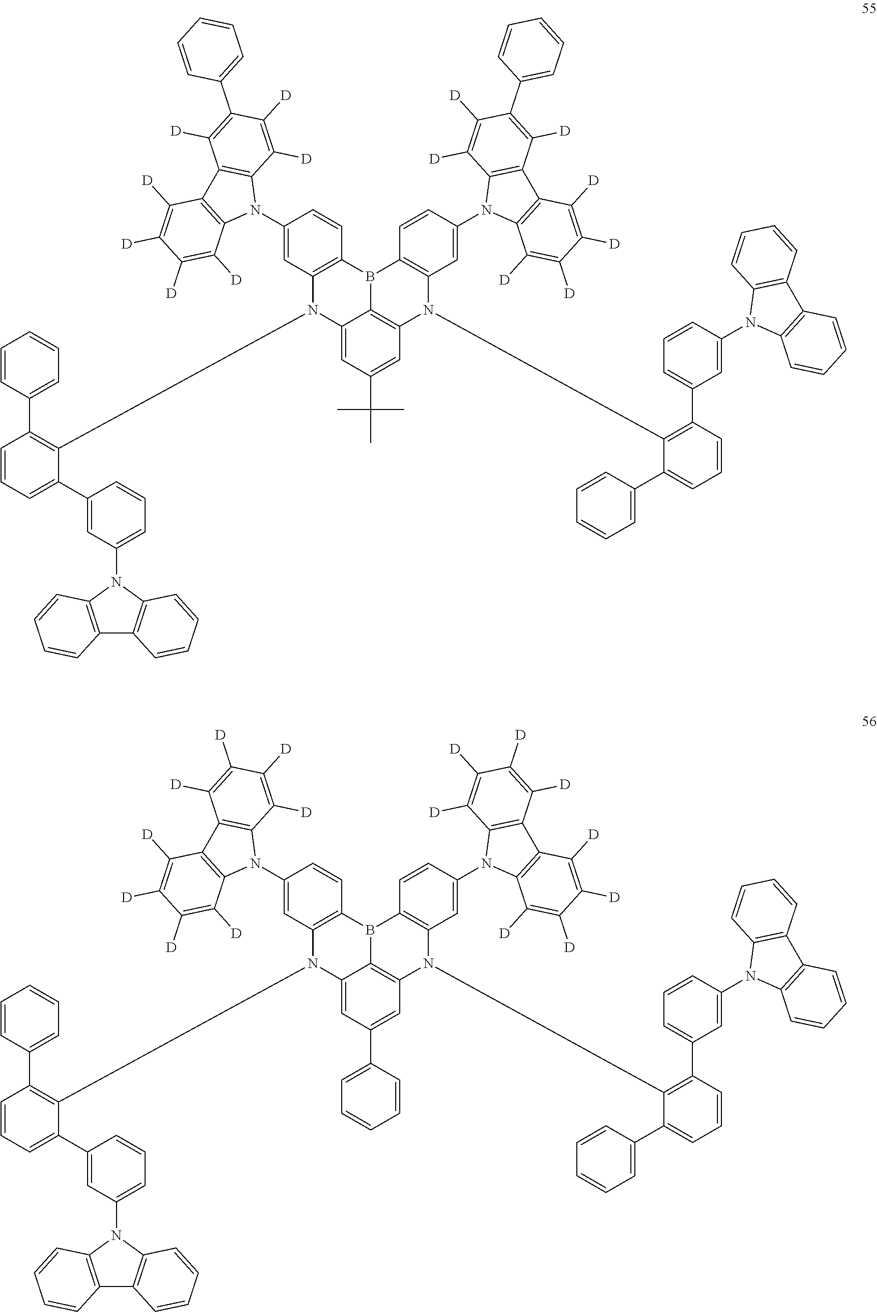

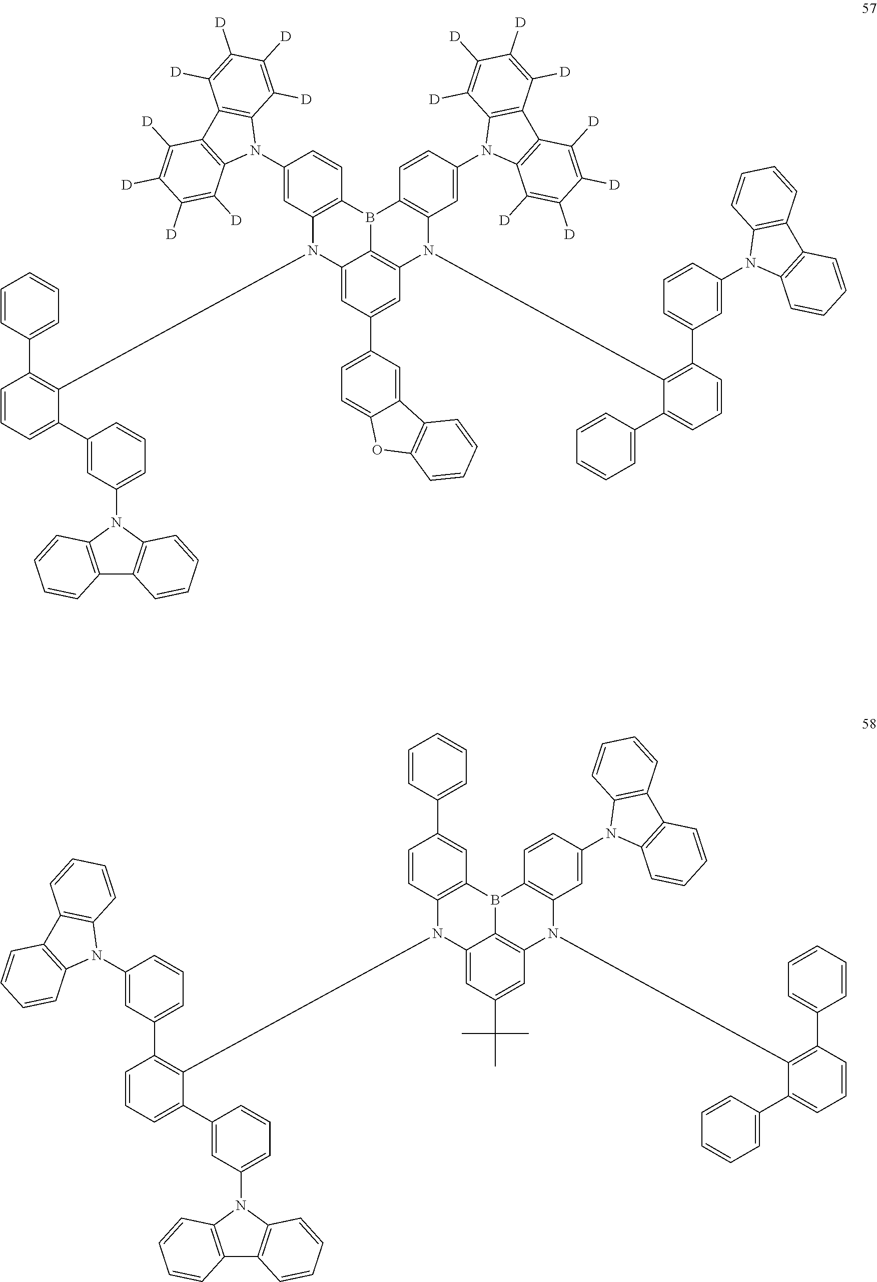 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1cccc(-n3c4ccccc4c4ccccc43)c1)c1cc(-c3ccc4oc5ccccc5c4c3)cc3c1B2c1ccc(-n2c4c([2H])c([2H])c([2H])c([2H])c4c4c([2H])c([2H])c([2H])c([2H])c42)cc1N3c1c(-c2ccccc2)cccc1-c1cccc(-n2c3ccccc3c3ccccc32)c1 ; CC(C)(C)c1cc2c3c(c1)N(c1c(-c4ccccc4)cccc1-c1ccccc1)c1cc(-n4c5ccccc5c5ccccc54)ccc1B3c1cc(-c3ccccc3)ccc1N2c1c(-c2cccc(-n3c4ccccc4c4ccccc43)c2)cccc1-c1cccc(-n2c3ccccc3c3ccccc32)c1]

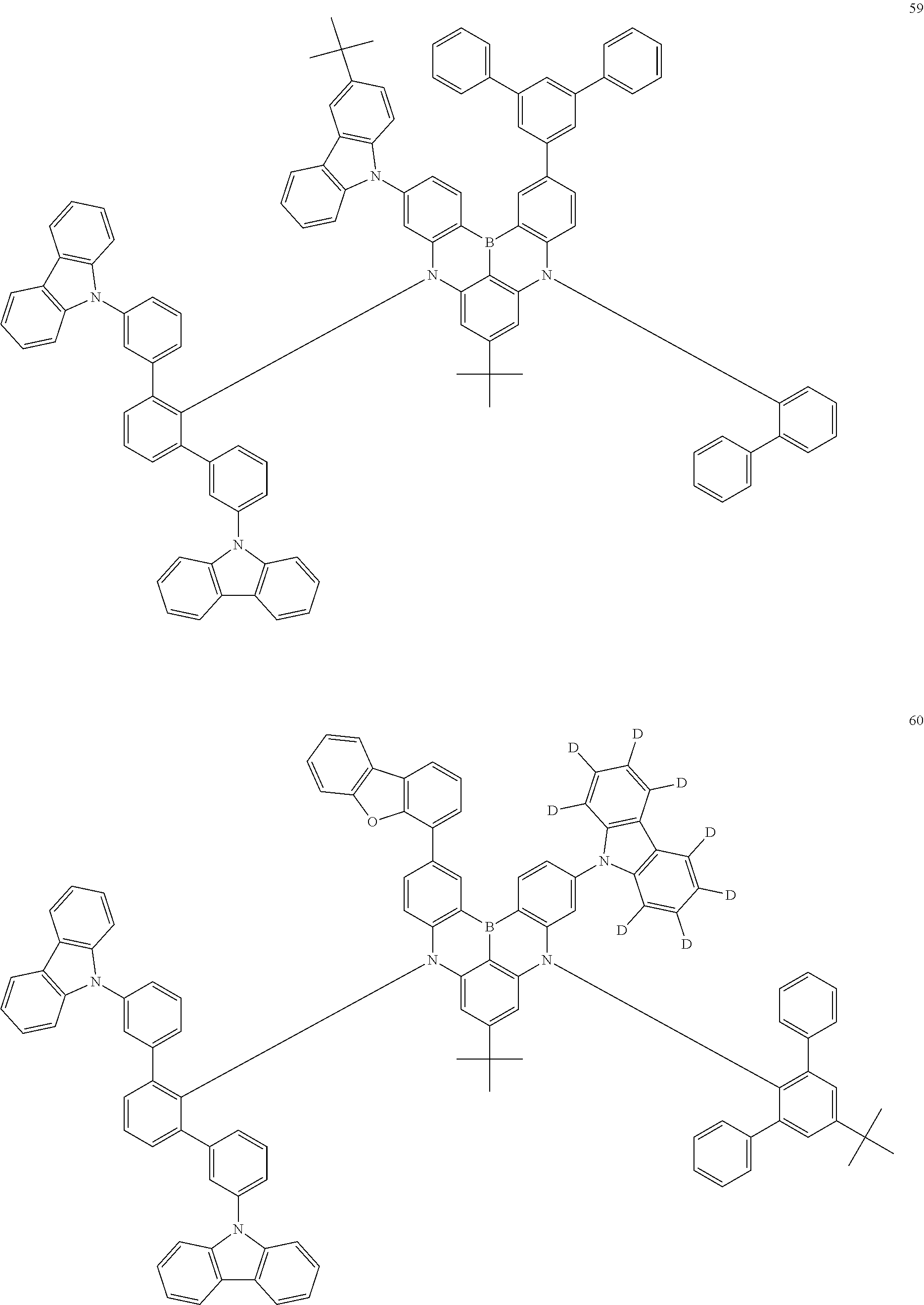 [SMILES: CC(C)(C)c1cc2c3c(c1)N(c1c(-c4cccc(-n5c6ccccc6c6ccccc65)c4)cccc1-c1cccc(-n4c5ccccc5c5ccccc54)c1)c1cc(-n4c5ccccc5c5cc(C(C)(C)C)ccc54)ccc1B3c1cc(-c3cc(-c4ccccc4)cc(-c4ccccc4)c3)ccc1N2c1ccccc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1cc(-c2cccc4c2oc2ccccc24)ccc1N3c1c(-c2cccc(-n3c4ccccc4c4ccccc43)c2)cccc1-c1cccc(-n2c3ccccc3c3ccccc32)c1]

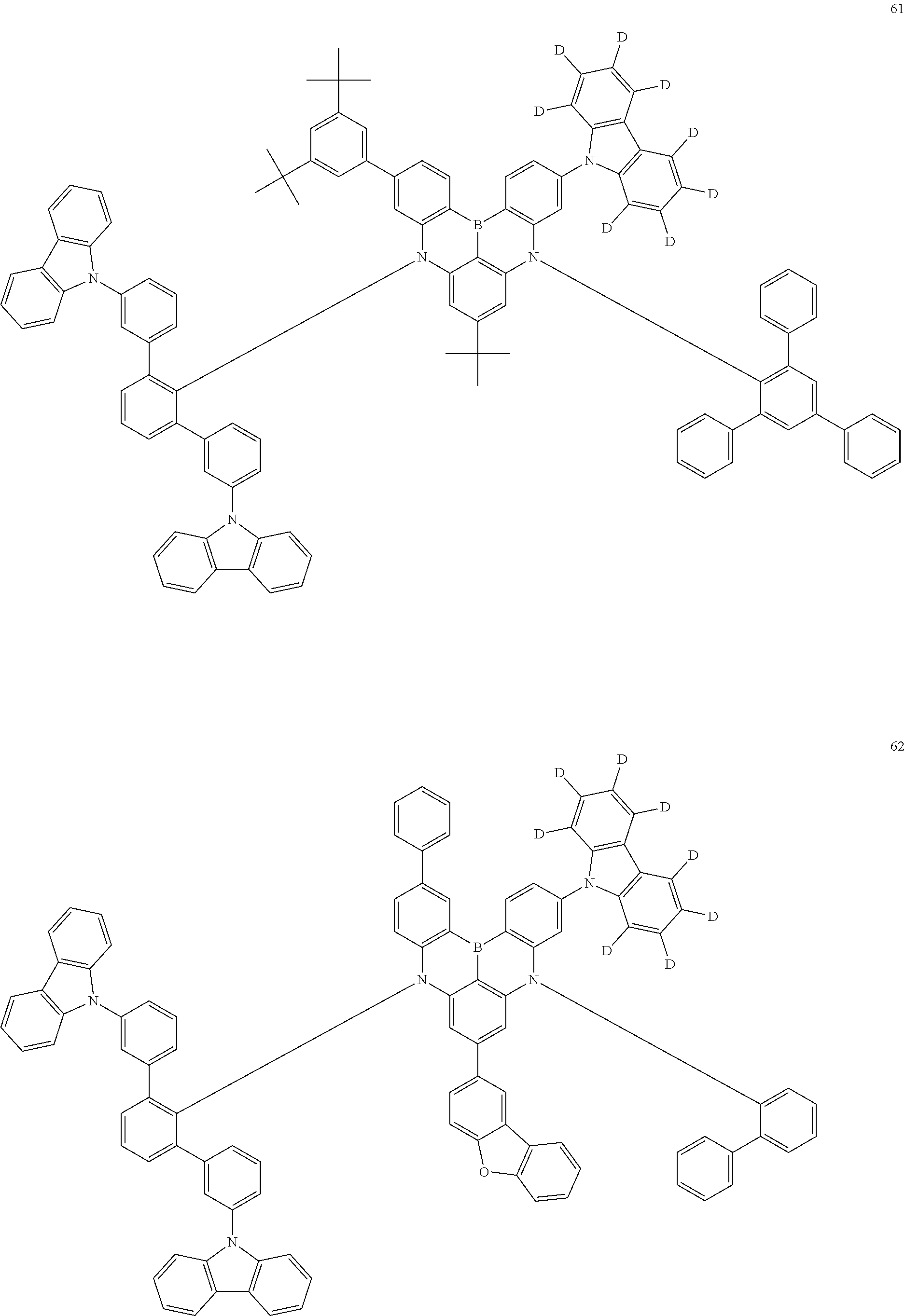 [SMILES: [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1ccccc1)c1cc(C(C)(C)C)cc3c1B2c1ccc(-c2cc(C(C)(C)C)cc(C(C)(C)C)c2)cc1N3c1c(-c2cccc(-n3c4ccccc4c4ccccc43)c2)cccc1-c1cccc(-n2c3ccccc3c3ccccc32)c1 ; [2H]c1c([2H])c([2H])c2c(c1[2H])c1c([2H])c([2H])c([2H])c([2H])c1n2-c1ccc2c(c1)N(c1ccccc1-c1ccccc1)c1cc(-c3ccc4oc5ccccc5c4c3)cc3c1B2c1cc(-c2ccccc2)ccc1N3c1c(-c2cccc(-n3c4ccccc4c4ccccc43)c2)cccc1-c1cccc(-n2c3ccccc3c3ccccc32)c1]

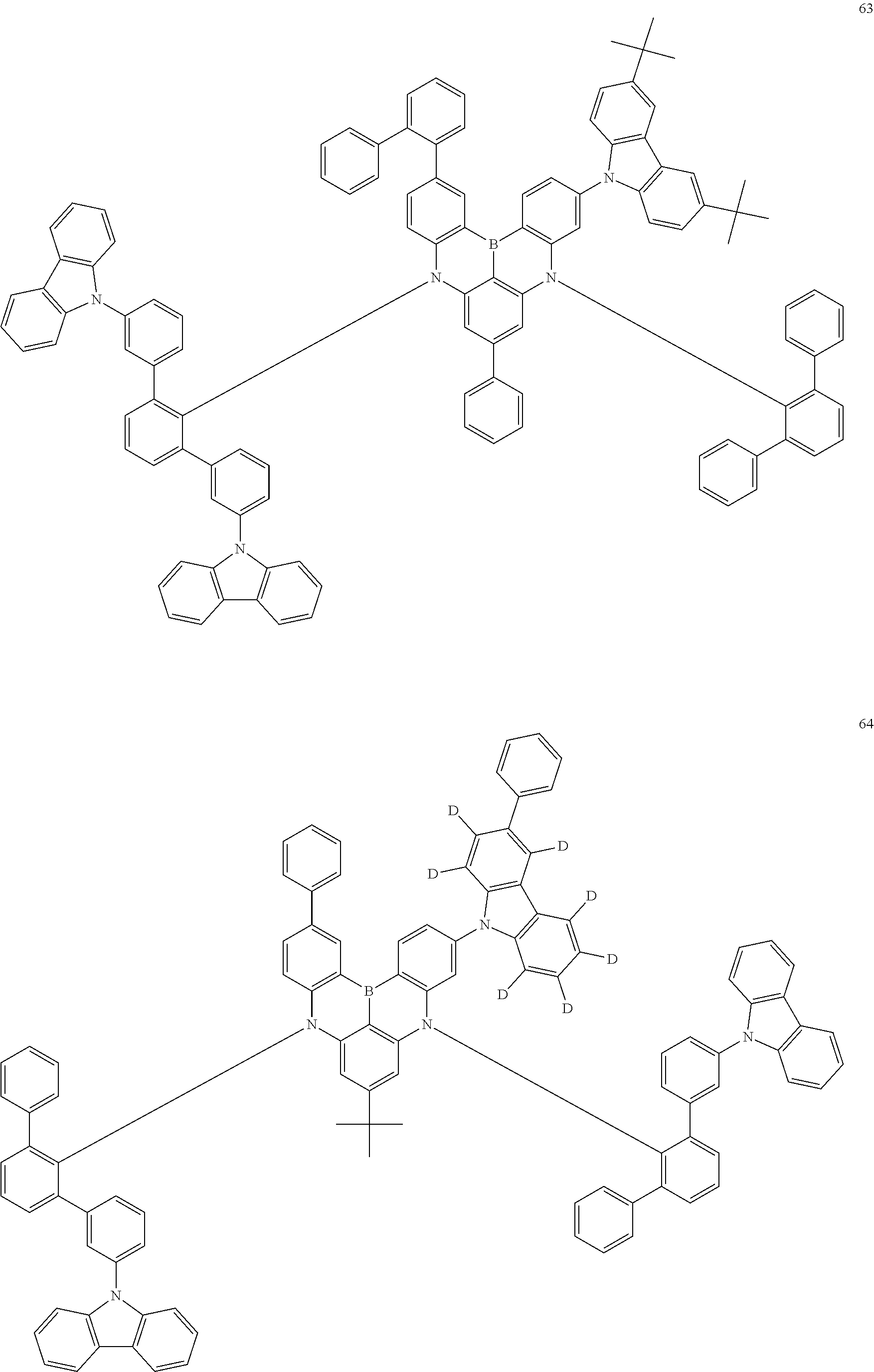 [SMILES: CC(C)(C)c1ccc2c(c1)c1cc(C(C)(C)C)ccc1n2-c1ccc2c(c1)N(c1c(-c3ccccc3)cccc1-c1ccccc1)c1cc(-c3ccccc3)cc3c1B2c1cc(-c2ccccc2-c2ccccc2)ccc1N3c1c(-c2cccc(-n3c4ccccc4c4ccccc43)c2)cccc1-c1cccc(-n2c3ccccc3c3ccccc32)c1 ; [2H]c1c([2H])c([2H])c2c(c1[2H])c1c([2H])c(-c3ccccc3)c([2H])c([2H])c1n2-c1ccc2c(c1)N(c1c(-c3ccccc3)cccc1-c1cccc(-n3c4ccccc4c4ccccc43)c1)c1cc(C(C)(C)C)cc3c1B2c1cc(-c2ccccc2)ccc1N3c1c(-c2ccccc2)cccc1-c1cccc(-n2c3ccccc3c3ccccc32)c1]

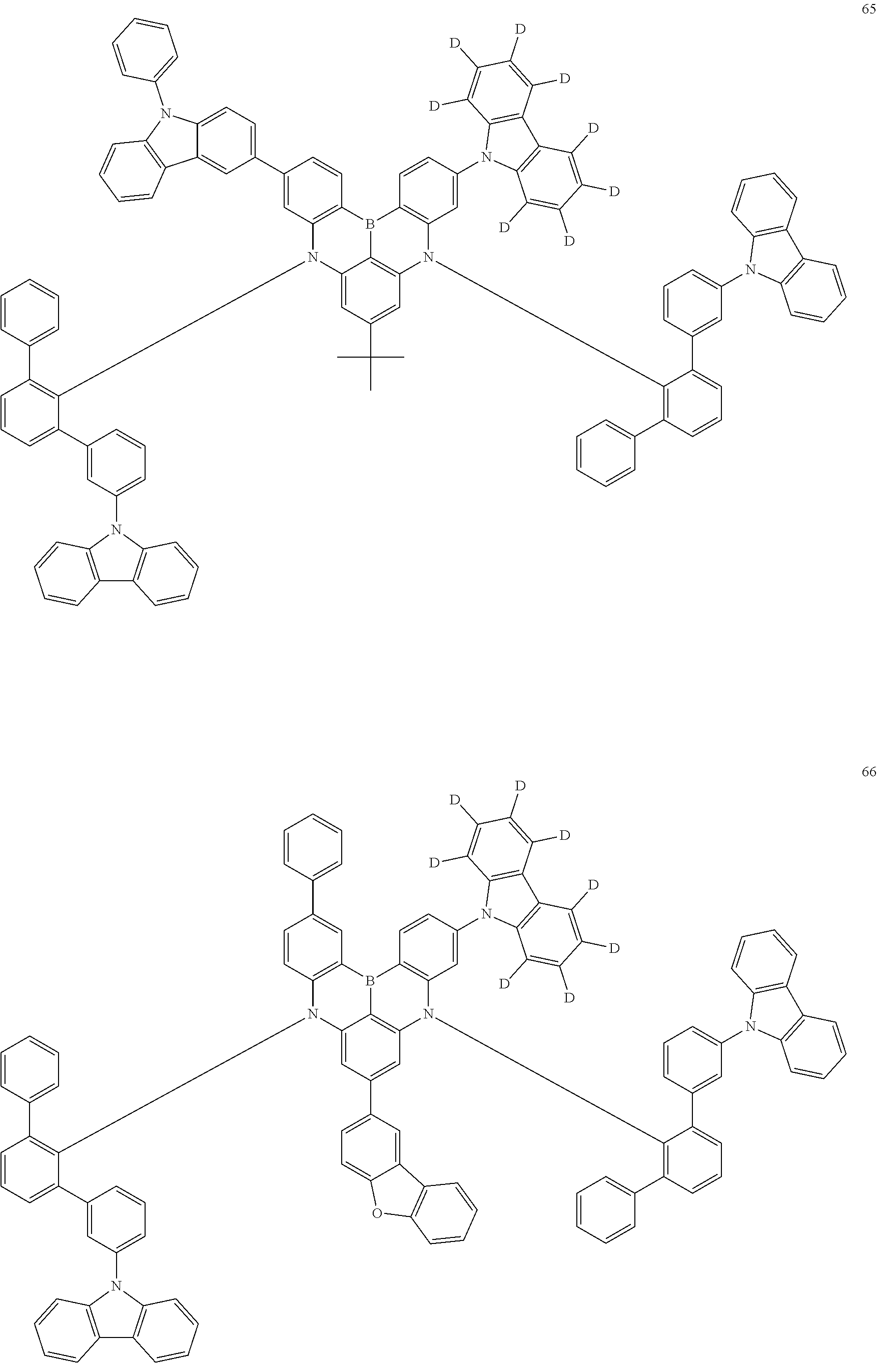 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1cccc(-n3c4ccccc4c4ccccc43)c1)c1cc(C(C)(C)C)cc3c1B2c1ccc(-c2ccc4c(c2)c2ccccc2n4-c2ccccc2)cc1N3c1c(-c2ccccc2)cccc1-c1cccc(-n2c3ccccc3c3ccccc32)c1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1cccc(-n3c4ccccc4c4ccccc43)c1)c1cc(-c3ccc4oc5ccccc5c4c3)cc3c1B2c1cc(-c2ccccc2)ccc1N3c1c(-c2ccccc2)cccc1-c1cccc(-n2c3ccccc3c3ccccc32)c1]

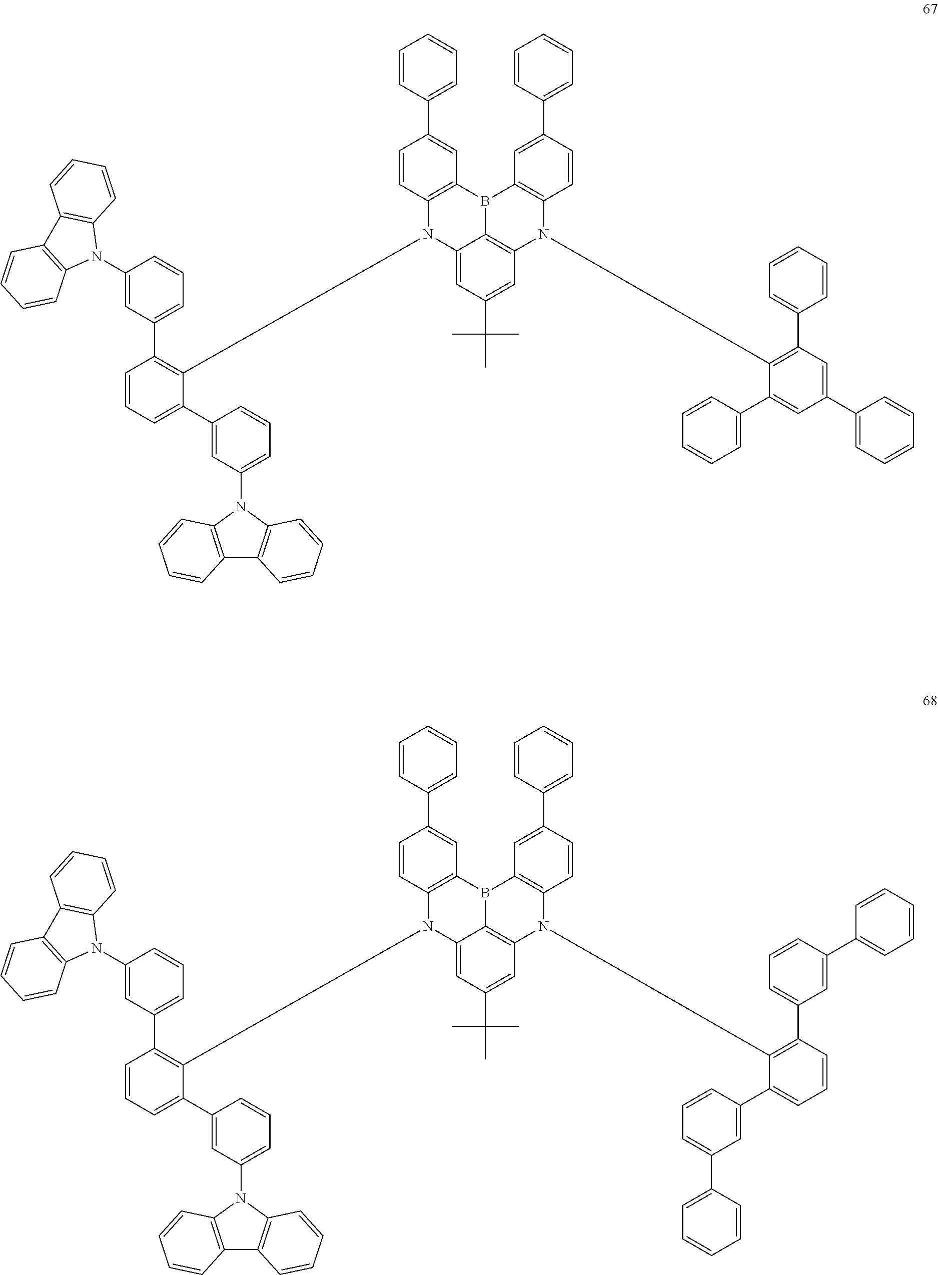 [SMILES: CC(C)(C)c1cc2c3c(c1)N(c1c(-c4ccccc4)cc(-c4ccccc4)cc1-c1ccccc1)c1ccc(-c4ccccc4)cc1B3c1cc(-c3ccccc3)ccc1N2c1c(-c2cccc(-n3c4ccccc4c4ccccc43)c2)cccc1-c1cccc(-n2c3ccccc3c3ccccc32)c1 ; CC(C)(C)c1cc2c3c(c1)N(c1c(-c4cccc(-n5c6ccccc6c6ccccc65)c4)cccc1-c1cccc(-n4c5ccccc5c5ccccc54)c1)c1ccc(-c4ccccc4)cc1B3c1cc(-c3ccccc3)ccc1N2c1c(-c2cccc(-c3ccccc3)c2)cccc1-c1cccc(-c2ccccc2)c1]

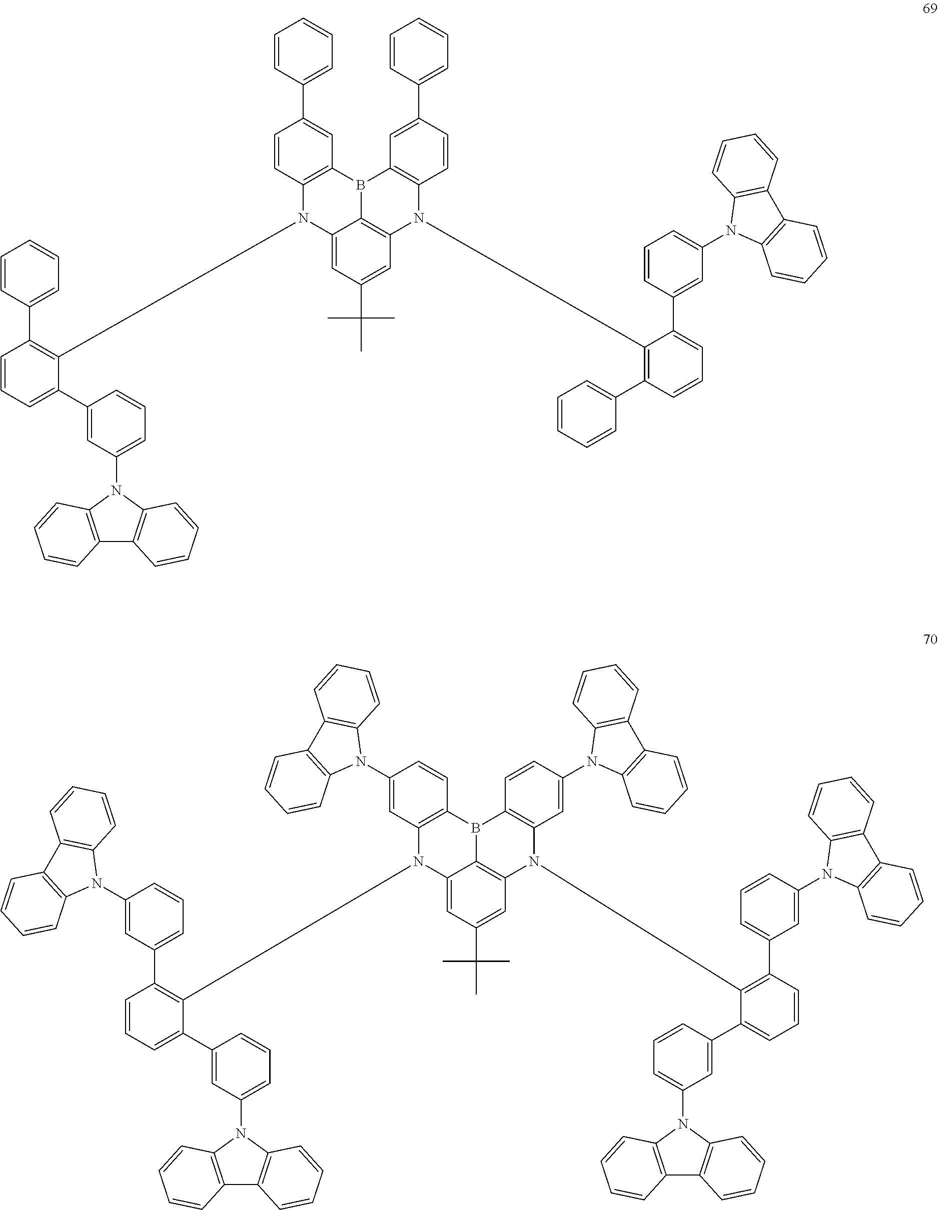 [SMILES: CC(C)(C)c1cc2c3c(c1)N(c1c(-c4ccccc4)cccc1-c1cccc(-n4c5ccccc5c5ccccc54)c1)c1ccc(-c4ccccc4)cc1B3c1cc(-c3ccccc3)ccc1N2c1c(-c2ccccc2)cccc1-c1cccc(-n2c3ccccc3c3ccccc32)c1 ; CC(C)(C)c1cc2c3c(c1)N(c1c(-c4cccc(-n5c6ccccc6c6ccccc65)c4)cccc1-c1cccc(-n4c5ccccc5c5ccccc54)c1)c1cc(-n4c5ccccc5c5ccccc54)ccc1B3c1ccc(-n3c4ccccc4c4ccccc43)cc1N2c1c(-c2cccc(-n3c4ccccc4c4ccccc43)c2)cccc1-c1cccc(-n2c3ccccc3c3ccccc32)c1]

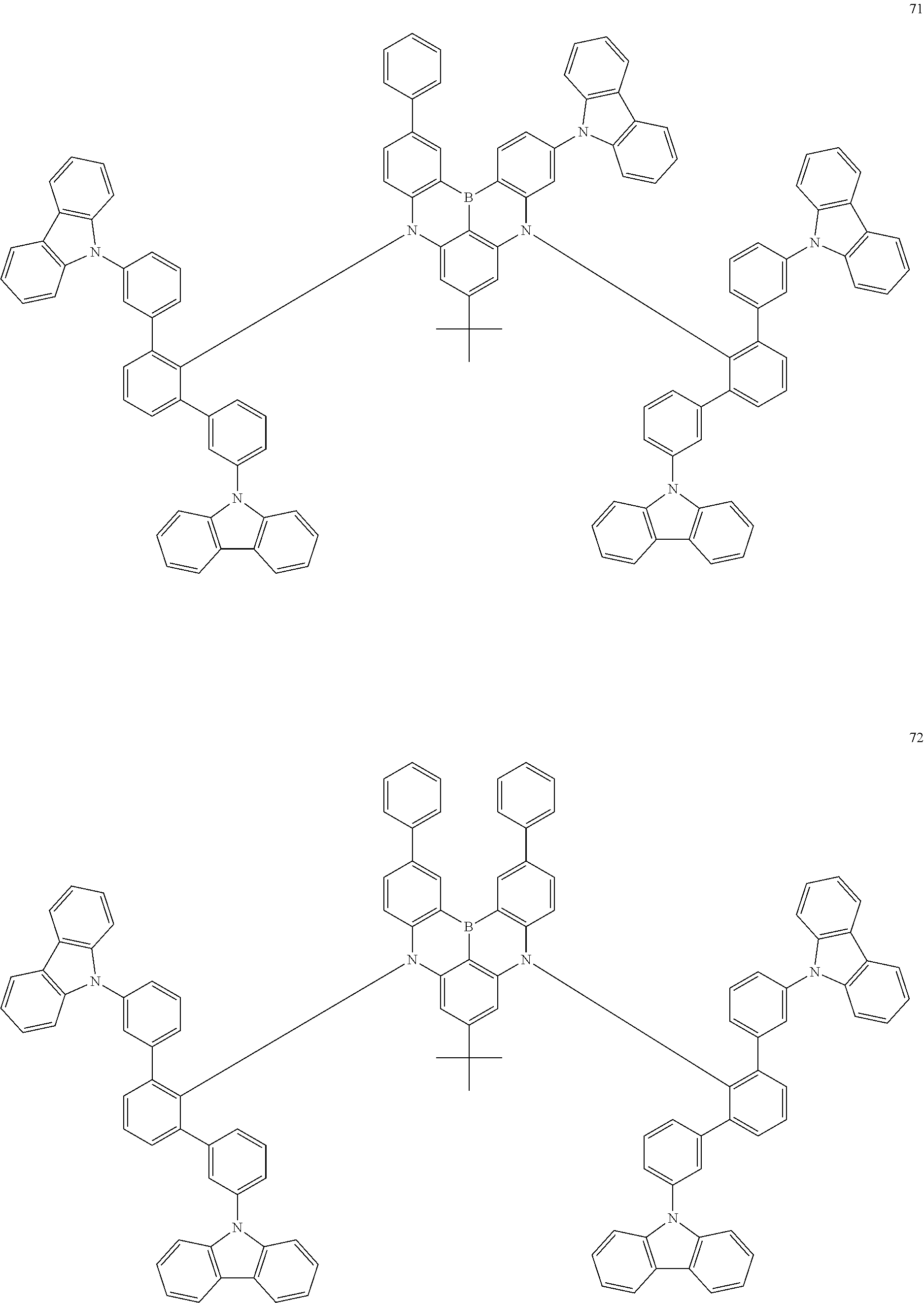 [SMILES: CC(C)(C)c1cc2c3c(c1)N(c1c(-c4cccc(-n5c6ccccc6c6ccccc65)c4)cccc1-c1cccc(-n4c5ccccc5c5ccccc54)c1)c1cc(-n4c5ccccc5c5ccccc54)ccc1B3c1cc(-c3ccccc3)ccc1N2c1c(-c2cccc(-n3c4ccccc4c4ccccc43)c2)cccc1-c1cccc(-n2c3ccccc3c3ccccc32)c1 ; CC(C)(C)c1cc2c3c(c1)N(c1c(-c4cccc(-n5c6ccccc6c6ccccc65)c4)cccc1-c1cccc(-n4c5ccccc5c5ccccc54)c1)c1ccc(-c4ccccc4)cc1B3c1cc(-c3ccccc3)ccc1N2c1c(-c2cccc(-n3c4ccccc4c4ccccc43)c2)cccc1-c1cccc(-n2c3ccccc3c3ccccc32)c1]

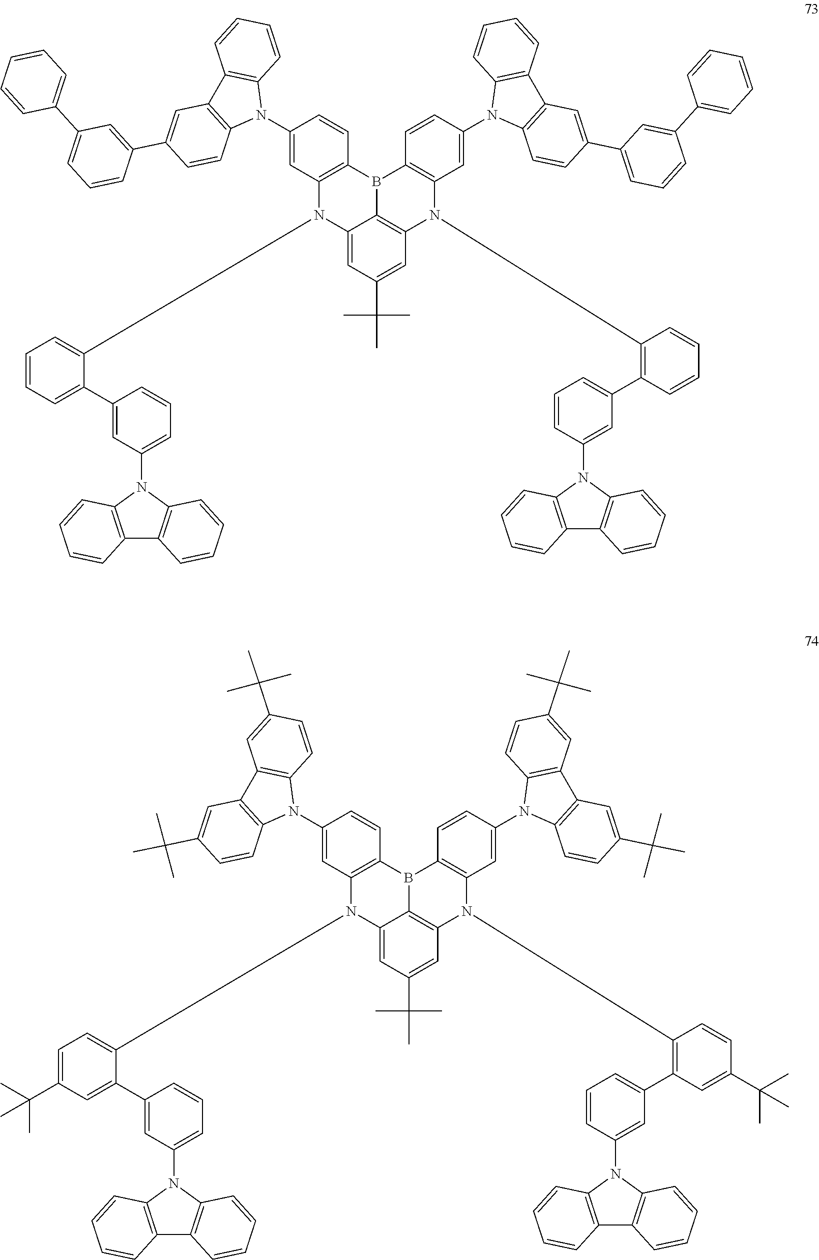 [SMILES: CC(C)(C)c1cc2c3c(c1)N(c1ccccc1-c1cccc(-n4c5ccccc5c5ccccc54)c1)c1cc(-n4c5ccccc5c5cc(-c6cccc(-c7ccccc7)c6)ccc54)ccc1B3c1ccc(-n3c4ccccc4c4cc(-c5cccc(-c6ccccc6)c5)ccc43)cc1N2c1ccccc1-c1cccc(-n2c3ccccc3c3ccccc32)c1 ; CC(C)(C)c1ccc(N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4ccc(C(C)(C)C)cc4-c4cccc(-n5c6ccccc6c6ccccc65)c4)c4cc(C(C)(C)C)cc2c43)c(-c2cccc(-n3c4ccccc4c4ccccc43)c2)c1]

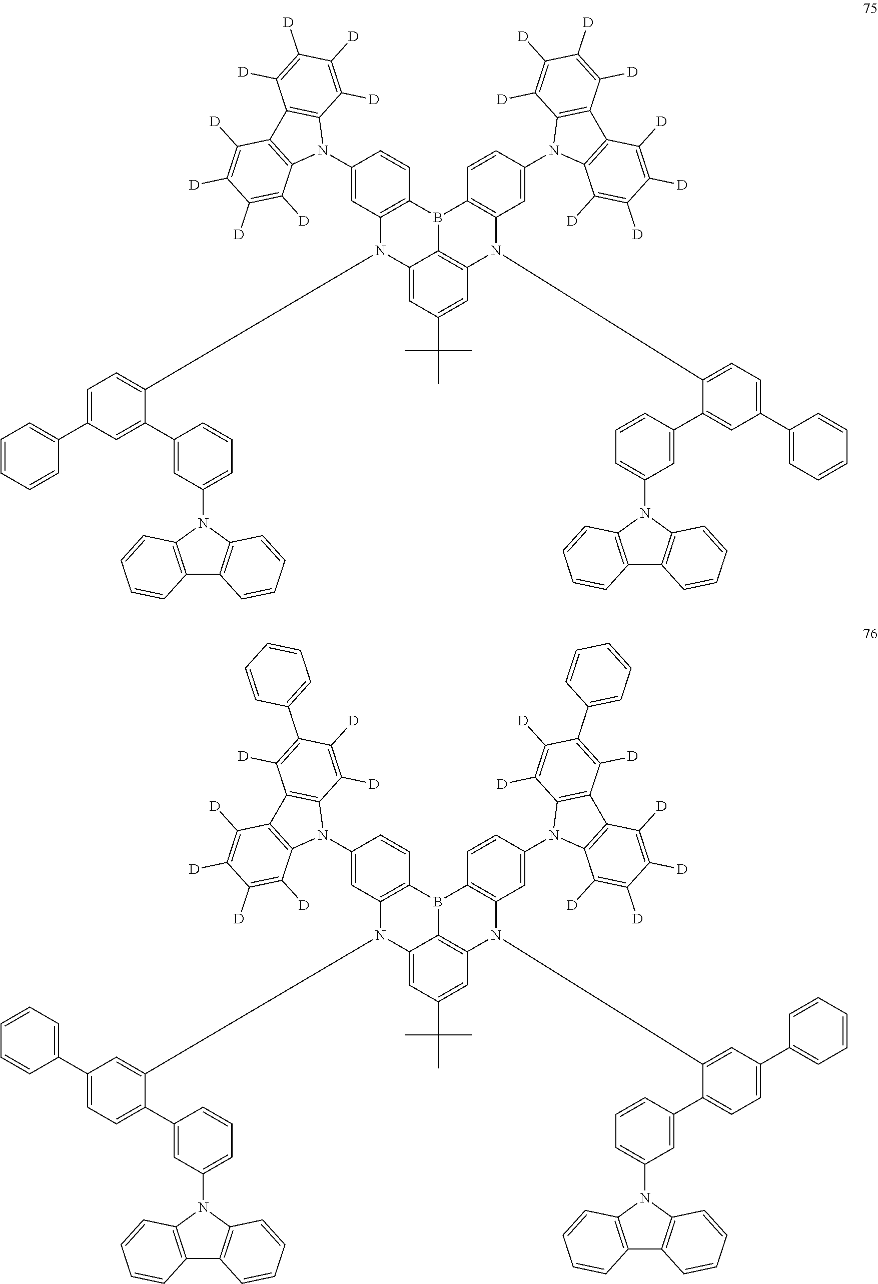

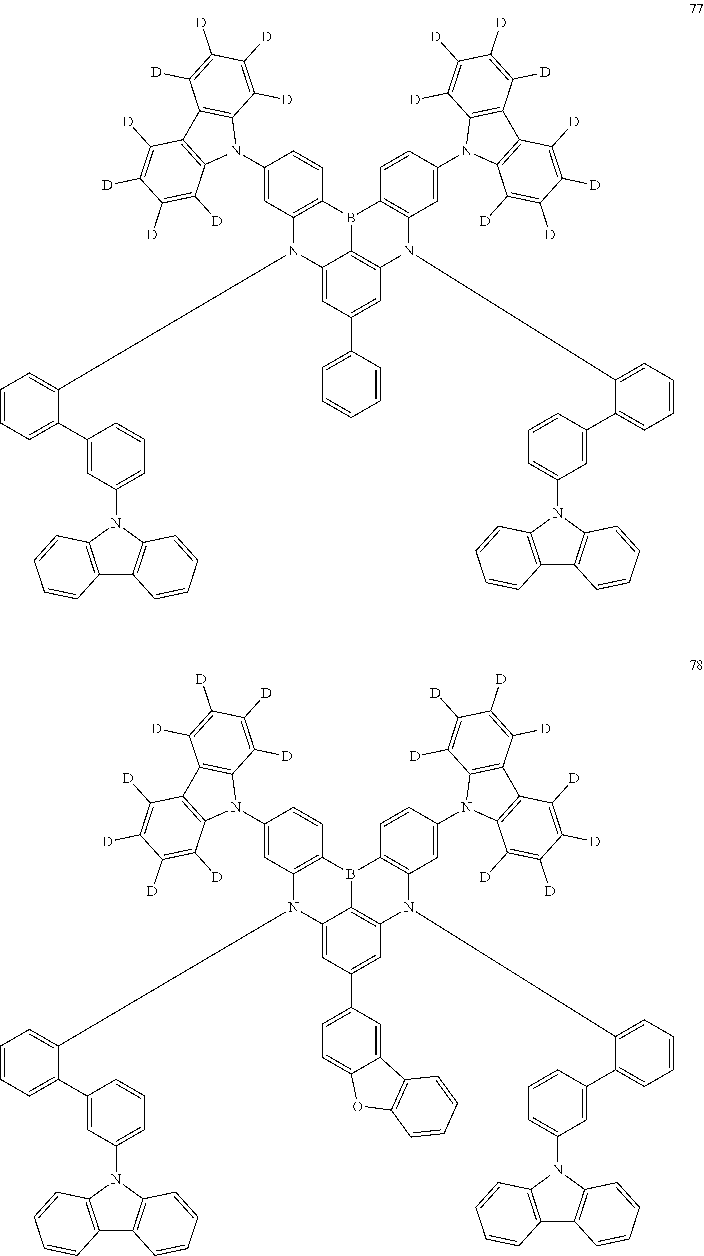

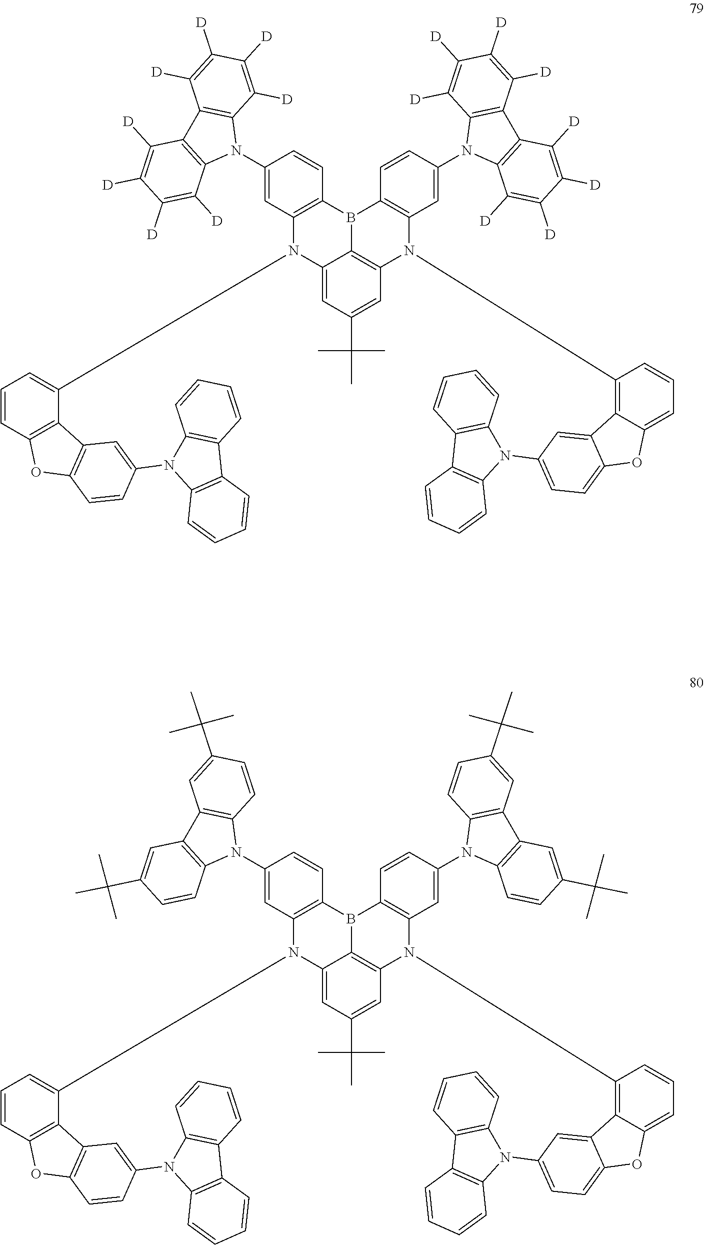 [SMILES: [2H]c1c([2H])c([2H])c2c(c1[2H])c1c([2H])c([2H])c([2H])c([2H])c1n2-c1ccc2c(c1)N(c1cccc3oc4ccc(-n5c6ccccc6c6ccccc65)cc4c13)c1cc(C(C)(C)C)cc3c1B2c1ccc(-n2c4c([2H])c([2H])c([2H])c([2H])c4c4c([2H])c([2H])c([2H])c([2H])c42)cc1N3c1cccc2oc3ccc(-n4c5ccccc5c5ccccc54)cc3c12 ; CC(C)(C)c1cc2c3c(c1)N(c1cccc4oc5ccc(-n6c7ccccc7c7ccccc76)cc5c14)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1N2c1cccc2oc3ccc(-n4c5ccccc5c5ccccc54)cc3c12]

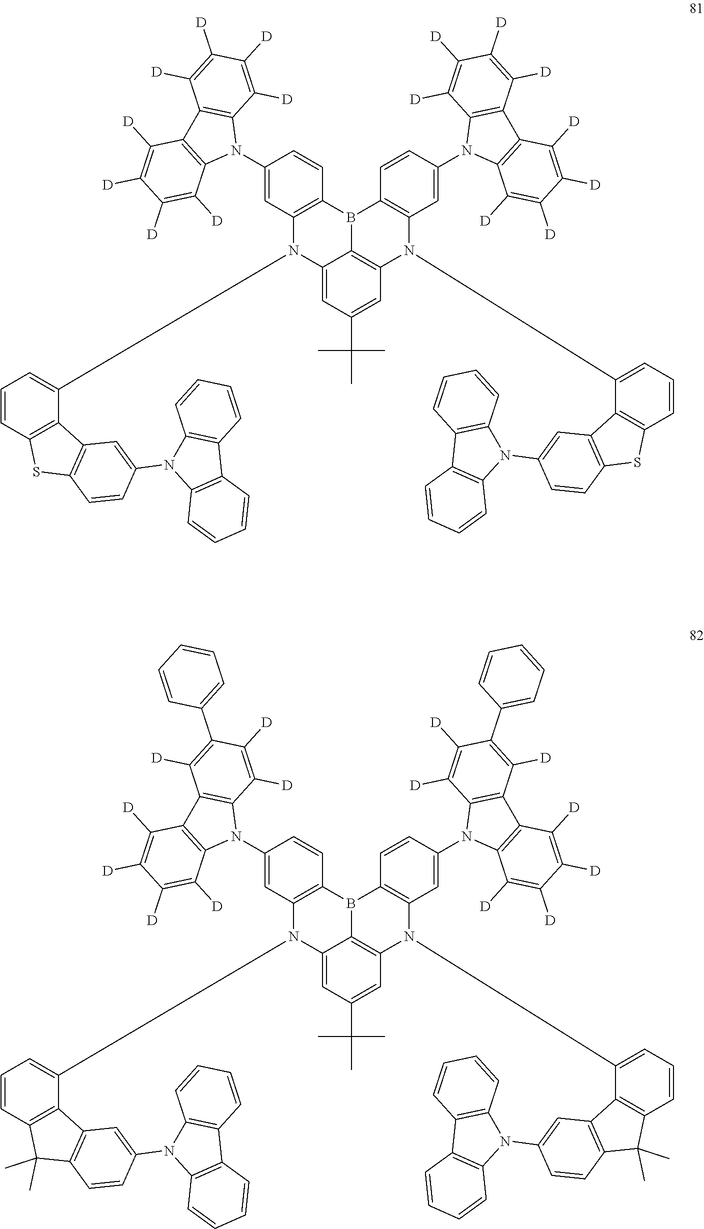

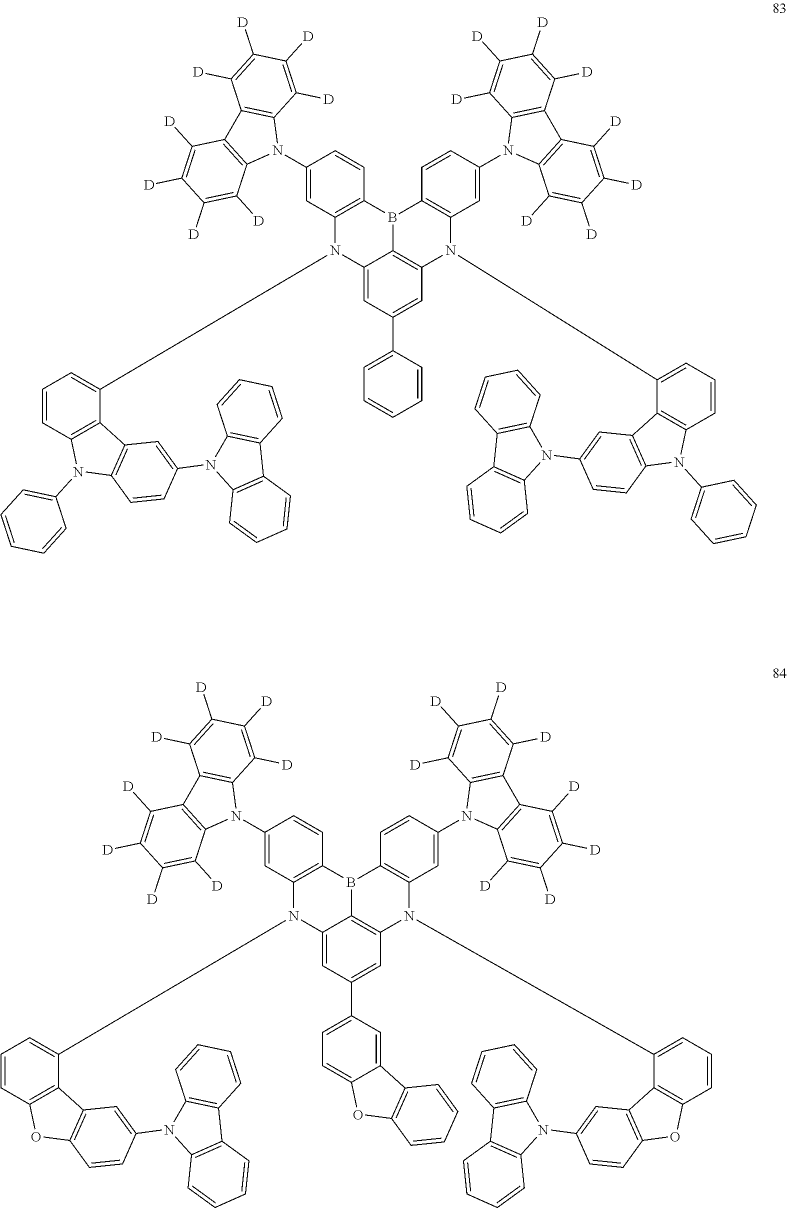

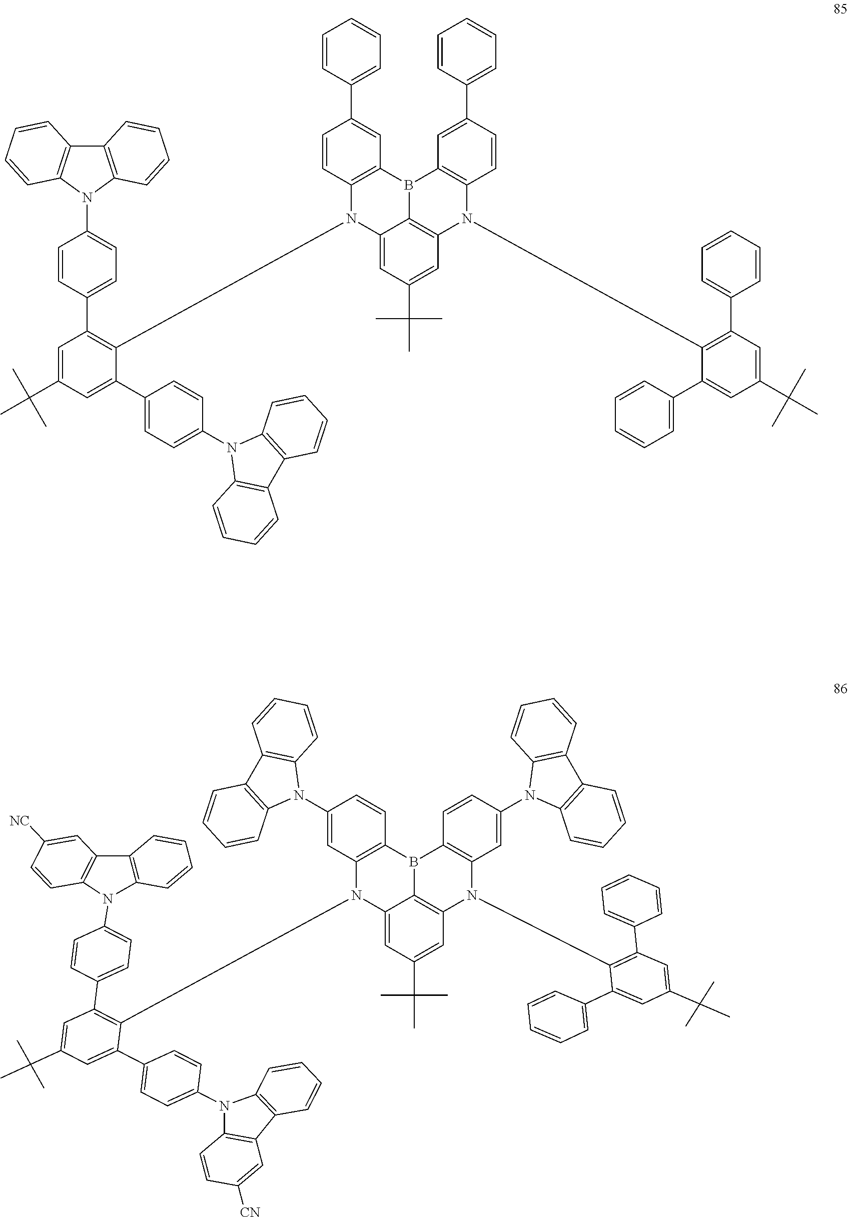

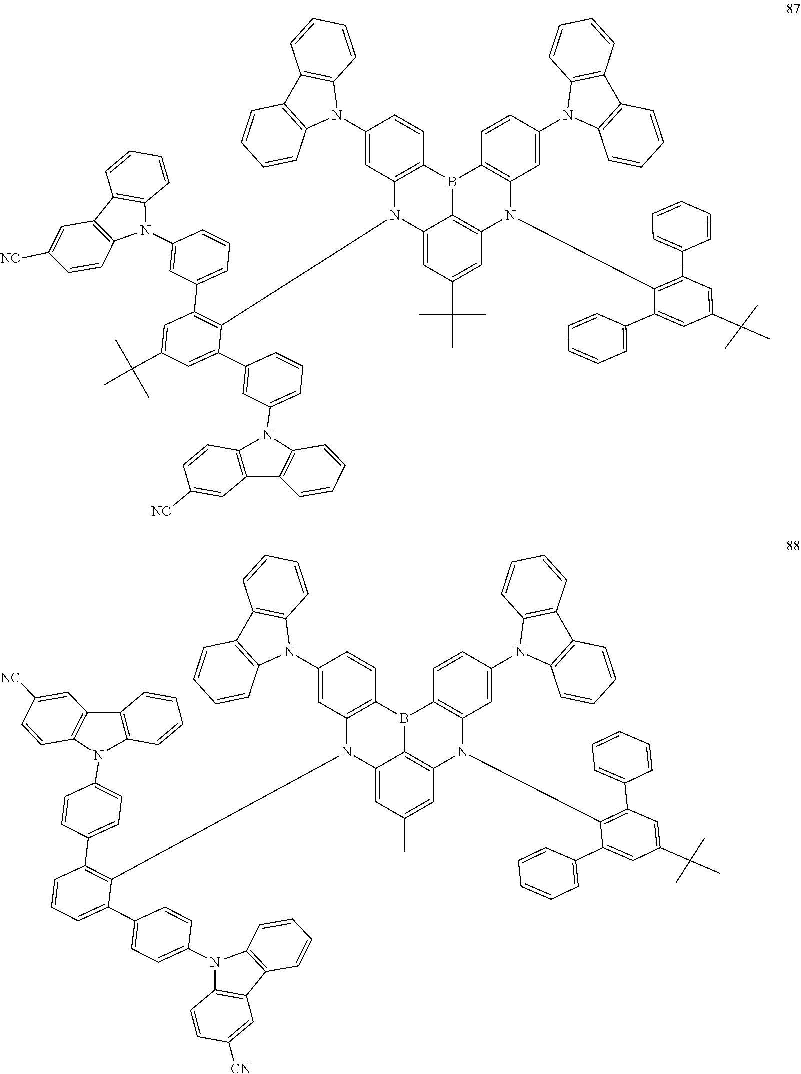 [SMILES: CC(C)(C)c1cc(-c2ccccc2)c(N2c3cc(-n4c5ccccc5c5ccccc54)ccc3B3c4ccc(-n5c6ccccc6c6ccccc65)cc4N(c4c(-c5cccc(-n6c7ccccc7c7cc(C#N)ccc76)c5)cc(C(C)(C)C)cc4-c4cccc(-n5c6ccccc6c6cc(C#N)ccc65)c4)c4cc(C(C)(C)C)cc2c43)c(-c2ccccc2)c1 ; Cc1cc2c3c(c1)N(c1c(-c4ccccc4)cc(C(C)(C)C)cc1-c1ccccc1)c1cc(-n4c5ccccc5c5ccccc54)ccc1B3c1ccc(-n3c4ccccc4c4ccccc43)cc1N2c1c(-c2ccc(-n3c4ccccc4c4cc(C#N)ccc43)cc2)cccc1-c1ccc(-n2c3ccccc3c3cc(C#N)ccc32)cc1]

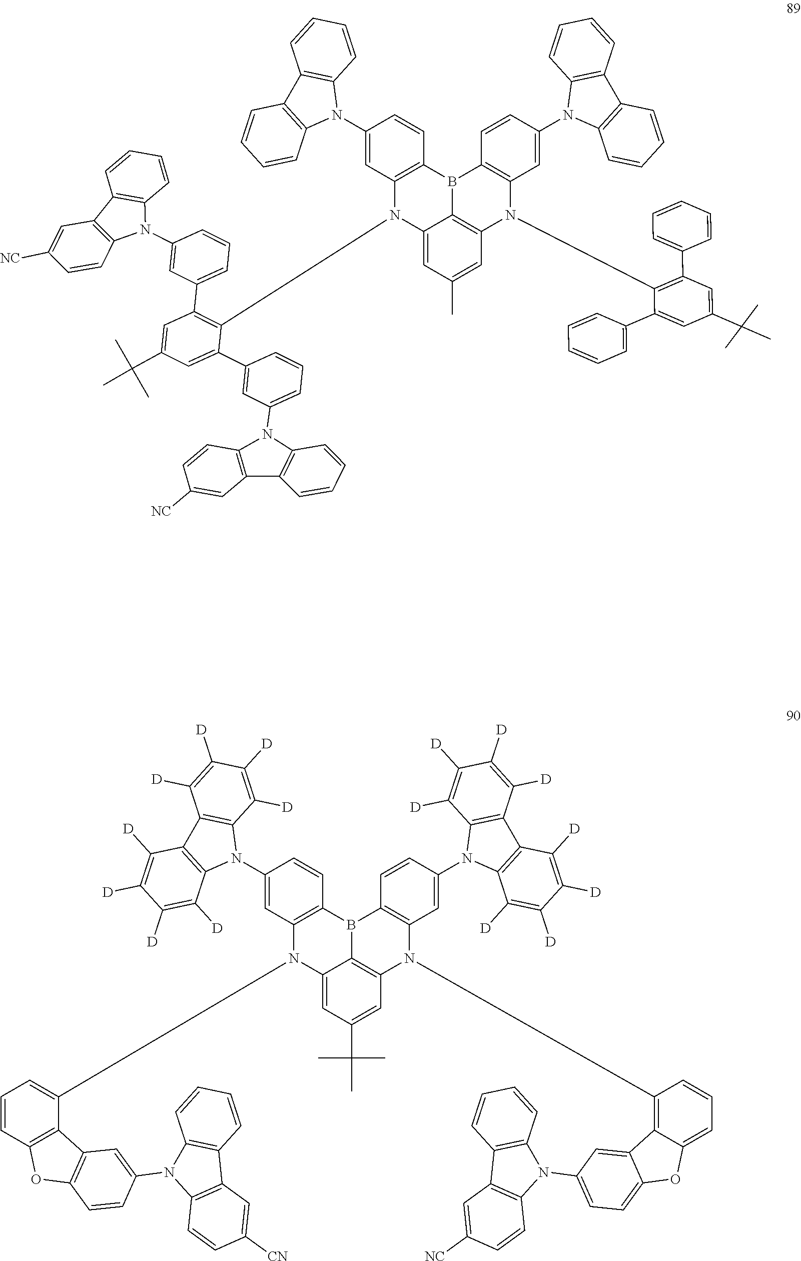 [SMILES: Cc1cc2c3c(c1)N(c1c(-c4cccc(-n5c6ccccc6c6cc(C#N)ccc65)c4)cc(C(C)(C)C)cc1-c1cccc(-n4c5ccccc5c5cc(C#N)ccc54)c1)c1cc(-n4c5ccccc5c5ccccc54)ccc1B3c1ccc(-n3c4ccccc4c4ccccc43)cc1N2c1c(-c2ccccc2)cc(C(C)(C)C)cc1-c1ccccc1 ; [2H]c1c([2H])c([2H])c2c(c1[2H])c1c([2H])c([2H])c([2H])c([2H])c1n2-c1ccc2c(c1)N(c1cccc3oc4ccc(-n5c6ccccc6c6cc(C#N)ccc65)cc4c13)c1cc(C(C)(C)C)cc3c1B2c1ccc(-n2c4c([2H])c([2H])c([2H])c([2H])c4c4c([2H])c([2H])c([2H])c([2H])c42)cc1N3c1cccc2oc3ccc(-n4c5ccccc5c5cc(C#N)ccc54)cc3c12]

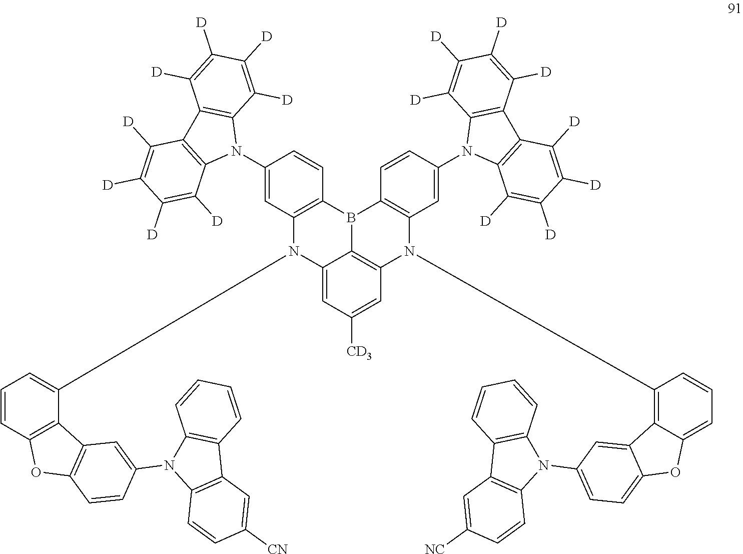 [SMILES: [2H]c1c([2H])c([2H])c2c(c1[2H])c1c([2H])c([2H])c([2H])c([2H])c1n2-c1ccc2c(c1)N(c1cccc3oc4ccc(-n5c6ccccc6c6cc(C#N)ccc65)cc4c13)c1cc(C([2H])([2H])[2H])cc3c1B2c1ccc(-n2c4c([2H])c([2H])c([2H])c([2H])c4c4c([2H])c([2H])c([2H])c([2H])c42)cc1N3c1cccc2oc3ccc(-n4c5ccccc5c5cc(C#N)ccc54)cc3c12]

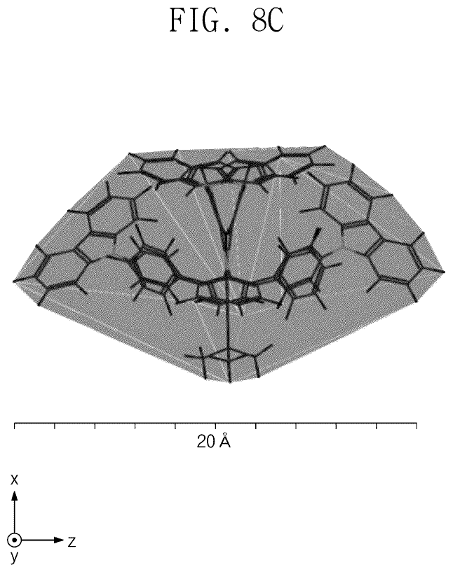

FIG. 8A to FIG. 8C are each an image showing a three-dimensional structure of the polycyclic compound according to one or more embodiments. FIG. 8A to FIG. 8C each shows a three-dimensional structure of Compound 1 among the compounds in Compound Group 1. FIG. 8A shows a three-dimensional structure of Compound 1 if (e.g., when) a surface defined by the x-axis and the y-axis is a front surface, and FIG. 8B shows a three-dimensional structure of Compound 1 if (e.g., when) a surface defined by the y-axis and the z-axis is a front surface. FIG. 8C illustrates a three-dimensional structure of Compound 1 if (e.g., when) the compound in FIG. 8A is viewed from a bottom surface.

A ruler at 2 Å intervals is shown to check the length of Compound 1 in the x-axis, y-axis, and z-axis directions. The length of the x-axis direction may be checked in FIG. 8A, the length of the y-axis direction may be checked in FIG. 8B, and the length of the z-axis direction may be checked in FIG. 8C. Each of the lengths of the x-axis, y-axis, and z-axis directions in FIG. 8A to FIG. 8C refers to a length between substituents located on both (e.g., simultaneously) farthest-out sides along the x-axis, y-axis, and z-axis directions in Compound 1.

Referring to FIG. 8A, it may be seen that a length in x-axis direction may be about 18 Å. In some embodiments, referring to FIG. 8B, it may be seen that a length in the y-axis direction may be about 14 Å, and referring to FIG. 8C, it may be seen that a length in the z-axis direction may be about 21 Å. For example, the polycyclic compound according to one or more embodiments may be seen to have the similar drawing in each of the x-axis direction, the y-axis-direction, and the z-axis direction, and thus it may be seen the polycyclic compound according to one or more embodiments including the biphenyl moiety including the carbazole moiety has a molecular shape close to a spherical form.

Therefore, the polycyclic compound according to one or more embodiments may have a three-dimensional structure close to a spherical shape, planarity thereof may be suppressed or reduced to thereby decrease intermolecular interaction, and excellent or suitable material stability may be exhibited due to a structure where the fused ring core is surrounded and protected by a substituent and/or the like.

In the light-emitting element ED according to one or more embodiments, the emission layer EML can be a delayed fluorescence emission layer including a host and a dopant. For example, the emission layer EML can emit thermally activated delayed fluorescence (TADF). The polycyclic compound of one or more embodiments can be a delayed fluorescence dopant. For example, the polycyclic compound of one or more embodiments can be a thermally activated delayed fluorescence dopant.

The emission layer EML may include (e.g., contain) the polycyclic compound according to one or more embodiments as a dopant. The polycyclic compound according to one or more embodiments used for dopant materials may have characteristics in that matching between a host material and a HOMO energy level is easy. The light-emitting element ED emitting thermal active delayed fluorescence and blue light while using a triplet exciton may include host materials that have a wide band gap and a high T1 energy level. For example, the light-emitting element ED according to one or more embodiments may contain the polycyclic compound according to one or more embodiments and a second compound to be described in more detail later as hole transporting host materials. For example, the hole transporting host materials may include a carbazole group. The hole transporting host materials including the carbazole group has a relatively deep HOMO energy level. The hole transporting host materials including the carbazole group may have a HOMO energy level close to about −5.5 eV, but one or more embodiments of the disclosure are not limited thereto.

When the dopant materials have a shallower HOMO energy level than the hole transporting host materials, the dopant traps a hole and directly causes charges recombination, and thus a trap assistant recombination (TAR) phenomenon may be promoted. Therefore, a triplet exciton concentration on the dopant may increase and thus efficiency and lifespan of the element may be reduced. In the polycyclic compound according to one or more embodiments used for the dopant materials, the biphenyl moiety connected to the carbazole moiety is connected to the five-membered fused ring core may have a deep HOMO energy level similar to a deep HOMO energy level of a hole transporting host, and thus the polycyclic compound according to one or more embodiments may contribute to improvements in lifespan and efficiency of the light-emitting element ED.

The polycyclic compound of one or more embodiments may be to emit blue light. For example, the polycyclic compound of one or more embodiments may be a light-emitting material having an emission center wavelength in a wavelength region of about 430 nanometer (nm) to about 490 nm. The polycyclic compound of one or more embodiments may be a light-emitting material having an emission center wavelength in a wavelength region of about 450 nm to about 470 nm.

In one or more embodiments, the emission layer EML includes the polycyclic compound of one or more embodiments and may include at least one among (e.g., selected from among) the second to fourth compounds. In one or more embodiments, the emission layer EML may include the second compound represented by Formula HT-1. For example, the second compound may be used as the hole transporting host material of the emission layer EML.

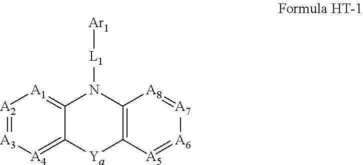

In Formula HT-1, A₁ to A₈ may each independently be N or CR₅₁. For example, all of A₁ to A₈ may be CR₅₁. In one or more embodiments, any one among (e.g., selected from among) A₁ to A₈ may be N, and the rest may be CR₅₁.

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, and/or the like, but one or more embodiments of the disclosure are not limited thereto.

In Formula HT-1, Yₐ may be a direct linkage, CR₅₂R₅₃, or SiR₅₄R₅₅. For example, it may refer to that the two benzene rings linked to the nitrogen atom in Formula HT-1 are linked via a direct linkage,

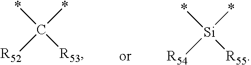

In Formula HT-1, if (e.g., when) Yₐ is a direct linkage, the second compound represented by Formula HT-1 may include a carbazole moiety.

In Formula HT-1, Ar₁ may be a substituted or unsubstituted aryl group having 6 to 30 ring-forming carbon atoms, or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, and/or the like, but one or more embodiments of the disclosure are not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In one or more embodiments, each of R₅₁ to R₅₅ may be bonded to an adjacent group to form a ring. For example, R₅₁ to R₅₅ may each independently be a hydrogen atom or a deuterium atom. R₅₁ to R₅₅ may each independently be an unsubstituted methyl group or an unsubstituted phenyl group.

In one or more embodiments, the second compound represented by Formula HT-1 may be represented by any one among (e.g., selected from among) the compounds represented by Compound Group 2. The emission layer EML may include at least one among (e.g., selected from among) the compounds represented by Compound Group 2 as a hole transporting host material.

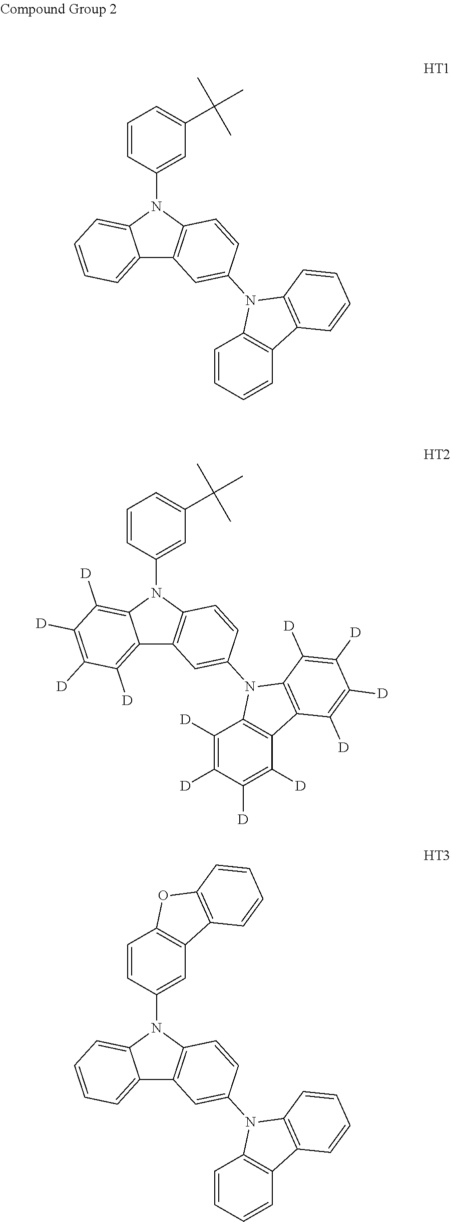 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

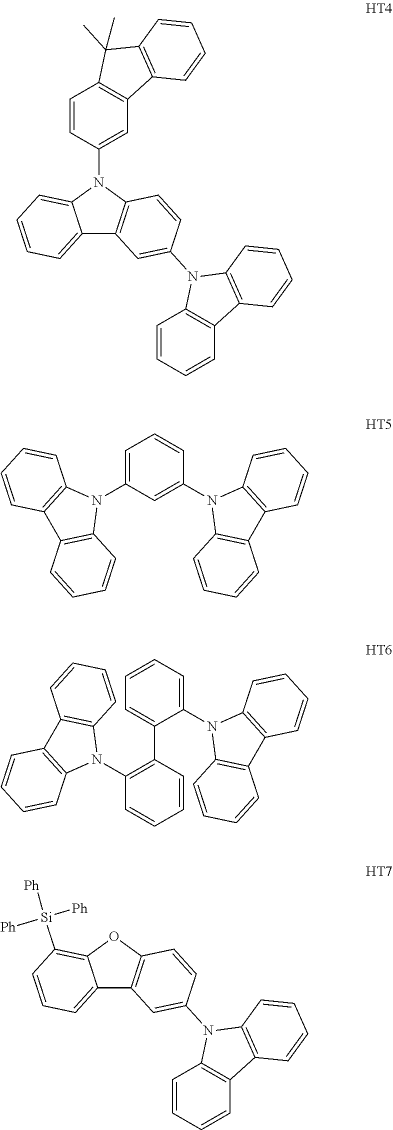 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

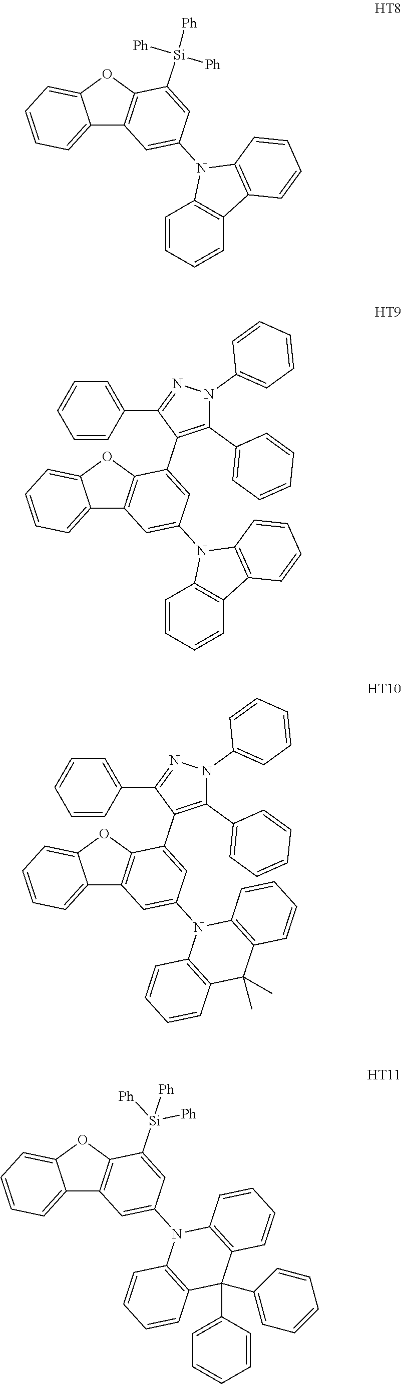 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

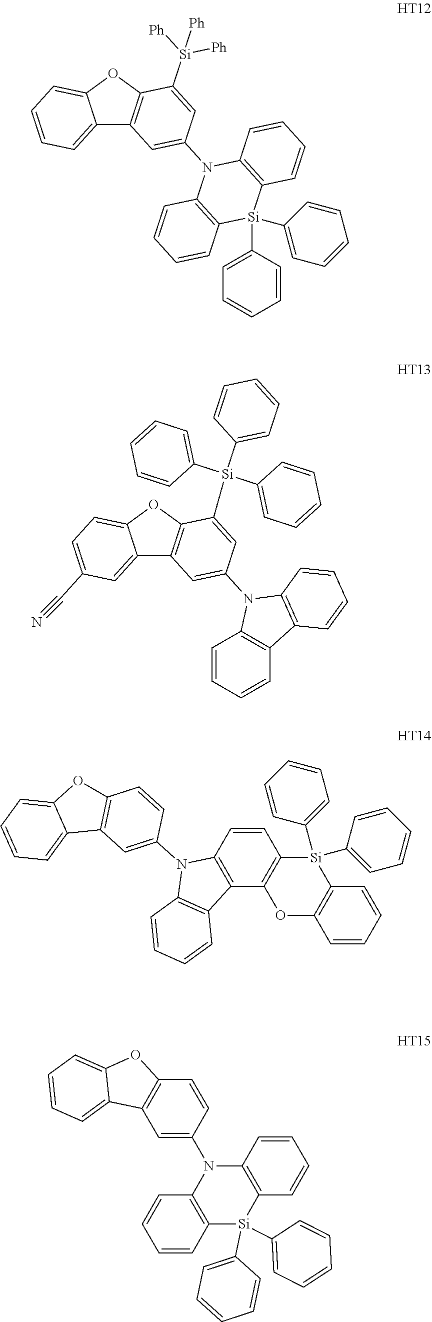 [SMILES: c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1]

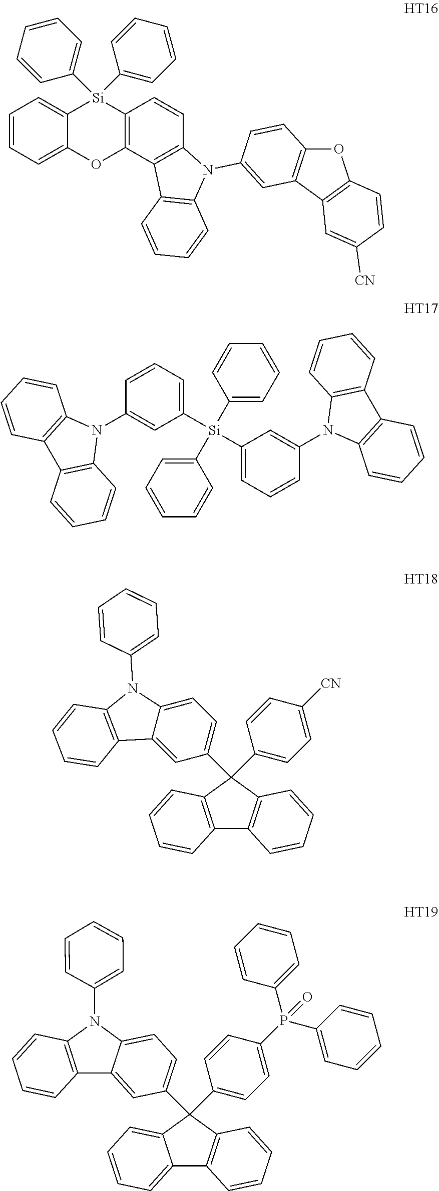 [SMILES: N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1]

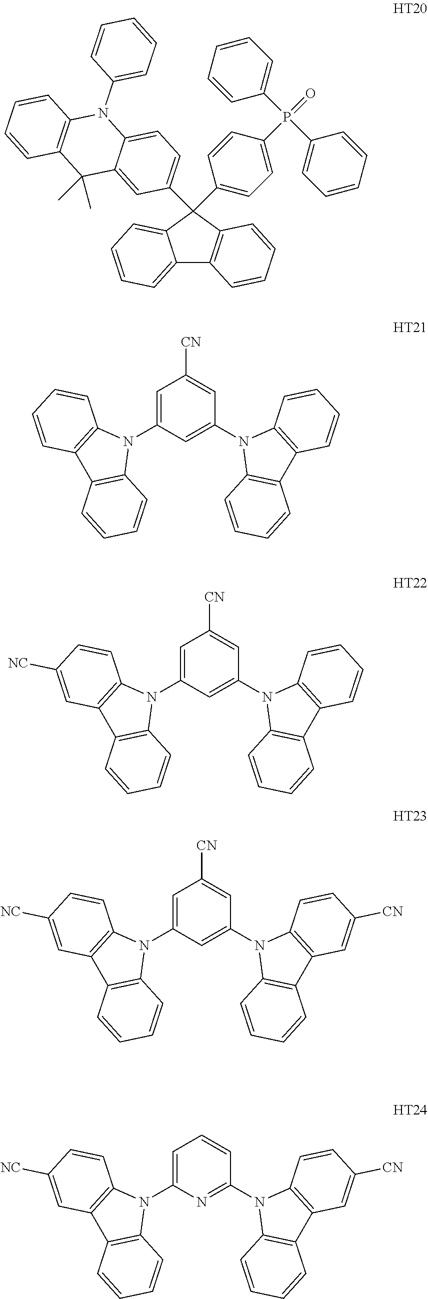 [SMILES: CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

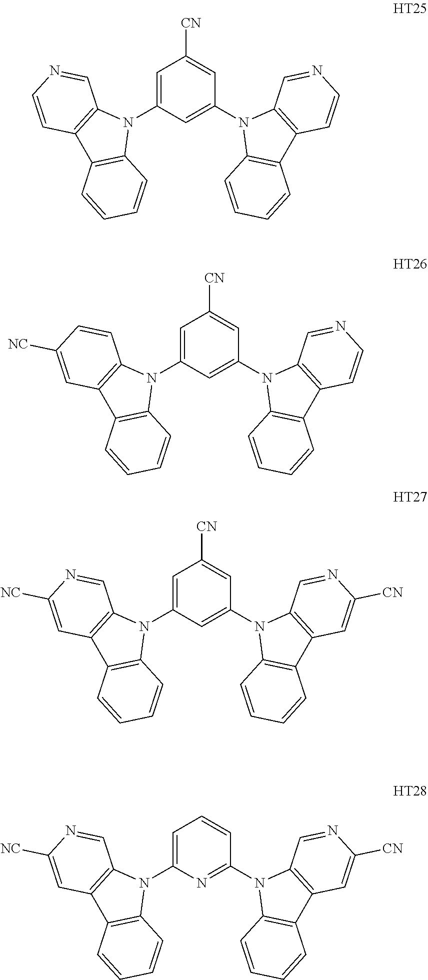 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

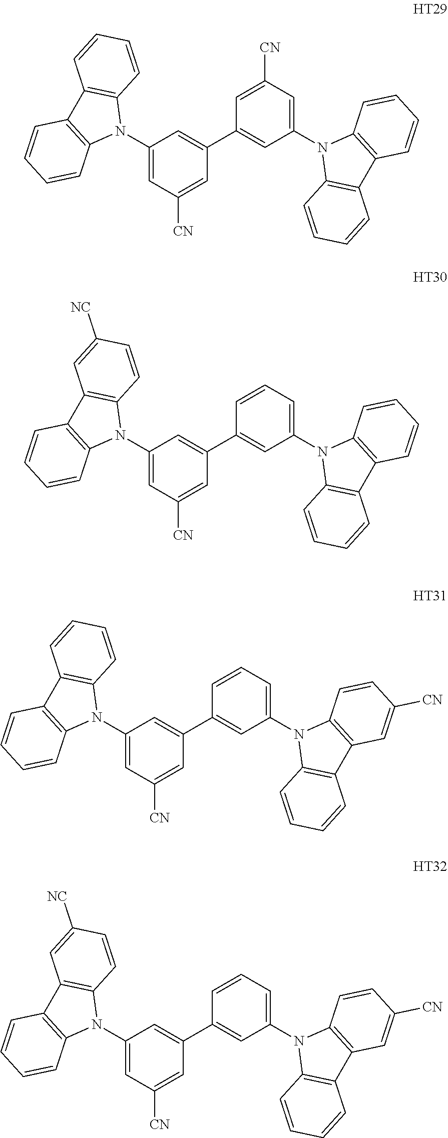 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1]

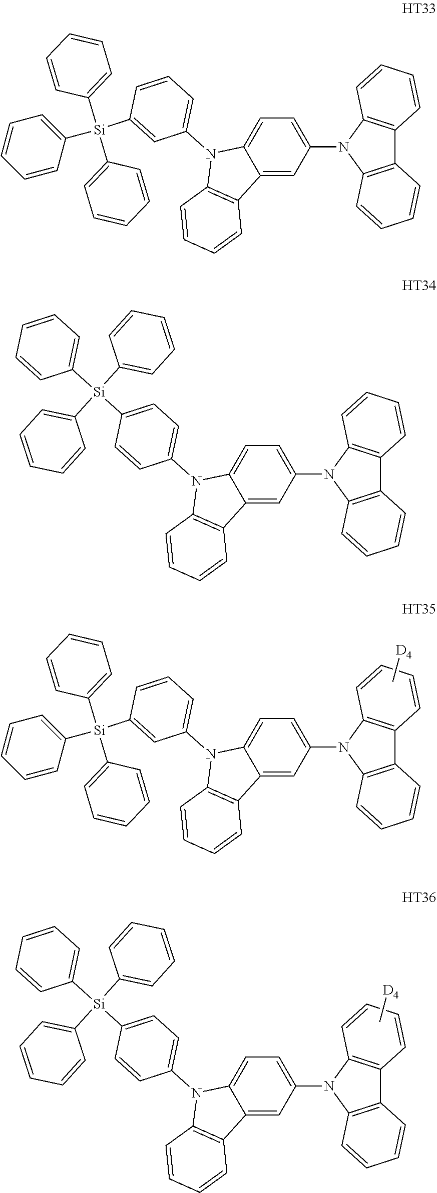

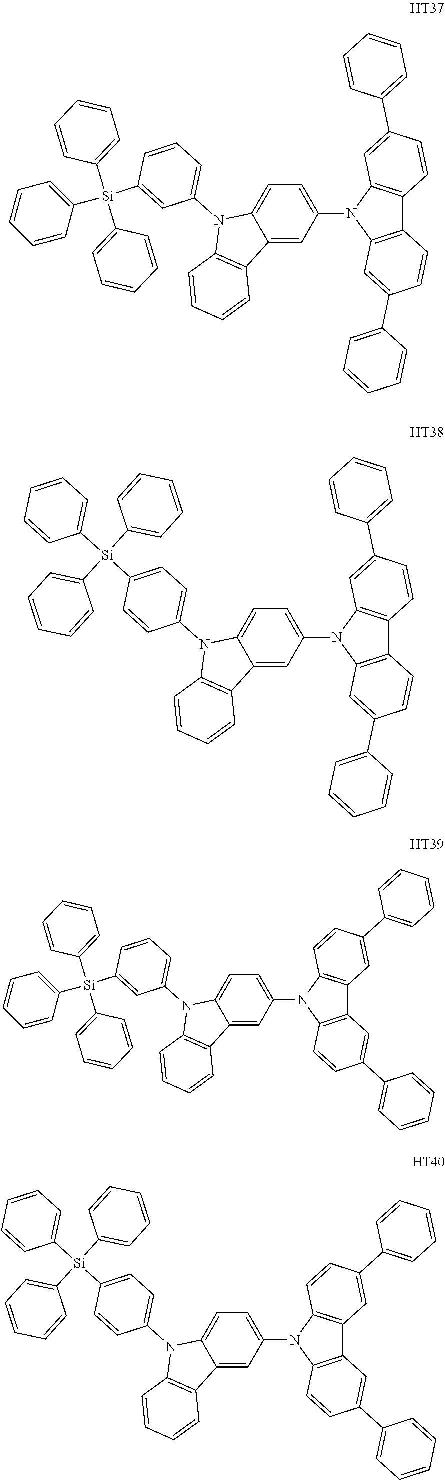 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

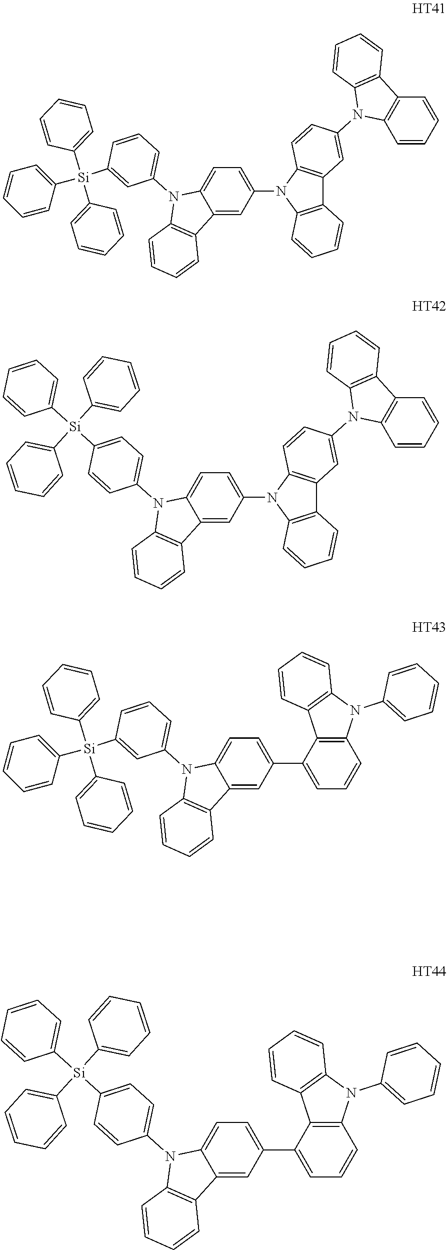 [SMILES: c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1 ; c1ccc(-n2c3ccccc3c3c(-c4ccc5c(c4)c4ccccc4n5-c4cccc([Si](c5ccccc5)(c5ccccc5)c5ccccc5)c4)cccc32)cc1 ; c1ccc(-n2c3ccccc3c3c(-c4ccc5c(c4)c4ccccc4n5-c4ccc([Si](c5ccccc5)(c5ccccc5)c5ccccc5)cc4)cccc32)cc1]

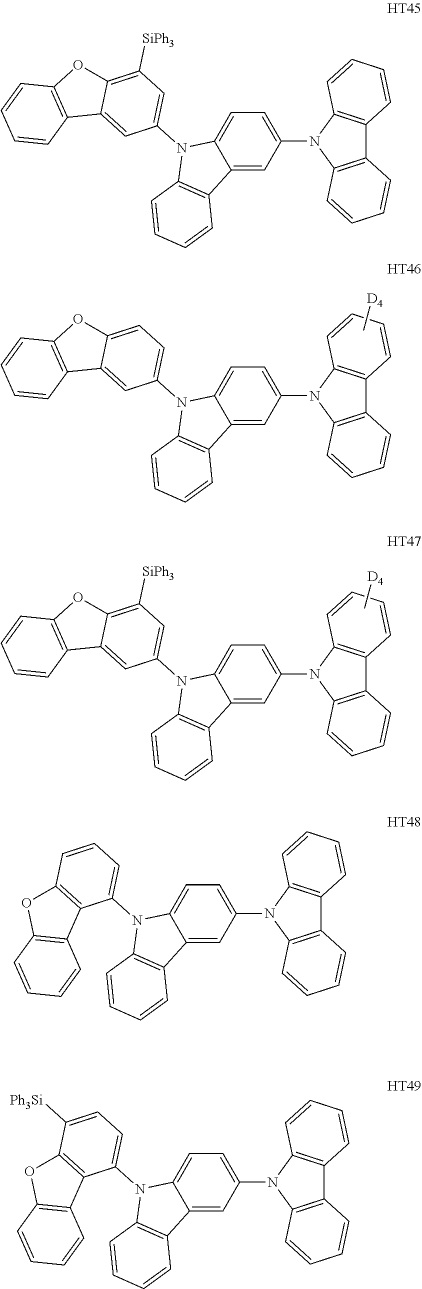

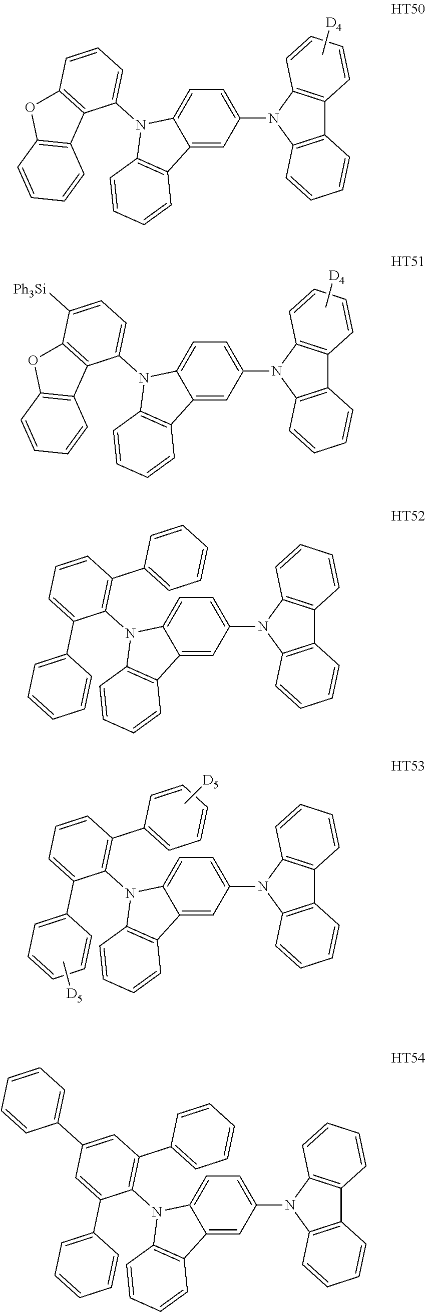

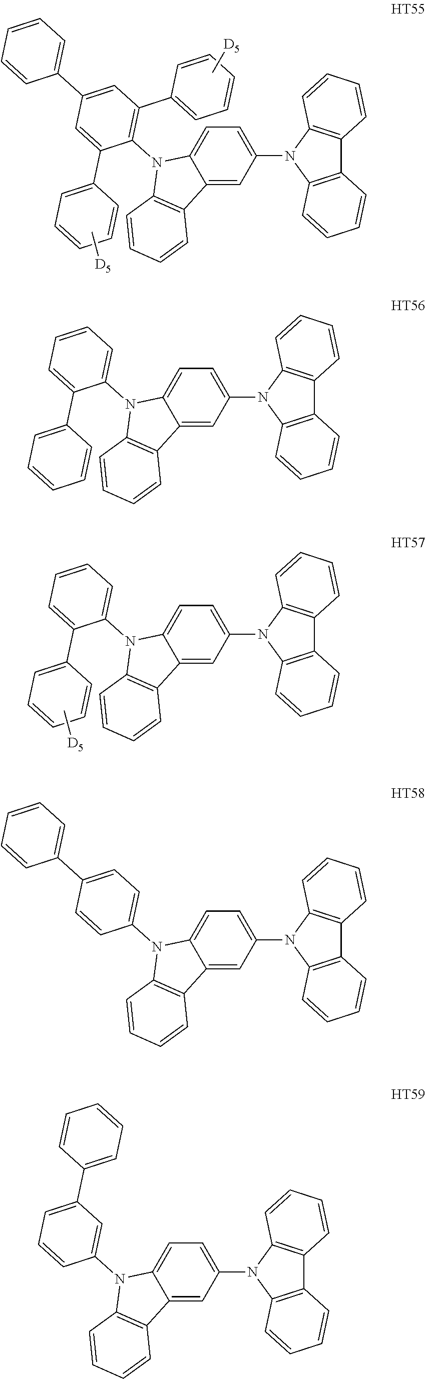

In embodiment compounds presented in Compound Group 2, “D” may refer to a deuterium atom, and “Ph” may refer to a substituted or unsubstituted phenyl group. For example, in embodiment compounds presented in Compound Group 2, “Ph” may refer to an unsubstituted phenyl group.

In one or more embodiments, the emission layer EML may include the third compound represented by Formula ET-1. For example, the third compound may be used as an electron transport host material for the emission layer EML.

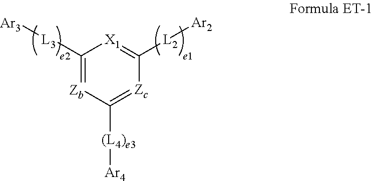

In Formula ET-1, at least one among (e.g., selected from among) Zₐ to Z_{c} is N, and the rest are CR₅₆. For example, any one among (e.g., selected from among) Zₐ to Ze may be N, and the rest may each independently be CR₅₆. In this case, the third compound represented by Formula ET-1 may include a pyridine moiety. In one or more embodiments, two among Zₐ to Ze may be N, and the rest may be CR₅₆. In this case, the third compound represented by Formula ET-1 may include a pyrimidine moiety. In one or more embodiments, Zₐ to Ze may all be N. In this case, the third compound represented by Formula ET-1 may include a triazine moiety.

In Formula ET-1, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, e1 to e3 may each independently be an integer of 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group, or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) e1 to e3 are integers of 2 or greater, L₂ to L₄ may each independently be a substituted or unsubstituted arylene group having 6 to 30 ring-forming carbon atoms, or a substituted or unsubstituted heteroarylene group having 2 to 30 ring-forming carbon atoms.

In one or more embodiments, the third compound may be represented by anyone among (e.g., selected from among) compounds in Compound Group 3. The light-emitting element ED of one or more embodiments may include any one among (e.g., selected from among) the compounds in Compound Group 3.

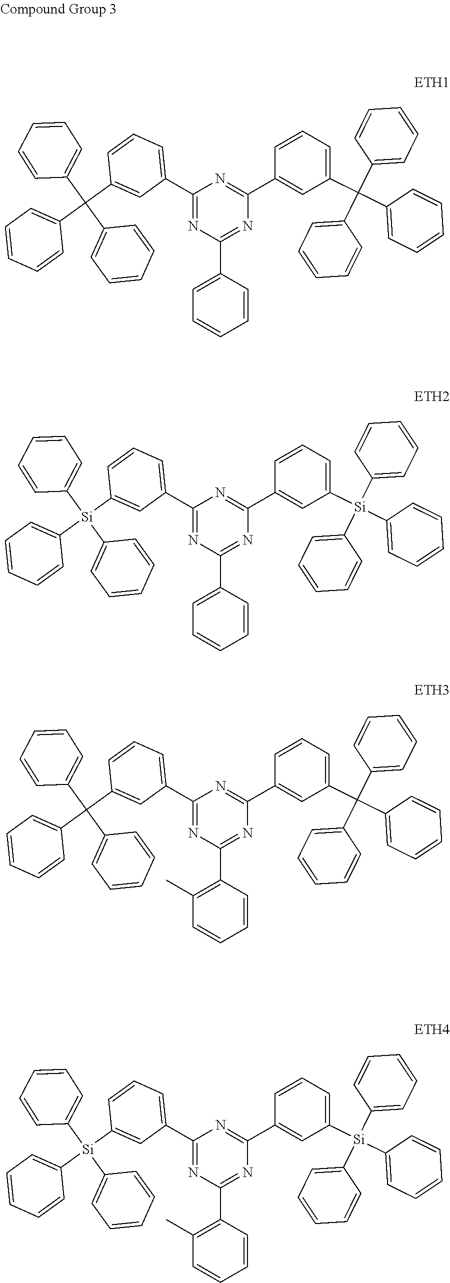 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

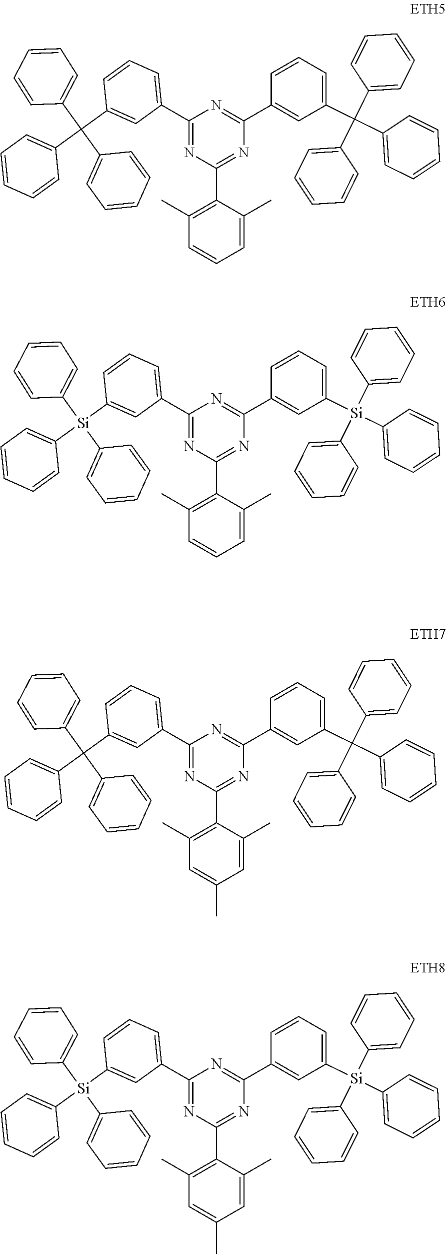 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

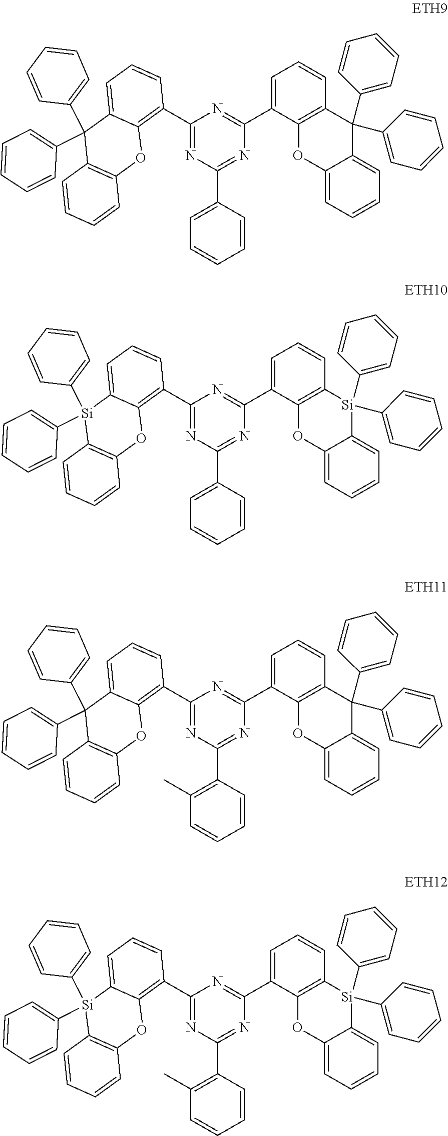 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

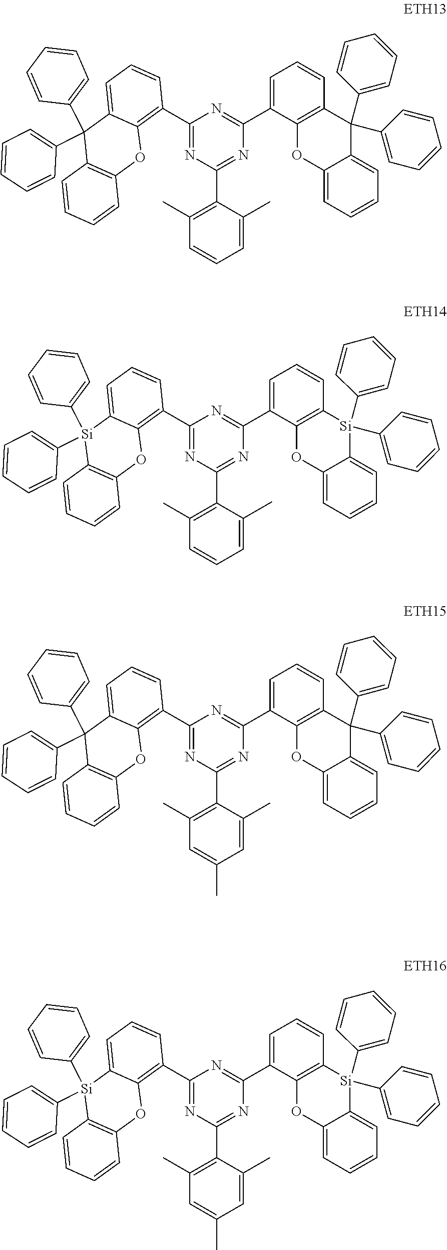 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

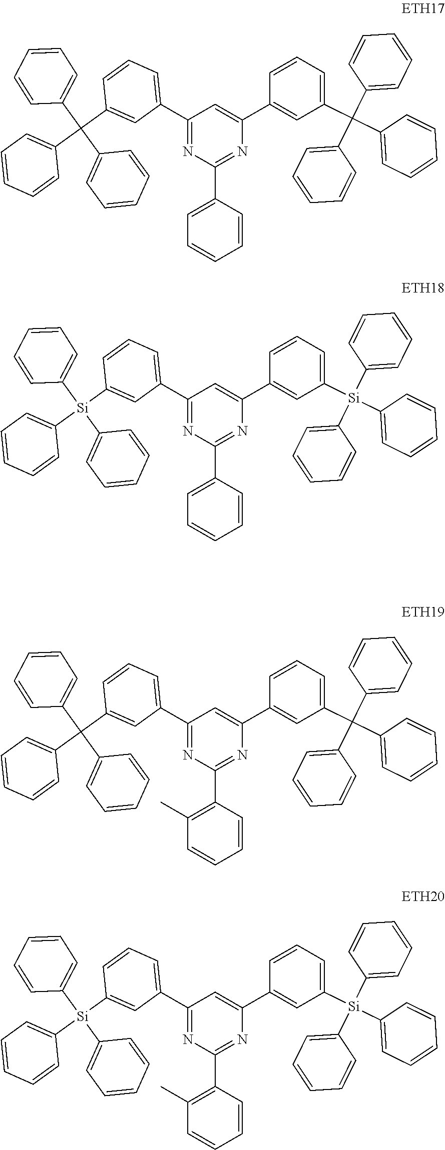 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

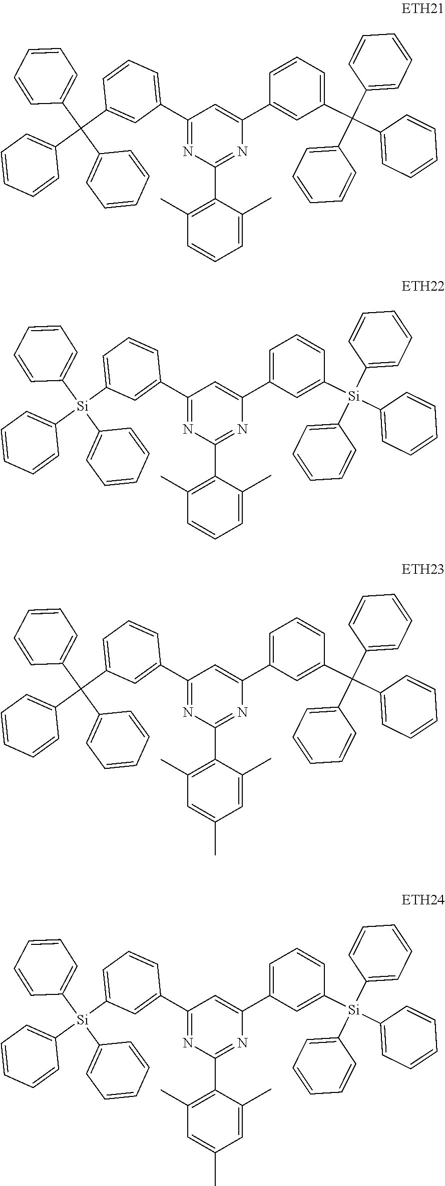 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

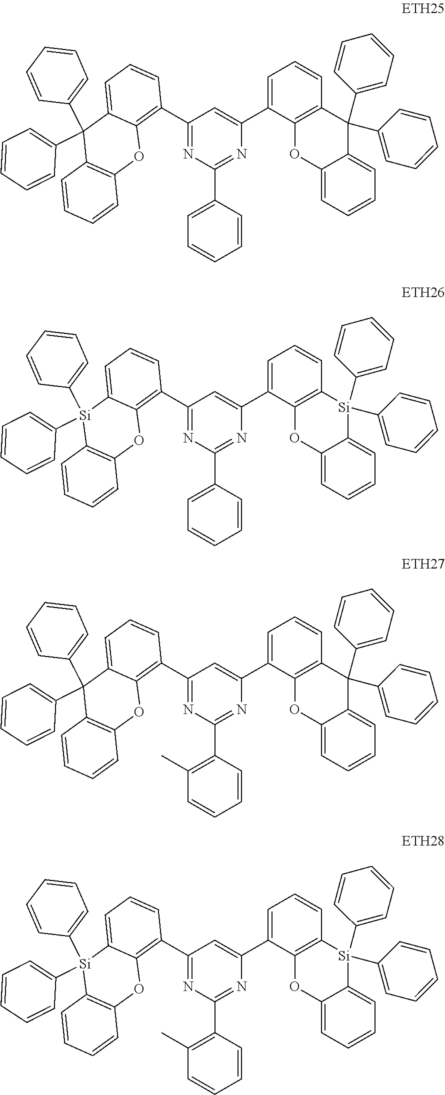 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

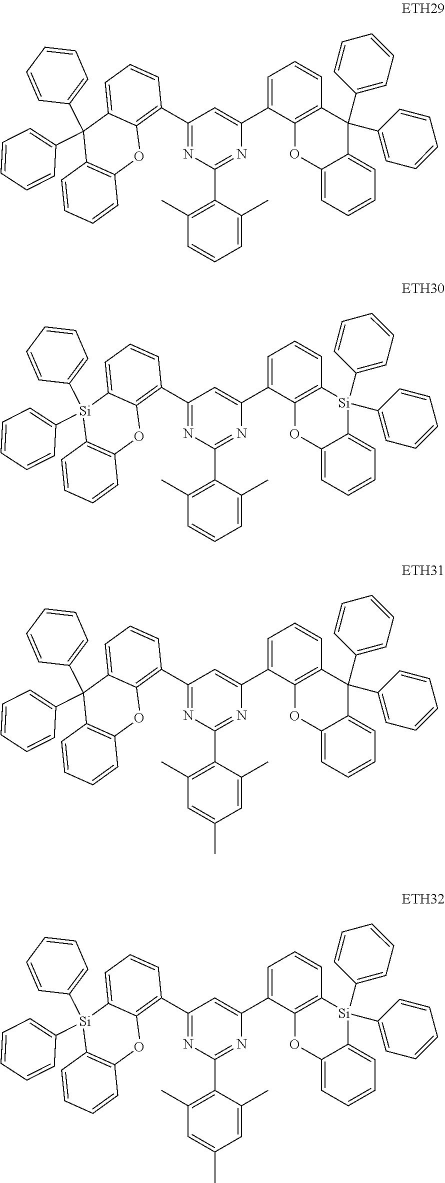 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

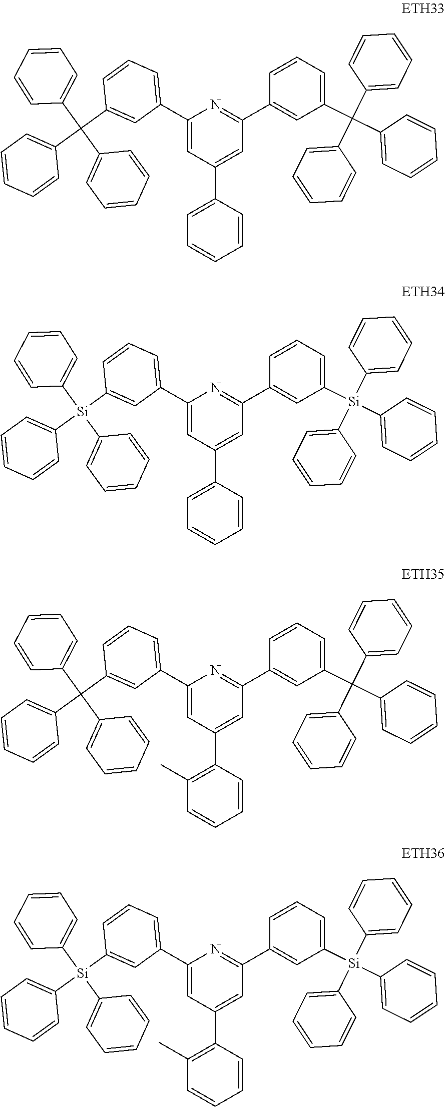 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

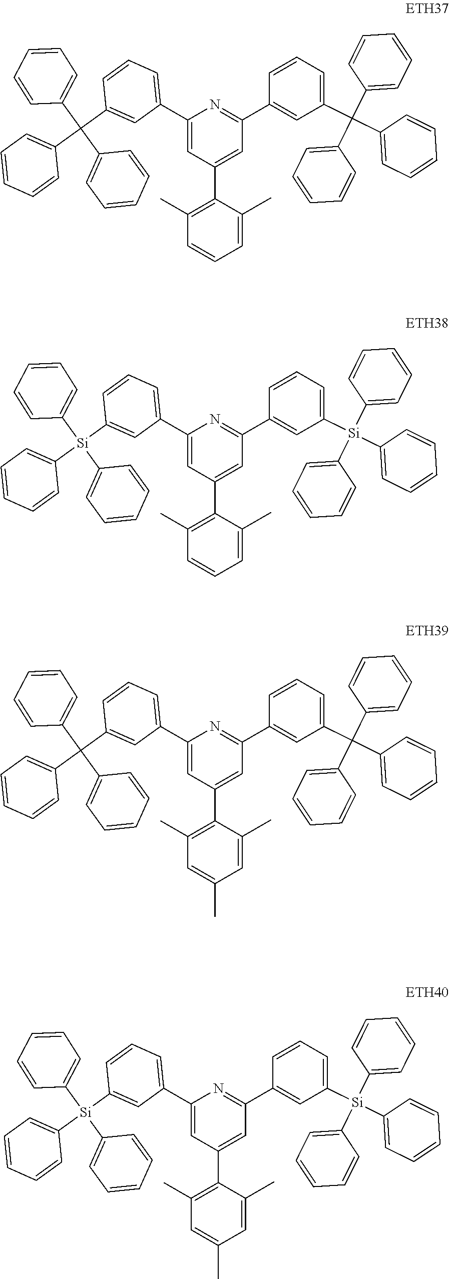 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

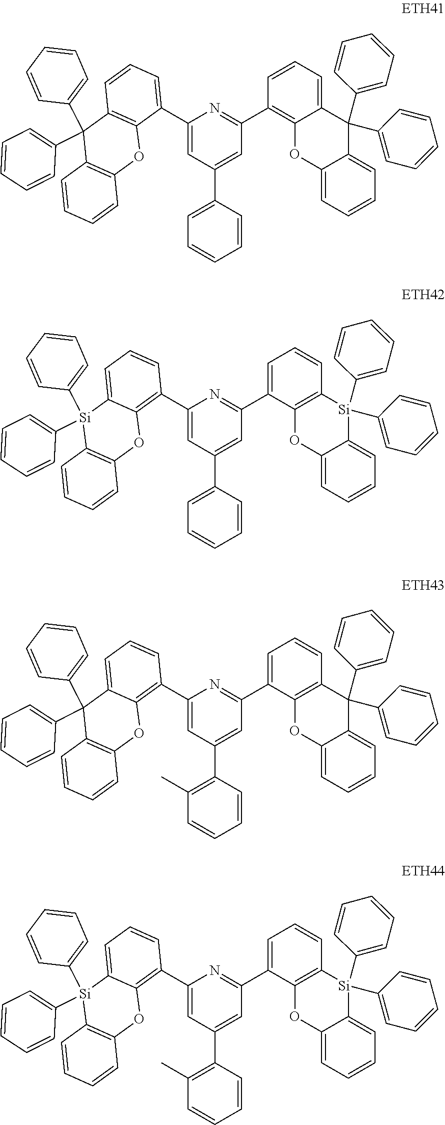 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

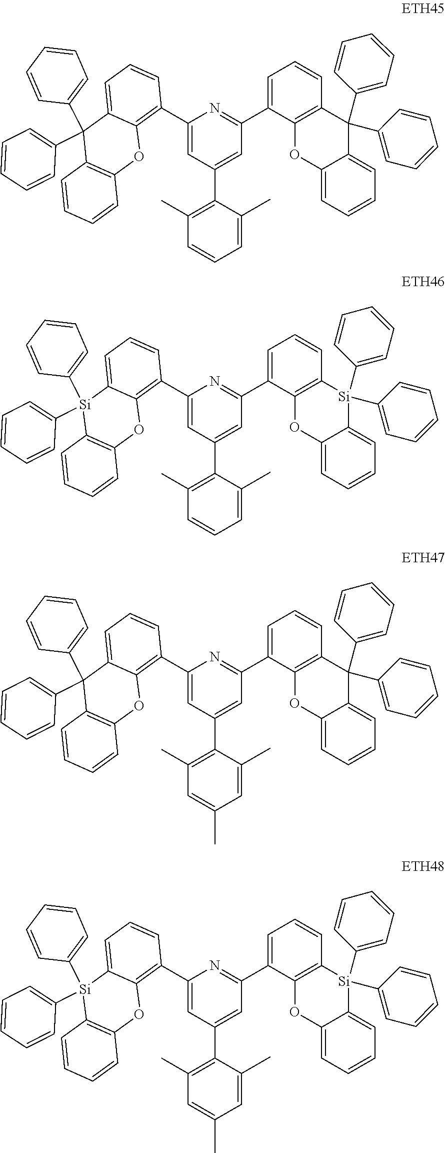 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

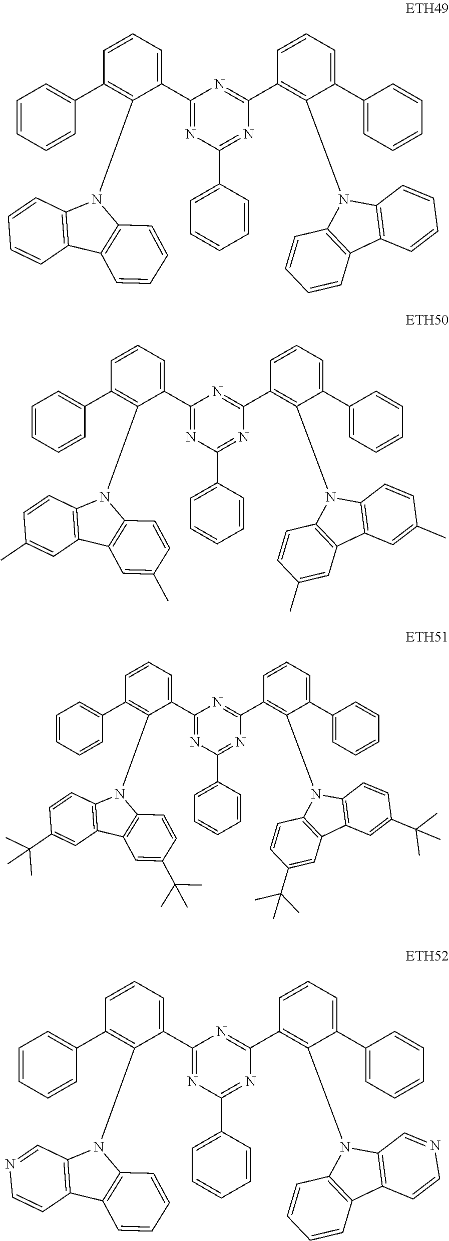

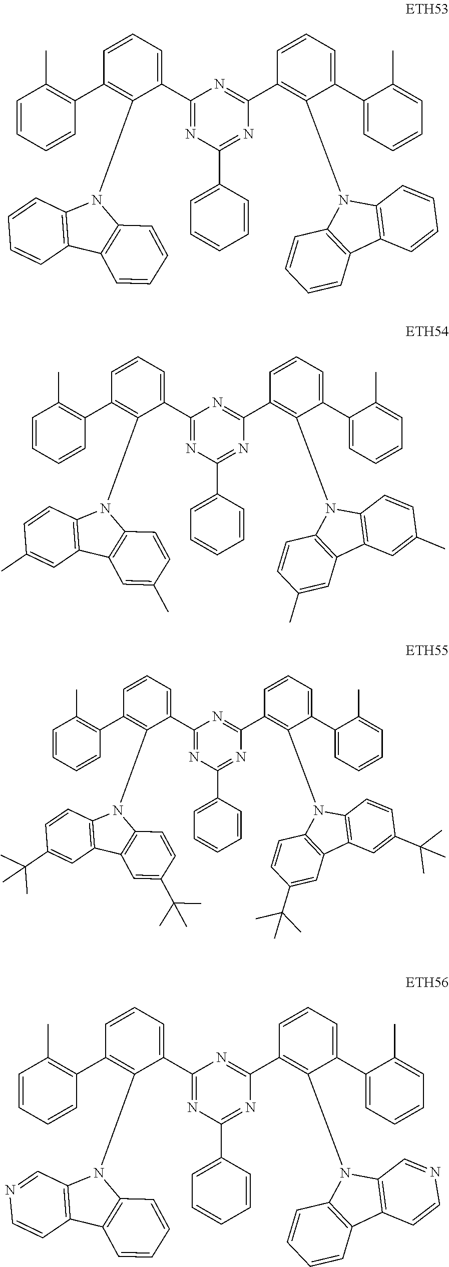

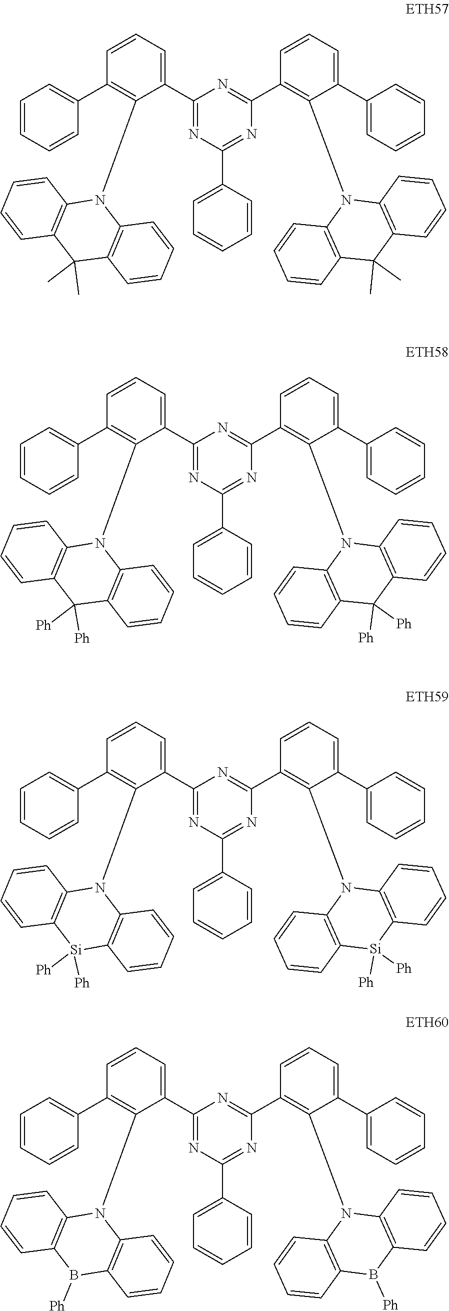

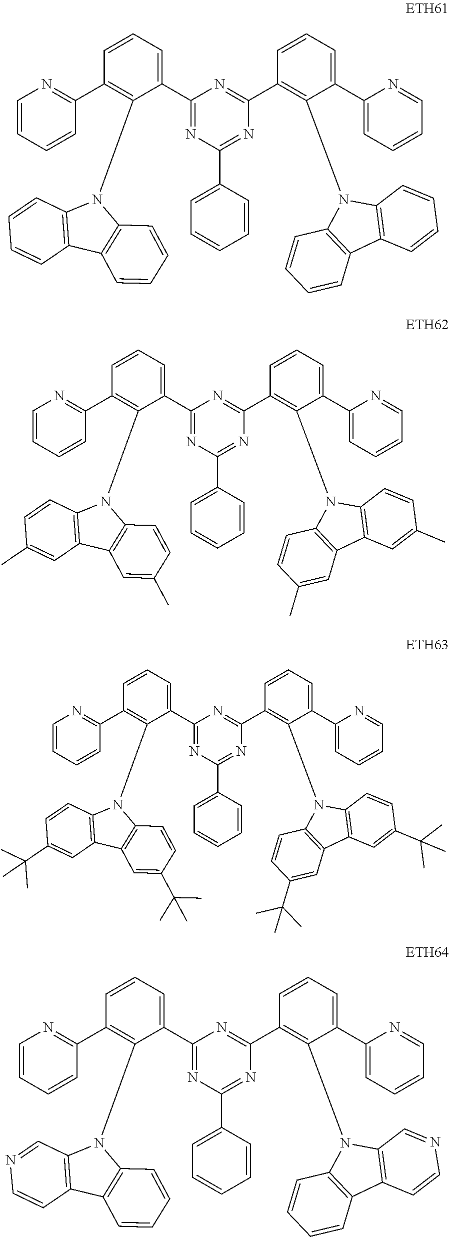

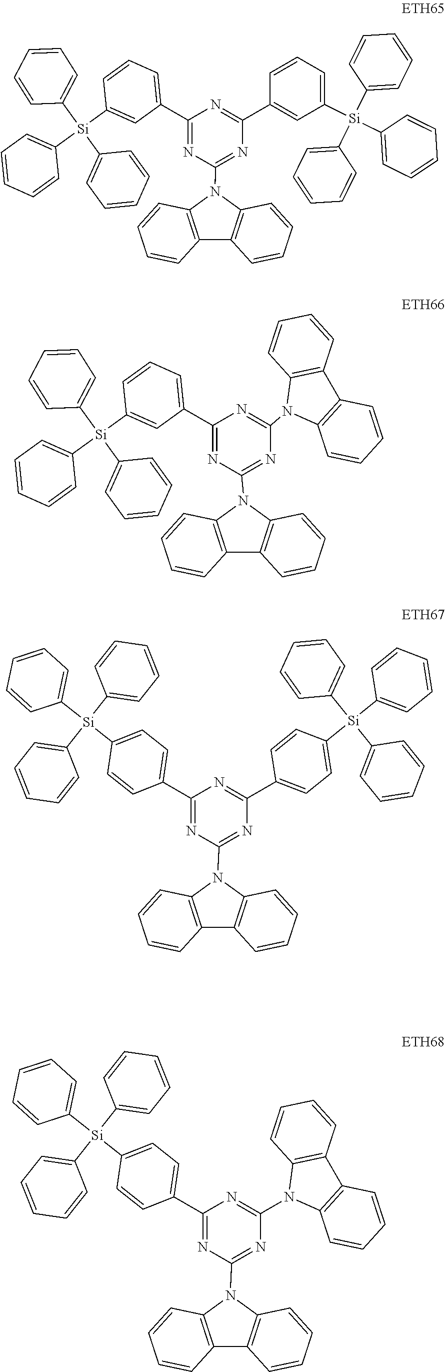 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

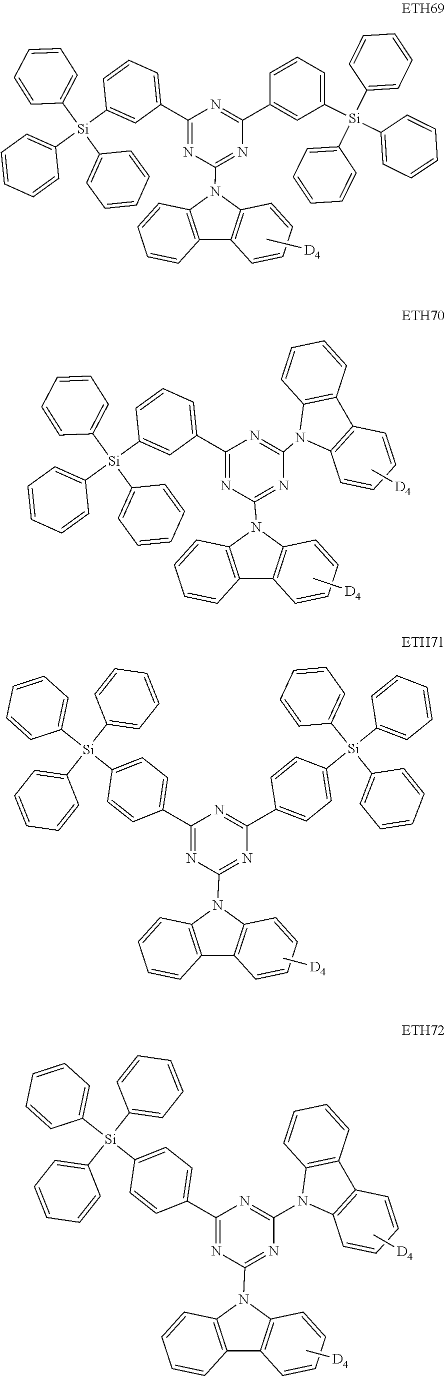

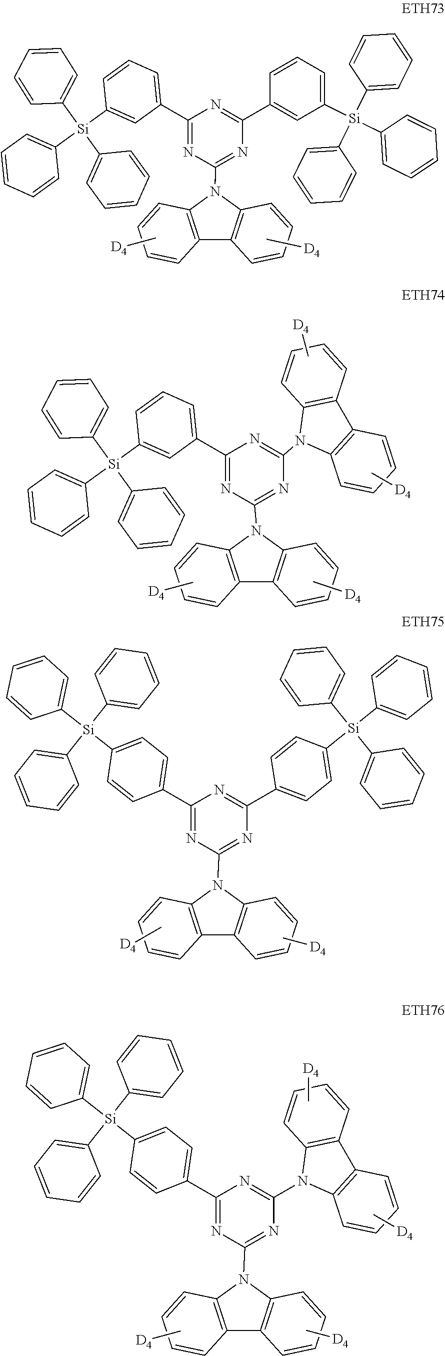

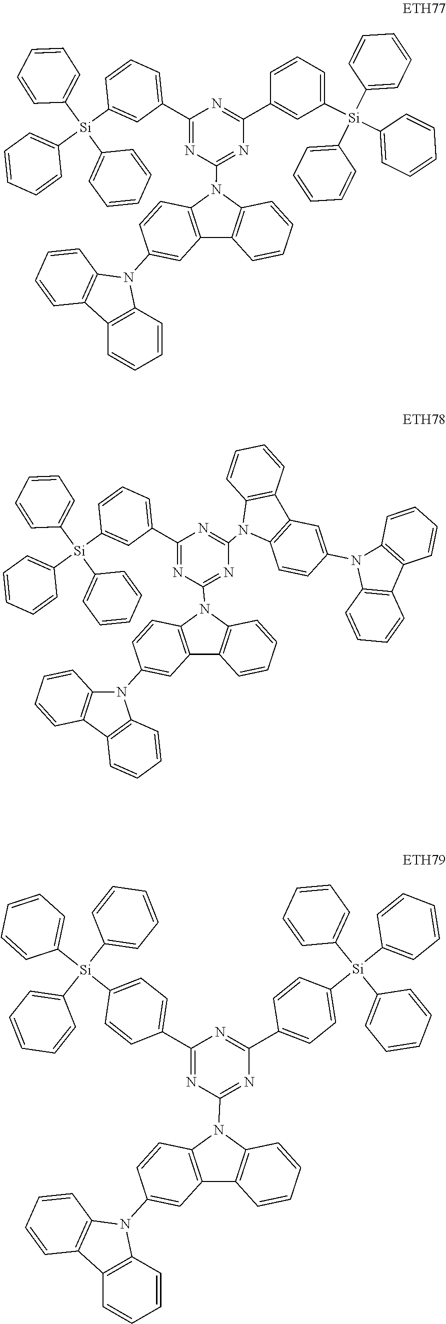 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

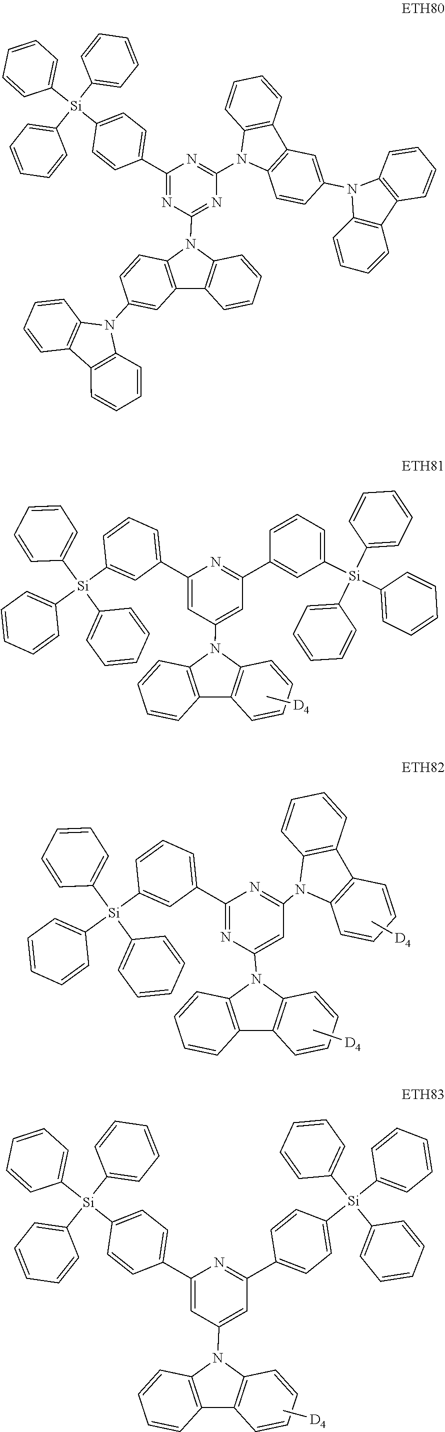

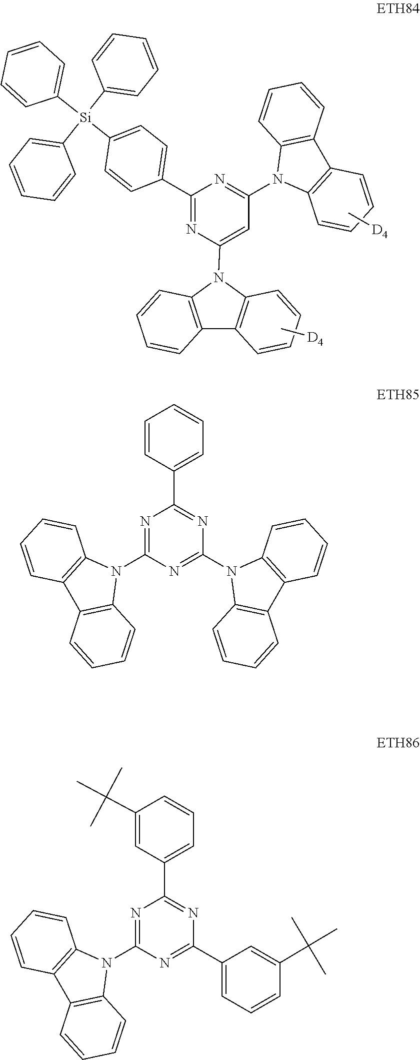

In one or more embodiments compounds presented in Compound Group 3, “D” refers to a deuterium atom and “Ph” refers to an unsubstituted phenyl group.

The emission layer EML may include the second compound and the third compound, and the second compound and the third compound may form an exciplex. In the emission layer EML, an exciplex may be formed by the hole transport host and the electron transport host. In this case, a triplet energy of the exciplex formed by the hole transporting host and the electron transporting host may correspond to the difference between a lowest unoccupied molecular orbital (LUMO) energy level of the electron transporting host and a highest occupied molecular orbital (HOMO) energy level of the hole transporting host.

For example, the absolute value of the triplet energy (T1) of the exciplex formed by the hole transporting host and the electron transporting host may be about 2.4 eV to about 3.0 eV. In some embodiments, the triplet energy of the exciplex may be a value smaller than an energy gap of each host material. The exciplex may have a triplet energy of about 3.0 eV or less that is an energy gap between the hole transporting host and the electron transporting host.

In one or more embodiments, the emission layer EML may include a fourth compound in addition to the first compound to the third compound as described. The fourth compound may be used as a phosphorescent sensitizer of the emission layer EML. The energy may be transferred from the fourth compound to the first compound, thereby emitting light.

For example, the emission layer EML may include, as the fourth compound, an organometallic complex containing platinum (Pt) as a central metal atom and ligands linked to the central metal atom. The emission layer EML in the light-emitting element ED of one or more embodiments may include, as the fourth compound, a compound represented by Formula D-1:

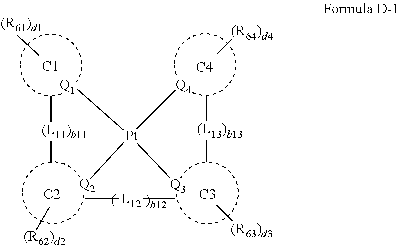

In Formula D-1, Q₁ to Q₄ may each independently be C or N, and C1 to C4 may each independently be a substituted or unsubstituted hydrocarbon ring having 5 to 30 ring-forming carbon atoms, or a substituted or unsubstituted heterocycle having 2 to 30 ring-forming carbon atoms.

In Formula D-1, L₁₁ to L₁₃ may each independently be a direct linkage, *—O—*, *—S—*,

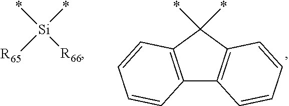

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, “-*” refers to a part linked to C1 to C4.

In Formula D-1, b11 to b13 may each independently be 0 or 1. If b11 is 0, C1 and C2 may not be linked to each other. If b12 is 0, C2 and C3 may not be linked to each other. If b13 is 0, C3 and C4 may not be linked to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In one or more embodiments, each of R₆₁ to R₆₆ may be bonded to an adjacent group to form a ring. R₆₁ to R₆₆ may each independently be a substituted or unsubstituted methyl group, or a substituted or unsubstituted t-butyl group.

In Formula D-1, d1 to d4 may each independently be an integer of 0 to 4. In Formula D-1, if each of d1 to d4 is 0, the fourth compound may not be substituted with each of R₆₁ to R₆₄. The case where each of d1 to d4 is 4 and R₆₁'s to R₆₄′ are each hydrogen atoms may be the same as the case where each of d1 to d4 is 0. When each of d1 to d4 is an integer of 2 or more, a plurality of R₆₁'s to R₆₄'s may each be the same or at least one among (e.g., selected from among) the plurality of R₆₁'S to R₆₄'s may be different from the others.

In Formula D-1, C1 to C4 may each independently be a substituted or unsubstituted hydrocarbon ring or a substituted or unsubstituted heterocycle represented by any one among (e.g., selected from among)C-1 to C-4:

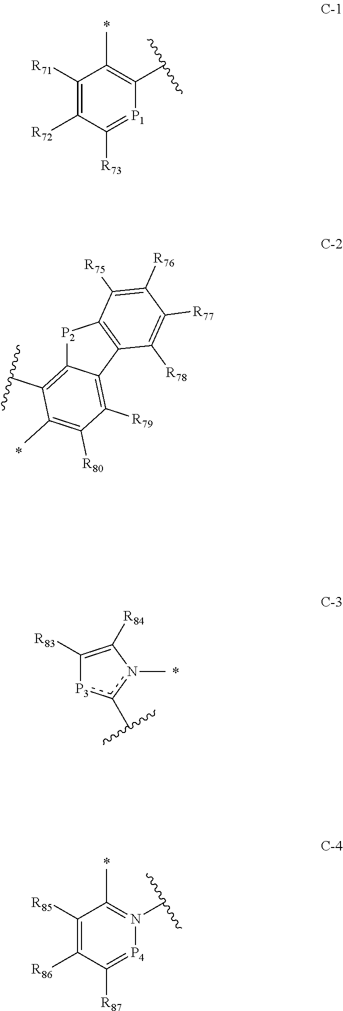

In C-1 to C-4, P₁ may be C—* or CR₇₄, P₂ may be N—* or NR₈₁, P₃ may be N—* or NR₈₂, and P₄ may be C—* or CR₈₈. R₇₁ to R₈₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In some embodiments, in C-1 to C-4,

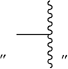

corresponds to a part linked to Pt that is a central metal atom, and “-*” corresponds to a part linked to a neighboring cyclic group (C1 to C4) or a linker (L₁₁ to L₁₃).

The emission layer EML of one or more embodiments may include the first compound, which is a polycyclic compound, and at least one of the second to fourth compounds. For example, the emission layer EML may include the first compound, the second compound, and the third compound. In the emission layer EML, the second compound and the third compound may form an exciplex, and the energy may be transferred from the exciplex to the first compound, thereby emitting light.

In some embodiments, the emission layer EML may include the first compound, the second compound, the third compound, and the fourth compound. In the emission layer EML, the second compound and the third compound may form an exciplex, and the energy may be transferred from the exciplex to the fourth compound and the first compound, thereby emitting light. In one or more embodiments, the fourth compound may be a sensitizer. The fourth compound included in the emission layer EML in the light-emitting element ED of one or more embodiments may serve as a sensitizer to deliver energy from the host to the first compound that is a light emitting dopant. For example, the fourth compound serving as an auxiliary dopant accelerates energy delivery to the first compound that is a light emitting dopant, thereby increasing the emission ratio of the first compound. Therefore, the emission layer EML of one or more embodiments may improve luminous efficiency. In some embodiments, if (e.g., when) the energy delivery to the first compound is increased, an exciton formed in the emission layer EML is not accumulated inside the emission layer EML and emits light rapidly, and thus deterioration of the light-emitting element ED may be reduced. Therefore, the service life of the light-emitting element ED of one or more embodiments may increase.

The light-emitting element ED of one or more embodiments may include all of the first compound, the second compound, the third compound, and the fourth compound, and the emission layer EML may include the combination of two host materials and two dopant materials. In the light-emitting element ED of one or more embodiments, the emission layer EML may concurrently (e.g., simultaneously) include the second compound and the third compound, which are two different hosts, the first compound that emits a delayed fluorescence, and the fourth compound including an organometallic complex, thereby exhibiting excellent or suitable luminous efficiency characteristics.

In one or more embodiments, the fourth compound represented by Formula D-1 may represented at least one among (e.g., selected from among) the compounds represented by Compound Group 4. The emission layer EML may include at least one among (e.g., selected from among) the compounds represented by Compound Group 4 as a sensitizer material.

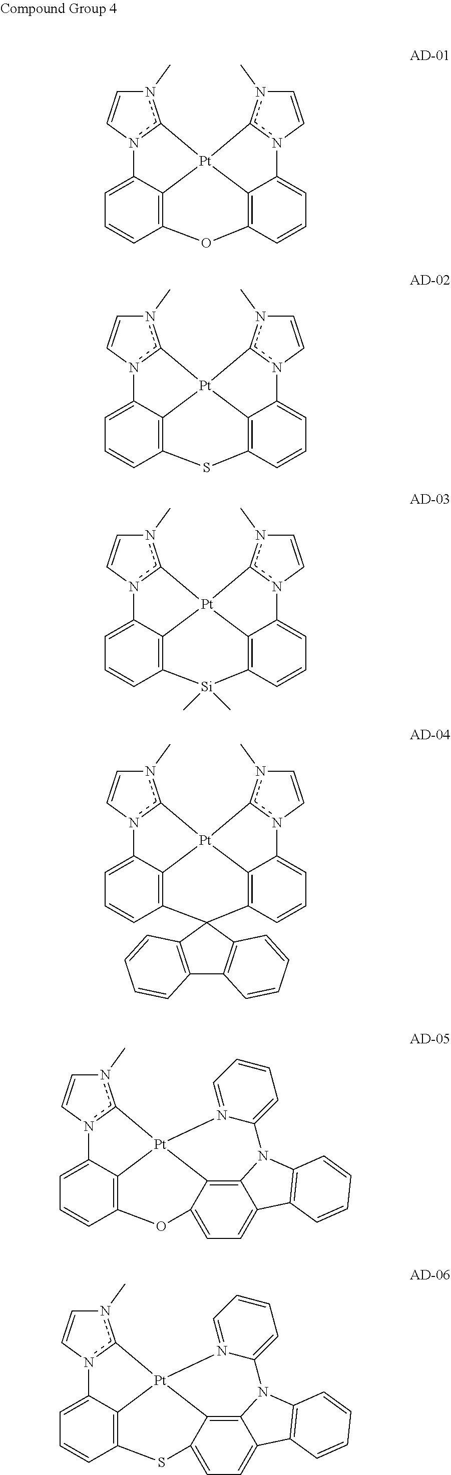

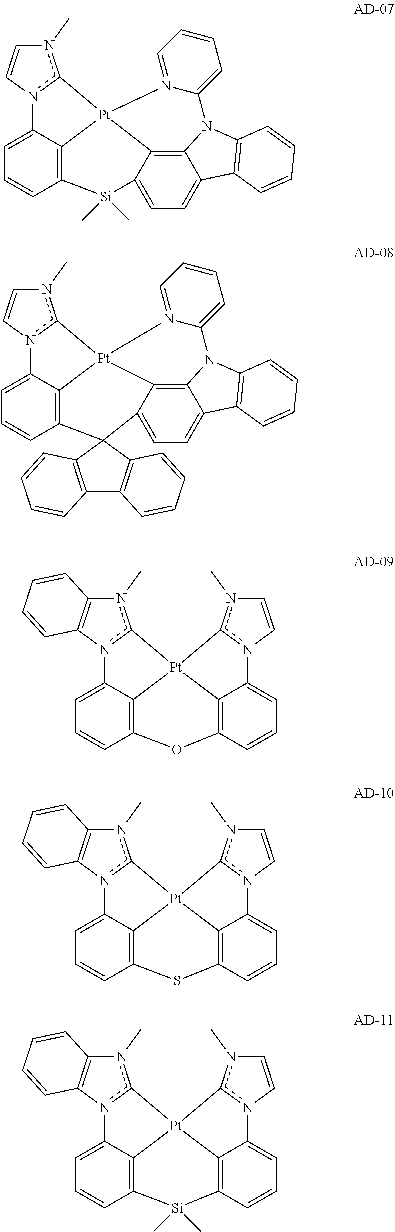

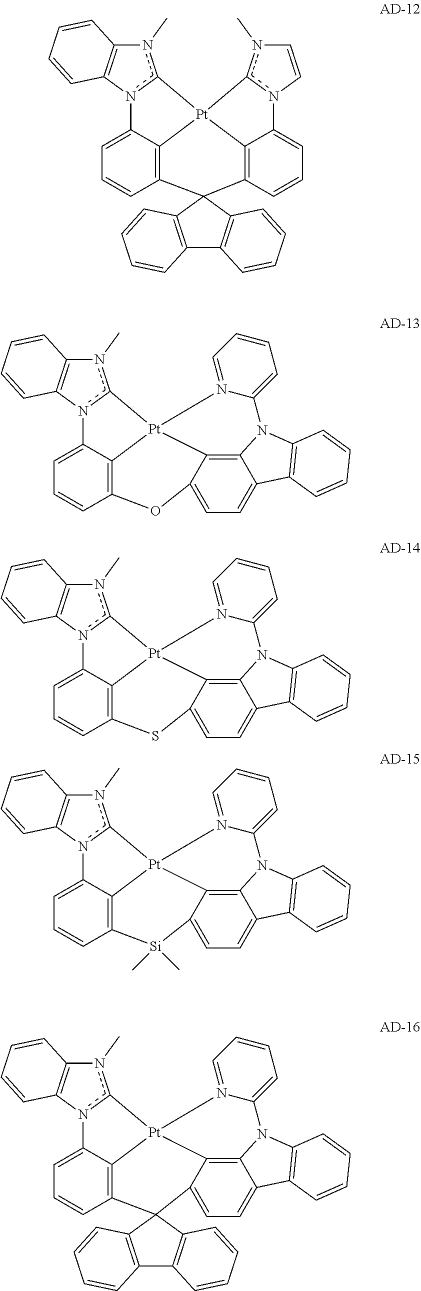

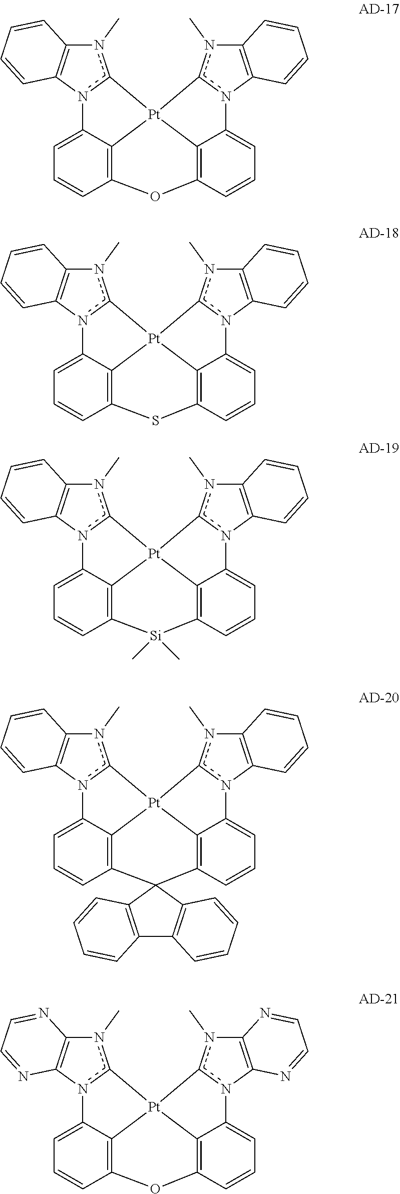

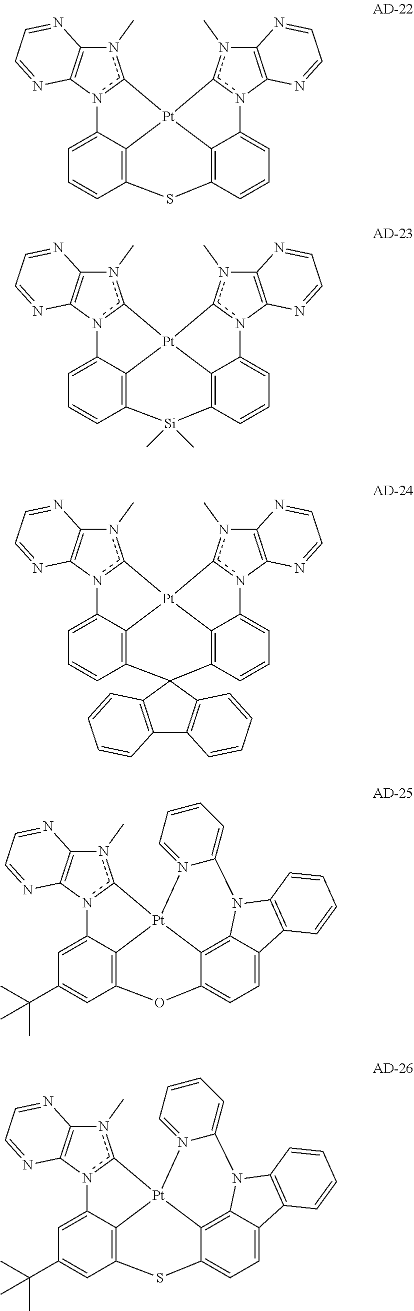

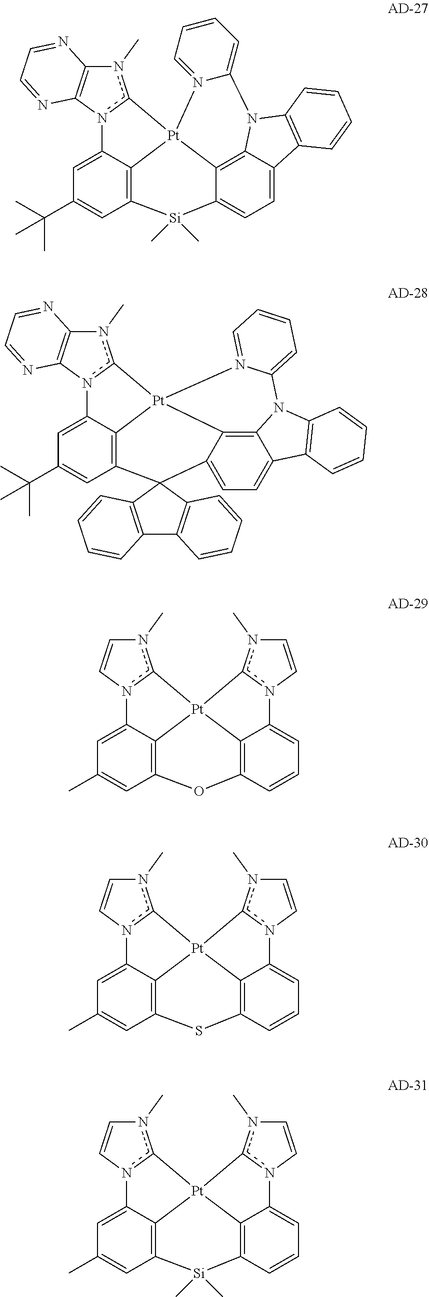

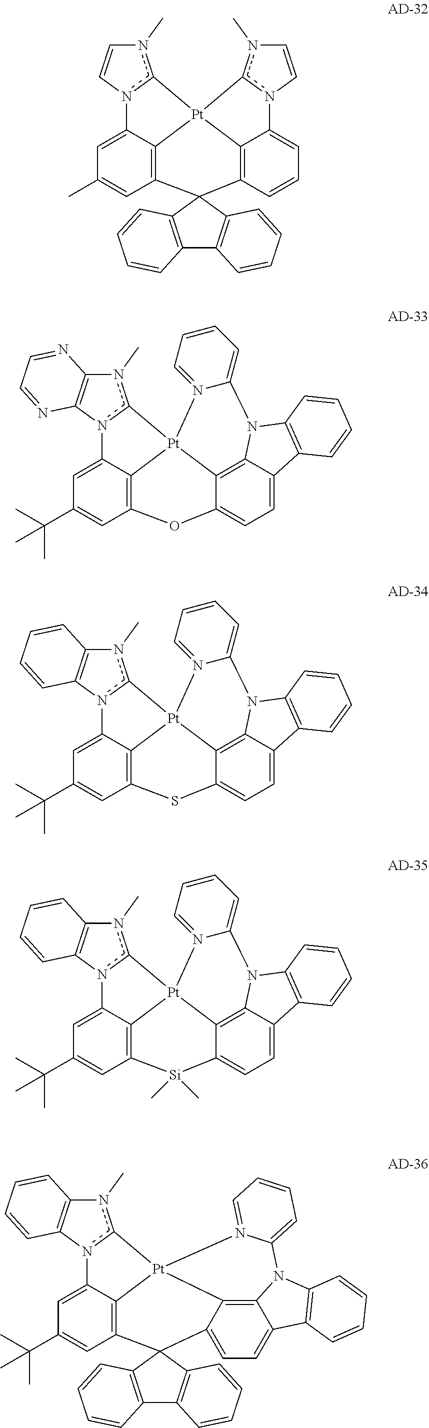

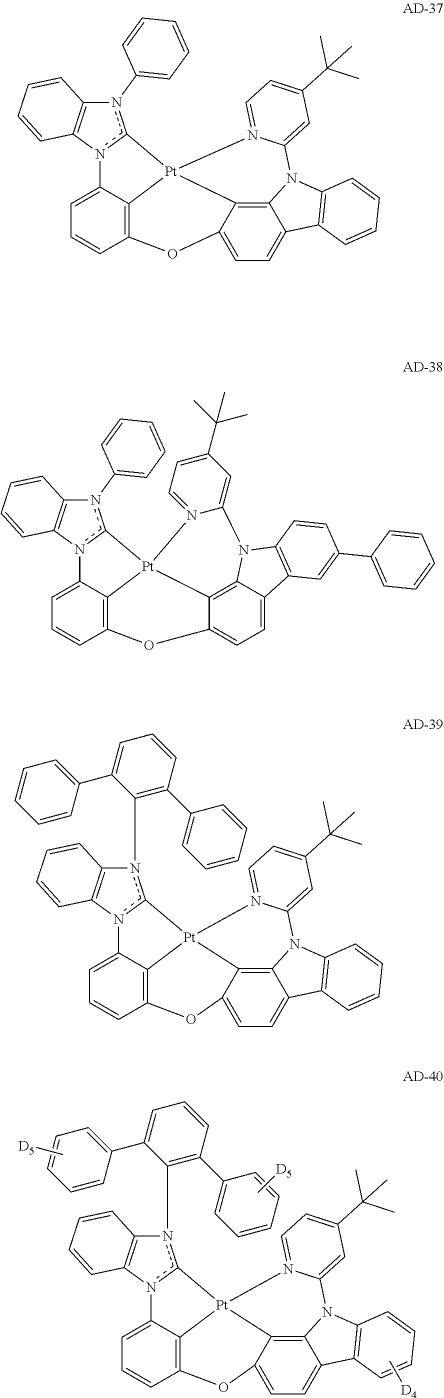

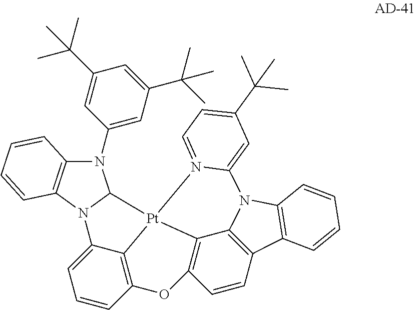

In one or more embodiments compounds presented in Compound Group 4, “D” refers to a deuterium atom.

When the emission layer EML in the light-emitting element ED of one or more embodiments includes all of the first compound, the second compound, and the third compound, with respect to the total weight of the first compound, the second compound, and the third compound, the content (e.g., amount) of the first compound may be about 0.1 wt % to about 5 wt %. However, one or more embodiments of the disclosure are not limited thereto. When the content (e.g., amount) of the first compound satisfy the herein-described proportion, the energy transfer from the second compound and the third compound to the first compound may increase, and thus the luminous efficiency and device service life may increase.

The contents (e.g., amounts) of the second compound and the third compound in the emission layer EML may be the rest excluding the weight of the first compound. For example, the contents (e.g., amounts) of the second compound and the third compound in the emission layer EML may be about 65 wt % to about 95 wt % with respect to the total weight of the first compound, the second compound, and the third compound.

In the total weight of the second compound and the third compound, the weight ratio of the second compound and the third compound may be about 3:7 to about 7:3.

When the contents (e.g., amounts) of the second compound and the third compound satisfy the herein-described ratio, a charge balance characteristic in the emission layer EML are improved, and thus the luminous efficiency and device service life may increase. When the contents (e.g., amounts) of the second compound and the third compound deviate from the herein-described ratio range, a charge balance in the emission layer EML is broken, and thus the luminous efficiency may be reduced and the device may be easily deteriorated.

When the emission layer EML includes the fourth compound, the content (e.g., amount) of the fourth compound in the emission layer EML may be about 10 wt % to about 30 wt % with respect to the total weight of the first compound, the second compound, the third compound, and the fourth compound. However, one or more embodiments of the disclosure are not limited thereto. When the content (e.g., amount) of the fourth compound satisfies the herein-described content (e.g., amount), the energy delivery from the host to the first compound which is a light emitting dopant may be increased, thereby a luminous ratio may be improved, and thus the luminous efficiency of the emission layer EML may be improved. W hen the first compound, the second compound, the third compound, and the fourth compound included in the emission layer EML satisfy the herein-described content (e.g., amount) ratio range, excellent or suitable luminous efficiency and long service life may be achieved.

The emission layer EML is provided on the hole transport region HTR. The emission layer EML may have a thickness of, for example, about 100 Å to about 1,000 Å or about 100 Å to about 300 Å. The emission layer EML may have a single layer formed of a single material, a single layer formed of a plurality of different materials, or a multilayer structure having a plurality of layers formed of a plurality of different materials.

In the light-emitting element according to one or more embodiments, illustrated in FIG. 3 to FIG. 7, the emission layer EML may contain the polycyclic compound according to one or more embodiments, described previously. In some embodiments, in the light-emitting element ED according to one or more embodiments, illustrated in FIG. 3 to FIG. 7, the emission layer EML may contain at least one among (e.g., selected from among) a first compound which is a polycyclic compound according to one or more embodiments, a second compound represented by Formula HT-1, and a third compound represented by Formula ET-1. In some embodiments, in the light-emitting element according to one or more embodiments, illustrated in FIG. 3 to FIG. 7, the emission layer EML may contain a first compound which is a polycyclic compound according to one or more embodiments, a second compound represented by Formula HT-1, a third compound represented by ET-1, and a fourth compound represented by Formula D-1.

In the light-emitting element ED of one or more embodiments, the emission layer EML may include an anthracene derivative, a pyrene derivative, a fluoranthene derivative, a chrysene derivative, a dihydrobenzanthracene derivative, or a triphenylene derivative. For example, the emission layer EML may include the anthracene derivative or the pyrene derivative.

In each light-emitting element ED of embodiments illustrated in FIGS. 3 to 6, the emission layer EML may further include a suitable host and dopant besides the herein-described host and dopant, and for example the emission layer EML may include a compound represented by Formula E-1. The compound represented by Formula E-1 may be used as a fluorescent host material.

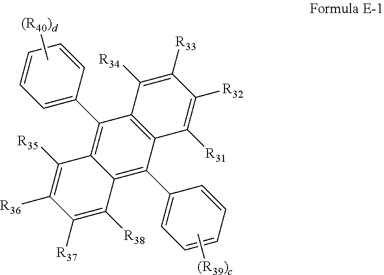

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In one or more embodiments, R₃₁ to R₄₀ may be bonded to an adjacent group to form a saturated hydrocarbon ring or an unsaturated hydrocarbon ring, a saturated heterocycle, or an unsaturated heterocycle.

In Formula E-1, c and d may each independently be an integer of 0 to 5.

Formula E-1 may be represented by any one among (e.g., selected from among) Compound E1 to Compound E19:

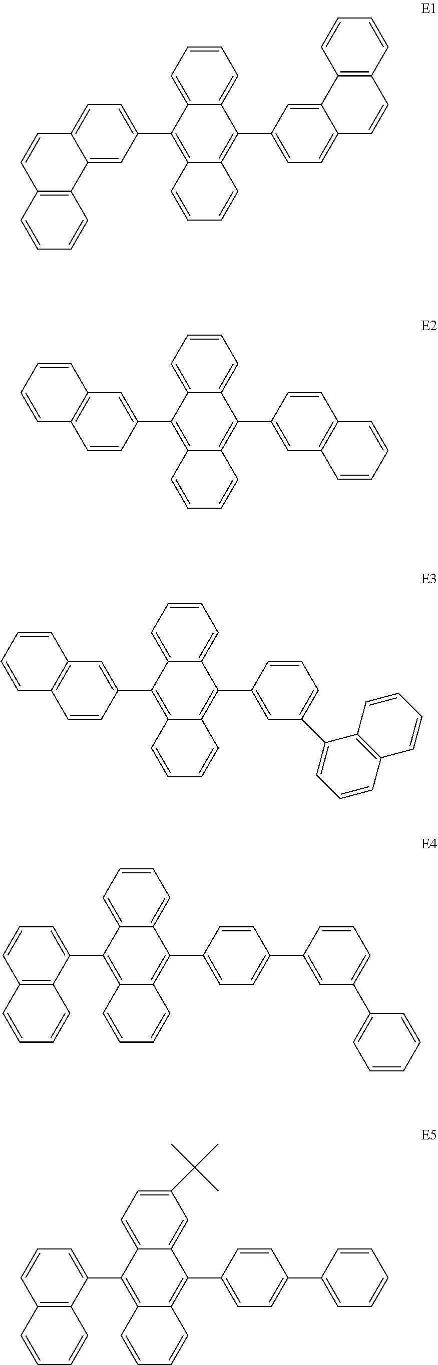

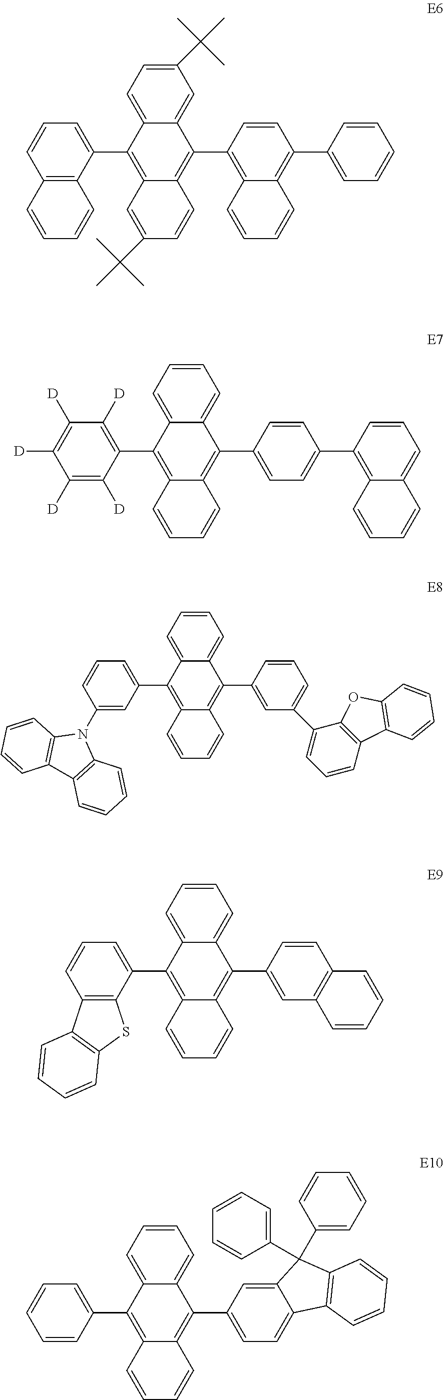

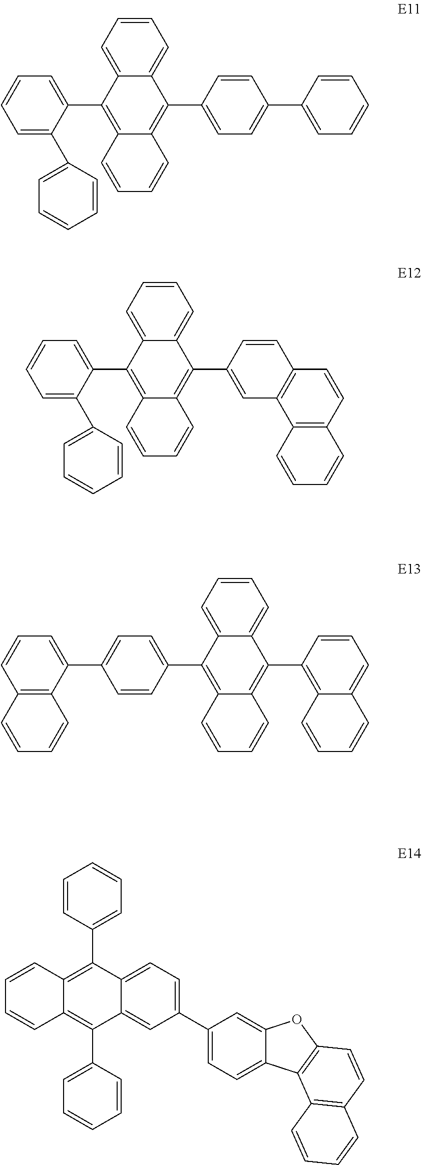

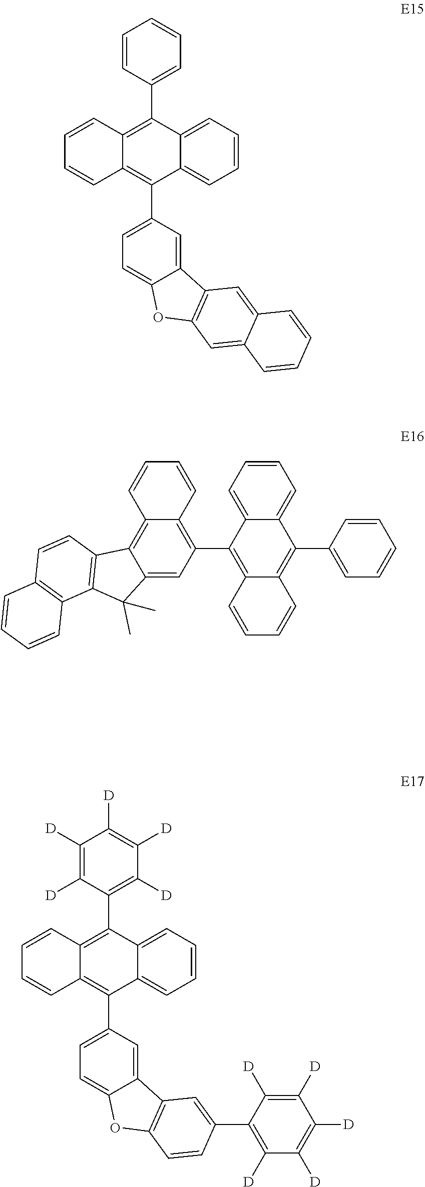

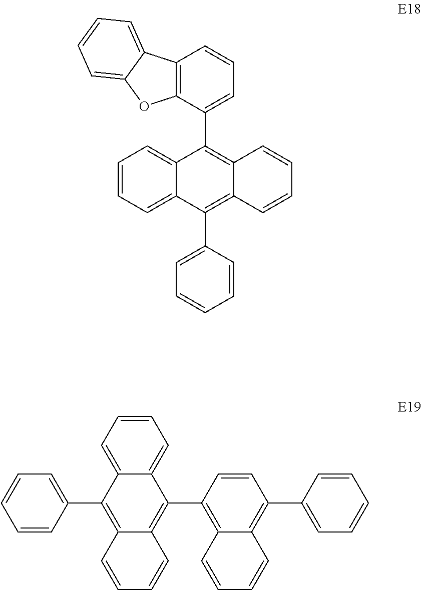

In one or more embodiments, the emission layer EML may include a compound represented by Formula E-2a or Formula E-2b. The compound represented by Formula E-2a or Formula E-2b may be used as a host material for phosphorescent light emitting element.

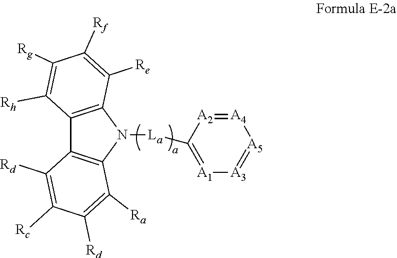

In Formula E-2a, a may be an integer of 0 to 10, and La may be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) a is an integer of 2 or greater, a plurality of La's may each independently be a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A₁ to A₅ may each independently be N or CRᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. Rₐ to Rᵢ may be bonded to an adjacent group to form a hydrocarbon ring or a heterocycle containing N, O, S, and/or the like, as a ring-forming atom.

In one or more embodiments, in Formula E-2a, two or three selected from among A₁ to A₅ may be N, and the rest may be CRI.

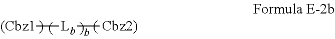

In Formula E-2b, Cbz1 and Cbz2 may each independently be an unsubstituted carbazole group, or a carbazole group substituted with an aryl group having 6 to 30 ring-forming carbon atoms. L_{b} is a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, b is an integer of 0 to 10, and if (e.g., when) b is an integer of 2 or more, a plurality of L_{b}'s may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one among (e.g., selected from among) the compounds of Compound Group E-2. However, the compounds listed in Compound Group E-2 are example, and the compound represented by Formula E-2a or Formula E-2b is not limited to those represented in Compound Group E-2.

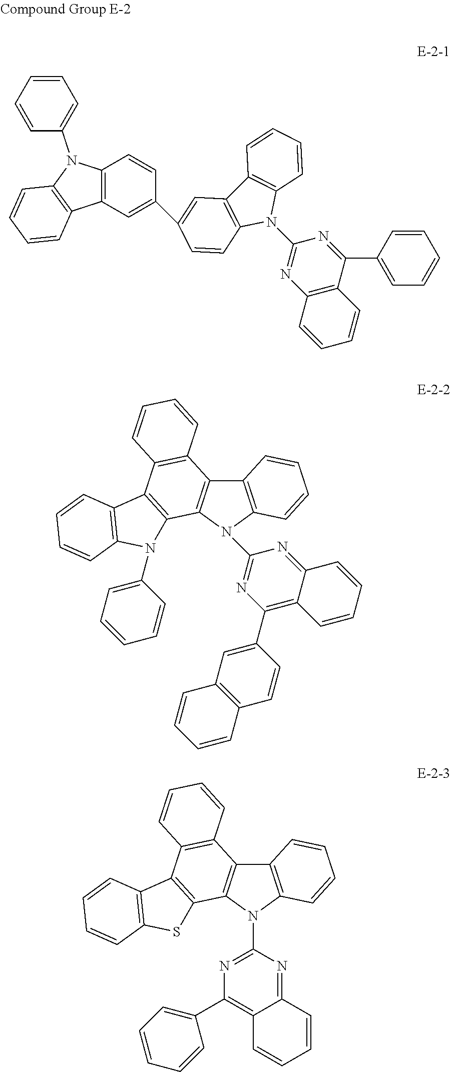

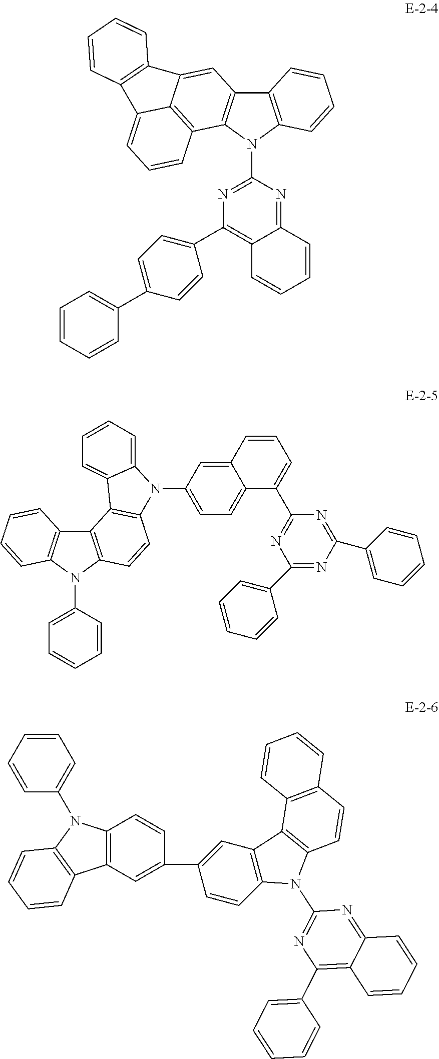 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

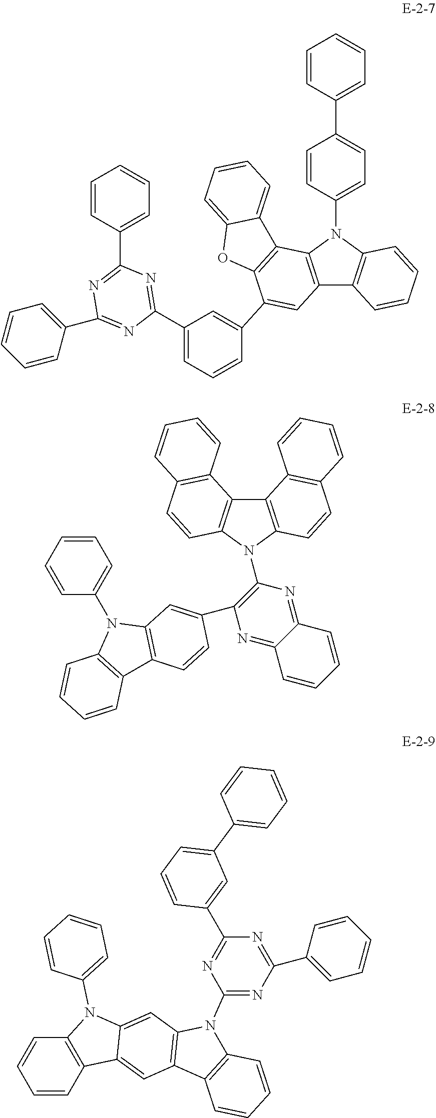

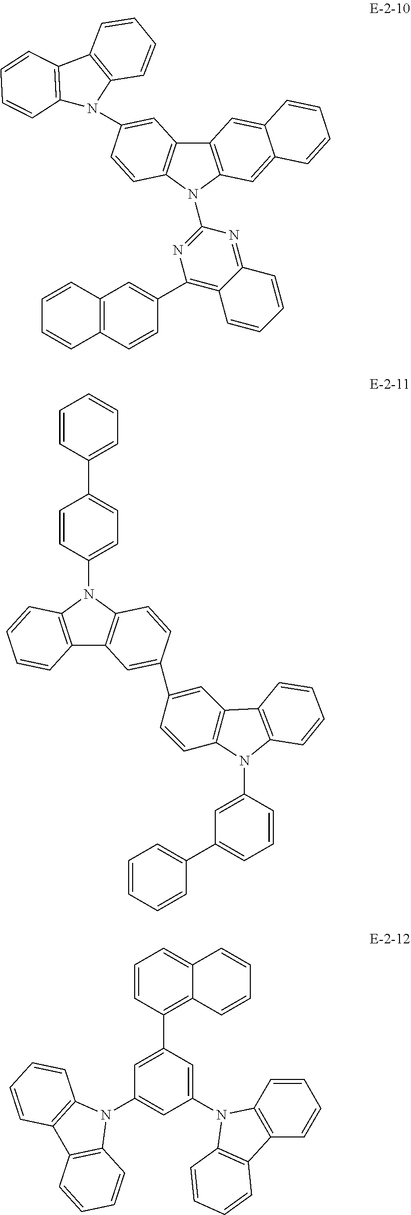

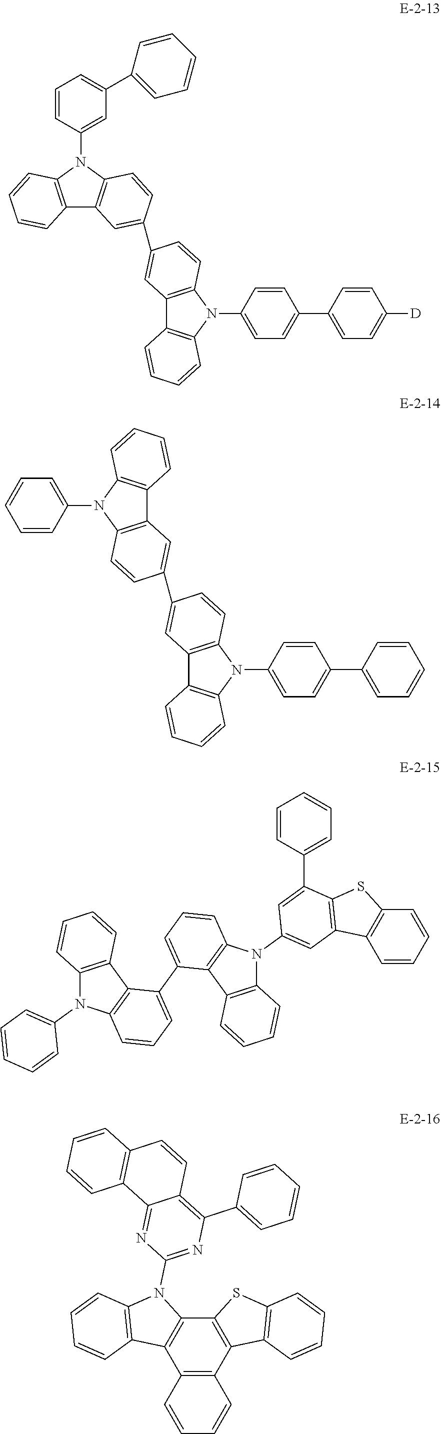 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2nc(-n3c4ccccc4c4c5ccccc5c5c6ccccc6sc5c43)nc3c2ccc2ccccc23)cc1]

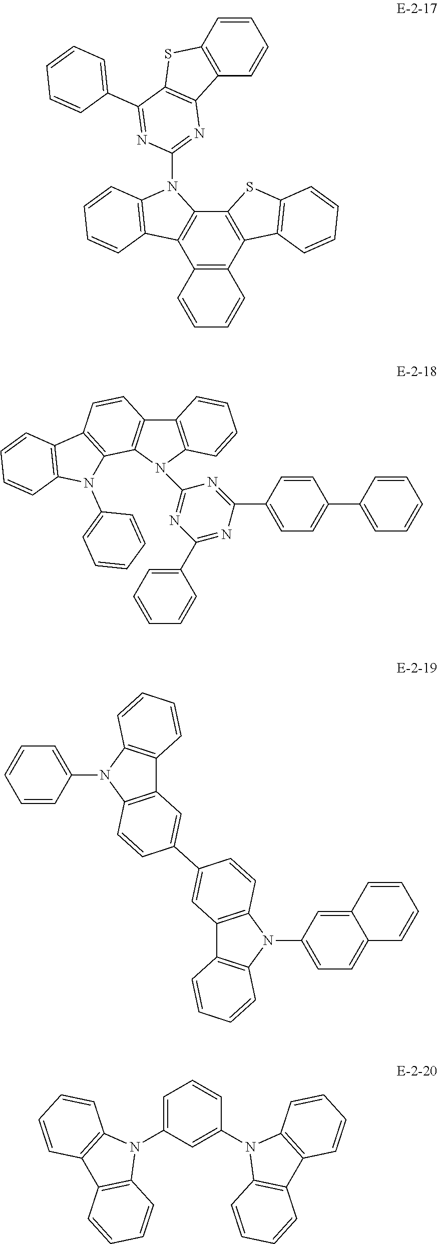 [SMILES: c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1]

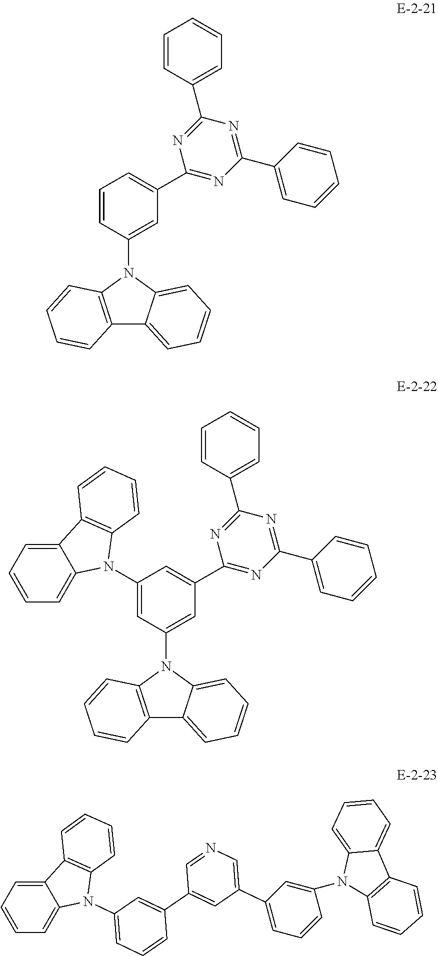 [SMILES: c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

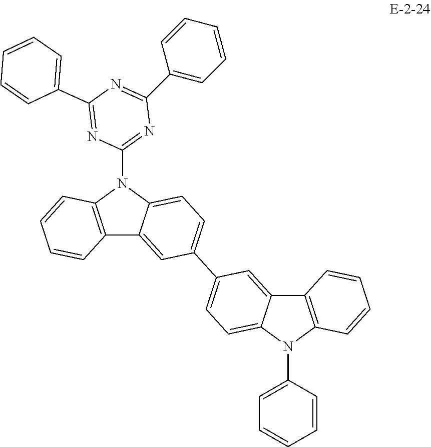 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may include the compound represented by Formula M-a. The compound represented by Formula M-a may be used as a phosphorescent dopant material.

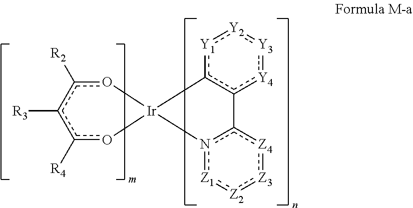

In Formula M-a, Y₁ to Y₄ and Z₁ to Z₄ may each independently be CR₁ or N, R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula M-a, m is 0 or 1, and n is 2 or 3. In Formula M-a, if (e.g., when) m is 0, n is 3, and if (e.g., when) m is 1, n is 2.

The compound represented by Formula M-a may be used as a phosphorescent dopant.

The compound represented by Formula M-a may be represented by any one among (e.g., selected from among) Compound M-a1 to Compound M-a25. However, Compounds M-a1 to M-a25 are examples, and the compound represented by Formula M-a is not limited to those represented by Compounds M-a1 to M-a25.

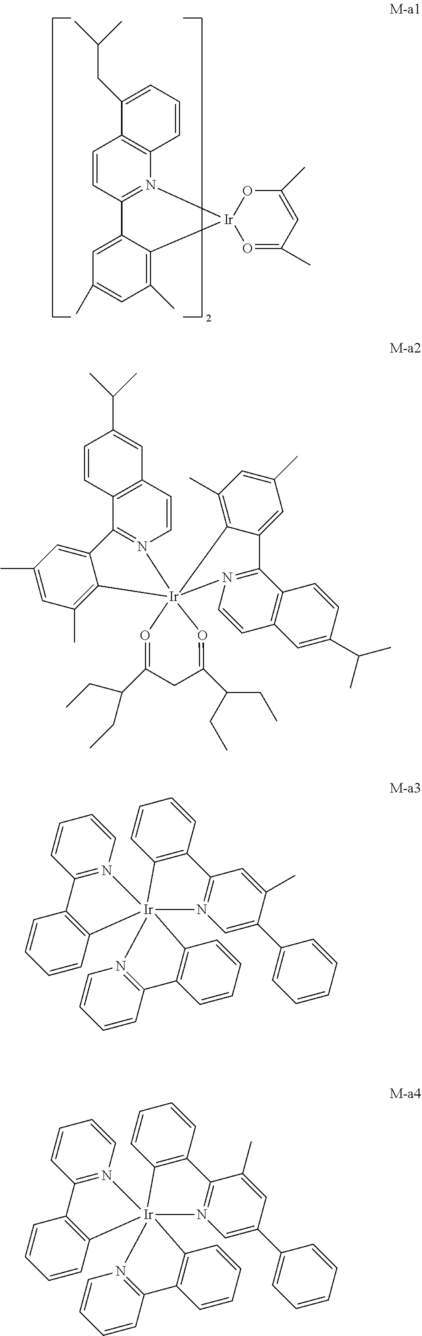

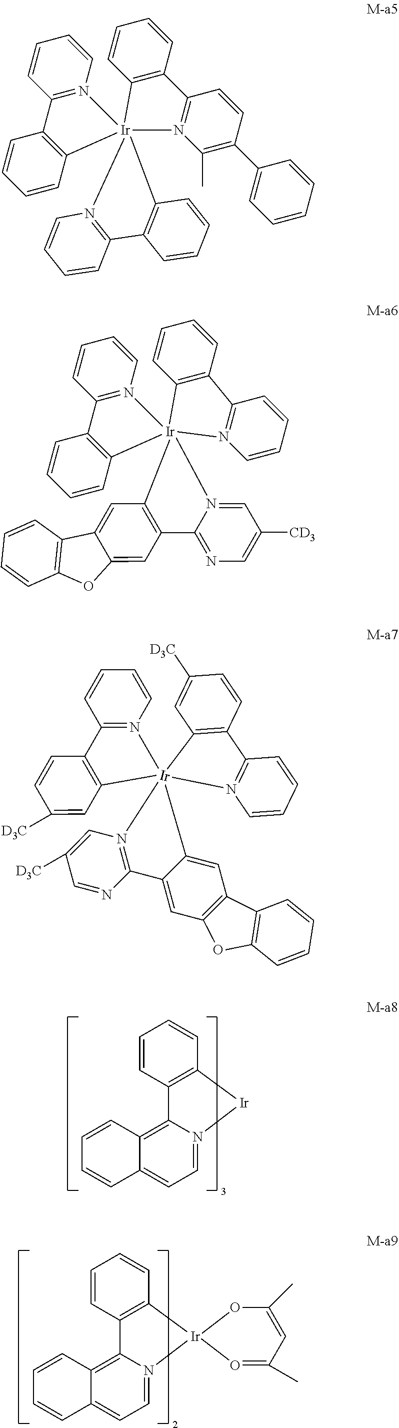

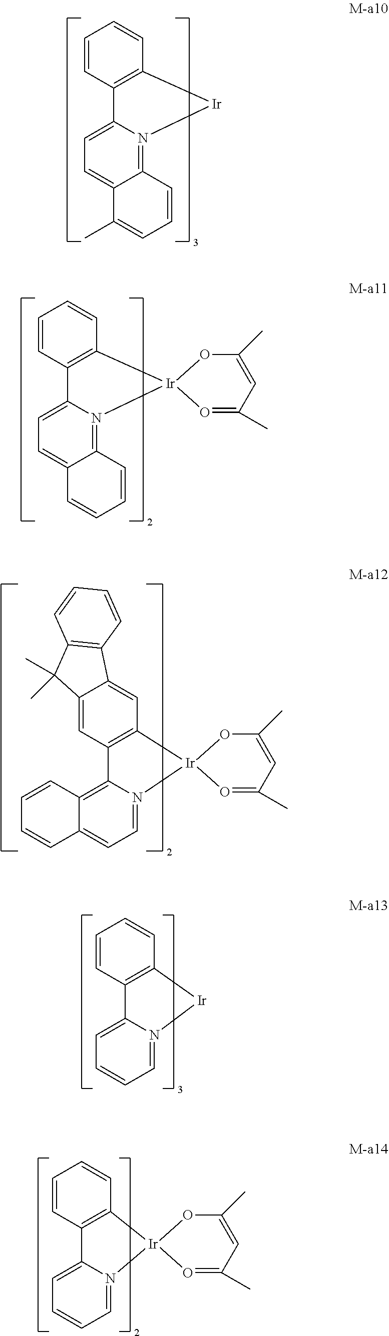

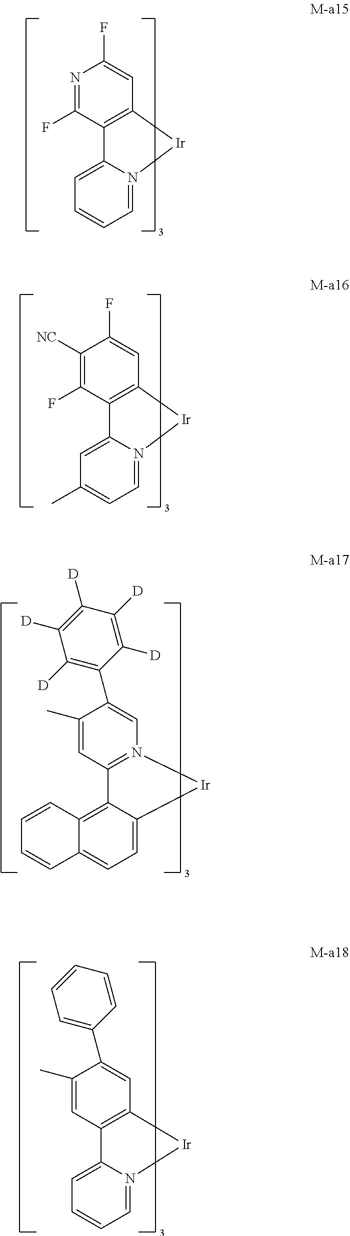

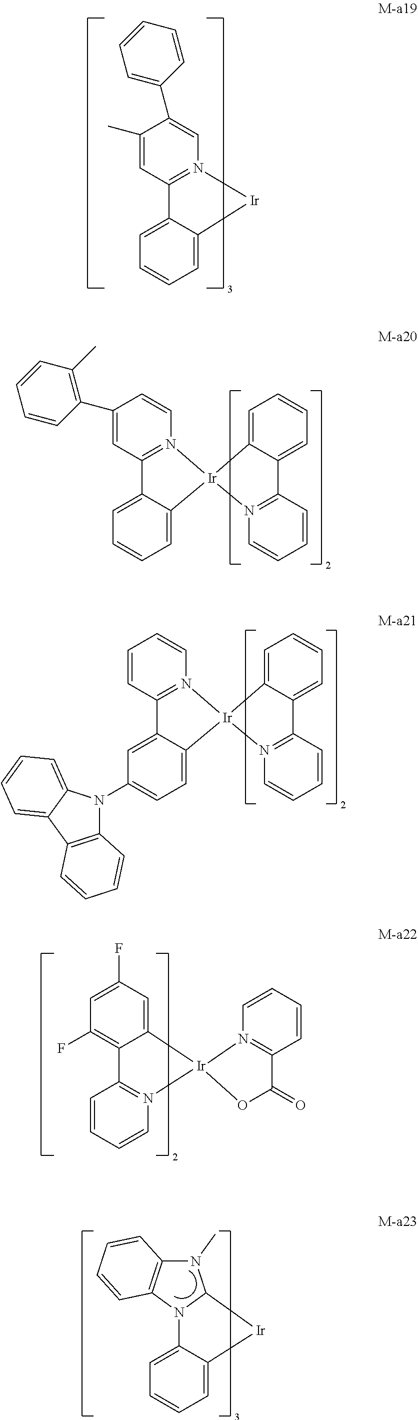

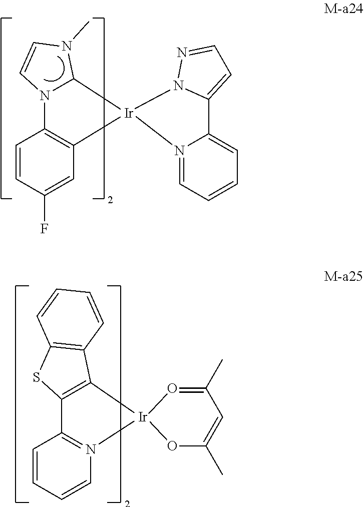

The emission layer EML may include a compound represented by any one among (e.g., selected from among) Formula F-a to Formula F-c. The compound represented by Formula F-a to Formula F-c may be used as a fluorescence dopant material.

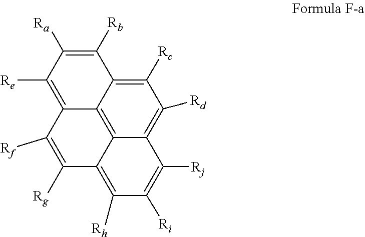

In Formula F-a, two selected from among Rₐ to Rⱼ may each independently be substituted with *—NAr₁Ar₂. The others, which are not substituted with =—NAr₁Ar₂, among Rₐ to Rⱼ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In *—NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

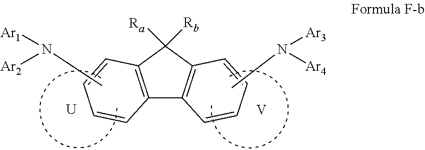

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms. At least one among (e.g., selected from among) Ar₁ to Ar₄ may be a heteroaryl group containing O or S as a ring-forming atom.

In Formula F-b, the number of rings represented by U and V may each independently be 0 or 1. For example, in Formula F-b, it refers to that if (e.g., when) the number of U or V is 1, one ring constitutes a fused ring at a portion indicated by U or V, and if (e.g., when) the number of U or V is 0, a ring indicated by U or V does not exist. For example, if (e.g., when) the number of U is 0 and the number of V is 1, or if (e.g., when) the number of U is 1 and the number of V is 0, the fused ring having a fluorene core in Formula F-b may be a cyclic compound having four rings. In some embodiments, if (e.g., when) each number of U and V is 0, the fused ring in Formula F-b may be a cyclic compound having three rings. In some embodiments, if (e.g., when) each number of U and V is 1, the fused ring having a fluorene core in Formula F-b may be a cyclic compound having five rings.

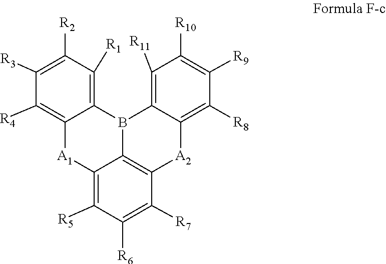

In Formula F-c, A₁ and A₂ may each independently be O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to Ru may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring.

In Formula F-c, A₁ and A₂ may each independently be bonded to substituents of an adjacent ring to form a fused ring. For example, if (e.g., when) A₁ and A₂ may each independently be NRₘ, A₁ may be bonded to R₄ or R₅ to form a ring. In some embodiments, A₂ may be bonded to R₇ or Rs to form a ring.

In one or more embodiments, the emission layer EML may further include, as a suitable dopant material, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and a derivative thereof (e.g., 2,5,8,11-tetra-t-butylperylene (TBP)), pyrene and a derivative thereof (e.g., 1,1-dipyrene, 1,4-dipyrenylbenzene, 1,4-bis(N,N-diphenylamino)pyrene), and/or the like.

The emission layer EML may further include a suitable phosphorescence dopant material. For example, a metal complex containing iridium (Ir), platinum (Pt), osmium (Os), aurum (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N,C2) (FIrpic), bis(2,4-difluorophenylpyridinato)-tetrakis(1-pyrazolyl)borate iridium(III) (F ir6), or platinum octaethyl porphyrin (PtOEP) may be used as a phosphorescent dopant. However, one or more embodiments of the disclosure are not limited thereto.

The emission layer EML may include a quantum dot material. The core of the quantum dot may be selected from among a Group II-VI compound, a Group I-II-VI compound, a Group I-IV-VI compound, a Group I-II-IV-VI compound, a Group II-IV-V compound, a Group III-VI compound, a Group I-III-VI compound, a Group III-V compound, a Group III-II-V compound, a Group IV-VI compound, a Group IV element, a Group IV compound, and/or a (e.g., any suitable) combination thereof.

The Group II-VI compound may be selected from among the group consisting of a binary compound selected from among the group consisting of CdSe, CdTe, CdS, ZnS, ZnSe, ZnTe, ZnO, HgS, HgSe, HgTe, MgSe, MgS, and/or a (e.g., any suitable) mixture thereof, a ternary compound selected from among the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and/or a (e.g., any suitable) mixture thereof, and a quaternary compound selected from among the group consisting of CdZnSeS, CdZnSeTe, CdZnSTe, CdHgSeS, CdHgSeTe, CdHgSTe, HgZnSeS, HgZnSeTe, HgZnSTe, and/or a (e.g., any suitable) mixture thereof. In one or more embodiments, Group II-VI compound may further include a Group I metal and/or IV element. The Group I-II-VI compound may be selected from among the group consisting of CuSnS or CuZnS, the Group II-IV-VI compound may be selected from among the group consisting of ZnSnS, and/or the like. The Group I-II-IV-VI compound may be selected from among a quaternary compound selected from among the group consisting of Cu₂ZnSnS₂, Cu₂ZnSnS₄, Cu₂ZnSnSe₄, Ag₂ZnSnS₂, and/or a (e.g., any suitable) mixture thereof. The Group II-IV-V compound may include a ternary compound such as ZnSnP, ZnSnP2, ZnSnAs2, ZnGeP2, ZnGeAs2, CdSnP2, CdGeP2, and/or a (e.g., any suitable) mixture thereof.

The Group III-VI compound may include a binary compound such as In₂S₃ or In₂Se₃, a ternary compound such as InGaS₃ or InGaSe₃, or any combination thereof.

The Group I-III-VI compound may be selected from among a ternary compound selected from among the group consisting of AgInS, AgInS₂, CuInS, CuInS₂, AgGaS₂, CuGaS₂ CuGaO₂, AgGaO₂, AgAlO₂, and/or a (e.g., any suitable) mixture thereof, or a quaternary compound such as AgInGaS, AgInGaS₂, AgInGaSe, AgInGaSe₂, CuInGaS, or CuInGaS₂.

The Group III-V compound may be selected from among the group consisting of a binary compound selected from among the group consisting of GaN, GaP, GaAs, GaSb, AlN, AlP, AlAs, AlSb, InN, InP, InAs, InSb, and/or a (e.g., any suitable) mixture thereof, a ternary compound selected from among the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and/or a (e.g., any suitable) mixture thereof, and a quaternary compound selected from among the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and/or a (e.g., any suitable) mixture thereof. In one or more embodiments, the Group III-V compound may further include a Group II metal. For example, InZnP, and/or the like, may be selected as a Group III-II-V compound.

The Group IV-VI compound may be selected from among the group consisting of a binary compound selected from among the group consisting of SnS, SnSe, SnTe, PbS, PbSe, PbTe, and/or a (e.g., any suitable) mixture thereof, a ternary compound selected from among the group consisting of SnSeS, SnSeTe, SnSTe, PbSeS, PbSeTe, PbSTe, SnPbS, SnPbSe, SnPbTe, and/or a (e.g., any suitable) mixture thereof, and a quaternary compound selected from among the group consisting of SnPbSSe, SnPbSeTe, SnPbSTe, and/or a (e.g., any suitable) mixture thereof. The Group IV element may be selected from among the group consisting of Si, Ge, and/or a (e.g., any suitable) mixture thereof. The Group IV compound may be a binary compound selected from among the group consisting of SiC, SiGe, and/or a (e.g., any suitable) mixture thereof.

Each element included in a polynary compound such as the binary compound, the ternary compound, or the quaternary compound may be present in a particle with a substantially uniform or non-substantially uniform concentration distribution. For example, the formulae refer to the types (kinds) of elements included in the compounds, and the elemental ratio in the compound may be different. For example, AgInGaS₂ may refer to AgInₓGa₁₋ₓS₂ (where x is a real number of 0 to 1).

In one or more embodiments, the quantum dot may have a single structure or a double structure of core-shell in which the concentration of each element included in the quantum dot is substantially uniform. For example, the material included in the core may be different from the material included in the shell.

The shell of the quantum dot may serve as a protection layer to prevent or reduce the chemical deformation of the core to maintain semiconductor properties, and/or a charging layer to impart electrophoresis properties to the quantum dot. The shell may be a single layer or multiple layers. An interface between the core and the shell may have a concentration gradient in which the concentration of an element present in the shell becomes lower towards the center.

An example of the shell of the quantum dots may include a metal or non-metal oxide, a semiconductor compound, and/or a (e.g., any suitable) combination thereof. For example, the metal or non-metal oxide may be a binary compound such as SiO₂, Al₂O₃, TiO₂, ZnO, MnO, Mn₂O₃, Mn₃O₄, CuO, FeO, Fe₂C₃, Fe₃O₄, COO, Co₃O₄, or NiO, or a ternary compound such as MgAl₂O₄, CoFe₂O₄, NiFe₂O₄, or CoMn₂O₄, but one or more embodiments of the disclosure are not limited thereto.

Also, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but one or more embodiments of the disclosure are not limited thereto.

Each element included in a polynary compound such as the binary compound, or the ternary compound may be present in a particle with a substantially uniform or non-substantially uniform concentration distribution. For example, the formulae refer to the types (kinds) of elements included in the compounds, and the elemental ratio in the compound may be different.

The quantum dot may have a full width of half maximum (FWHM) of a light emitting wavelength spectrum of about 45 nm or less, about 40 nm or less, or about 30 nm or less, and color purity or color reproducibility may be improved in the described ranges. In some embodiments, light emitted through such quantum dot is emitted in all directions so that a wide viewing angle may be improved.

In some embodiments, although the form of the quantum dot is not particularly limited as long as it is a form commonly used in the art, more specifically, the quantum dot in the form of spherical, pyramidal, multi-arm, or cubic nanoparticles, nanotubes, nanowires, nanofibers, nanoplate particles, and/or the like may be used.

As the size of the quantum dot is adjusted or the elemental ratio in the quantum dot compound is adjusted, it is possible to control the energy band gap, and thus light in one or more suitable wavelength ranges may be obtained in the quantum dot emission layer. Therefore, the quantum dot as above (using different sizes of quantum dots or different elemental ratios in the quantum dot compound) is used, and thus the light-emitting element, which emits light in one or more suitable wavelengths, may be implemented. For example, the adjustment of the size of the quantum dot or the elemental ratio in the quantum dot compound may be selected to emit red, green, and/or blue light. In some embodiments, the quantum dots may be configured to emit white light by combining one or more suitable colors of light.

In each of the light-emitting elements ED of embodiments illustrated in FIGS. 3 to 7, the electron transport region ETR is provided on the emission layer EML. The electron transport region ETR may include at least one of the hole blocking layer HBL, the electron transport layer ETL, or the electron injection layer EIL, but one or more embodiments of the disclosure are not limited thereto.

The electron transport region ETR may have a single layer formed of a single material, a single layer formed of a plurality of different materials, or a multilayer structure including a plurality of layers formed of a plurality of different materials.

For example, the electron transport region ETR may have a single layer structure of the electron injection layer EIL or the electron transport layer ETL, and may have a single layer structure formed of an electron injection material and an electron transport material. In some embodiments, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL are stacked in order from the emission layer EML, but one or more embodiments of the disclosure are not limited thereto. The electron transport region ETR may have a thickness, for example, from about 1,000 Å to about 1,500 Å.

The electron transport region ETR may be formed using one or more suitable methods such as a vacuum deposition method, a spin coating method, a cast method, a Langmuir-Blodgett (LB) method, an inkjet printing method, a laser printing method, and a laser induced thermal imaging (LITI) method.

The electron transport region ETR may include a compound represented by Formula ET-2:

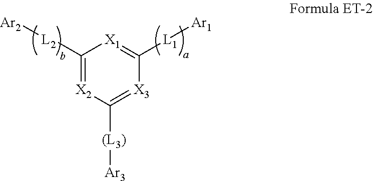

In Formula ET-2, at least one among (e.g., selected from among) X₁ to X₃ is N, and the rest are CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer of 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) a to c may each independently be an integer of 2 or more, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, one or more embodiments of the disclosure are not limited thereto, and the electron transport region ETR may include, for example, at least one selected from among tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate)(Bebq₂), 9,10-di(naphthalen-2-yl)anthracene (ADN), 1,3-bis[3,5-di(pyridin-3-yl)phenyl]benzene (BmPyPhB), and/or a (e.g., any suitable) mixture thereof.

The electron transport region ETR may include at least one among (e.g., selected from among) Compound ET1 to Compound ET36:

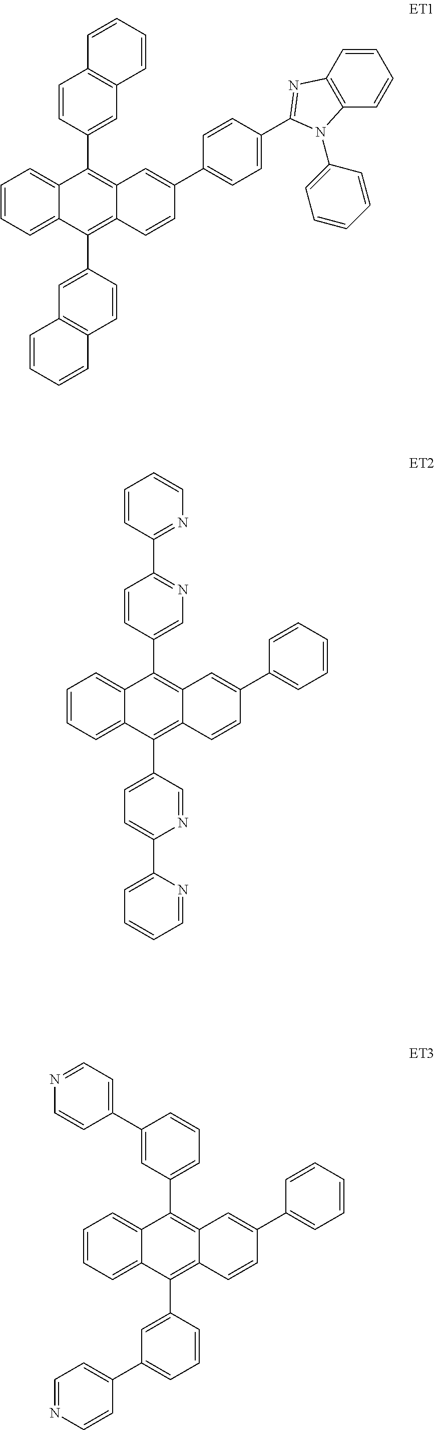 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

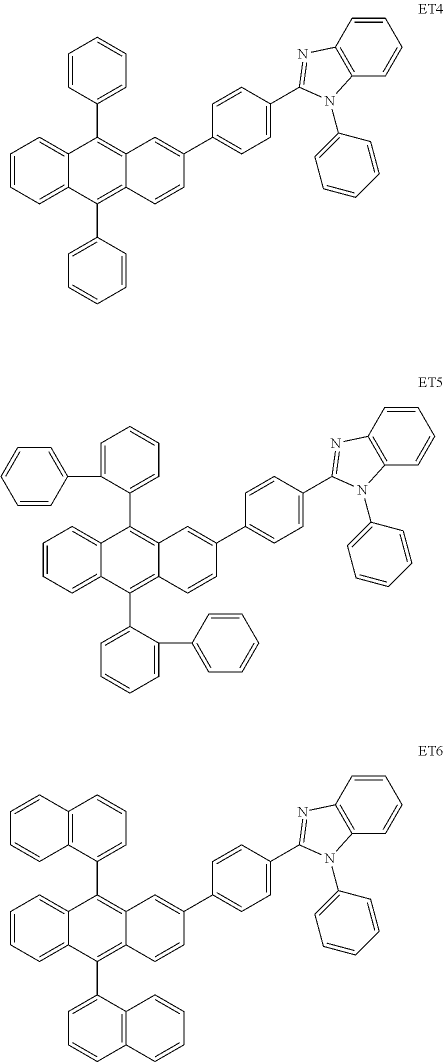 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

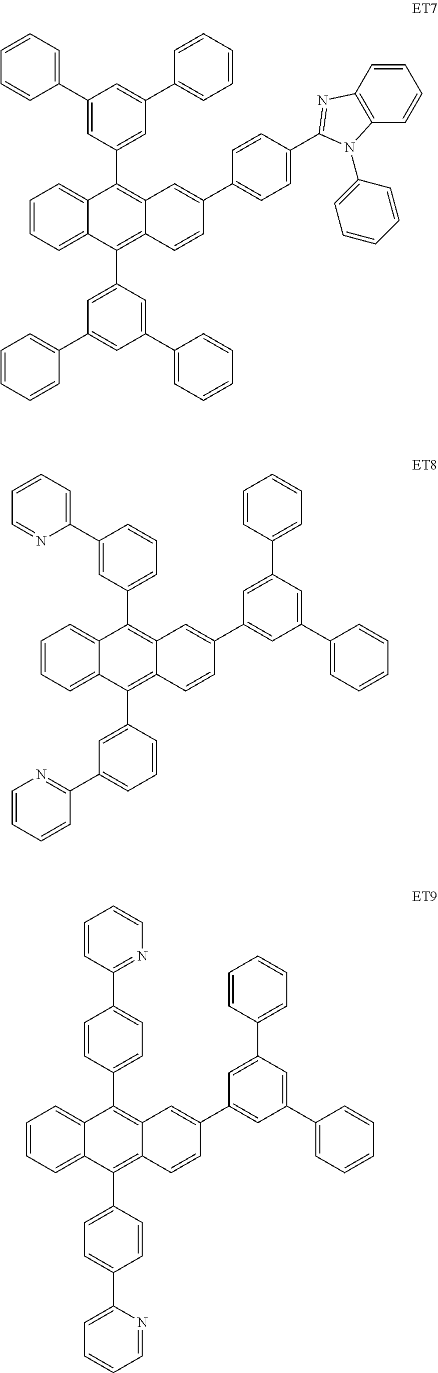 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

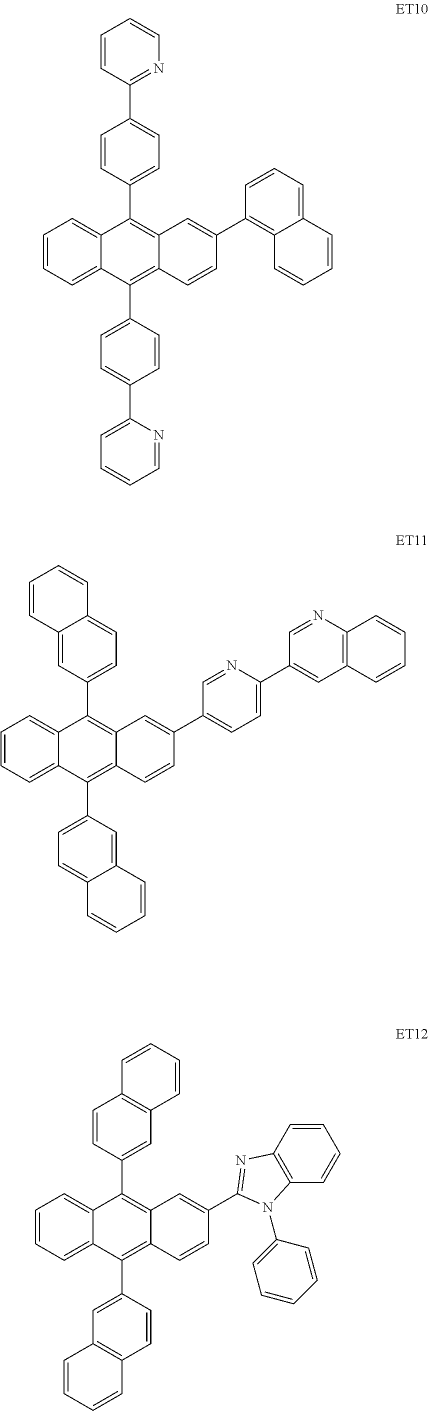 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

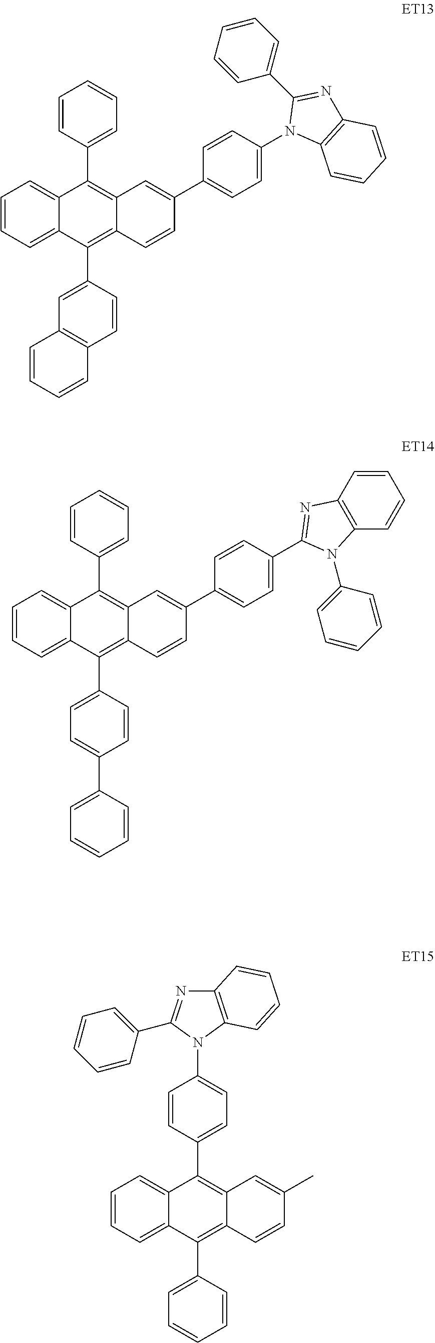 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5ccc(-c6nc7ccccc7n6-c6ccccc6)cc5)ccc34)cc2)cc1 ; Cc1ccc2c(-c3ccccc3)c3ccccc3c(-c3ccc(-n4c(-c5ccccc5)nc5ccccc54)cc3)c2c1]

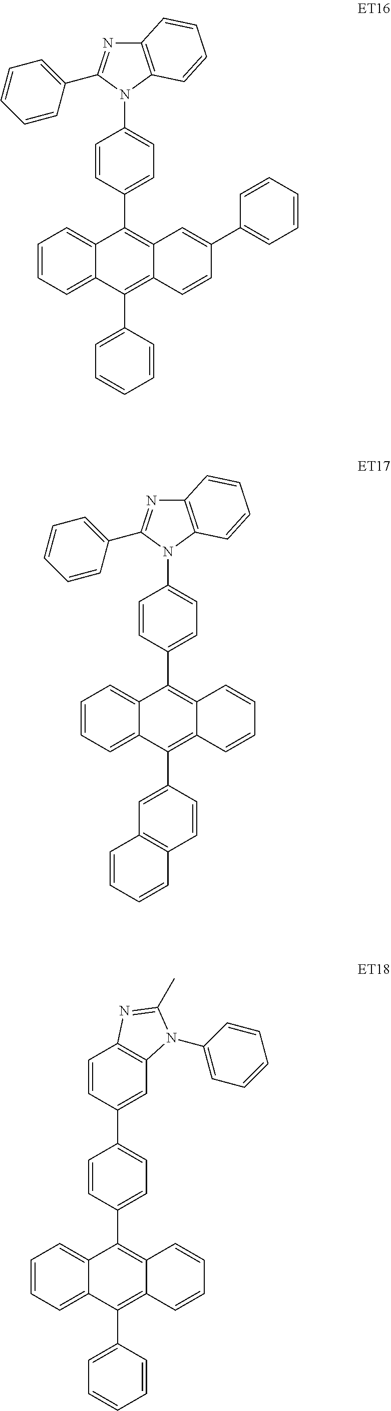 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

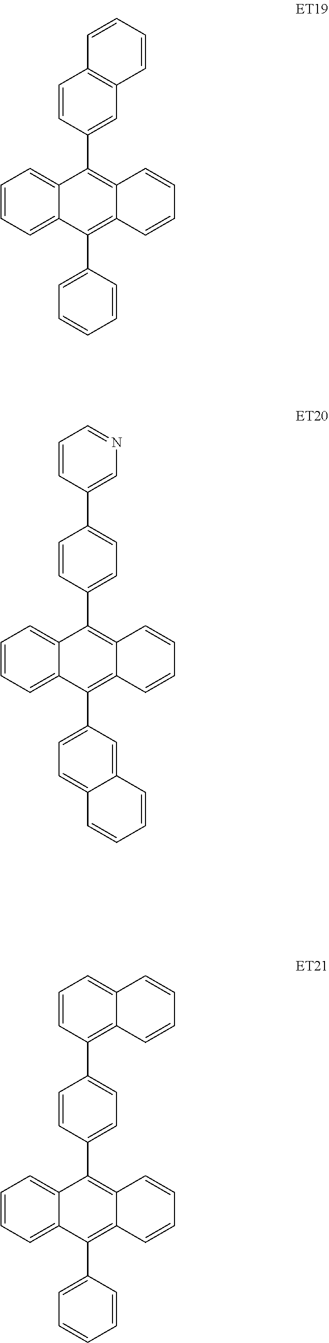

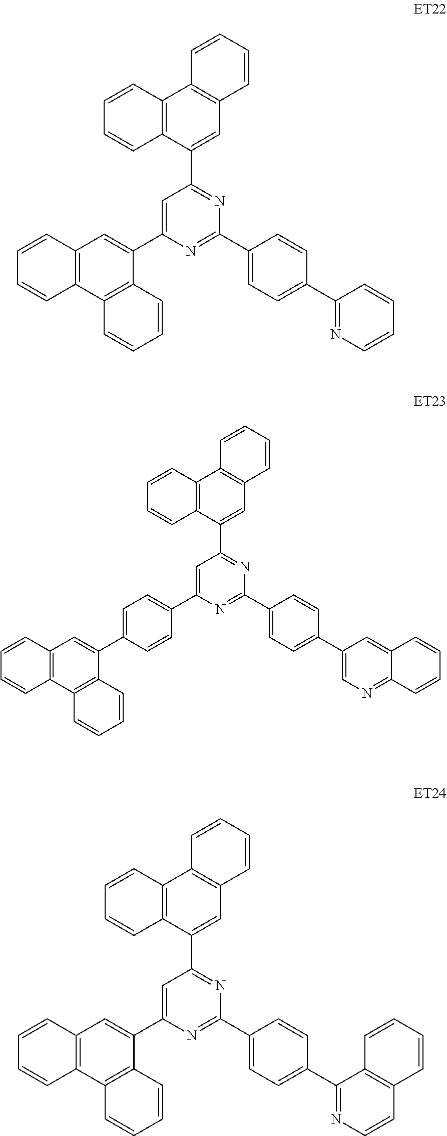 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

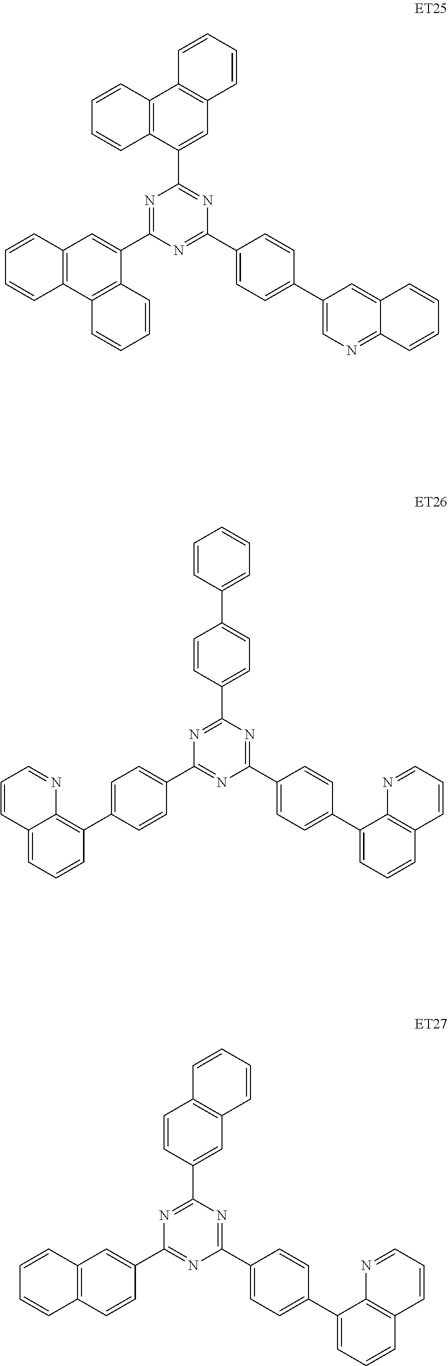 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

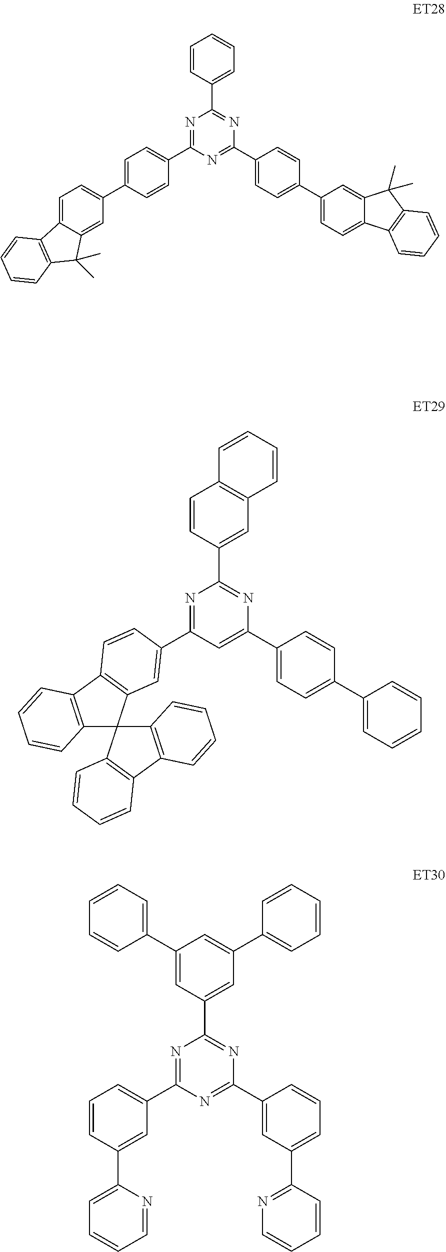 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

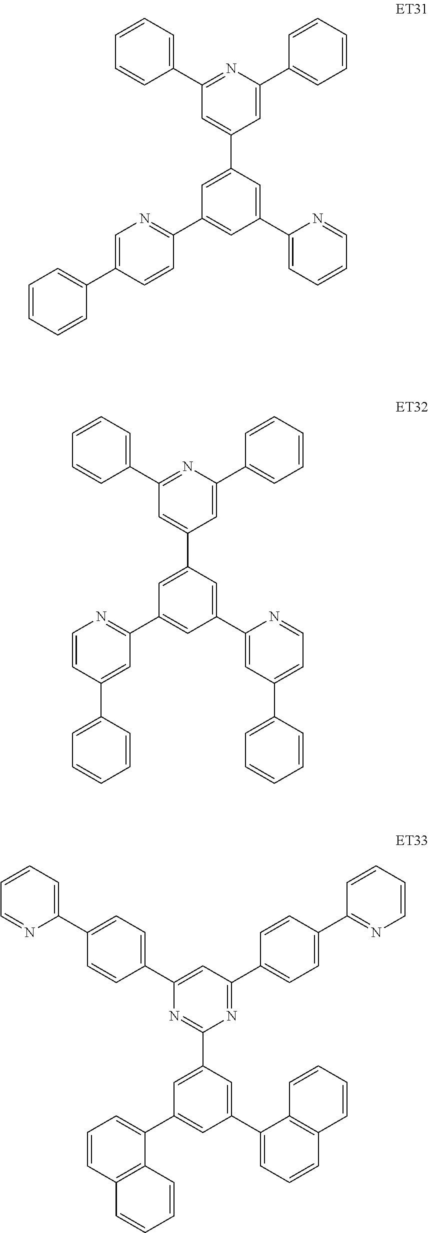 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

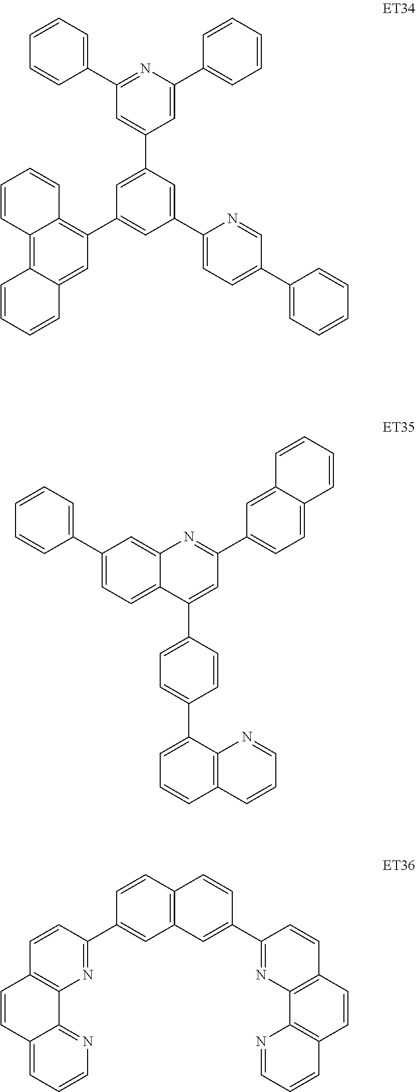 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In some embodiments, the electron transport region ETR may include a metal halide such as LiF, NaCl, CsF, RbCl, RbI, CuI, and KI, a lanthanide metal such as Yb, and a co-deposited material of the metal halide and the lanthanide metal. For example, the electron transport region ETR may include KI:Yb, RbI:Yb, LiF:Yb, and/or the like, as a co-deposited material. In one or more embodiments, the electron transport region ETR may be formed using a metal oxide such as Li₂O or BaO, or 8-hydroxyl-lithium quinolate (Liq), and/or the like, but one or more embodiments of the disclosure are not limited thereto. The electron transport region ETR may also be formed of a mixture material of an electron transport material and an insulating organometallic salt. The organometallic salt may be a material having an energy band gap of about 4 eV or more. For example, the organometallic salt may include, for example, a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the herein-described materials, but one or more embodiments of the disclosure are not limited thereto.

The electron transport region ETR may include the herein-described compounds of the electron transport region ETR in at least one of the electron injection layer EIL, the electron transport layer ETL, or the hole blocking layer H BL.

When the electron transport region ETR includes the electron transport layer ETL, the electron transport layer ETL may have a thickness of about 100 Å to about 1,000 Å, for example, about 150 Å to about 500 Å. If the thickness of the electron transport layer ETL satisfies the aforementioned range, satisfactory electron transport characteristics may be obtained without a substantial increase in driving voltage.

When the electron transport region ETR includes the electron injection layer EIL, the electron injection layer E IL may have a thickness of about 1 Å to about 100 Å, for example, about 3 Å to about 90 Å. If the thickness of the electron injection layer EIL satisfies the herein-described range, satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but one or more embodiments of the disclosure are not limited thereto. For example, if (e.g., when) the first electrode EL1 is an anode, the second electrode EL2 may be a cathode, and if (e.g., when) the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), and/or the like.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or a compound or mixture thereof (e.g., AgMg, AgYb, or MgYb). In one or more embodiments, the second electrode EL2 may have a multilayer structure including a reflective film or a transflective film formed of the herein-described materials, and a transparent conductive film formed of ITO, IZO, ZnO, ITZO, and/or the like. For example, the second electrode EL2 may include the herein-described metal materials, combinations of at least two metal materials of the herein-described metal materials, oxides of the herein-described metal materials, and/or the like.

the second electrode EL2 may be connected with an auxiliary electrode. If the second electrode EL2 is connected with the auxiliary electrode, the resistance of the second electrode EL2 may be decreased.

In one or more embodiments, a capping layer CPL may further be arranged on the second electrode EL2 of the light-emitting element ED of one or more embodiments. The capping layer CPL may include a multilayer or a single layer.

In one or more embodiments, the capping layer CPL may be an organic layer or an inorganic layer. For example, if (e.g., when) the capping layer CPL contains an inorganic material, the inorganic material may include an alkaline metal compound (e.g., LiF), an alkaline earth metal compound (e.g., MgF₂), SiON, SiNₓ, SiO_{y}, and/or the like.

For example, if (e.g., when) the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), and/or the like, or an epoxy resin, or acrylate such as methacrylate. However, one or more embodiments of the disclosure are not limited thereto, and the capping layer CP L may include at least one among (e.g., selected from among) Compounds P1 to P5:

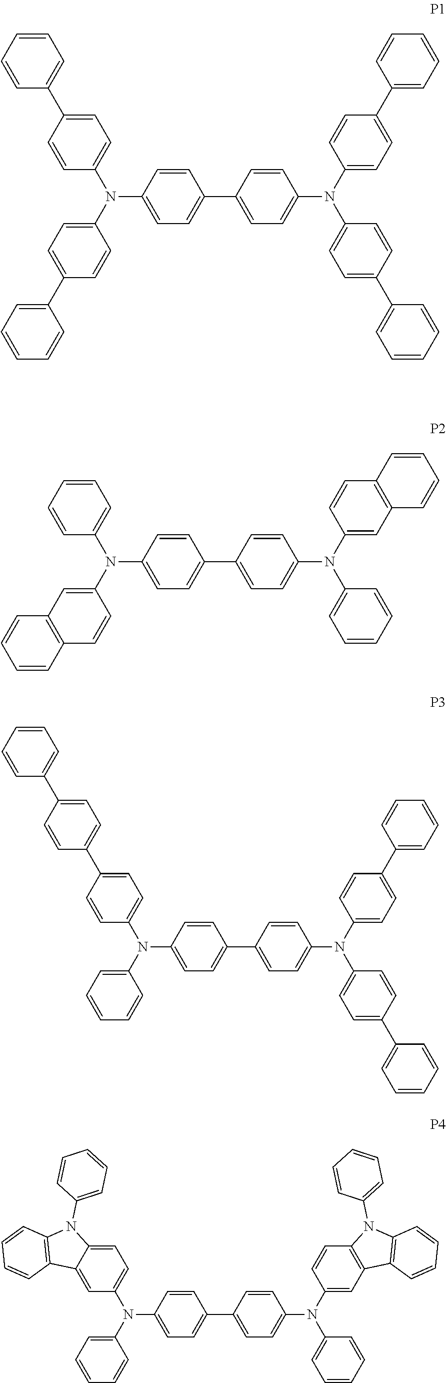 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

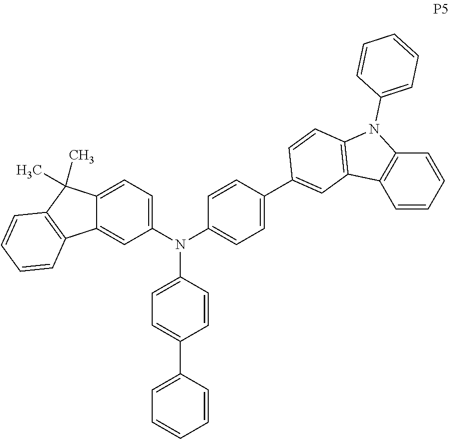 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In one or more embodiments, the refractive index of the capping layer CPL may be about 1.6 or more. For example, the refractive index of the capping layer CPL may be about 1.6 or more with respect to light in a wavelength range of about 550 nm to about 660 nm.

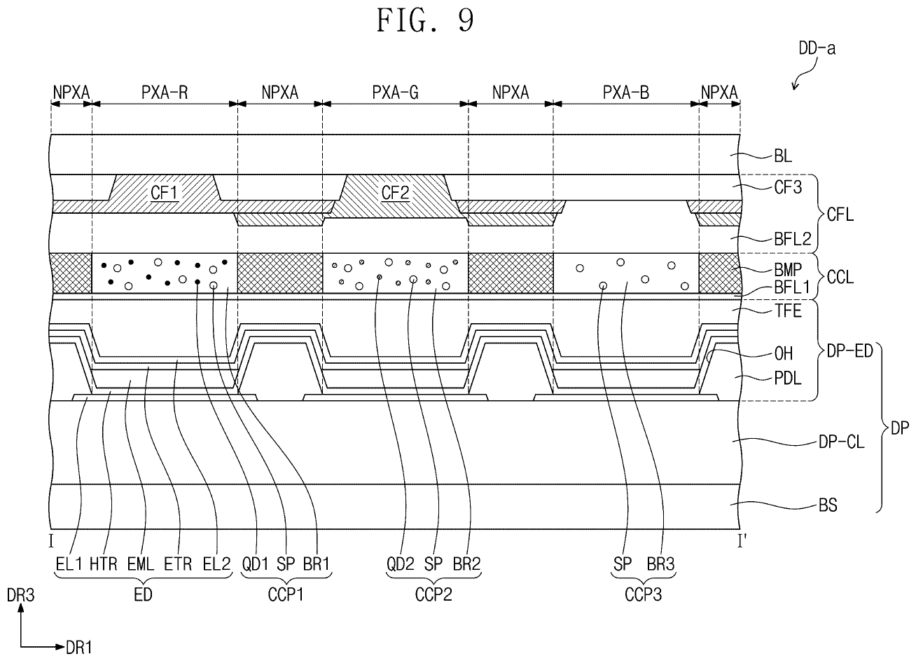

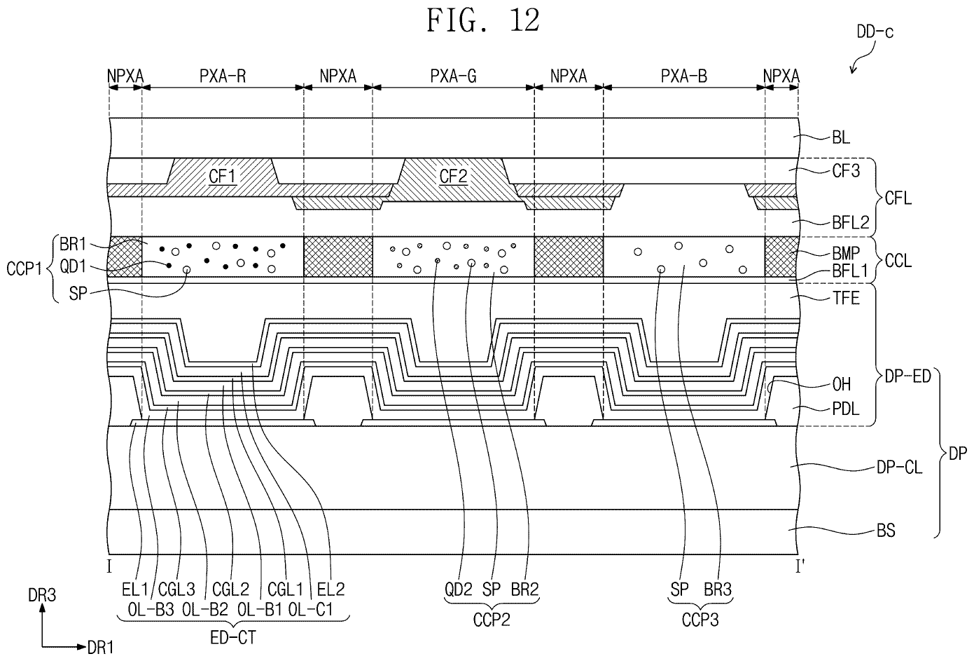

Each of FIGS. 9 to 12 is a cross-sectional view of a display device according to one or more embodiments of the disclosure. Hereinafter, in describing the display devices of embodiments with reference to FIGS. 9 to 12, the duplicated features which have been described in FIGS. 1 to 7 are not described again, but their differences will be mainly described.

Referring to FIG. 9, the display device DD-a according to one or more embodiments may include a display panel DP including a display device layer DP-ED, a light control layer CCL arranged on the display panel DP, and a color filter layer CF L. In one or more embodiments illustrated in FIG. 7, the display panel DP may include a base layer BS, a circuit layer DP-CL provided on the base layer BS, and the display device layer DP-ED, and the display device layer DP-ED may include a light-emitting element ED.

The light-emitting element ED may include a first electrode EL1, a hole transport region HTR arranged on the first electrode EL1, an emission layer EML arranged on the hole transport region HTR, an electron transport region ETR arranged on the emission layer EML, and a second electrode EL2 arranged on the electron transport region ETR. In one or more embodiments, the structures of the light-emitting elements of FIGS. 3 to 7 as described may be equally applied to the structure of the light-emitting element ED illustrated in FIG. 9. The light-emitting element ED illustrated in FIG. 9 may contain at least one among (e.g., selected from among) the polycyclic compound, and the second to fourth compounds. Therefore, the light-emitting element ED may exhibit characteristics of high efficiency and long lifespan.

Referring to FIG. 9, the emission layer EML may be arranged in an opening OH defined in a pixel defining film PDL. For example, the emission layer EML which is divided by the pixel defining film PDL and provided corresponding to each light emitting regions PXA-R, PXA-G, and PXA-B may be to emit light in substantially the same wavelength range. In the display device DD-a of one or more embodiments, the emission layer EML may be to emit blue light. In one or more embodiments, unlike the configuration illustrated, in one or more embodiments, the emission layer EML may be provided as a common layer in the entire light emitting regions PXA-R, PXA-G, and PXA-B.

The light control layer CCL may be arranged on the display panel DP. The light control layer CCL may include a light conversion body. The light conversion body may be a quantum dot, a phosphor, and/or the like. The light conversion body may be to emit provided light by converting the wavelength thereof. For example, the light control layer CCL may a layer containing the quantum dot or a layer containing the phosphor.

The light control layer CCL may include a plurality of light control parts CCP1, CCP2 and CCP3. The light control parts CCP1, CCP2, and CCP3 may be spaced and/or apart (e.g., spaced apart or separated) from each other.

Referring to FIG. 9, divided patterns BMP may be arranged between the light control parts CCP1, CCP2 and CCP3 which are spaced and/or apart (e.g., spaced apart or separated) from each other, but one or more embodiments of the disclosure are not limited thereto. FIG. 7 illustrates that the divided patterns BMP do not overlap the light control parts CCP1, CCP2 and CCP3, but at least a portion of the edges of the light control parts CCP1, CCP2 and CCP3 may overlap the divided patterns BMP.

The light control layer CCL may include a first light control part CCP1 containing a first quantum dot Q D1 which converts first color light provided from the light-emitting element ED into second color light, a second light control part CCP2 containing a second quantum dot QD2 which converts the first color light into third color light, and a third light control part CCP3 which transmits the first color light.

In one or more embodiments, the first light control part CCP1 may provide red light that is the second color light, and the second light control part CCP2 may provide green light that is the third color light. The third light control part CCP3 may provide blue light by transmitting the blue light that is the first color light provided from the light-emitting element ED. For example, the first quantum dot QD1 may be a red quantum dot, and the second quantum dot QD2 may be a green quantum dot. The same as described may be applied with respect to the quantum dots QD1 and QD2.

In some embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) any quantum dot but include the scatterer SP.

The scatterer SP may be inorganic particles. For example, the scatterer SP may include at least one of TiO₂, ZnO, Al₂O₃, SiO₂, or hollow sphere silica. The scatterer SP may include any one among (e.g., selected from among) TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 each may include base resins BR1, BR2, and BR3 in which the quantum dots QD1 and QD2 and the scatterer SP are dispersed. In one or more embodiments, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may be formed of one or more suitable resin compositions, which may be generally referred to as a binder. For example, the base resins BR1, BR2, and BR3 may be acrylic-based resins, urethane-based resins, silicone-based resins, epoxy-based resins, and/or the like. The base resins BR1, BR2, and BR3 may be transparent resins. In one or more embodiments, the first base resin BR1, the second base resin BR2, and the third base resin BR3 may be the same as or different from each other.

The light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may block the light control parts CCP1, CCP2 and CCP3 from being exposed to moisture/oxygen. In one or more embodiments, the barrier layer BFL1 may cover the light control parts CCP1, CCP2, and CCP3. In some embodiments, the barrier layer BFL2 may be provided between the light control parts CCP1, CCP2, and CCP3 and filters CF1, CF2, and CF3.

The barrier layers BFL1 and BFL2 may include at least one inorganic layer. For example, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, and/or the like. In one or more embodiments, the barrier layers BFL1 and BFL2 may further include an organic film. The barrier layers BFL1 and BFL2 may be formed of a single layer or a plurality of layers.

In the display device DD-a of one or more embodiments, the color filter layer CFL may be arranged on the light control layer CCL. For example, the color filter layer CFL may be directly arranged on the light control layer CCL. In this case, the barrier layer BFL2 may not be provided.

The color filter layer CFL may include filters CF1, CF2, and CF3. The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and a pigment or dye. The first filter CF1 may include a red pigment or dye, the second filter CF2 may include a green pigment or dye, and the third filter CF3 may include a blue pigment or dye.

In one or more embodiments, one or more embodiments of the disclosure are not limited thereto, and the third filter CF3 may not include (e.g., may exclude) a pigment or dye. The third filter CF3 may include a polymeric photosensitive resin and may not include (e.g., may exclude) a (e.g., any) pigment or dye. The third filter CF3 may be transparent. The third filter CF3 may be formed of a transparent photosensitive resin.

Furthermore, in one or more embodiments, the first filter CF1 and the second filter CF2 may be a yellow filter. The first filter CF1 and the second filter CF2 may not be separated but be provided as one filter.

Although not illustrated, the color filter layer CF L may further include a light shielding part. The light shielding part may be a black matrix. The light shielding part may include an organic light shielding material or an inorganic light shielding material containing a black pigment or dye. The light shielding part may prevent or reduce light leakage, and may separate boundaries between the adjacent filters CF1, CF2, and CF3.

The first to third filters CF1, CF2, and CF3 may be arranged corresponding to the red light emitting region PXA-R, the green light emitting region PXA-G, and the blue light emitting region PXA-B, respectively.

A base substrate BL may be arranged on the color filter layer CF L. The base substrate BL may be a member which provides a base surface in which the color filter layer CF L, the light control layer CCL, and/or the like are arranged. The base substrate BL may be a glass substrate, a metal substrate, a plastic substrate, and/or the like. However, one or more embodiments of the disclosure are not limited thereto, and the base substrate BL may be an inorganic layer, an organic layer, or a composite material layer. In some embodiments, unlike the configuration illustrated, in one or more embodiments, the base substrate BL may not be provided.

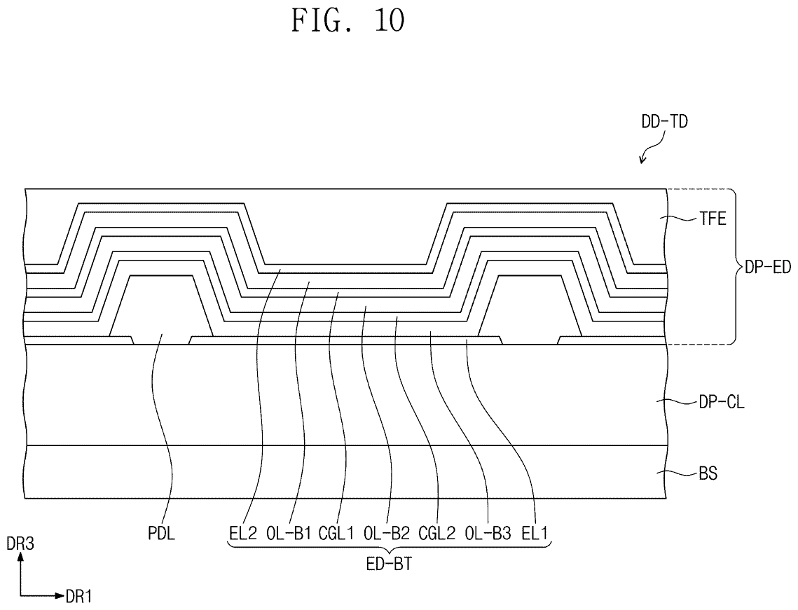

FIG. 10 is a cross-sectional view illustrating a portion of a display device according to one or more embodiments. In the display device DD-TD of one or more embodiments, the light-emitting element ED-BT may include a plurality of light emitting structures OL-B1, OL-B2, and OL-B3. At least one among (e.g., selected from among) the plurality of emission structures OL-B1, OL-B2, and OL-B3 may contain at least one the polycyclic compound according to one or more embodiments, and the second to fourth compounds. Therefore, the light-emitting element ED may exhibit characteristics of high efficiency and long lifespan.

The light-emitting element ED-BT may include a first electrode EL1 and a second electrode EL2 which face each other, and the plurality of light emitting structures OL-B1, OL-B2, and OL-B3 sequentially stacked in the thickness direction between the first electrode EL1 and the second electrode EL2. The light emitting structures OL-B1, OL-B2, and OL-B3 each may include an emission layer EML (FIG. 9) and a hole transport region HTR and an electron transport region ETR arranged with the emission layer EML (FIG. 9) located therebetween.

For example, the light-emitting element ED-BT included in the display device DD-TD of one or more embodiments may be a light-emitting element having a tandem structure and including a plurality of emission layers.

In one or more embodiments illustrated in FIG. 10, all light beams respectively emitted from the light emitting structures OL-B1, OL-B2, and OL-B3 may be blue light. However, one or more embodiments of the disclosure are not limited thereto, and the light beams respectively emitted from the light emitting structures OL-B1, OL-B2, and CL-B3 may have wavelength ranges different from each other. For example, the light-emitting element ED-BT including the plurality of light emitting structures OL-B1, OL-B2, and CL-B3 which emit light beams having wavelength ranges different from each other may be to emit white light.

Charge generation layers CGL1 and CGL2 may be respectively arranged between two of the neighboring light emitting structures CL-B1, OL-B2, and CL-B3. The charge generation layers CGL1 and CGL2 may include a p-type (kind) charge generation layer and/or an n-type (kind) charge generation layer.

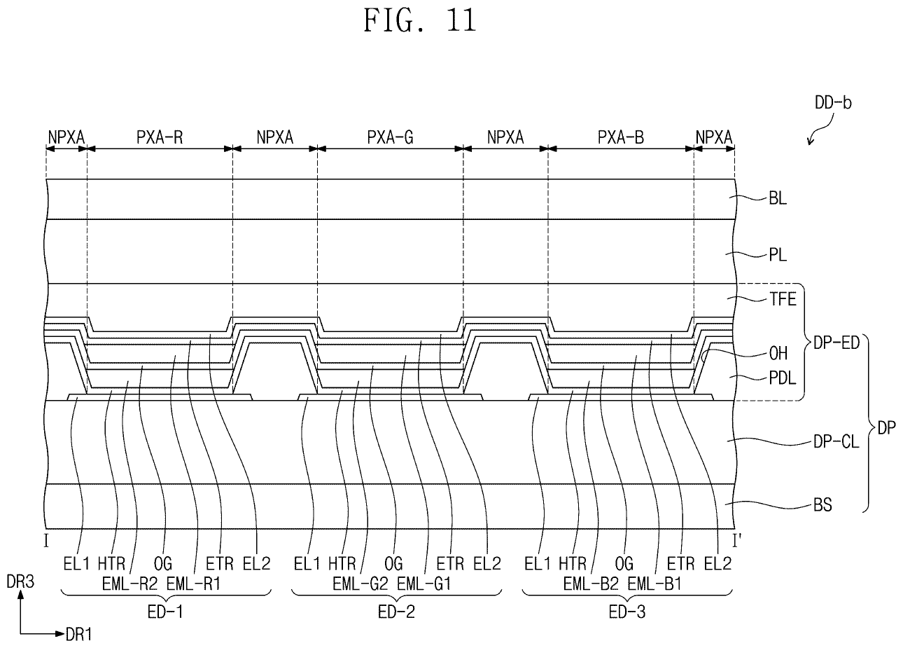

Referring to FIG. 11, the display device DD-b according to one or more embodiments may include light-emitting elements ED-1, ED-2, and ED-3 in which two emission layers are stacked. At least one of the light-emitting elements ED-1, ED-2, and ED-3 may include at least one of the polycyclic compound of one or more embodiments and the second to fourth compounds. Accordingly, the light-emitting element ED-BT may exhibit characteristics of high efficiency and long life. Compared with the display device DD of one or more embodiments illustrated in FIG. 2, one or more embodiments illustrated in FIG. 11 has a difference in that the first to third light-emitting elements ED-1, ED-2, and ED-3 each include two emission layers stacked in the thickness direction. In each of the first to third light-emitting elements ED-1, ED-2, and ED-3, the two emission layers may be to emit light in substantially the same wavelength region.

The first light-emitting element ED-1 may include a first red emission layer EML-R1 and a second red emission layer EML-R2. The second light-emitting element ED-2 may include a first green emission layer EML-G1 and a second green emission layer EML-G2. In some embodiments, the third light-emitting element ED-3 may include a first blue emission layer EML-B1 and a second blue emission layer EML-B2.

An emission auxiliary part OG may be arranged between the first red emission layer EML-R1 and the second red emission layer EML-R2, between the first green emission layer EML-G1 and the second green emission layer EML-G2, and between the first blue emission layer EML-B1 and the second blue emission layer EML-B2. The emission auxiliary part OG may include a single layer or a multilayer. The emission auxiliary part OG may include a charge generation layer. For example, the emission auxiliary part OG may include an electron transport region, a charge generation layer, and a hole transport region that are sequentially stacked. The emission auxiliary part OG may be provided as a common layer in the whole of the first to third light-emitting elements ED-1, ED-2, and ED-3. However, one or more embodiments of the disclosure are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may be arranged between the emission auxiliary part OG and the electron transport region ETR. The second red emission layer EML-R2, the second green emission layer EML-G2, and the second blue emission layer EML-B2 may be arranged between the hole transport region HTR and the emission auxiliary part OG.

For example, the first light-emitting element ED-1 may include the first electrode EL1, the hole transport region HTR, the second red emission layer EML-R2, the emission auxiliary part OG, the first red emission layer EML-R1, the electron transport region ETR, and the second electrode EL2 that are sequentially stacked. The second light-emitting element ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked. The third light-emitting element ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked.

In one or more embodiments, an optical auxiliary layer P L may be arranged on the display device layer DP-ED. The optical auxiliary layer PL may include a polarizing layer. The optical auxiliary layer P L may be arranged on the display panel DP and control reflected light in the display panel DP due to external light. Unlike the configuration illustrated, the optical auxiliary layer P L in the display device according to one or more embodiments may not be provided.

Unlike FIGS. 10 and 11, FIG. 12 illustrates that a display device DD-c includes four light emitting structures OL-B1, OL-B2, OL-B3, and CL-C1. A light-emitting element ED-CT may include a first electrode EL1 and a second electrode EL2 which face each other, and first to fourth light emitting structures OL-B1, OL-B2, CL-B3, and CL-C1 that are sequentially stacked in the thickness direction between the first electrode EL1 and the second electrode EL2. At least one among (e.g., selected from among) the first to fourth emission structures OL-B1, OL-B2, OL-B3, and CL-C1 may contain at least one among (e.g., selected from among) the polycyclic compound according to one or more embodiments and the second to fourth compounds.

Therefore, the light-emitting element ED-BT may exhibit characteristics of high efficiency and long lifespan. Charge generation layers CGL1, CGL2, and CGL3 may be arranged between the first to fourth light emitting structures CL-B1, OL-B2, CL-B3, and OL-C1. Among the four light emitting structures, the first to third light emitting structures OL-B1, OL-B2, and CL-B3 may be to emit blue light, and the fourth light emitting structure OL-C1 may be to emit green light. However, one or more embodiments of the disclosure are not limited thereto, and the first to fourth light emitting structures OL-B1, OL-B2, OL-B3, and CL-C1 may be to emit light beams in different wavelength regions.

The charge generation layers CGL1, CGL2, and CGL3 arranged between adjacent light emitting structures OL-B1, OL-B2, OL-B3, and CL-C1 may include a p-type (kind) charge generation layer and/or an n-type (kind) charge generation layer.

In one or more embodiments, the electronic device may include a display device including a plurality of light-emitting elements, and a control part which controls the display device. The electronic device of one or more embodiments may be a device that is activated according to an electrical signal. The electronic device may include display devices of one or more suitable embodiments. For example, the electronic device may include not only large-sized electronic devices such as a television set, a monitor, or an outdoor billboard but also include small- and medium-sized electronic devices such as a personal computer, a laptop computer, a personal digital terminal, a display device for a vehicle, a game console, a portable electronic device, or a camera.

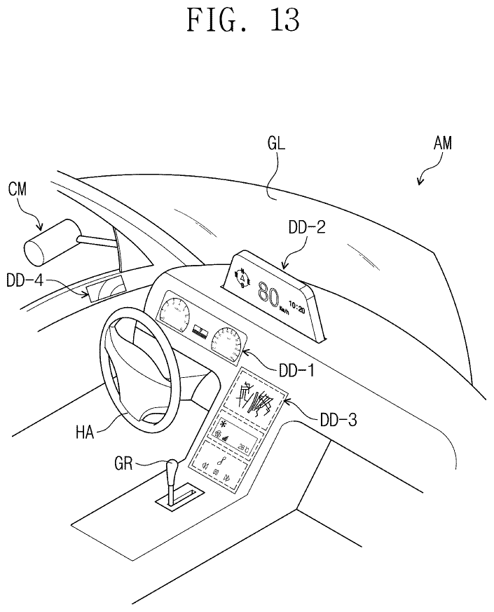

FIG. 13 is a view illustrating a vehicle AM in which first to fourth display devices DD-1, DD-2, DD-3, and DD-4 are arranged. At least one among (e.g., selected from among) the first to fourth display devices DD-1, DD-2, DD-3, and DD-4 may include the same configuration as the display devices DD, DD-TD, DD-a, DD-b, and DD-c as described with reference to FIGS. 1, and 2, and 9 to 12.

FIG. 13 illustrates a vehicle AM, but this is an example, and the first to fourth display devices DD-1, DD-2, DD-3, and DD-4 may be arranged in another transportation refers to such as bicycles, motorcycles, trains, ships, and airplanes. In some embodiments, at least one among (e.g., selected from among) the first to fourth display devices DD-1, DD-2, DD-3, and DD-4 including the same configuration as the display devices DD, DD-TD, DD-a, DD-b, and DD-c of one or more embodiments may be employed in a personal computer, a laptop computer, a personal digital terminal, a game console, a portable electronic device, a television, a monitor, an outdoor billboard, and/or the like. In some embodiments, these are merely provided as embodiments, and thus may be employed in other electronic devices unless departing from the disclosure.

At least one among (e.g., selected from among) the first to fourth display devices DD-1, DD-2, DD-3, and DD-4 may include the light-emitting element ED of one or more embodiments as described with reference to FIGS. 3 to 7. At least one among (e.g., selected from among) the first to fourth display devices DD-1, DD-2, DD-3, and DD-4 may contain at least one among (e.g., selected from among) the polycyclic compound according to one or more embodiments, and the second to fourth compounds. Therefore, the first to fourth display devices DD-1, DD-2, DD-3, and DD-4 containing at least one among (e.g., selected from among) the polycyclic compound according to one or more embodiments, and the second to fourth compounds may have improved display efficiency and display lifespan.

Referring to FIG. 13, the vehicle AM may include a steering wheel HA and a gear GR for driving the vehicle AM. In some embodiments, the vehicle AM may include a front window GL arranged so as to face the driver.

The first display device DD-1 may be arranged in a first region overlapping the steering wheel HA. For example, the first display device DD-1 may be a digital cluster which displays first information of the vehicle AM. The first information may include a first scale which indicates a driving speed of the vehicle AM, a second scale which indicates an engine speed (that is, revolutions per minute (RPM)), an image which indicates a fuel state, and/or the like. A first scale and a second scale may be indicated as a digital image.

The second display device DD-2 may be arranged in a second region opposite to (e.g., facing) the driver's seat and overlapping the front window GL. The driver's seat may be a seat in which the steering wheel HA is arranged. For example, the second display device DD-2 may be a head up display (HUD) which displays second information of the vehicle AM. The second display device DD-2 may be optically transparent. The second information may include digital numbers which indicate a driving speed, and may further include information such as the current time. Unlike the configuration illustrated, the second information of the second display device DD-2 may be projected to the front window G L to be displayed.

The third display device DD-3 may be arranged in a third region adjacent to the gear GR. For example, the third display device DD-3 may be arranged between the driver's seat and the passenger seat and may be a center information display (CID) for a vehicle for displaying third information. The passenger seat may be a seat spaced and/or apart (e.g., spaced apart or separated) from the driver's seat with the gear GR arranged therebetween. The third information may include information about traffic (e.g., navigation information), playing music or radio or a video (or an image), temperatures inside the vehicle AM, and/or the like.

The fourth display device DD-4 may be spaced and/or apart (e.g., spaced apart or separated) from the steering wheel HA and the gear GR, and may be arranged in a fourth region adjacent to the side of the vehicle AM. For example, the fourth display device DD-4 may be a digital side-view mirror which displays fourth information. The fourth display device DD-4 may display an image outside the vehicle AM taken by a camera module CM arranged outside the vehicle AM. The fourth information may include an image outside the vehicle AM.

The herein-described first to fourth information may be examples, and the first to fourth display devices DD-1, DD-2, DD-3, and DD-4 may further display information about the inside and outside of the vehicle AM. The first to fourth information may include different information. However, one or more embodiments of the disclosure are not limited thereto, and a part of the first to fourth information may include the same information as one another.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

Hereinafter, the polycyclic compound according to one or more embodiments and the light emitting element according to one or more embodiments of the present disclosure will be further explained referring to one or more embodiments and comparative embodiments. The embodiments are only illustrations to assist the understanding of the subject matter of the present disclosure, and the scope of the present disclosure is not limited thereto.

### EXAMPLES

### 1. Synthesis of Polycyclic Compound According to One or More Embodiments

A synthetic method of a polycyclic compound according to one or more embodiments will be described in more detail by exemplifying synthetic methods of Compounds 3, 25, 47, 79, 1, 85 and 86. In the following descriptions, the synthetic method of the polycyclic compound is provided as an example, but the synthetic method of the polycyclic compound according to one or more embodiments of the disclosure are not limited to the following examples.

### (1) Synthesis of Compound 3

Polycyclic Compound 3 according to an example may be synthesized by, for example, Reaction Scheme 1.

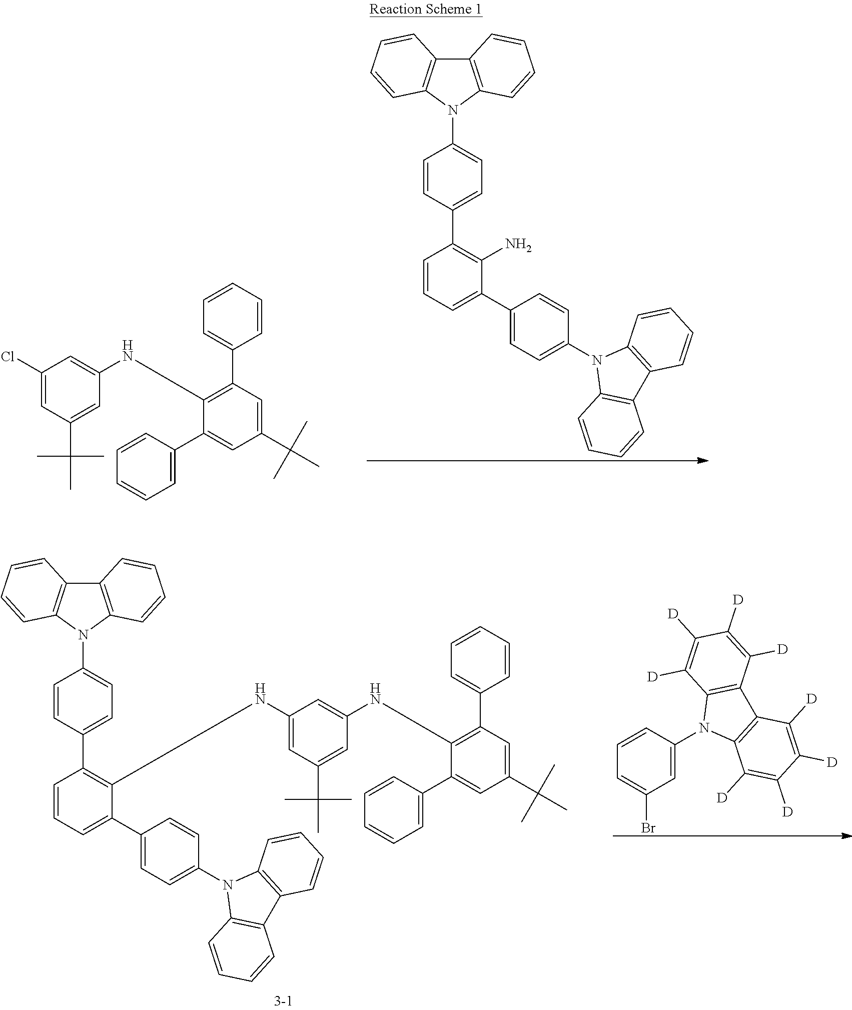 [SMILES: CC(C)(C)c1cc(Cl)cc(Nc2c(-c3ccccc3)cc(C(C)(C)C)cc2-c2ccccc2)c1 ; Nc1c(-c2ccc(-n3c4ccccc4c4ccccc43)cc2)cccc1-c1ccc(-n2c3ccccc3c3ccccc32)cc1 ; CC(C)(C)c1cc(Nc2c(-c3ccc(-n4c5ccccc5c5ccccc54)cc3)cccc2-c2ccc(-n3c4ccccc4c4ccccc43)cc2)cc(Nc2c(-c3ccccc3)cc(C(C)(C)C)cc2-c2ccccc2)c1 ; [2H]c1c([2H])c([2H])c2c(c1[2H])c1c([2H])c([2H])c([2H])c([2H])c1n2-c1cccc(Br)c1]

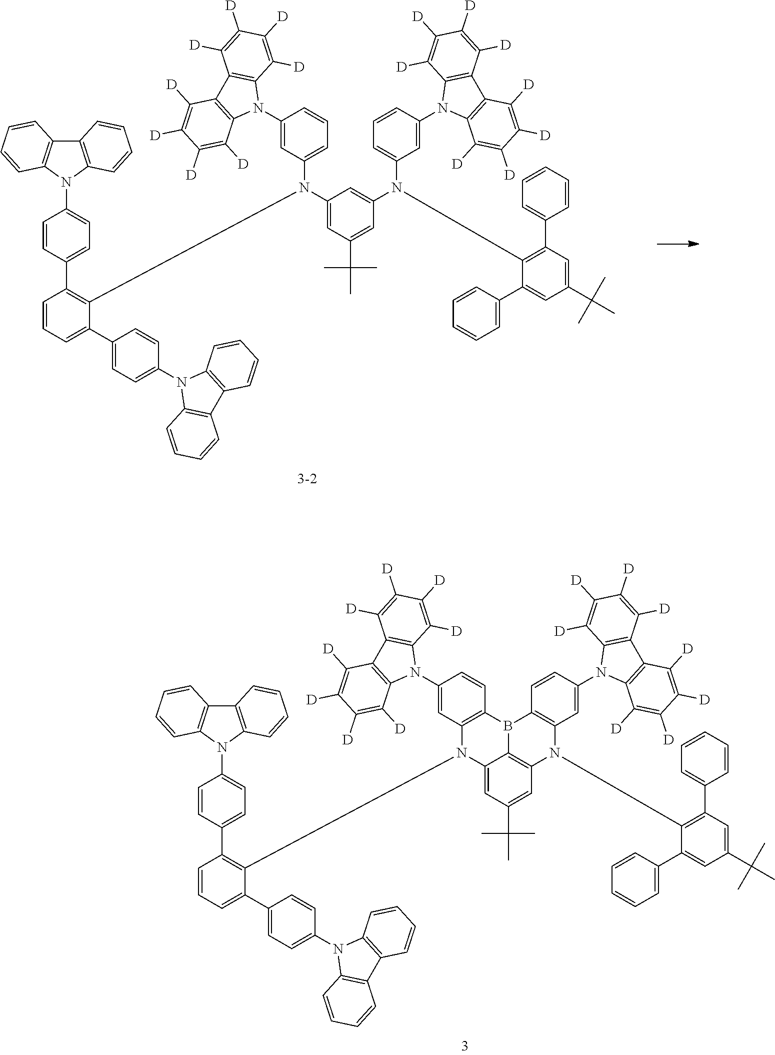

### Synthesis of Intermediate 3-1

5′-(tert-butyl)-N-(3-(tert-butyl)-5-chlorophenyl)-[1,1′:3′,1″-terphenyl]-2′-amine (1 eq), 4,4″-di(9H-carbazol-9-yl)-[1,1′:3′,1″-terphenyl]-2′-amine (1 eq), tris(dibenzylideneacetone)dipalladium(0) (0.05 eq), tri-tert-butylphosphine (0.1 eq), and sodium tert-butoxide (3 eq) were dissolved in toluene and then stirred at about 110° C. for about 12 hours. After cooling, the resultant was diluted with ethyl acetate and washed three times with water, then an organic layer obtained by separating was dried over MgSO₄ and then dried under reduced pressure. The resultant was purified by column chromatography with methylene chloride (MC) and n-Hexane to obtain Intermediate 3-1 (yield of 77%).

### Synthesis of Intermediate 3-2

Intermediate 3-1 (1 eq), 9-(3-bromophenyl)-93-carbazole-1,2,3,4,5,6,7,8-d8 (3.3 eq), tris(dibenzylideneacetone)dipalladium(0) (0.15 eq), tri-tert-butylphosphine (0.3 eq), and sodium tert-butoxide (5 eq) was dissolved in o-xylene and then stirred at about 160° C. for about 60 hours. After cooling, the resultant was diluted with ethyl acetate and washed three times with water, then an organic layer obtained by separating was dried over MgSO₄ and then dried under reduced pressure. The resultant was purified by column chromatography with MC and n-Hexane to obtain Intermediate 3-2 (yield of 39%)

### Synthesis of Compound 3

Intermediate 3-2 (1 eq) was dissolved in ortho dichlorobenzene and cooled to about 0° C., and then BBr₃ (3 eq) was slowly added in nitrogen atmosphere. After the dropwise addition was completed, the temperature was raised to about 180° C. and stirred for about 24 hours. After cooling, triethylamine was slowly added to the flask containing the reactant to quench the reaction. Then, ethyl alcohol was added to the reactant, and the resulting product was precipitated, filtered to obtain solids. The obtained solids were purified by column chromatography using MC and n-Hexane, and then recrystallized using toluene and acetone to obtain Compound 3 (yield of 13%).

### (2) Synthesis of Compound 25

Polycyclic Compound 25 according to an example may be synthesized by, for example, Reaction Scheme 2.

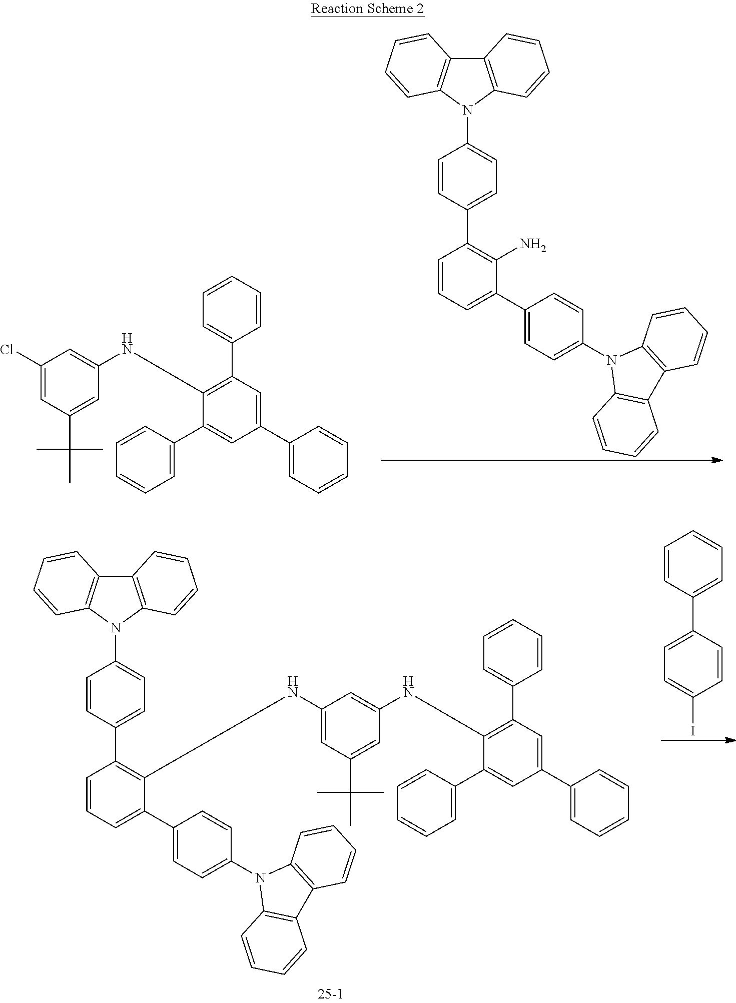 [SMILES: CC(C)(C)c1cc(Cl)cc(Nc2c(-c3ccccc3)cc(-c3ccccc3)cc2-c2ccccc2)c1 ; Nc1c(-c2ccc(-n3c4ccccc4c4ccccc43)cc2)cccc1-c1ccc(-n2c3ccccc3c3ccccc32)cc1 ; CC(C)(C)c1cc(Nc2c(-c3ccc(-n4c5ccccc5c5ccccc54)cc3)cccc2-c2ccc(-n3c4ccccc4c4ccccc43)cc2)cc(Nc2c(-c3ccccc3)cc(-c3ccccc3)cc2-c2ccccc2)c1 ; Ic1ccc(-c2ccccc2)cc1]

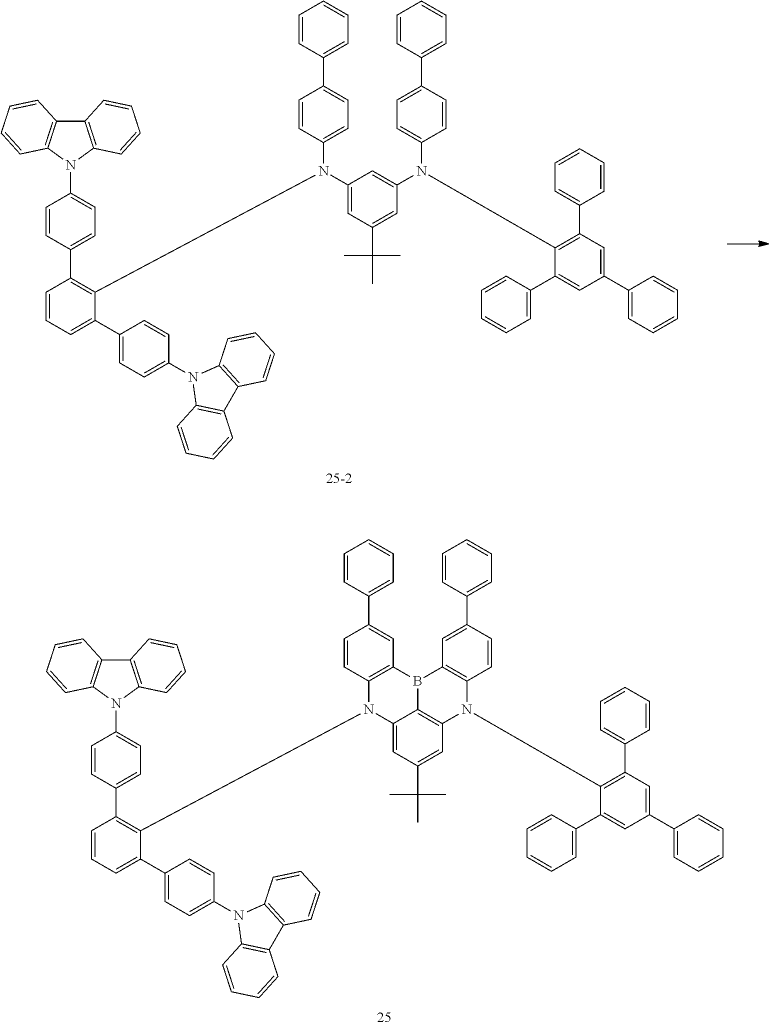 [SMILES: CC(C)(C)c1cc(N(c2ccc(-c3ccccc3)cc2)c2c(-c3ccc(-n4c5ccccc5c5ccccc54)cc3)cccc2-c2ccc(-n3c4ccccc4c4ccccc43)cc2)cc(N(c2ccc(-c3ccccc3)cc2)c2c(-c3ccccc3)cc(-c3ccccc3)cc2-c2ccccc2)c1 ; CC(C)(C)c1cc2c3c(c1)N(c1c(-c4ccccc4)cc(-c4ccccc4)cc1-c1ccccc1)c1ccc(-c4ccccc4)cc1B3c1cc(-c3ccccc3)ccc1N2c1c(-c2ccc(-n3c4ccccc4c4ccccc43)cc2)cccc1-c1ccc(-n2c3ccccc3c3ccccc32)cc1]

### Synthesis of Intermediate 25-1

N-(3-(tert-butyl)-5-chlorophenyl)-5′-phenyl-[1,1′:3′,1″-terphenyl]-2′-amine (1 eq), 4,4″-di(9H-carbazol-9-yl)-[1,1′:3′,1″-terphenyl]-2′-amine (1 eq), tris(dibenzylideneacetone)dipalladium(0) (0.05 eq), tri-tert-butylphosphine (0.1 eq), and sodium tert-butoxide (3 eq) were dissolved in toluene and then stirred at about 110° C. for about 12 hours. After cooling, the resultant was diluted with ethyl acetate and washed three times with water, then an organic layer obtained by separating was dried over MgSO₄ and then dried under reduced pressure. The resultant was purified by column chromatography with MC and n-Hexane to obtain Intermediate 25-1 (yield of 74N %).

### Synthesis of Intermediate 25-2

Intermediate 25-1 (1 eq), 4-iodo-1,1′-biphenyl (3 eq), -tris(dibenzylideneacetone)dipalladium(0) (0.15 eq), tri-tert-butylphosphine (0.3 eq), and sodium tert-butoxide (5 eq) were dissolved in o-xylene and then stirred at about 160° C. for about 60 hours. After cooling, the resultant was diluted with ethyl acetate and washed three times with water, then an organic layer obtained by separating was dried over MgSO₄ and then dried under reduced pressure. The resultant was purified by column chromatography with MC and n-Hexane to obtain Intermediate 25-2 (yield of 47%).

### Synthesis of Compound 25

Intermediate 25-2 (1 eq) was dissolved in ortho dichlorobenzene and then cooled to about 0° C., and then BBr₃ (3 eq) was slowly added in nitrogen atmosphere. After the dropwise addition was completed, the temperature was raised to about 180° C. and stirred for about 24 hours. After cooling, triethylamine was slowly added to the flask containing the reactant to quench the reaction. Then, ethyl alcohol was added to the reactant, and the resulting product was precipitated, filtered to obtain solids. The obtained solids were purified by column chromatography with MC and n-Hexane, and then recrystallized using toluene and acetone to obtain Compound 25 (yield of 15%).

### (3) Synthesis of Compound 47

Polycyclic Compound 47 according to an example may be synthesized by, for example, Reaction Scheme 3.

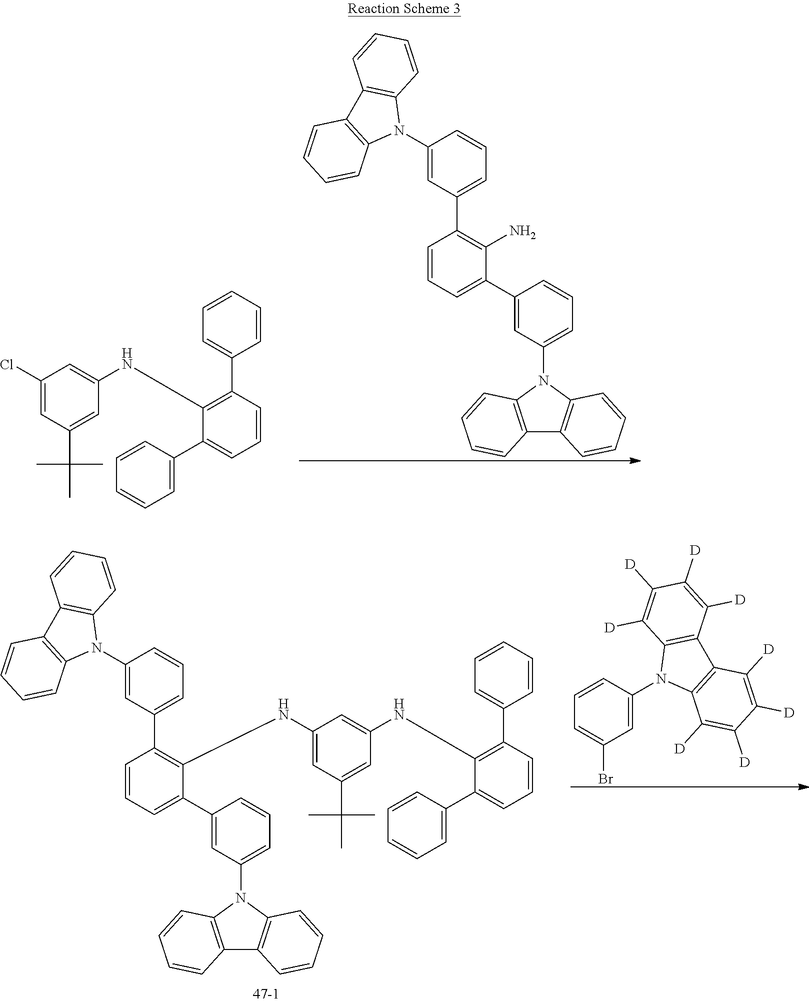

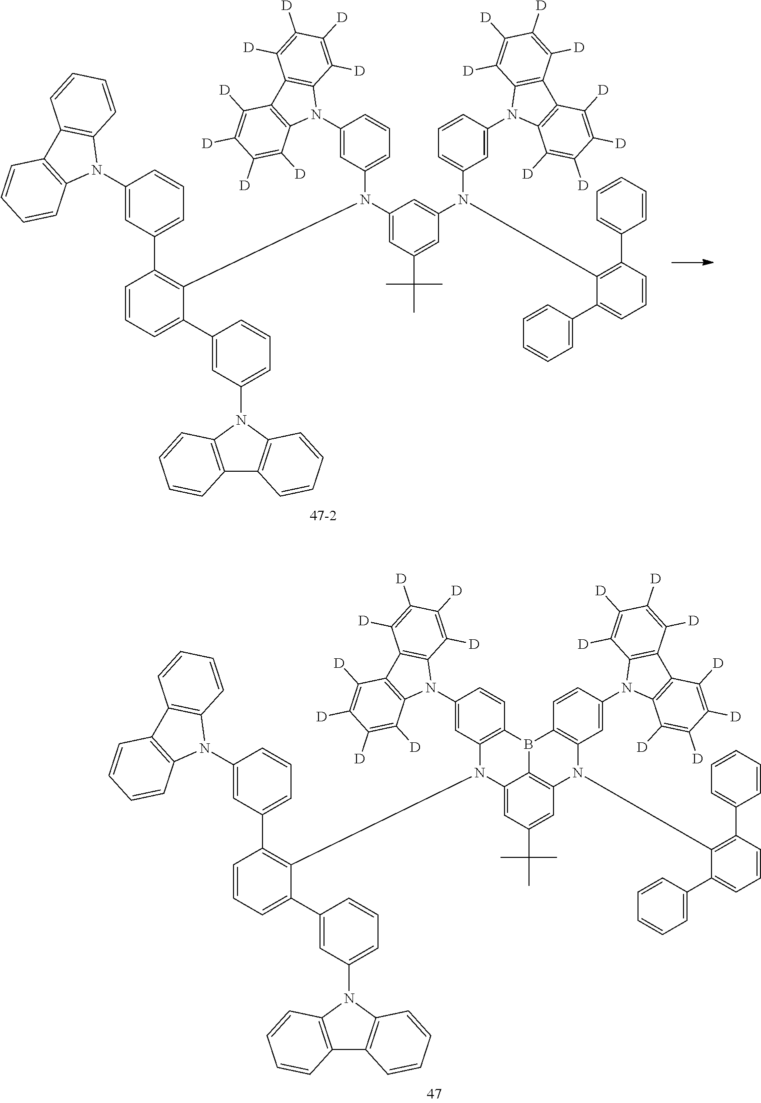

### Synthesis of Intermediate 47-1

N-(3-(tert-butyl)-5-chlorophenyl)-[1,1′:3′,1″-terphenyl]-2′-amine (1 eq), 3,3″-di(9NH-carbazol-9-yl)-[1,1′:3′,1″-terphenyl]-2′-amine (1 eq), tris(dibenzylideneacetone)dipalladium(0) (0.05 eq), tri-tert-butylphosphine (0.1 eq), and sodium tert-butoxide (3 eq) were dissolved in toluene and then stirred at about 110° C. for about 12 hours. After cooling, the resultant was diluted with ethyl acetate and washed three times with water, then an organic layer obtained by separating was dried over MgSO₄ and then dried under reduced pressure. The resultant was purified by column chromatography with MC and n-Hexane to obtain Intermediate 47-1 (yield of 67%).

### Synthesis of Intermediate 47-2

Intermediate 47-1 (1 eq), 9-(3-bromophenyl)-9NH-carbazole-1,2,3,4,5,6,7,8-de (3.5 eq), tris(dibenzylideneacetone)dipalladium(0) (0.15 eq), tri-tert-butylphosphine (0.3 eq), and sodium tert-butoxide (5 eq) were dissolved in o-xylene and then stirred at about 160° C. for about 60 hours. After cooling, the resultant was diluted with ethyl acetate and washed three times with water, then an organic layer obtained by separating was dried over MgSO₄ and then dried under reduced pressure. The resultant was purified by column chromatography with MC and n-Hexane to obtain Intermediate 47-2 (yield of 33%).

### Synthesis of Compound 47

Intermediate 47-2 (1 eq) was dissolved in ortho dichlorobenzene and then cooled to about 0° C., and then BBr₃ (3 eq) was slowly added in nitrogen atmosphere. After the dropwise addition was completed, the temperature was raised to about 180° C. and stirred for about 24 hours. After cooling, triethylamine was slowly added to the flask containing the reactant to quench the reaction. Then, ethyl alcohol was added to the reactant, and the resulting product was precipitated, filtered to obtain solids. The obtained solids were purified by column chromatography with MC and n-Hexane, and then recrystallized using toluene and acetone to obtain Compound 47 (yield of 9%).

### (4) Synthesis of Compound 79

Polycyclic Compound 79 according to an example may be synthesized by, for example, Reaction Scheme 4.

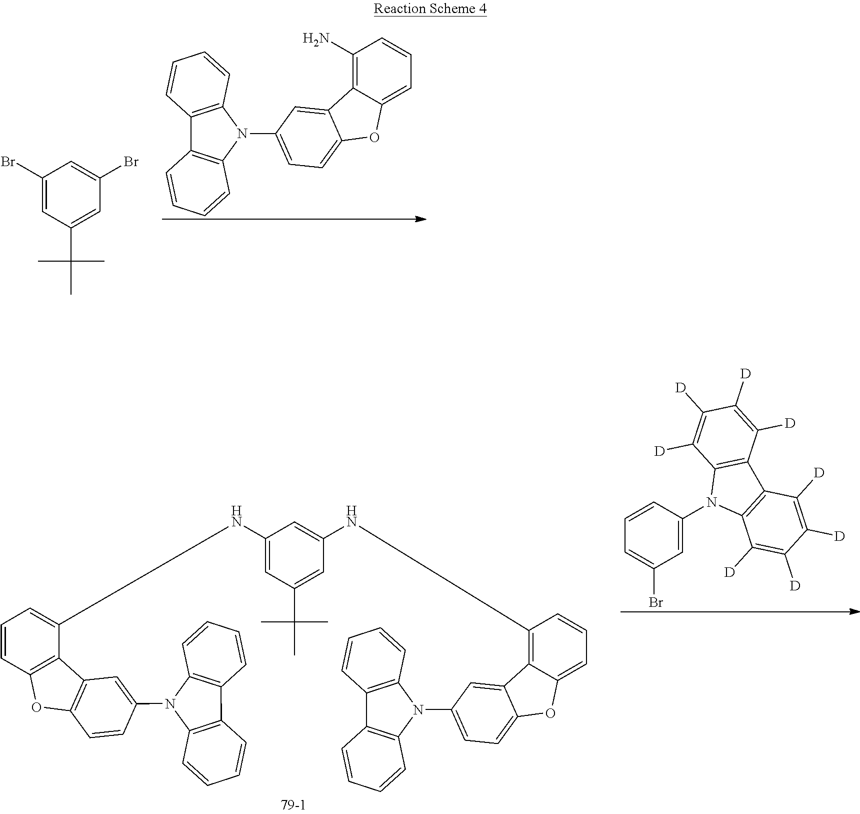

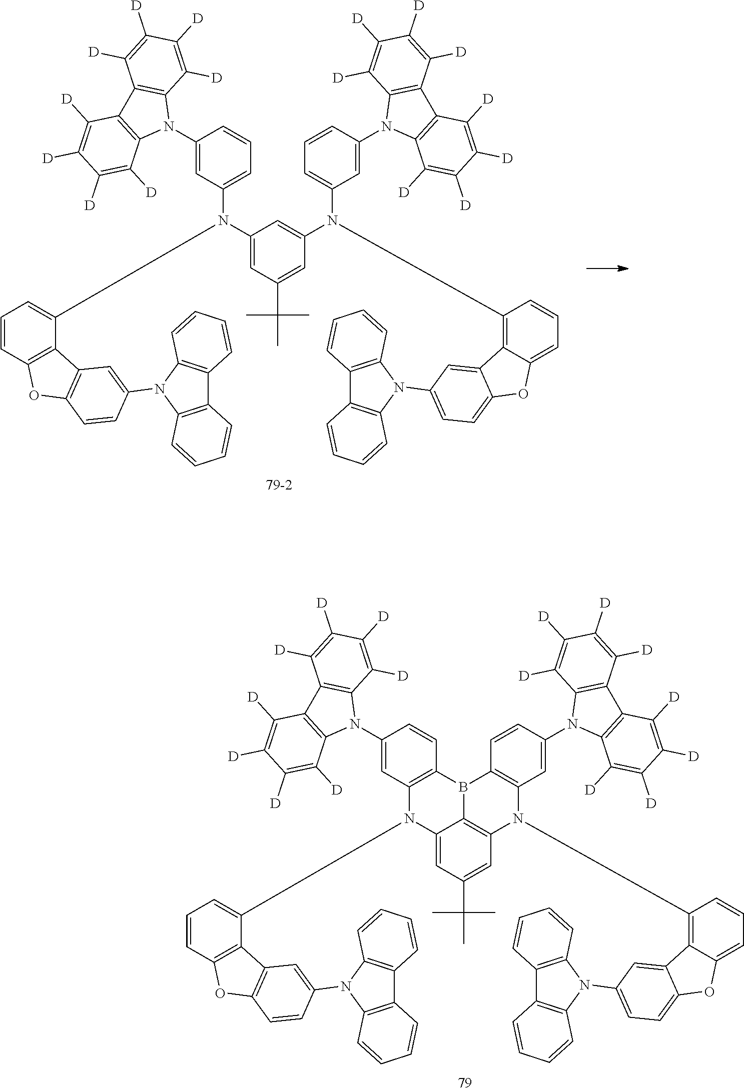

### Synthesis of Intermediate 79-1

1,3-dibromo-5-(tert-butyl)benzene (1 eq), 8-(9H-carbazol-9-yl)dibenzo[b,d]furan-1-amine (2.05 eq), tris(dibenzylideneacetone)dipalladium(0) (0.1 eq), tri-tert-butylphosphine (0.2 eq), and sodium tert-butoxide (3 eq) were dissolved in toluene and then stirred at about 110° C. for about 12 hours. After cooling, the resultant was diluted with ethyl acetate and washed three times with water, then an organic layer obtained by separating was dried over MgSO₄ and then dried under reduced pressure. The resultant was purified by column chromatography with MC and n-Hexane to obtain Intermediate 79-1 (yield of 71%).

### Synthesis of Intermediate 79-2

Intermediate 79-1 (1 eq), 9-(3-bromophenyl)-9H-carbazole-1,2,3,4,5,6,7,8-d8 (2.2 eq), tris(dibenzylideneacetone)dipalladium(0) (0.10 eq), tri-tert-butylphosphine (0.2 eq), and sodium tert-butoxide (3 eq) were dissolved in o-xylene and then stirred at about 160° C. for about 60 hours. After cooling, the resultant was diluted with ethyl acetate and washed three times with water, then an organic layer obtained by separating was dried over MgSO₄ and then dried under reduced pressure. The resultant was purified by column chromatography with MC and n-Hexane to obtain Intermediate 79-2 (yield of 79%).

### Synthesis of Compound 79

Intermediate 79-2 (1 eq) was dissolved in ortho dichlorobenzene and then cooled to about 0° C., and then BBr₃ (3 eq) was slowly added in nitrogen atmosphere. After the dropwise addition was completed, the temperature was raised to about 180° C. and stirred for about 24 hours. After cooling, triethylamine was slowly added to the flask containing the reactant to quench the reaction. Then, ethyl alcohol was added to the reactant, and the resulting product was precipitated, filtered to obtain solids. The obtained solids were purified by column chromatography with MC and n-Hexane, and then recrystallized using toluene and acetone to obtain Compound 79 (yield of 16%).

### (5) Synthesis of Compound 1

Polycyclic Compound 1 according to an example may be synthesized by, for example, Reaction Scheme 5.

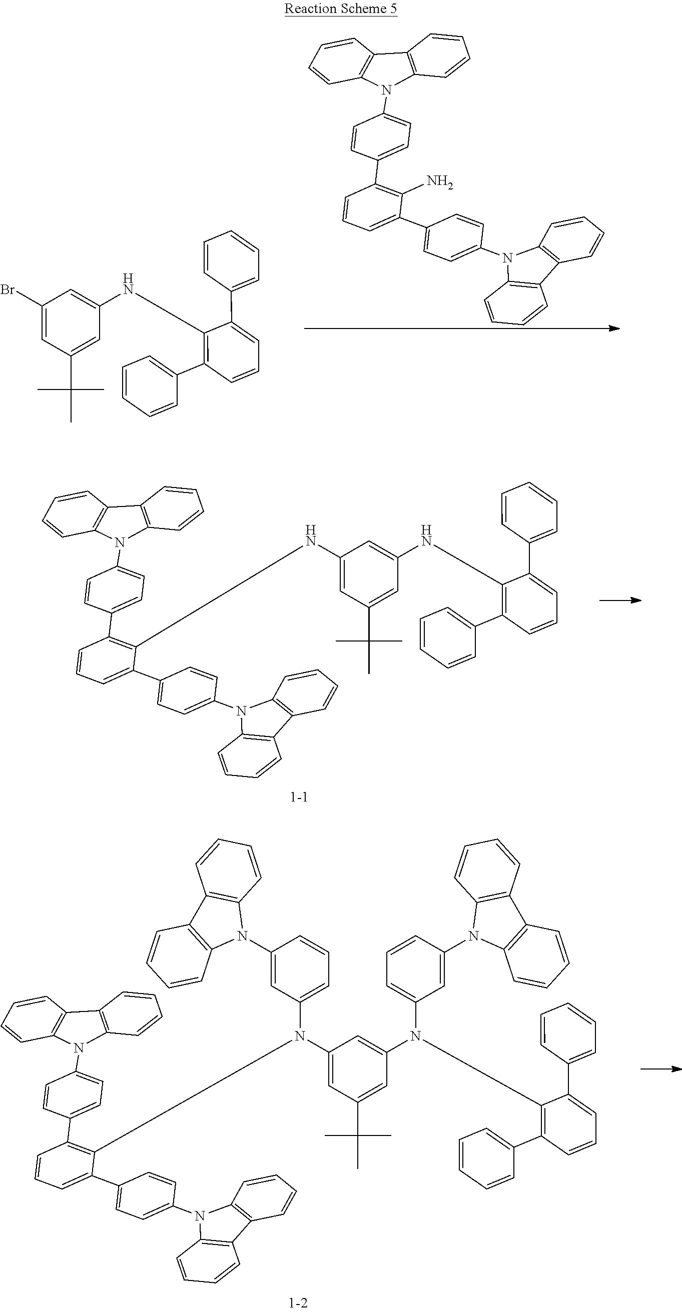 [SMILES: CC(C)(C)c1cc(Br)cc(Nc2c(-c3ccccc3)cccc2-c2ccccc2)c1 ; Nc1c(-c2ccc(-n3c4ccccc4c4ccccc43)cc2)cccc1-c1ccc(-n2c3ccccc3c3ccccc32)cc1 ; CC(C)(C)c1cc(Nc2c(-c3ccccc3)cccc2-c2ccccc2)cc(Nc2c(-c3ccc(-n4c5ccccc5c5ccccc54)cc3)cccc2-c2ccc(-n3c4ccccc4c4ccccc43)cc2)c1 ; CC(C)(C)c1cc(N(c2cccc(-n3c4ccccc4c4ccccc43)c2)c2c(-c3ccccc3)cccc2-c2ccccc2)cc(N(c2cccc(-n3c4ccccc4c4ccccc43)c2)c2c(-c3ccc(-n4c5ccccc5c5ccccc54)cc3)cccc2-c2ccc(-n3c4ccccc4c4ccccc43)cc2)c1]

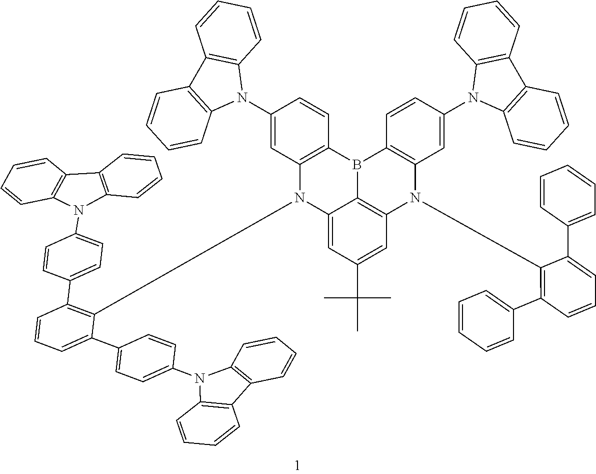 [SMILES: CC(C)(C)c1cc2c3c(c1)N(c1c(-c4ccc(-n5c6ccccc6c6ccccc65)cc4)cccc1-c1ccc(-n4c5ccccc5c5ccccc54)cc1)c1cc(-n4c5ccccc5c5ccccc54)ccc1B3c1ccc(-n3c4ccccc4c4ccccc43)cc1N2c1c(-c2ccccc2)cccc1-c1ccccc1]

### Synthesis of Intermediate 1-1

N-(3-bromo-5-(tert-butyl)phenyl)-[1,1′:3′,1″-terphenyl]-2′-amine (1 eq), 4,4″-di(9H-carbazol-9-yl)-[1,1′:3′,1″-terphenyl]-2′-amine (1.1 eq), tris(dibenzylideneacetone)dipalladium(0) (0.05 eq), tri-tert-butylphosphine (0.1 eq), and sodium tert-butoxide (3 eq) were dissolved in toluene and then stirred at about 110° C. for about 12 hours. After cooling, the resultant was diluted with ethyl acetate and washed three times with water, then an organic layer obtained by separating was dried over MgSO₄ and then dried under reduced pressure. The resultant was purified by column chromatography with MC and n-Hexane to obtain Intermediate 1-1 (yield of 79%).

### Synthesis of Intermediate 1-2

Intermediate 1-1 (1 eq), 9-(3-iodophenyl)-9H-carbazole (3.5 eq), tris(dibenzylideneacetone)dipalladium(0) (0.15 eq), tri-tert-butylphosphine (0.3 eq), and sodium tert-butoxide (5 eq) were dissolved in o-xylene and then stirred at about 160° C. for about 60 hours. After cooling, the resultant was diluted with ethyl acetate and washed three times with water, then an organic layer obtained by separating was dried over MgSO₄ and then dried under reduced pressure. The resultant was purified by column chromatography with MC and n-Hexane to obtain Intermediate 1-2 (yield of 41%).

### Synthesis of Compound 1

Intermediate 1-2 (1 eq) was dissolved in ortho dichlorobenzene and then cooled to about 0° C., and then BBr₃ (3 eq) was slowly added in nitrogen atmosphere. After the dropwise addition was completed, the temperature was raised to about 180° C. and stirred for about 24 hours. After cooling, triethylamine was slowly added to the flask containing the reactant to quench the reaction. Then, ethyl alcohol was added to the reactant, and the resulting product was precipitated, filtered to obtain solids. The obtained solids were purified by column chromatography with MC and n-Hexane, and then recrystallized using toluene and acetone to obtain Compound 1 (yield of 12%).

### (6) Synthesis of Compound 85

Polycyclic Compound 85 according to an example may be synthesized by, for example, Reaction Scheme 6.

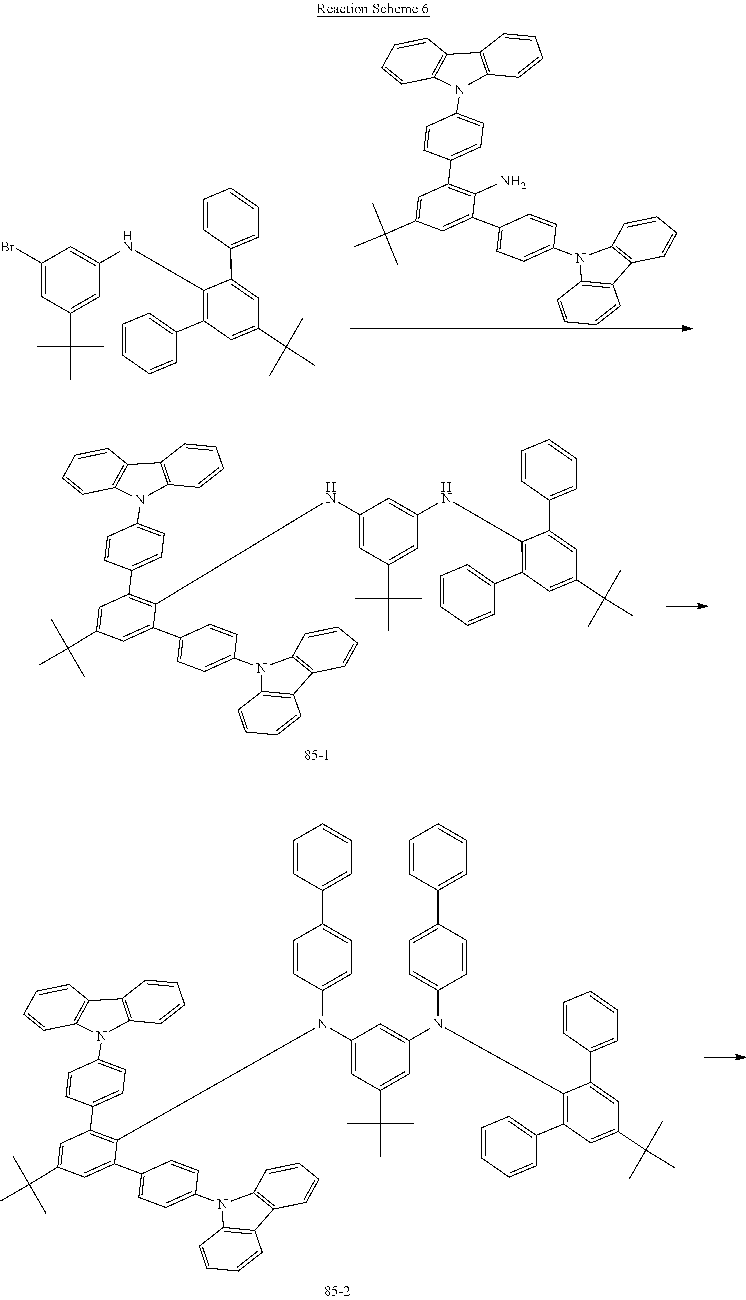

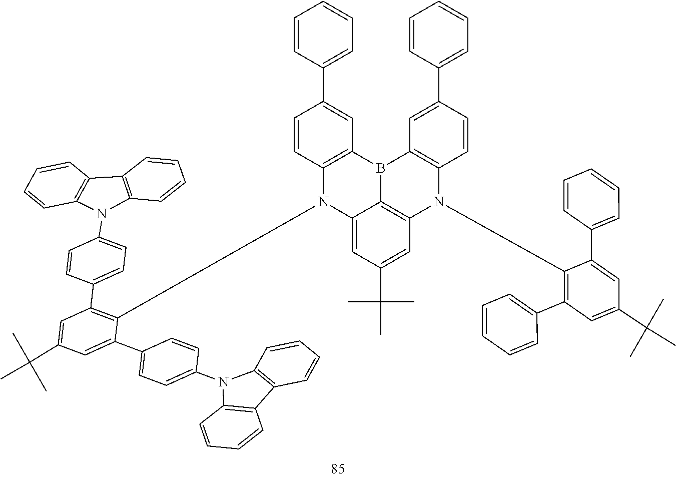 [SMILES: CC(C)(C)c1cc(-c2ccccc2)c(N2c3ccc(-c4ccccc4)cc3B3c4cc(-c5ccccc5)ccc4N(c4c(-c5ccc(-n6c7ccccc7c7ccccc76)cc5)cc(C(C)(C)C)cc4-c4ccc(-n5c6ccccc6c6ccccc65)cc4)c4cc(C(C)(C)C)cc2c43)c(-c2ccccc2)c1]

### Synthesis of Intermediate 85-1

N-(3-bromo-5-(tert-butyl)phenyl)-5′-(tert-butyl)-[1,1′:3′,1″-terphenyl]-2′-amine (1 eq), 5′-(tert-butyl)-4,4″-di(9H-carbazol-9-yl)-[1,1′:3′,1″-terphenyl]-2′-amine (1.1 eq), tris(dibenzylideneacetone)dipalladium(0) (0.05 eq), tri-tert-butylphosphine (0.1 eq), and sodium tert-butoxide (3 eq) were dissolved in toluene and then stirred at about 100° C. for about 12 hours. After cooling, the resultant was diluted with ethyl acetate and washed three times with water, then an organic layer obtained by separating was dried over MgSO₄ and then dried under reduced pressure. The resultant was purified by column chromatography with MC and n-Hexane to obtain Intermediate 85-1 (yield of 81%).

### Synthesis of Intermediate 85-2

Intermediate 85-1 (1 eq), 4-iodo-1,1′-biphenyl (4 eq), tris(dibenzylideneacetone)dipalladium(0) (0.15 eq), tri-tert-butylphosphine (0.3 eq), and sodium tert-butoxide (5 eq) were dissolved in o-xylene and then stirred at about 160° C. for about 60 hours. After cooling, the resultant was diluted with ethyl acetate and washed three times with water, then an organic layer obtained by separating was dried over MgSO₄ and then dried under reduced pressure. The resultant was purified by column chromatography with MC and n-Hexane to obtain Intermediate 85-2 (yield of 39%).

### Synthesis of Compound 85

Intermediate 85-2 (1 eq) was dissolved in ortho dichlorobenzene and then cooled to about 0° C., and then BBr₃ (3 eq) was slowly added in nitrogen atmosphere. After the dropwise addition was completed, the temperature was raised to about 180° C. and stirred for about 24 hours. After cooling, triethylamine was slowly added to the flask containing the reactant to quench the reaction. Then, ethyl alcohol was added to the reactant, and the resulting product was precipitated, filtered to obtain solids. The obtained solids were purified by column chromatography with MC and n-Hexane, and then recrystallized using toluene and acetone to obtain Compound 85 (yield of 11%).

### (7) Synthesis of Compound 86

Polycyclic Compound 86 according to an example may be synthesized by, for example, Reaction Scheme 7.

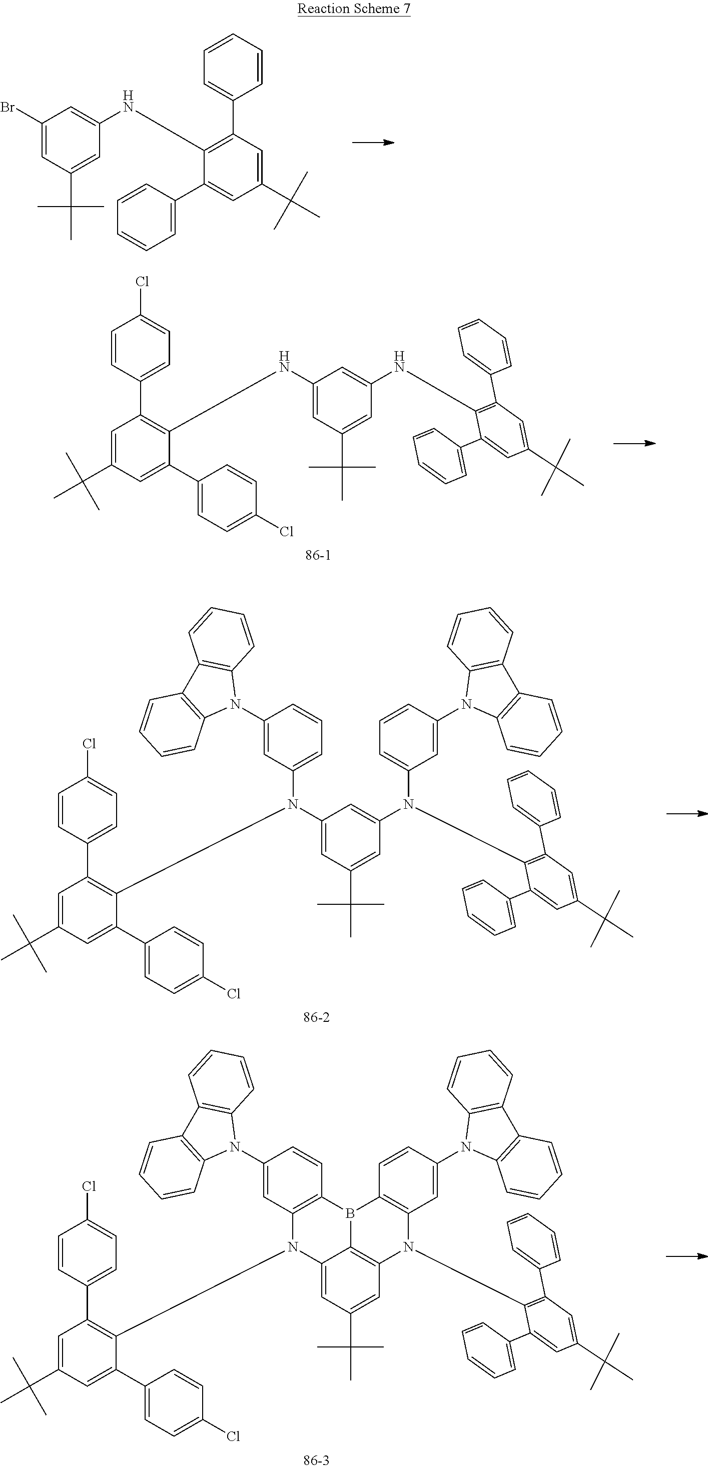

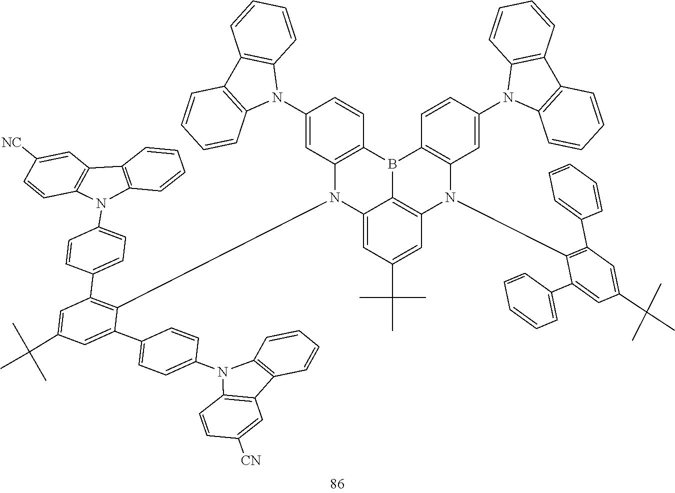 [SMILES: CC(C)(C)c1cc(-c2ccccc2)c(N2c3cc(-n4c5ccccc5c5ccccc54)ccc3B3c4ccc(-n5c6ccccc6c6ccccc65)cc4N(c4c(-c5ccc(-n6c7ccccc7c7cc(C#N)ccc76)cc5)cc(C(C)(C)C)cc4-c4ccc(-n5c6ccccc6c6cc(C#N)ccc65)cc4)c4cc(C(C)(C)C)cc2c43)c(-c2ccccc2)c1]

### Synthesis of Intermediate 86-1

N-(3-bromo-5-(tert-butyl)phenyl)-5′-(tert-butyl)-[1,1′:3′,1″-terphenyl]-2′-amine (1 eq), 5′-(tert-butyl)-4,4″-dichloro-[1,1′:3′,1″-terphenyl]-2′-amine (1.1 eq), tris(dibenzylideneacetone)dipalladium(0) (0.05 eq), tri-tert-butylphosphine (0.1 eq), and sodium tert-butoxide (3 eq) were dissolved in toluene and then stirred at about 80° C. for about 6 hours. After cooling, the resultant was diluted with ethyl acetate and washed three times with water, then an organic layer obtained by separating was dried over MgSO₄ and then dried under reduced pressure. The resultant was purified by column chromatography with MC and n-Hexane to obtain Intermediate 86-1 (yield of 58%).

### Synthesis of Intermediate 86-2

Intermediate 86-1 (1 eq), 9-(3-iodophenyl)-9H-carbazole (4 eq), tris(dibenzylideneacetone)dipalladium(0) (0.15 eq), tri-tert-butylphosphine (0.3 eq), and sodium tert-butoxide (5 eq) were dissolved in o-xylene and then stirred at about 140° C. for about 36 hours. After cooling, the resultant was diluted with ethyl acetate and washed three times with water, then an organic layer obtained by separating was dried over MgSO₄ and then dried under reduced pressure. The resultant was purified by column chromatography with MC and n-Hexane to obtain Intermediate 86-2 (yield of 38%).

### Synthesis of Intermediate 86-3

Intermediate 86-2 (1 eq) was dissolved in ortho dichlorobenzene and then cooled to about 0° C., and then BBr₃ (3 eq) was slowly added in nitrogen atmosphere. After the dropwise addition was completed, the temperature was raised to about 180° C. and stirred for about 24 hours. After cooling, triethylamine was slowly added to the flask containing the reactant to quench the reaction. Then, ethyl alcohol was added to the reactant, and the resulting product was precipitated, filtered to obtain solids. The obtained solids were purified by column chromatography with MC and n-Hexane, and then recrystallized using toluene and acetone to obtain Intermediate 86-3 (yield of 10%).

### Synthesis of Compound 86

Intermediate 86-3 (1 eq), 9H-carbazole-3-carbonitrile (3.5 eq), tris(dibenzylideneacetone)dipalladium(0) (0.15 eq), tri-tert-butylphosphine (0.3 eq), and sodium tert-butoxide (6 eq) was dissolved in o-xylene and then stirred at about 150° C. for about 24 hours. After cooling, the resultant was diluted with ethyl acetate and washed three times with water, then an organic layer obtained by separating was dried over MgSO₄ and then dried under reduced pressure. The resultant was purified by column chromatography with MC and n-Hexane to obtain Compound 86 (yield of 54%).

### 2. Evaluation of Compound Characteristics

Characteristics of the polycyclic compounds embodiments and comparative embodiments were evaluated through a simulation and the evaluation results are listed in Table 1. The evaluation results of characteristics of Compounds 1 and 85, which are the polycyclic compounds according to one or more embodiments, and Compound C1 according to a comparative embodiment are shown in Table 1. In Table 1, HOMO represents a highest occupied molecular orbital (HOMO) energy level, and LUMO represents a lowest unoccupied molecular orbital (HOMO) energy level. S1(nm) represents an emission wavelength in a lowest singlet state, and T1(nm) represents an emission wavelength in a lowest triplet state. F 1 represents oscillator strength (f). ΔEST represents an absolute value of an energy level difference between the S1 and T1 states.

### Compound 1, Compound 85, and Comparative Example Compound C1

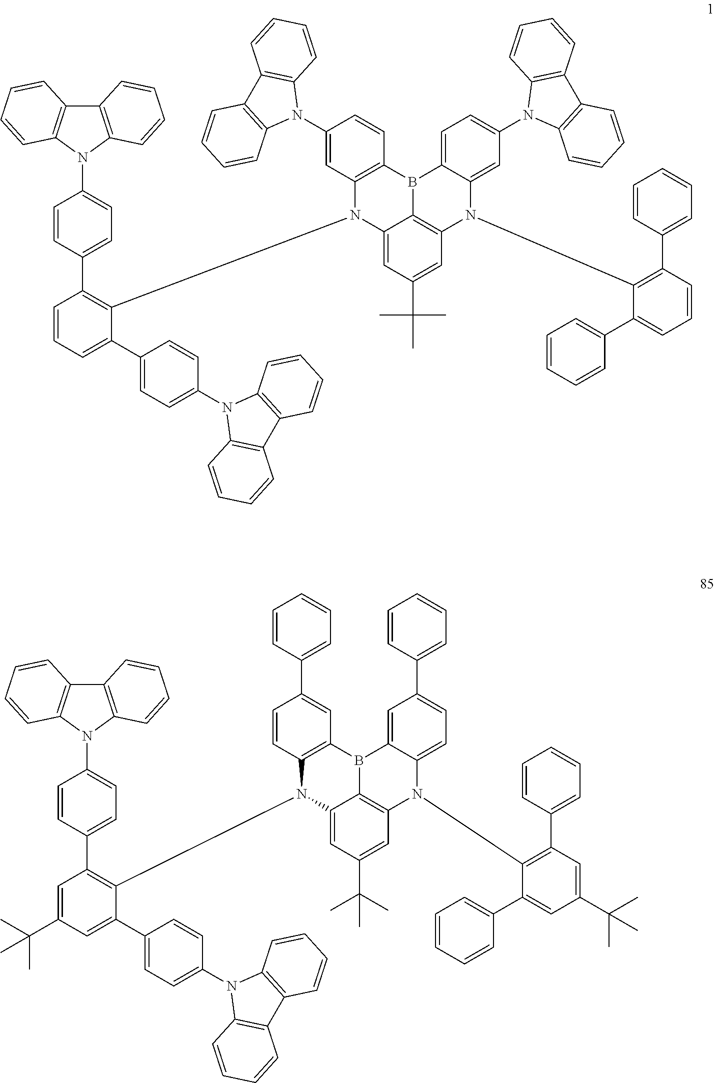

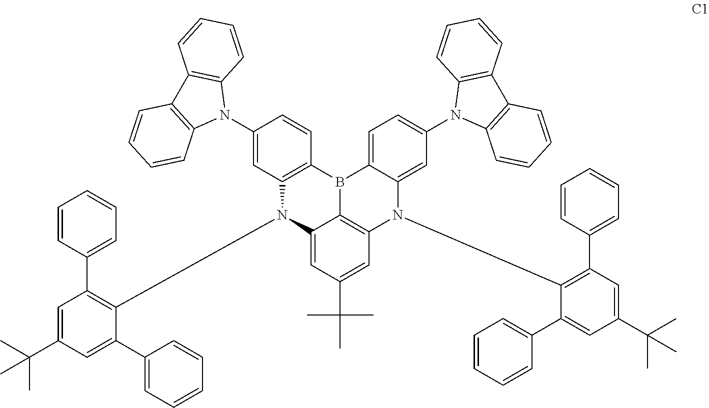

TABLE 1

| | HOMO | LUMO | S1(nm) | F1 | T1(nm) | ΔE_{ST} |
|---|---|---|---|---|---|---|
| Compound 1 | −5.36 | −1.82 | 416.7 | 0.27 | 479.9 | 0.392 |
| Compound 85 | −5.01 | −1.5 | 419.4 | 0.174 | 485 | 2.5567 |
| Comparative | −4.9 | −1.39 | 419.1 | 0.203 | 485.6 | 0.405 |
| Example | | | | | | |
| Compound C1 | | | | | | |

Referring to Table 1, it may be seen that Compound 1 exhibits a deeper HOMO energy level than Comparative Example Compound C1. In one or more embodiments, it may be seen that Comparative Example Compound C1, Compound 1, and Compound 85 show similar S1(nm) and T1(nm) values.

From the results in Table 1, in Compounds 1 and 85 corresponding to the polycyclic compound according to one or more embodiments, compared to Comparative Example Compound C1, a carbazole group is connected to a biphenyl derivative (that is, a terphenyl group) linked to a five-membered fused core, which has an effect in that a HOMO energy level become deeper, and thus an increase in a T1 exciton concentration due to a TAR phenomenon may be inhibited or reduced. Therefore, efficiency and lifespan of the light-emitting element are expected to be improved.

For example, the evaluation of polycyclic compounds, including Compounds and 85 (embodiments) and Compound C1 (comparative embodiment), revealed that Compound 1 has a deeper HOMO energy level compared to Compound C1, while all compounds showed similar S1 and T1 values. The deeper HOMO energy level in Compounds 1 and 85, due to the connection of a carbazole group to a biphenyl derivative linked to a five-membered fused core, helps inhibit an increase in T1 exciton concentration due to the TAR phenomenon. This results in expected improvements in the efficiency and lifespan of the light-emitting element.

### 3. Manufacture and Evaluation of Light-Emitting Element

### (1) Manufacture of Light-Emitting Element

A light-emitting element containing a polycyclic compound according to one or more embodiments, or Comparative Example Compound was manufactured by the following method. The light-emitting elements according to Example 1 to 7 were manufactured respectively using the polycyclic compounds according to one or more embodiments as a dopant material in the emission layer. The light-emitting elements according to Comparative Examples were manufactured using Comparative Example Compounds C1 to C4 as a dopant material in the emission layer.

A glass substrate (a product of Corning Inc.), on which an ITO electrode of about 15 ohm per square centimeter (Q/cm²) (1200 angstrom (Å) was formed as a first electrode, was cut to a size of about 50 millimeter (mm)×50 mm×0.7 mm, cleansed by ultrasonic waves using isopropyl alcohol and pure water for about five minutes each, then and irradiated with ultraviolet rays for about 30 minutes and exposed to ozone to be cleansed. Then, the glass substrate was mounted on a vacuum deposition apparatus.

Compound H-1-1 doped with 1,4,5,8,9,11-Hexaazatriphenylenehexacarbonitrile (HAT-CN) was deposited on the first electrode to form a hole injection layer having a thickness of about 100 Å, and then Compound H-1-1 was vacuum deposited on the hole injection layer to form a hole transport layer having a thickness of about 600 Å. An electron blocking layer having a thickness of about 50 Å was formed on the hole transport layer using a compound HT33.

Thereafter, a host mixture in which a second compound and a third compound according to one or more embodiments are mixed, a fourth compound, and Example Compound or Comparative Example Compound as a First compound were co-deposited in a weight ratio of about 86.6:13:0.4 to form an emission layer having a thickness of 300 Å. As the host compound, Compound HT33 which is the hole transporting host (HT host) and Compound ETH66 which is an electron transporting host (ET host) were provided in a weight ratio of about 65:35. As the fourth compound, Compound AD-41 was used. As the dopant material, Example Compound or Comparative Example was used.

Compound ETH2 was vacuum deposited on the emission layer to form a hole blocking layer having a thickness of about 50 Å. Thereafter, Compound ETH2 and 8-Quinolinolato lithium (Liq) were concurrently (e.g., simultaneously) deposited on the hole blocking layer in a mixture of a weight ratio of about 5:5 to form an electron transport layer having a thickness of about 310 Å. LiF was vacuum deposited on the electron transport layer to form an electron injection layer having a thickness of about 15 Å. Then, Al was deposited under a condition of about 1000 Å to form a second electrode, thereby completing a manufacture of a light-emitting element.

The compounds used in the manufacture of the light-emitting elements are as follows.

### Common Material Used in Manufacture of Light-Emitting Element

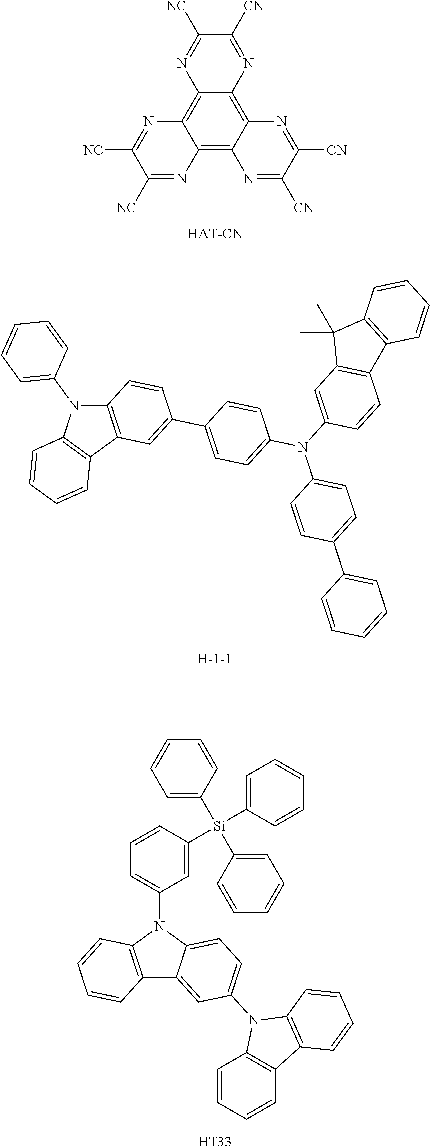 [SMILES: N#Cc1nc2c3nc(C#N)c(C#N)nc3c3nc(C#N)c(C#N)nc3c2nc1C#N ; CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc([Si](c2ccccc2)(c2ccccc2)c2cccc(-n3c4ccccc4c4cc(-n5c6ccccc6c6ccccc65)ccc43)c2)cc1 ; "HT33"]

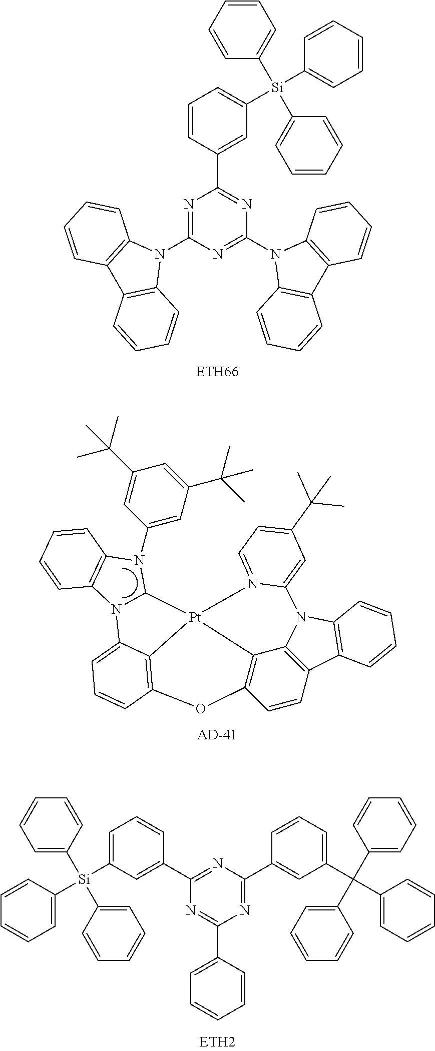

### Dopant Material According to Examples and Comparative Examples Used in Manufacture of Light-Emitting Element

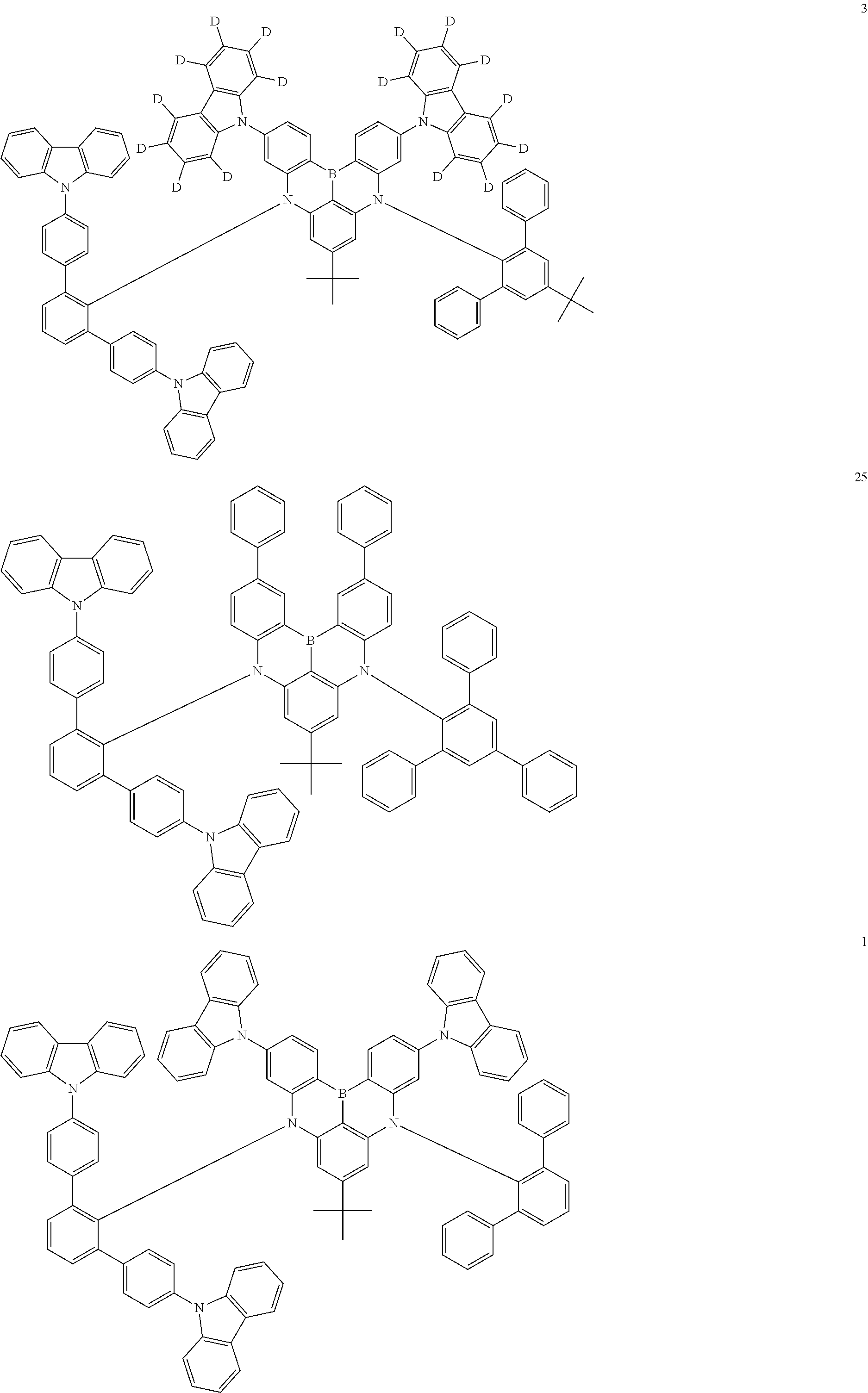

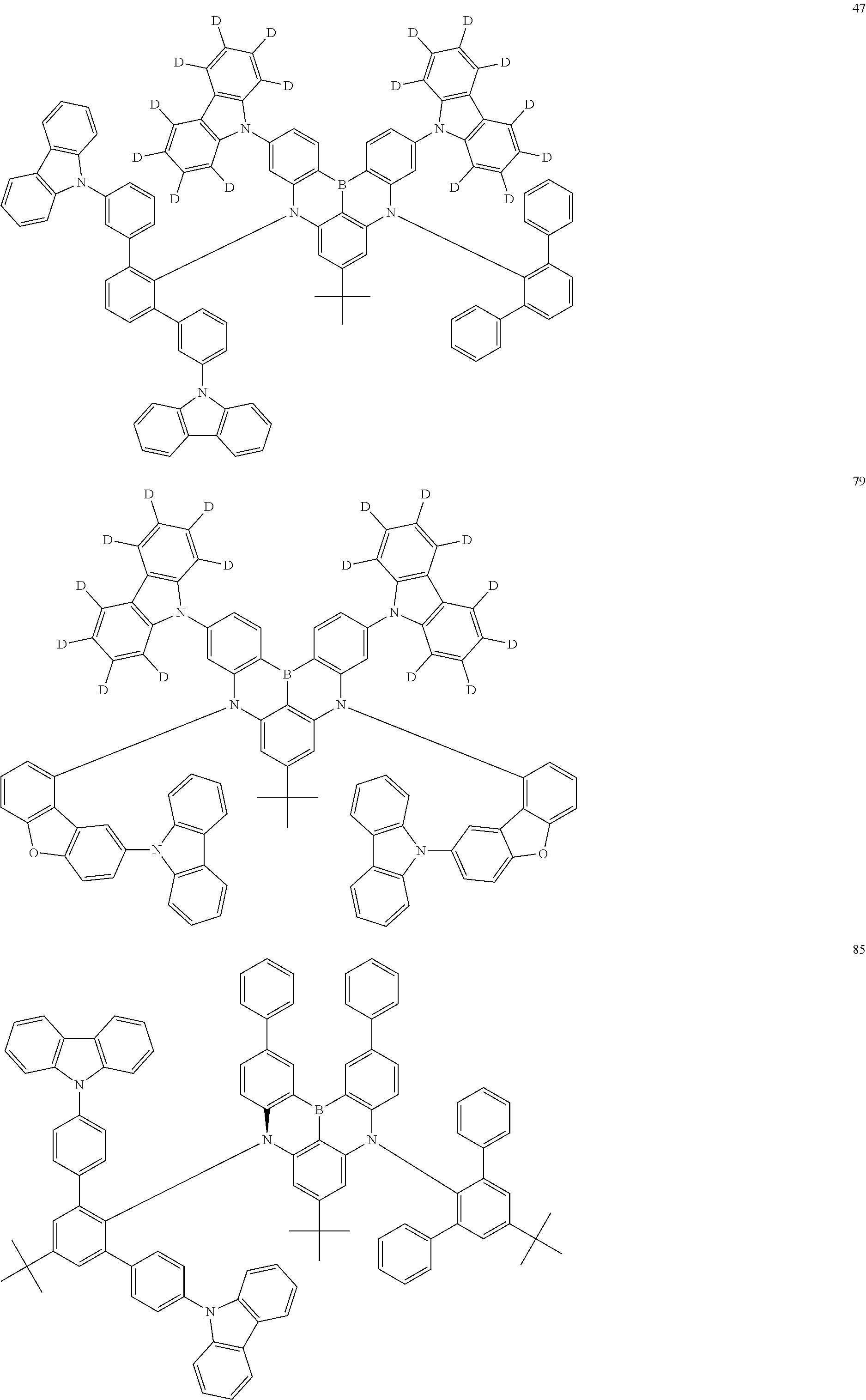

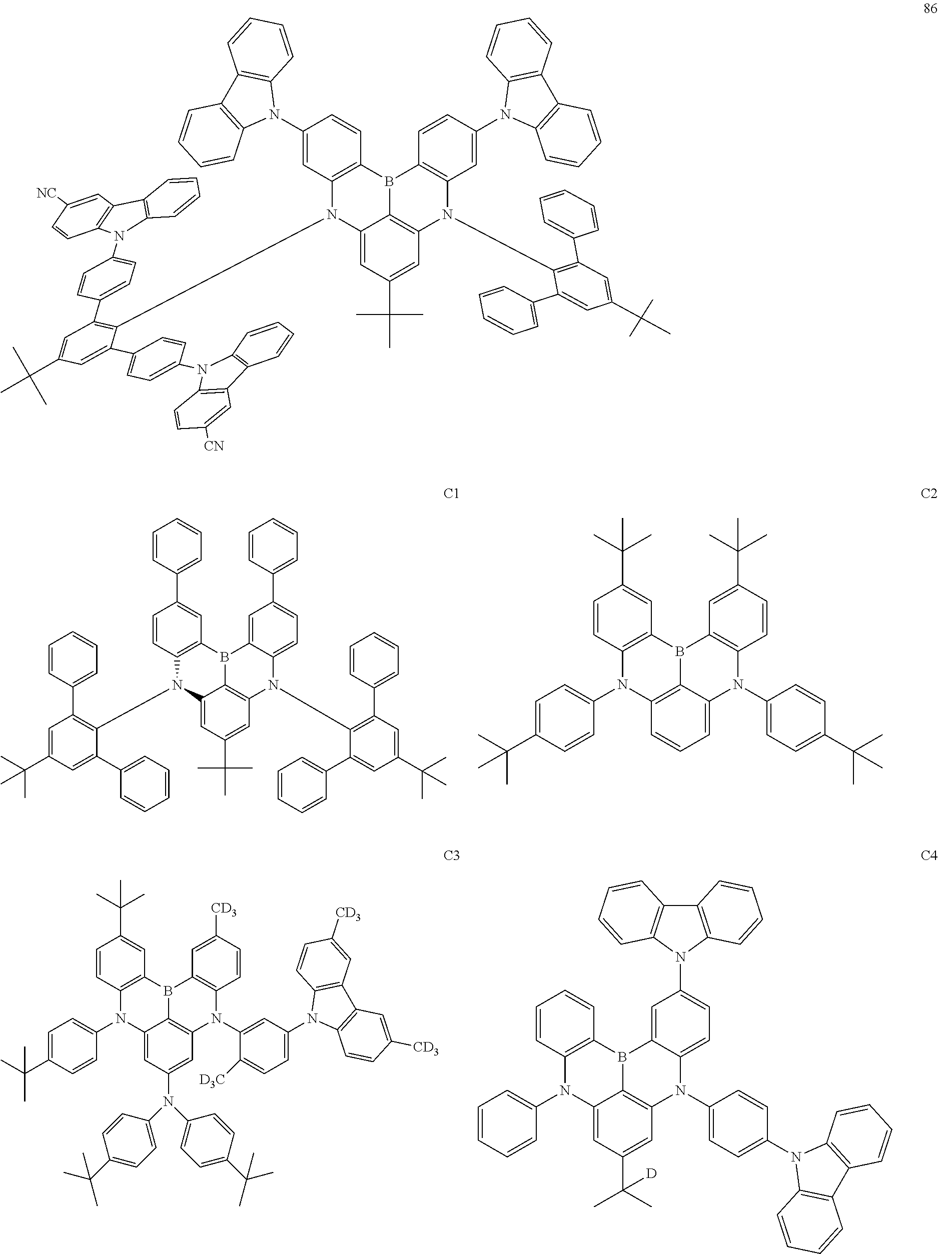

### 4. Evaluation of Light-Emitting Element Characteristics

Each of the light-emitting elements was evaluated and the evaluation result is listed in Table 2. Measurements of driving voltage (V) at a current density of 10 (milliampere per square centimeter (mA/cm²)), luminous efficiency (candela per Ampere per year ((cd/A/y)), and emission wavelength (nanometer (nm)) were performed using Keithley MU 236 and a PR 650 luminance meter for the light-emitting elements according to Examples and Comparative Examples. Time taken for the luminance to decrease from an initial luminance to 95% of the initial luminance was measure and a relative lifespan value of the light-emitting element was calculated with respect to the lifespan of the light-emitting element according to Comparative Example 1, and Lifespan ratio in Table 2 represents the calculated relative lifespan value.

TABLE 2

| | Host Compound | | | | | | |
|---|---|---|---|---|---|---|---|
| | (2nd | | | | | | |
| | Compound:3rd | | | Driving | Luminous | Emission | Lifespan |
| | Compound = | 4th | 1st | voltage | efficiency | wavelength | ratio |
| | 65:35) | Compound | Compound | (V) | (cd/A) | (nm) | (T95) |
| Example 1 | HT33/ETH66 | AD-41 | 3 | 4.2 | 26.2 | 460 | 7.1 |
| Example 2 | HT33/ETH66 | AD-41 | 25 | 4.3 | 25.7 | 462 | 6.5 |
| Example 3 | HT33/ETH66 | AD-41 | 47 | 4.3 | 26.0 | 461 | 6.8 |
| Example 4 | HT33/ETH66 | AD-41 | 79 | 4.1 | 26.1 | 461 | 6.6 |
| Example 5 | HT33/ETH66 | AD-41 | 1 | 4.2 | 26.3 | 460 | 6.9 |
| Example 6 | HT33/ETH66 | AD-41 | 85 | 4.4 | 25.1 | 462 | 6.2 |
| Example 7 | HT33/ETH66 | AD-41 | 86 | 4.1 | 26.4 | 459 | 6.5 |
| Comparative | HT33/ETH66 | AD-41 | C2 | 5.4 | 18.7 | 465 | 1 |
| Example 1 | | | | | | | |
| Comparative | HT33/ETH66 | AD-41 | C1 | 4.5 | 24.7 | 463 | 5.7 |
| Example 2 | | | | | | | |
| Comparative | HT33/ETH66 | AD-41 | C3 | 5.2 | 20.5 | 458 | 1.3 |
| Example 3 | | | | | | | |
| Comparative | HT33/ETH66 | AD-41 | C4 | 4.8 | 21.6 | 466 | 2.3 |
| Example 4 | | | | | | | |

Referring to the results in Table 2, it may be seen that the light-emitting elements according to Examples exhibit lower driving voltage characteristics than the light-emitting elements according to Comparative Examples. The light-emitting elements according to Examples exhibit similar emission wavelength characteristics to the light-emitting elements according to Comparative Examples containing Comparative Example Compounds each having a similar core structure to the Example Compounds.

The light-emitting elements according to Examples exhibit high luminous efficiency and excellent or suitable lifespan characteristics compared to the light-emitting elements according to Comparative Examples. For example, because the light-emitting elements according to Examples contains the polycyclic compound according to one or more embodiments having improved material stability in the emission layer, deterioration of the polycyclic compound in the emission layer decreases and thus the luminous efficiency and element lifespan characteristics in the emission layer appears to have been improved.

For example, in the light-emitting elements according to Comparative Example Compounds C3 and C4, a carbazole group, to which a phenylene linker is linked, is connected at a meta or para position to have a shape moving away from the five-membered fused core. Therefore, in Comparative Example Compounds C3 and C4, the carbazole group may not serve as a protective group for substantially protecting the core. Rather, because planarity of carbazole causes molecular packing, interaction with around (e.g., surrounding) molecules increases, resulting in a negative impact on the lifespan of the light emitting element. In particular, in Comparative Example Compound C3, an amine group, which is a strong donor, is substituted to have a HOMO level, thereby causing a severe hole trap, and thus the light-emitting element has a weakened driving voltage and lifetime characteristics.

In the light-emitting element according to one or more embodiments, the emission layer may contain the polycyclic compound according to one or more embodiments. The polycyclic compound according to one or more embodiments includes, as a core structure, a five-membered fused ring containing two nitrogen atoms and one boron as ring-forming atoms, and may contain a biphenyl derivative bonded to the five-membered fused core and a carbazole moiety bonded to the biphenyl derivative. Therefore, the polycyclic compound according to one or more embodiments may have a structure in which the five-membered fused core is protected. Therefore, in the polycyclic compound according to one or more embodiments, because a multi-resonant core portion where luminescence-related transitions occur is protected, an intermolecular interaction capable of causing side effect other than the emission is suppressed or reduced, and thus material stability may increase. The light-emitting element containing the polycyclic compound in the emission layer may exhibit high efficiency and long lifespan characteristics.

For example, the evaluation of light-emitting elements, as shown in Table 2, included measurements of driving voltage, luminous efficiency, emission wavelength, and lifespan ratio. The results indicate that the light-emitting elements in the examples exhibit lower driving voltage and similar emission wavelength characteristics compared to the comparative examples. Additionally, the examples demonstrate higher luminous efficiency and better lifespan characteristics due to the improved material stability of the polycyclic compounds in the emission layer. Specifically, the polycyclic compounds in the examples have a structure that protects the five-membered fused core, reducing detrimental intermolecular interactions and enhancing material stability. Consequently, the light-emitting elements in the examples are expected to have higher efficiency and longer lifespan compared to those in the comparative examples.

The light-emitting element according to one or more embodiments contains the polycyclic compound according to one or more embodiments in the emission layer, and thus may exhibit characteristic of high efficiency and long lifespan.

The polycyclic compound according to one or more embodiments may contribute to improvements in luminous efficiency and long lifespan of the light-emitting element.

The display device according to one or more embodiments may exhibit excellent or suitable display quality.

The display device, electronic device, a device of manufacturing thereof, and/or any other relevant devices or components according to embodiments of the present disclosure described herein may be implemented utilizing any suitable hardware, firmware (e.g., an application-specific integrated circuit), software, or a combination of software, firmware, and hardware. For example, the one or more suitable components of the display and/or electronic device may be formed on one integrated circuit (IC) chip or on separate IC chips. Further, the one or more suitable components of display and/or electronic apparatus and/or device may be implemented on a flexible printed circuit film, a tape carrier package (TC P), a printed circuit board (PCB), or formed on one substrate. Further, the one or more suitable components of the display and/or electronic device may be a process or thread, running on one or more processors, in one or more computing devices, executing computer program instructions and interacting with other system components for performing the one or more suitable functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of one or more suitable computing devices may be combined or integrated into a single computing device, or the functionality of a particular computing device may be distributed across one or more other computing devices without departing from the scope of the embodiments of the present disclosure.

In the context of the present application and unless otherwise defined, the terms “use,” “using,” and “used” may be considered synonymous with the terms “utilize,” “utilizing,” and “utilized,” respectively.

A person of ordinary skill in the art, in view of the present disclosure in its entirety, would appreciate that each suitable feature of the one or more suitable embodiments of the present disclosure may be combined or combined with each other, partially or entirely, and may be technically interlocked and operated in one or more suitable ways, and each embodiment may be implemented independently of each other or in conjunction with each other in any suitable manner unless otherwise stated or implied.

Hitherto, although one or more embodiments of the present disclosure have been described, it is understood that the present disclosure should not be limited to these embodiments but one or more suitable changes and modifications may be made by one ordinary skilled in the art within the spirit and scope of the present disclosure as hereinafter claimed.

Therefore, the technical scope of the disclosure is not intended to be limited to the contents set forth in the detailed description of the specification, but is intended to be defined by the appended claims, and equivalents thereof.

What is claimed is:

1. A light-emitting element comprising:
a first electrode;
a second electrode on the first electrode; and
an emission layer between the first electrode and the second electrode and comprising a first compound represented by Formula 1: 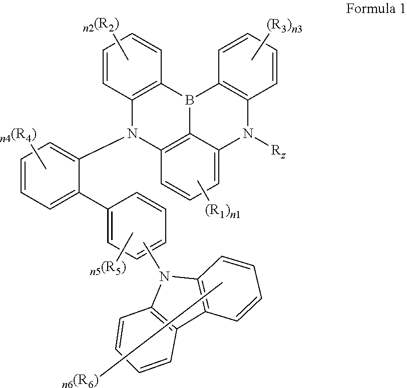
wherein, in Formula 1,
R₁ to R₃, R₆ and R_{z} are each independently a hydrogen atom, a deuterium atom, a cyano group, a substituted or unsubstituted alkyl group having 1 to 30 carbons, a substituted or unsubstituted aryl group having 6 to 60 ring-forming carbons, or a substituted or unsubstituted heteroaryl group having 2 to 60 ring-forming carbons,
R₄ and R₅ are each independently a hydrogen atom, a deuterium atom, a cyano group, a hydroxy group, a substituted or unsubstituted thio group, a substituted or unsubstituted oxy group, a substituted or unsubstituted amine group, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, or a substituted or unsubstituted heteroaryl group having 2 to 30 ring-forming carbons, and/or are each bonded to an adjacent group to form a ring,
n1 is an integer of 0 to 3,
n2 to n5 are each independently an integer of 0 to 4, and
n6 is an integer of 0 to 8.

2. The light-emitting element of claim 1, wherein the first compound is represented by Formula 2: 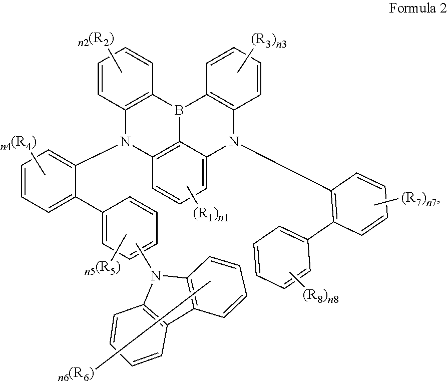
and
wherein, in Formula 2,
R₇ and R₈ are each independently a hydrogen atom, a deuterium atom, a cyano group, a hydroxy group, a substituted or unsubstituted thio group, a substituted or unsubstituted oxy group, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, or a substituted or unsubstituted heteroaryl group having 2 to 30 ring-forming carbons, and/or are each bonded to an adjacent group to form a ring,
n7 is an integer of 0 to 4,
n8 is an integer of 0 to 5, and
R₁ to R₆, and n1 to n6 are as defined in Formula 1.

3. The light-emitting element of claim 1, wherein the first compound is represented by Formula 2-A or Formula 2-B: 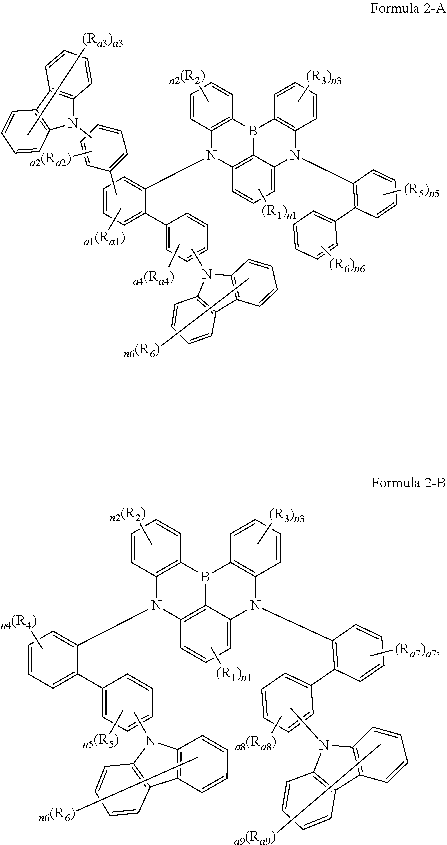
and
wherein, in Formula 2-A and Formula 2-B,
Rₐ₁ to Rₐ₆, and Rₐ₉ are each independently a hydrogen atom, a deuterium atom, a substituted or unsubstituted alkyl group having 1 to 30 carbons, a substituted or unsubstituted aryl group having 6 to 30 ring-forming carbons, a substituted or unsubstituted heteroaryl group having 2 to 30 ring-forming carbons, or a substituted or unsubstituted alkyl group having 1 to 30 carbons,
Rₐ₇ and Rₐ₈ are each independently a hydrogen atom, a deuterium atom, a cyano group, a hydroxy group, a substituted or unsubstituted thio group, a substituted or unsubstituted oxy group, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, or a substituted or unsubstituted heteroaryl group having 2 to 30 ring-forming carbons, and/or are each bonded to an adjacent group to form a ring,
a1 is an integer of 0 to 3,
a2, a4, a5, a7 and a8 are each independently an integer of 0 to 4,
a3 and a9 are each independently an integer of 0 to 8,
a6 is an integer of 0 to 5, and
R₁ to R₆ and n1 to n6 are as defined in Formula 1.

4. The light-emitting element of claim 1, wherein the first compound is represented by Formula 3-1 or Formula 3-2: 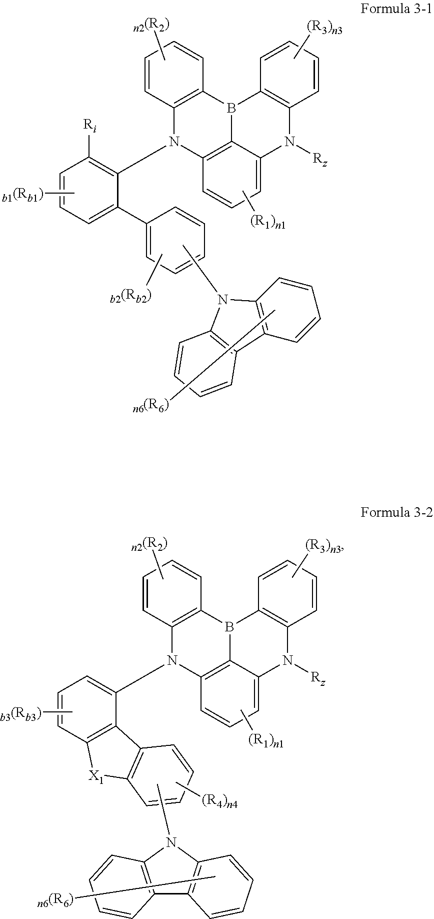
and
wherein, in Formula 3-2,
X₁ is O, S, NRₓ₁ or CRₓ₂Rₓ₃, and
Rₓ₁ to Rₓ₃ are each independently a hydrogen atom, a deuterium atom, a substituted or unsubstituted alkyl group having 1 to 10 carbons, or a substituted or unsubstituted aryl group having 6 to 15 ring-forming carbons, and
in Formula 3-1 and Formula 3-2,
Rᵢ, and R_{b1} to R_{b4} are each independently a hydrogen atom, a deuterium atom, a substituted or unsubstituted alkyl group having 1 to 30 carbons, or a substituted or unsubstituted aryl group having 6 to 30 ring-forming carbons,
b1, b3 and b4 are each independently an integer of 0 to 3,
b2 is an integer of 0 to 4, and
R₁ to R₃, R₆, R_{z}, n1 to n3, and n6 are as defined in Formula 1.

5. The light-emitting element of claim 4, wherein the first compound is represented by Formula 3-1-A: 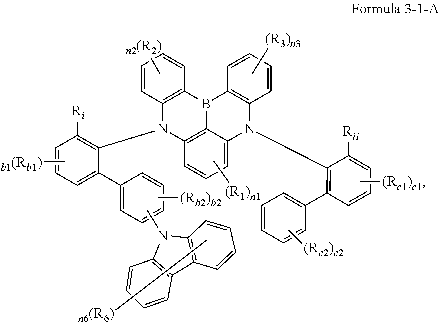
and
wherein, in Formula 3-1-A,
Rᵢᵢ, R_{c1}, and R_{c2} are each independently a hydrogen atom, a deuterium atom, a substituted or unsubstituted alkyl group having 1 to 30 carbons, a substituted or unsubstituted aryl group having 6 to 30 ring-forming carbons, or a substituted or unsubstituted heteroaryl group having 2 to 30 ring-forming carbons,
c1 is an integer of 0 to 3,
c2 is an integer of 0 to 5, and
R₁ to R₃, R₆, Rᵢ, R_{b1}, R_{b2}, n1 to n3, n6, b1 and b2 are as defined in Formula 1 and Formula 3-1.

6. The light-emitting element of claim 4, wherein the first compound is represented by Formula 3-2-A: 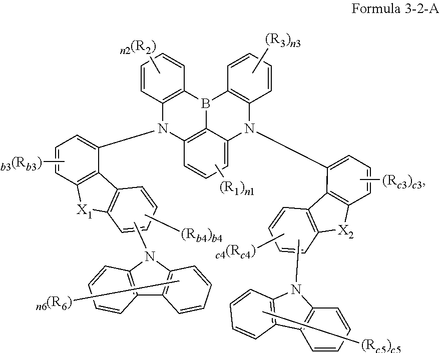
and
wherein, in Formula 3-2-A,
X₂ is O, S, NRₓ₄, or CRₓ₅Rₓ₆,
Rₓ₄ to Rₓ₆ are each independently a hydrogen atom, a deuterium atom, a substituted or unsubstituted alkyl group having 1 to 10 carbons, or a substituted or unsubstituted aryl group having 6 to 15 ring-forming carbons,
R_{c3} to R_{c5} are each independently a hydrogen atom, a deuterium atom, a substituted or unsubstituted alkyl group having 1 to 30 carbons, or a substituted or unsubstituted aryl group having 6 to 30 ring-forming carbons,
c3 and c4 are each independently an integer of 0 to 3,
c5 is an integer of 0 to 8, and
X₁, R₁ to R₃, R₆, R_{b3}, R₄, n1 to n3, n6, b3, and b4 are as defined in Formula 1 and Formula 3-2.

7. The light-emitting element of claim 1, wherein the first compound is represented by Formula 4: 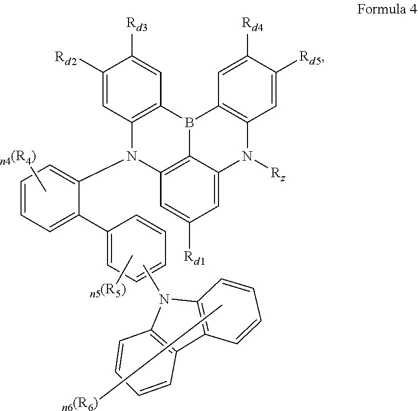
and
wherein, in Formula 4,
R_{d1} is a substituted or unsubstituted alkyl group having 1 to 10 carbons, a substituted or unsubstituted aryl group having 6 to 30 ring-forming carbons, or a substituted or unsubstituted heteroaryl group having 2 to 30 ring-forming carbons, at least one selected from among R_{d2} and R_{d3}, and at least one selected from among R_{d4} and R_{d5} are each independently a substituted or unsubstituted aryl group having 6 to 30 ring-forming carbons, or a substituted or unsubstituted heteroaryl group having 2 to 30 ring-forming carbons, and any remaining selected from among R_{d2}, R_{d3}, R_{d4}, and R_{d5} are each independently a hydrogen atom, or a deuterium atom, and
R_{z}, R₄ to R₆, and n4 to n6 are as defined in Formula 1.

8. The light-emitting element of claim 1, wherein at least one selected from among hydrogen atoms of the first compound is substituted with a deuterium atom.

9. The light-emitting element of claim 1, wherein the emission layer is configured to emit blue light.

10. The light-emitting element of claim 1, wherein the emission layer further comprises at least one of a second compound represented by Formula HT-1, a third compound represented by Formula ET-1, or a fourth compound represented by Formula D-1: 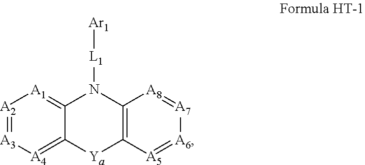
wherein, in Formula HT-1,
A₁ to A₈ are each independently N, or CR₅₁,
L₁ is a direct linkage, a substituted or unsubstituted arylene group having 6 to 30 ring-forming carbons, or a substituted or unsubstituted heteroarylene group having 2 to 30 ring-forming carbons,
Yₐ is a direct linkage, CR₅₂R₅₃, or SiR₅₄R₅₅,
Ar₁ is a substituted or unsubstituted aryl group having 6 to 30 ring-forming carbons, or a substituted or unsubstituted heteroaryl group having 2 to 30 ring-forming carbons,
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted alkyl group having 1 to 20 carbons, a substituted or unsubstituted alkenyl group having 2 to 20 carbons, a substituted or unsubstituted aryl group having 6 to 60 ring-forming carbons, or a substituted or unsubstituted heteroaryl group having 2 to 60 ring-forming carbons, and/or are each bonded to an adjacent group to form a ring: 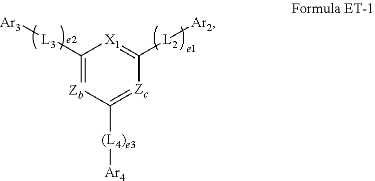
wherein, in Formula ET-1,
at least one selected from among Zₐ to Z_{c} is N, and any remaining are CR₅₆,
R₅₆ is a hydrogen atom, a deuterium atom, a substituted or unsubstituted alkyl group having 1 to 20 carbons, a substituted or unsubstituted aryl group having 6 to 60 ring-forming carbons, or a substituted or unsubstituted heteroaryl group having 2 to 60 ring-forming carbons,
e1 to e3 are each independently an integer of 0 to 10,
Ar₂ to Ar₄ are each independently a hydrogen atom, a deuterium atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons, and
L₂ to L₄ are each independently a direct linkage, a substituted or unsubstituted arylene group having 6 to 30 ring-forming carbons, or a substituted or unsubstituted heteroaryl group having 2 to 30 ring-forming carbons: 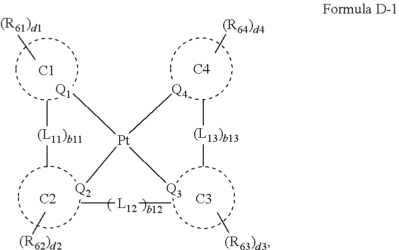
and
wherein in Formula D-1,
Q₁ to Q₄ are each independently C or N,
C1 to C4 are each independently a substituted or unsubstituted hydrocarbon ring having 5 to 30 ring-forming carbons, or a substituted or unsubstituted heterocycle having 2 to 30 ring-forming carbons,
L₁₁ to L₁₃ are each independently a direct linkage, *—O—* , *—S—* , 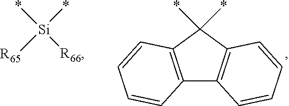
a substituted or unsubstituted divalent alkyl group having 1 to 20 carbons, a substituted or unsubstituted arylene group having 6 to 30 ring-forming carbons, or a substituted or unsubstituted heteroarylene group having 2 to 30 ring-forming carbons,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbons, a substituted or unsubstituted alkenyl group having 2 to 20 ring-forming carbons, a substituted or unsubstituted aryl group having 6 to 60 ring-forming carbons, or a substituted or unsubstituted heteroaryl group having 2 to 60 ring-forming carbons, or bonded to an adjacent group to from a ring, and
d1 to d4 are each independently an integer of 0 to 4.

11. A polycyclic compound represented by Formula 1: 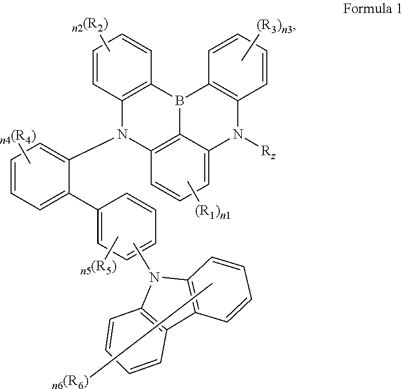
wherein, in Formula 1,
R₁ to R₃, R₆ and R_{z} are each independently a hydrogen atom, a deuterium atom, a cyano group, a substituted or unsubstituted alkyl group having 1 to 30 carbons, a substituted or unsubstituted aryl group having 6 to 60 ring-forming carbons, or a substituted or unsubstituted heteroaryl group having 2 to 60 ring-forming carbons, R₄ and R₅ are each independently a hydrogen atom, a deuterium atom, a cyano group, a hydroxy group, a substituted or unsubstituted thio group, a substituted or unsubstituted oxy group, a substituted or unsubstituted amine group, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, or a substituted or unsubstituted heteroaryl group having 2 to 30 ring-forming carbons, and/or are each bonded to an adjacent group to form a ring,
n1 is an integer of 0 to 3,
n2 to n5 are each independently an integer of 0 to 4, and
n6 is an integer of 0 to 8.

12. The polycyclic compound of claim 11, wherein the polycyclic compound is represented by Formula 2: 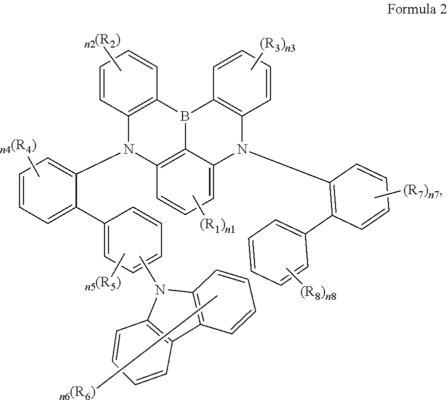
and
wherein, in Formula 2,
R₇ and R₈ are each independently a hydrogen atom, a deuterium atom, cyano, group, a hydroxy group, a substituted or unsubstituted thio group, a substituted or unsubstituted oxy group, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, or a substituted or unsubstituted heteroaryl group having 2 to 30 ring-forming carbons, and/or are each bonded to an adjacent group to form a ring,
n7 is an integer of 0 to 4,
n8 is an integer of 0 to 5, and
R₁ to R₆, and n1 to n6 are as defined in Formula 1.

13. The polycyclic compound of claim 11, wherein the polycyclic compound is represented by Formula 2-A or Formula 2-B: 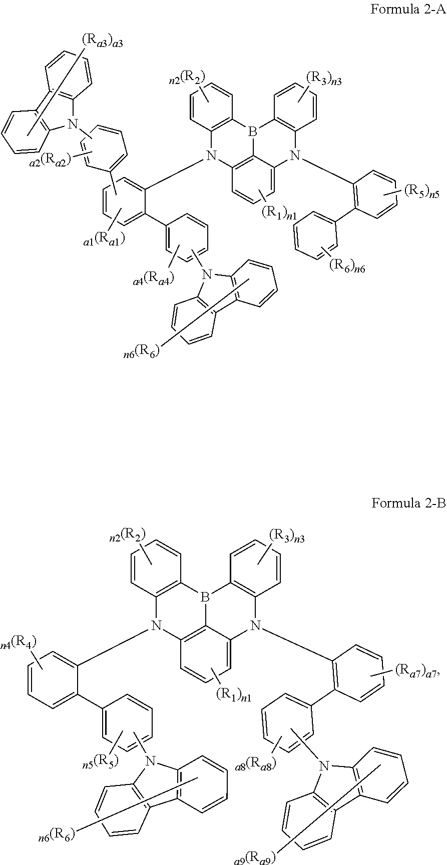
and
wherein, in Formula 2-A and Formula 2-B,
Rₐ₁ to Rₐ₆, and Rₐ₉ are each independently a hydrogen atom, a deuterium atom, a substituted or unsubstituted alkyl group having 1 to 30 carbons, a substituted or unsubstituted aryl group having 6 to 30 ring-forming carbons, or a substituted or unsubstituted heteroaryl group having 2 to 30 ring-forming carbons,
Rₐ₇ and Rₐ₈ are each independently a hydrogen atom, a deuterium atom, a cyano group, a hydroxy group, a substituted or unsubstituted thio group, a substituted or unsubstituted oxy group, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, or a substituted or unsubstituted heteroaryl group having 2 to 30 ring-forming carbons, and/or are each bonded to an adjacent group to form a ring,
a1 is an integer of 0 to 3,
a2, a4, a5, a7 and a8 are each independently
a3 and a9 are an integer of 0 to 8,
a6 is an integer of 0 to 5, and
R₁ to R₆ and n1 to n6 are as defined in Formula 1.

14. The polycyclic compound of claim 11, wherein the polycyclic compound is represented by Formula 3-1 or Formula 3-2: 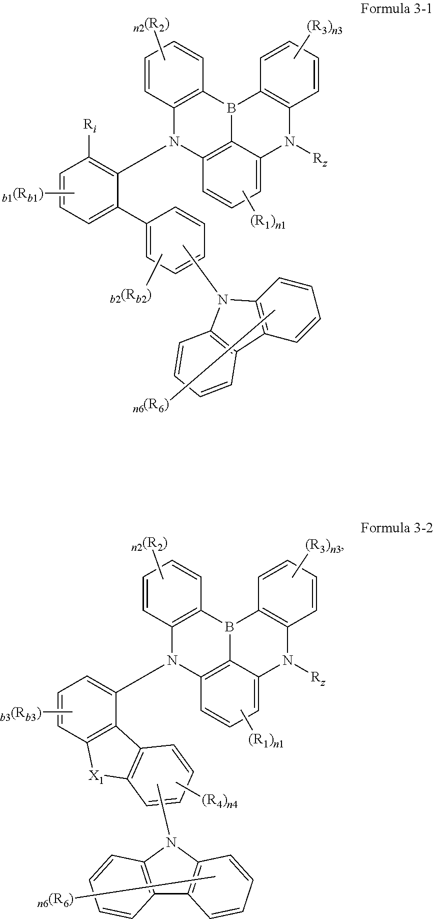
and
wherein, in Formula 3-2,
X₁ is O, S, NRₓ₁ or CRₓ₂Rₓ₃, and
Rₓ₁ to Rₓ₃ are each independently a hydrogen atom, a deuterium atom, a substituted or unsubstituted alkyl group having 1 to 10 carbons, or a substituted or unsubstituted aryl group having 6 to 15 ring-forming carbons,
in Formula 3-1 and Formula 3-2,
Rᵢ, and R_{b1} to R_{b4} are each independently a hydrogen atom, a deuterium atom, a substituted or unsubstituted alkyl group having 1 to 30 carbons, or a substituted or unsubstituted aryl group having 6 to 30 ring-forming carbons,
b1, b3 and b4 are each independently an integer of 0 to 3,
b2 is an integer of 0 to 4, and
R₁ to R₃, R₆, R_{z}, n1 to n3, and n6 are as defined in Formula 1.

15. The polycyclic compound of claim 11, wherein the polycyclic compound is represented by Formula 4: 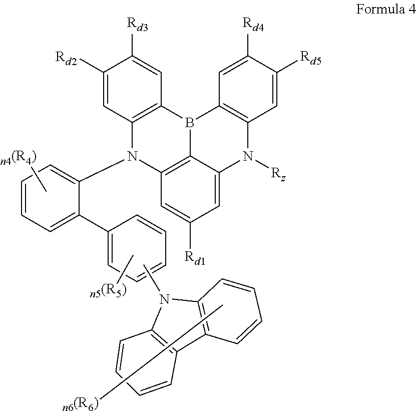
wherein, in Formula 4,
R_{d1} is a substituted or unsubstituted alkyl group having 1 to 10 carbons, a substituted or unsubstituted aryl group having 6 to 30 ring-forming carbons, or a substituted or unsubstituted heteroaryl group having 2 to 30 ring-forming carbons,
at least one selected from among R_{d2} and R_{d3}, and at least one selected from among R_{d4} and R_{d5} are each independently a substituted or unsubstituted aryl group having 6 to 30 ring-forming carbons, or a substituted or unsubstituted heteroaryl group having 2 to 30 ring-forming carbons, and any remaining selected from among R_{d2}, R_{d3}, R_{d4}, and R_{d5} are each independently a hydrogen atom, a deuterium atom, and
R_{z}, R₄ to R₆, and n4 to n6 are as defined in Formula 1.

16. The polycyclic compound of claim 11, wherein R_{z} is a substituted or unsubstituted biphenyl group, a substituted or unsubstituted terphenyl group, a substituted or unsubstituted quarterphenyl group, a substituted or unsubstituted quinquephenyl group, a substituted or unsubstituted fluorenyl group, a substituted or unsubstituted carbazole group, a substituted or unsubstituted dibenzofuran group, or a substituted or unsubstituted dibenzothiophene group.

17. The polycyclic compound of claim 11, wherein the polycyclic compound is represented by any one selected from among compounds in Compound Group 1: 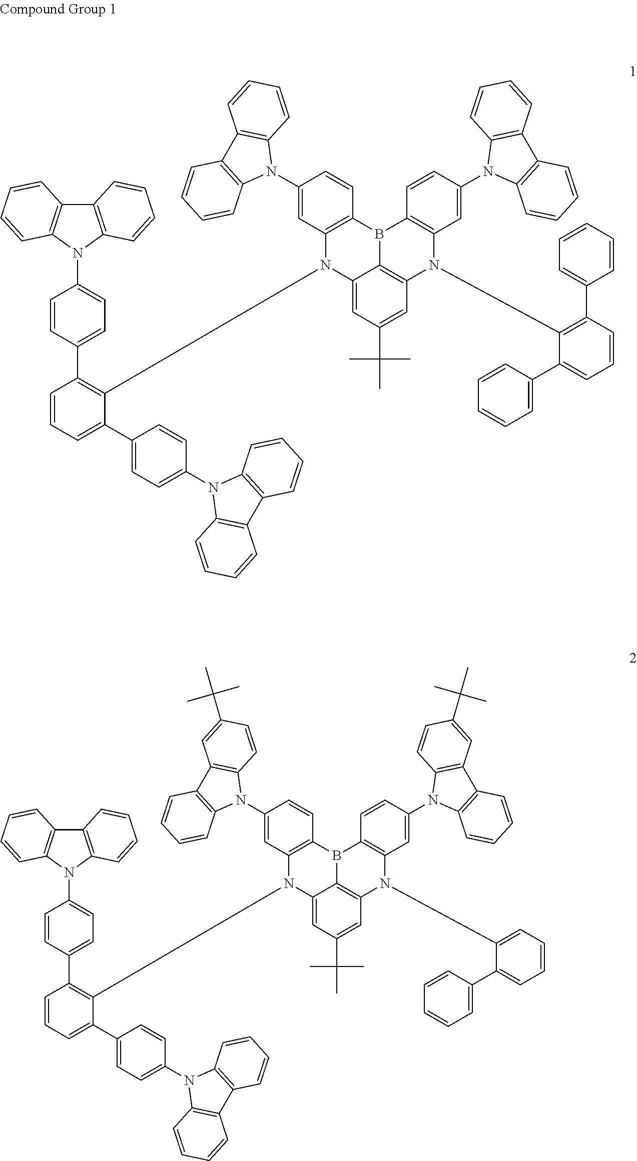 [SMILES: CC(C)(C)c1cc2c3c(c1)N(c1c(-c4ccc(-n5c6ccccc6c6ccccc65)cc4)cccc1-c1ccc(-n4c5ccccc5c5ccccc54)cc1)c1cc(-n4c5ccccc5c5ccccc54)ccc1B3c1ccc(-n3c4ccccc4c4ccccc43)cc1N2c1c(-c2ccccc2)cccc1-c1ccccc1 ; CC(C)(C)c1cc2c3c(c1)N(c1c(-c4ccc(-n5c6ccccc6c6ccccc65)cc4)cccc1-c1ccc(-n4c5ccccc5c5ccccc54)cc1)c1cc(-n4c5ccccc5c5cc(C(C)(C)C)ccc54)ccc1B3c1ccc(-n3c4ccccc4c4cc(C(C)(C)C)ccc43)cc1N2c1ccccc1-c1ccccc1] 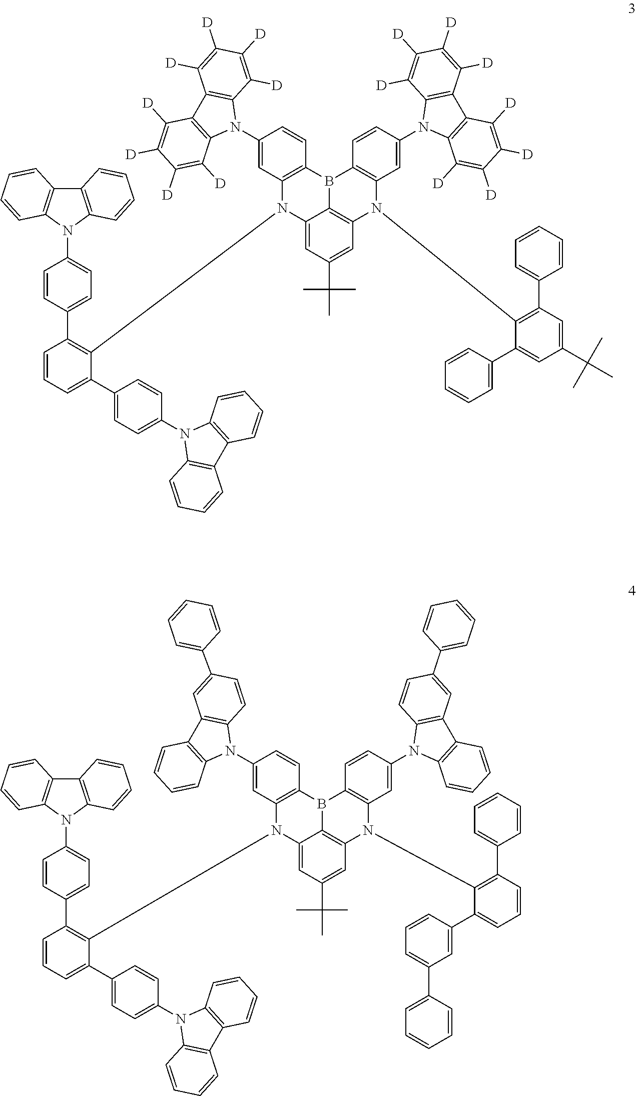 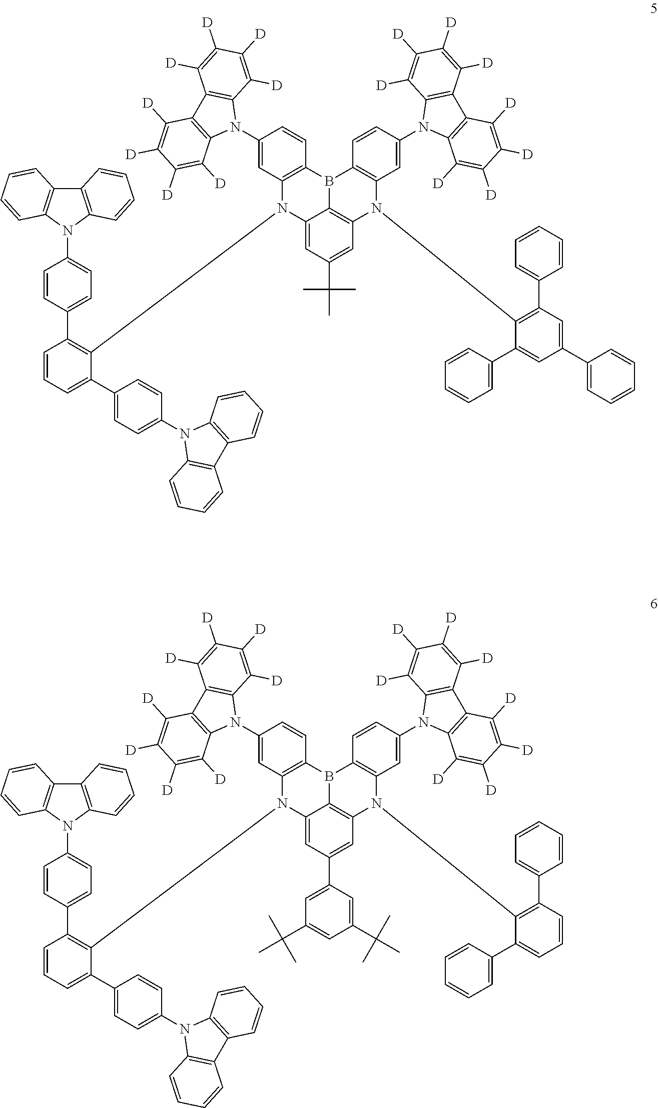 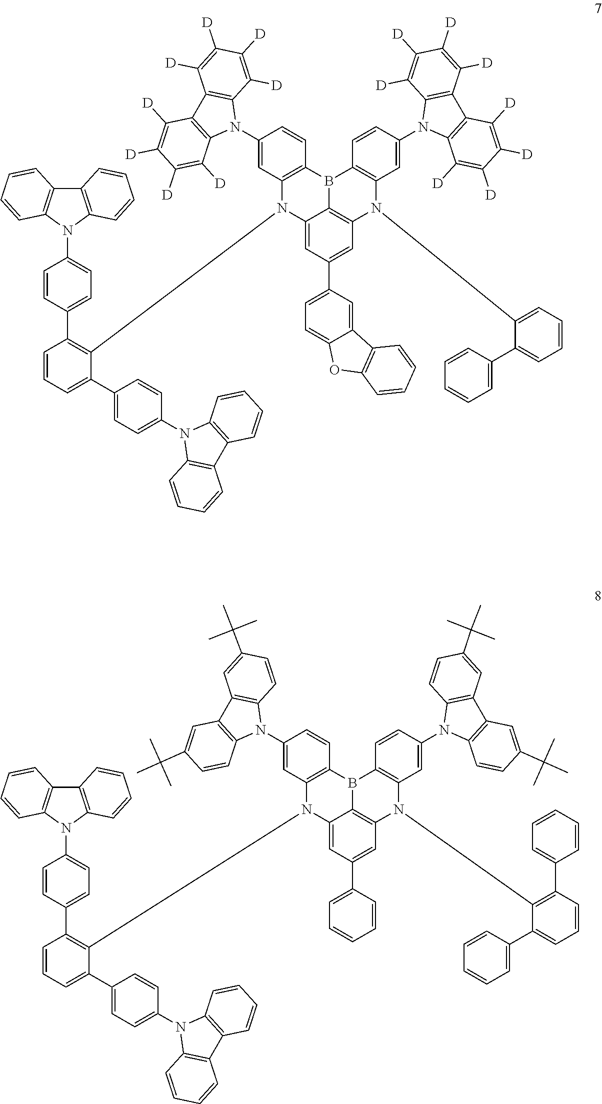 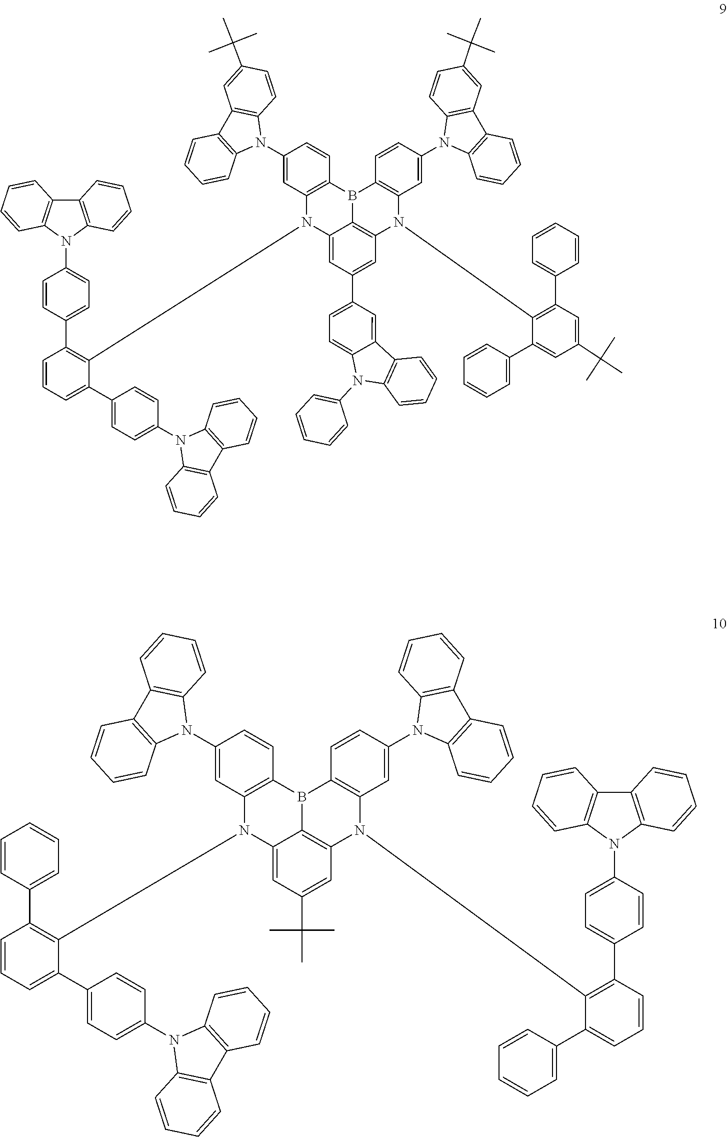 [SMILES: CC(C)(C)c1cc(-c2ccccc2)c(N2c3cc(-n4c5ccccc5c5cc(C(C)(C)C)ccc54)ccc3B3c4ccc(-n5c6ccccc6c6cc(C(C)(C)C)ccc65)cc4N(c4c(-c5ccc(-n6c7ccccc7c7ccccc76)cc5)cccc4-c4ccc(-n5c6ccccc6c6ccccc65)cc4)c4cc(-c5ccc6c(c5)c5ccccc5n6-c5ccccc5)cc2c43)c(-c2ccccc2)c1 ; CC(C)(C)c1cc2c3c(c1)N(c1c(-c4ccccc4)cccc1-c1ccc(-n4c5ccccc5c5ccccc54)cc1)c1cc(-n4c5ccccc5c5ccccc54)ccc1B3c1ccc(-n3c4ccccc4c4ccccc43)cc1N2c1c(-c2ccccc2)cccc1-c1ccc(-n2c3ccccc3c3ccccc32)cc1] 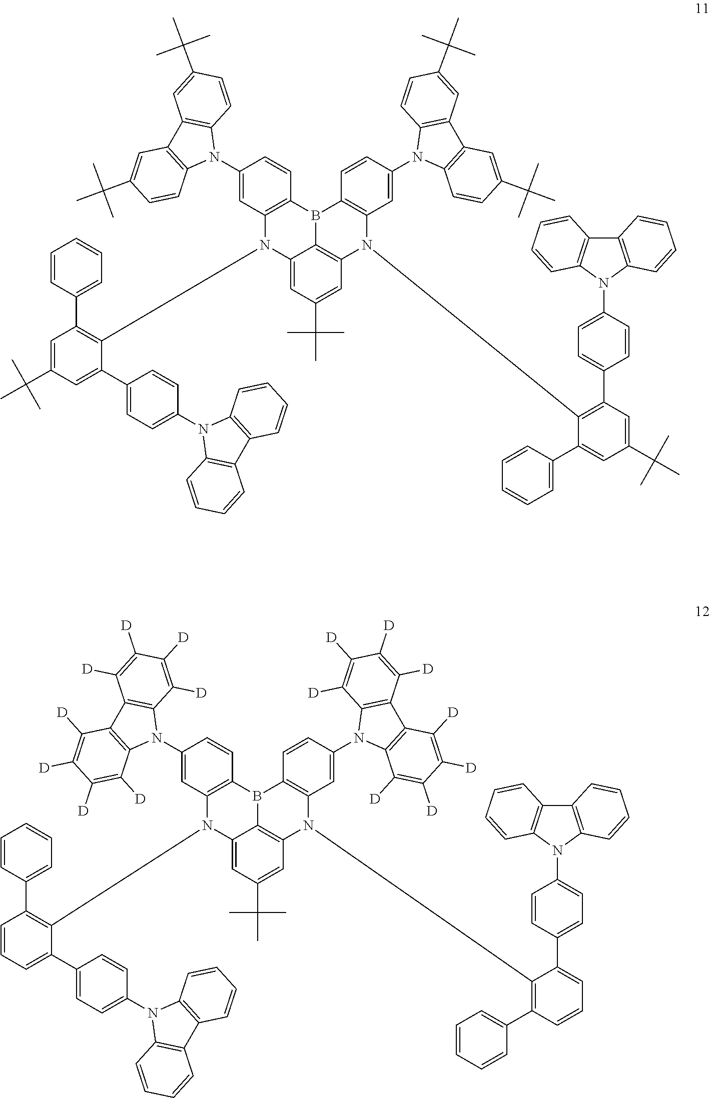 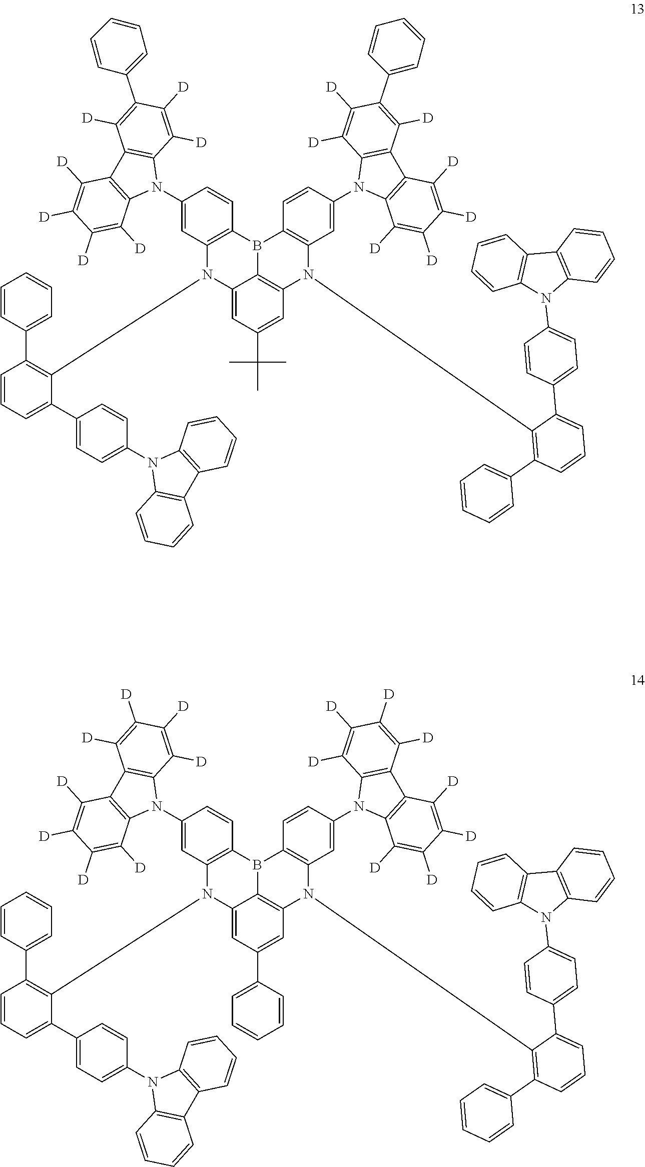 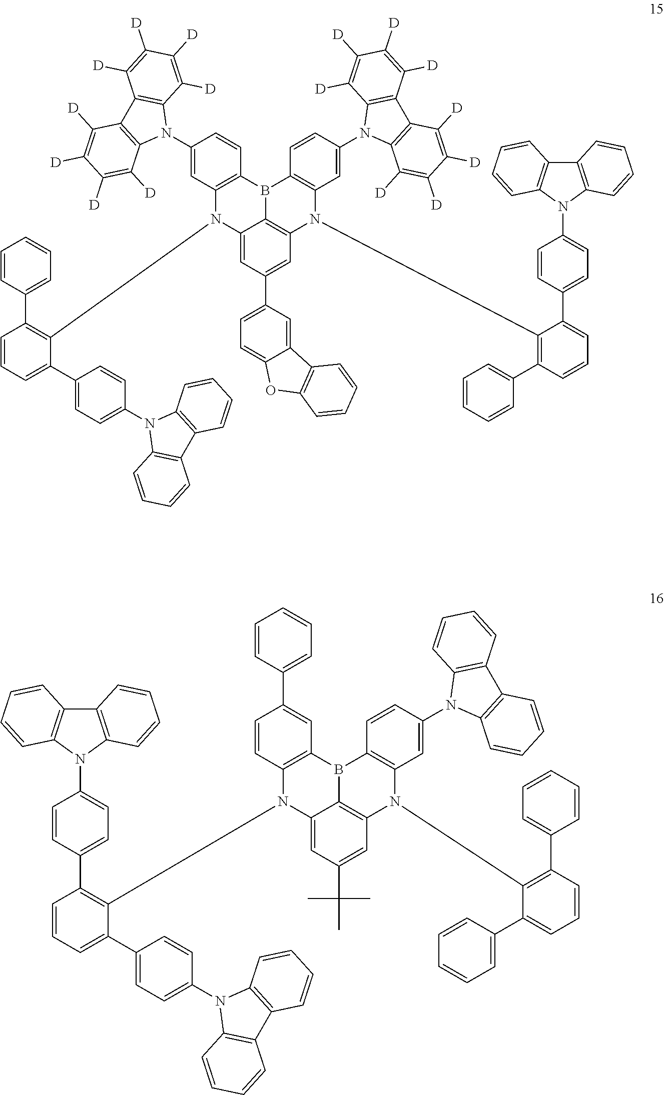 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccc(-n3c4ccccc4c4ccccc43)cc1)c1cc(-c3ccc4oc5ccccc5c4c3)cc3c1B2c1ccc(-n2c4c([2H])c([2H])c([2H])c([2H])c4c4c([2H])c([2H])c([2H])c([2H])c42)cc1N3c1c(-c2ccccc2)cccc1-c1ccc(-n2c3ccccc3c3ccccc32)cc1 ; CC(C)(C)c1cc2c3c(c1)N(c1c(-c4ccccc4)cccc1-c1ccccc1)c1cc(-n4c5ccccc5c5ccccc54)ccc1B3c1cc(-c3ccccc3)ccc1N2c1c(-c2ccc(-n3c4ccccc4c4ccccc43)cc2)cccc1-c1ccc(-n2c3ccccc3c3ccccc32)cc1] 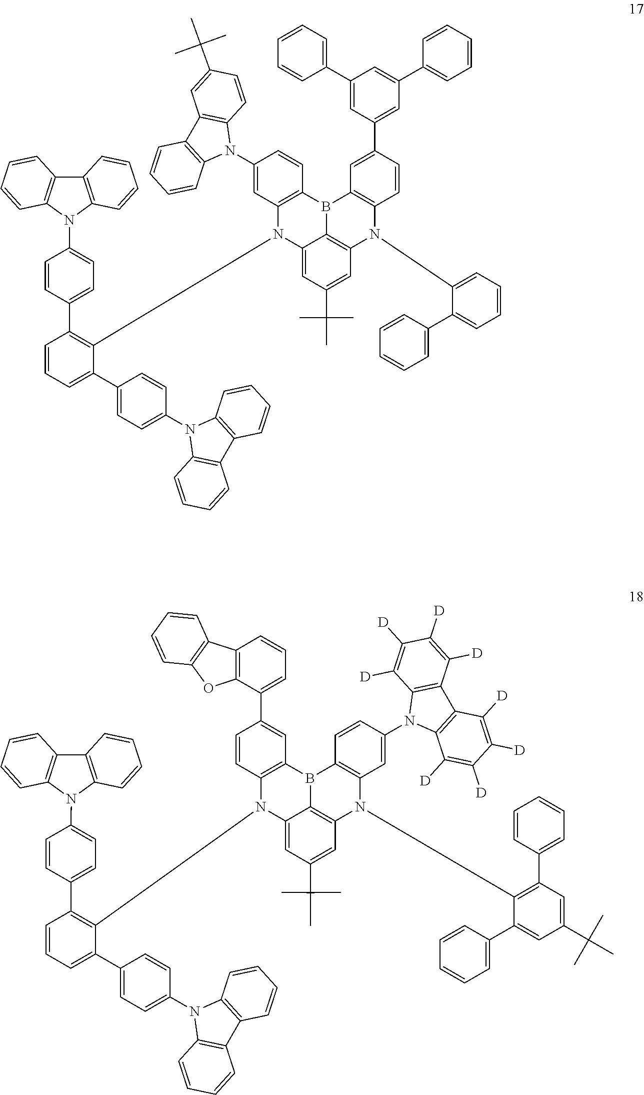 [SMILES: CC(C)(C)c1cc2c3c(c1)N(c1c(-c4ccc(-n5c6ccccc6c6ccccc65)cc4)cccc1-c1ccc(-n4c5ccccc5c5ccccc54)cc1)c1cc(-n4c5ccccc5c5cc(C(C)(C)C)ccc54)ccc1B3c1cc(-c3cc(-c4ccccc4)cc(-c4ccccc4)c3)ccc1N2c1ccccc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1cc(-c2cccc4c2oc2ccccc24)ccc1N3c1c(-c2ccc(-n3c4ccccc4c4ccccc43)cc2)cccc1-c1ccc(-n2c3ccccc3c3ccccc32)cc1] 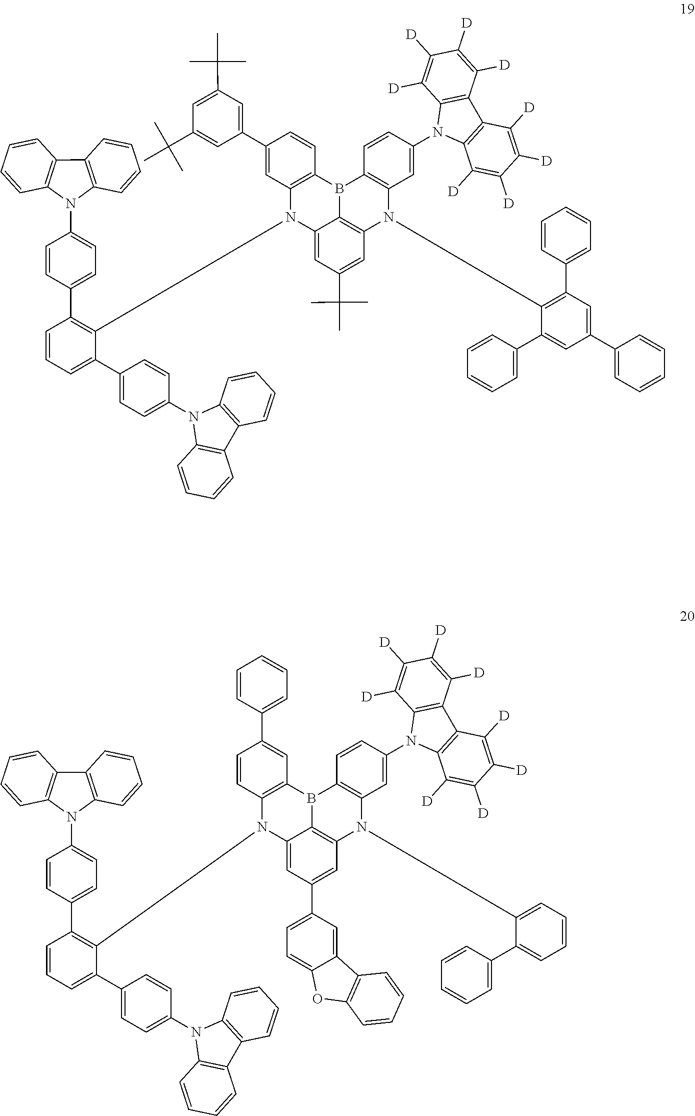 [SMILES: [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1ccccc1)c1cc(C(C)(C)C)cc3c1B2c1ccc(-c2cc(C(C)(C)C)cc(C(C)(C)C)c2)cc1N3c1c(-c2ccc(-n3c4ccccc4c4ccccc43)cc2)cccc1-c1ccc(-n2c3ccccc3c3ccccc32)cc1 ; [2H]c1c([2H])c([2H])c2c(c1[2H])c1c([2H])c([2H])c([2H])c([2H])c1n2-c1ccc2c(c1)N(c1ccccc1-c1ccccc1)c1cc(-c3ccc4oc5ccccc5c4c3)cc3c1B2c1cc(-c2ccccc2)ccc1N3c1c(-c2ccc(-n3c4ccccc4c4ccccc43)cc2)cccc1-c1ccc(-n2c3ccccc3c3ccccc32)cc1] 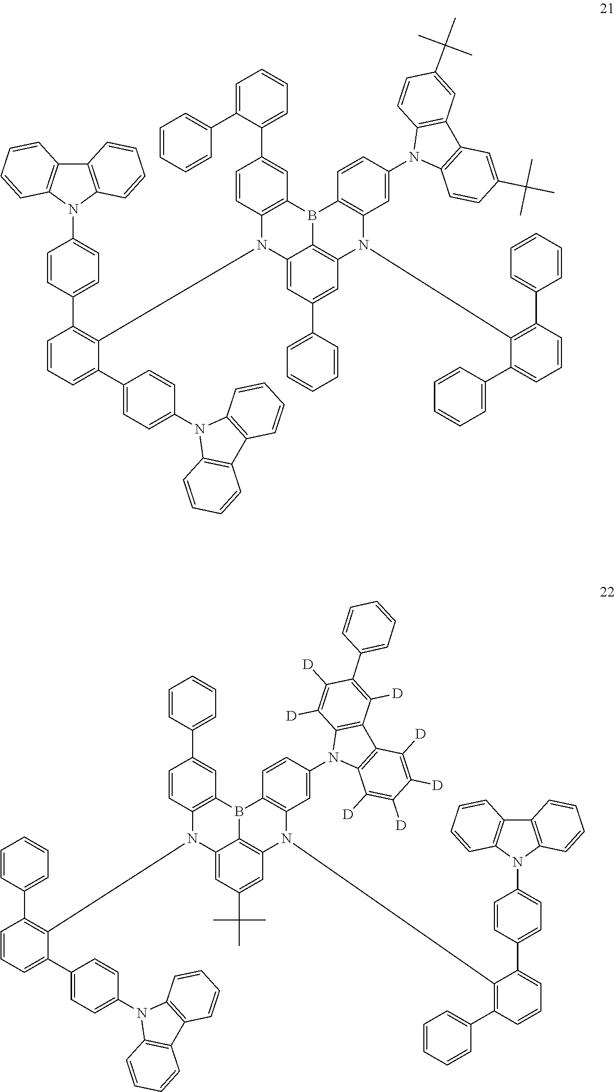 [SMILES: CC(C)(C)c1ccc2c(c1)c1cc(C(C)(C)C)ccc1n2-c1ccc2c(c1)N(c1c(-c3ccccc3)cccc1-c1ccccc1)c1cc(-c3ccccc3)cc3c1B2c1cc(-c2ccccc2-c2ccccc2)ccc1N3c1c(-c2ccc(-n3c4ccccc4c4ccccc43)cc2)cccc1-c1ccc(-n2c3ccccc3c3ccccc32)cc1 ; [2H]c1c([2H])c([2H])c2c(c1[2H])c1c([2H])c(-c3ccccc3)c([2H])c([2H])c1n2-c1ccc2c(c1)N(c1c(-c3ccccc3)cccc1-c1ccc(-n3c4ccccc4c4ccccc43)cc1)c1cc(C(C)(C)C)cc3c1B2c1cc(-c2ccccc2)ccc1N3c1c(-c2ccccc2)cccc1-c1ccc(-n2c3ccccc3c3ccccc32)cc1] 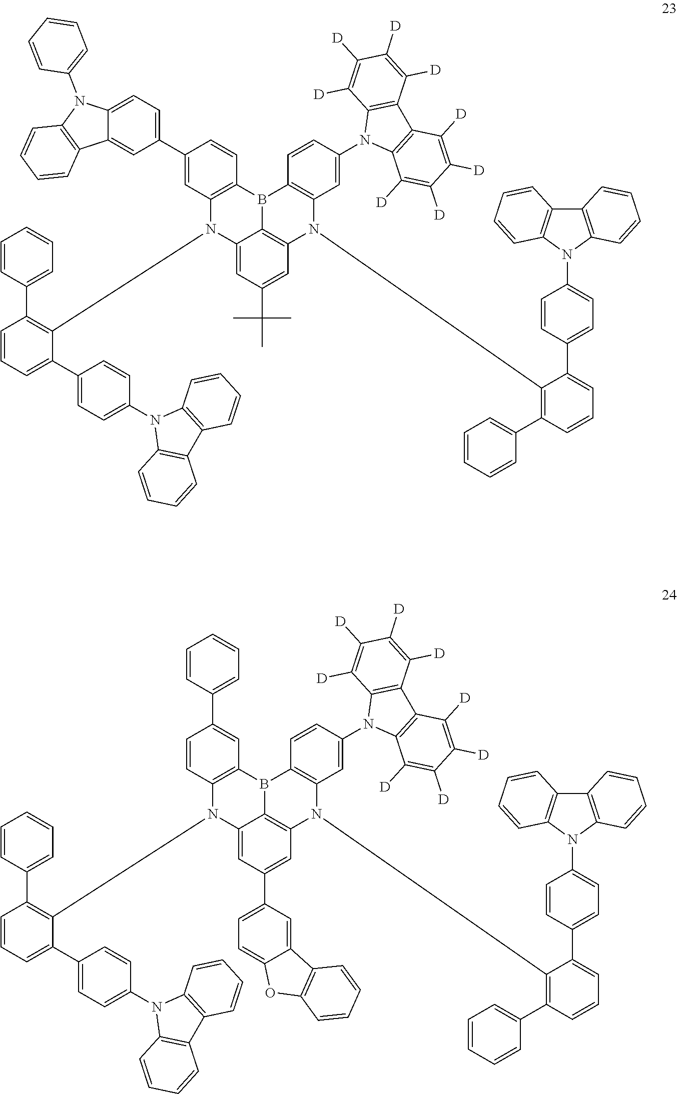 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccc(-n3c4ccccc4c4ccccc43)cc1)c1cc(C(C)(C)C)cc3c1B2c1ccc(-c2ccc4c(c2)c2ccccc2n4-c2ccccc2)cc1N3c1c(-c2ccccc2)cccc1-c1ccc(-n2c3ccccc3c3ccccc32)cc1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccc(-n3c4ccccc4c4ccccc43)cc1)c1cc(-c3ccc4oc5ccccc5c4c3)cc3c1B2c1cc(-c2ccccc2)ccc1N3c1c(-c2ccccc2)cccc1-c1ccc(-n2c3ccccc3c3ccccc32)cc1] 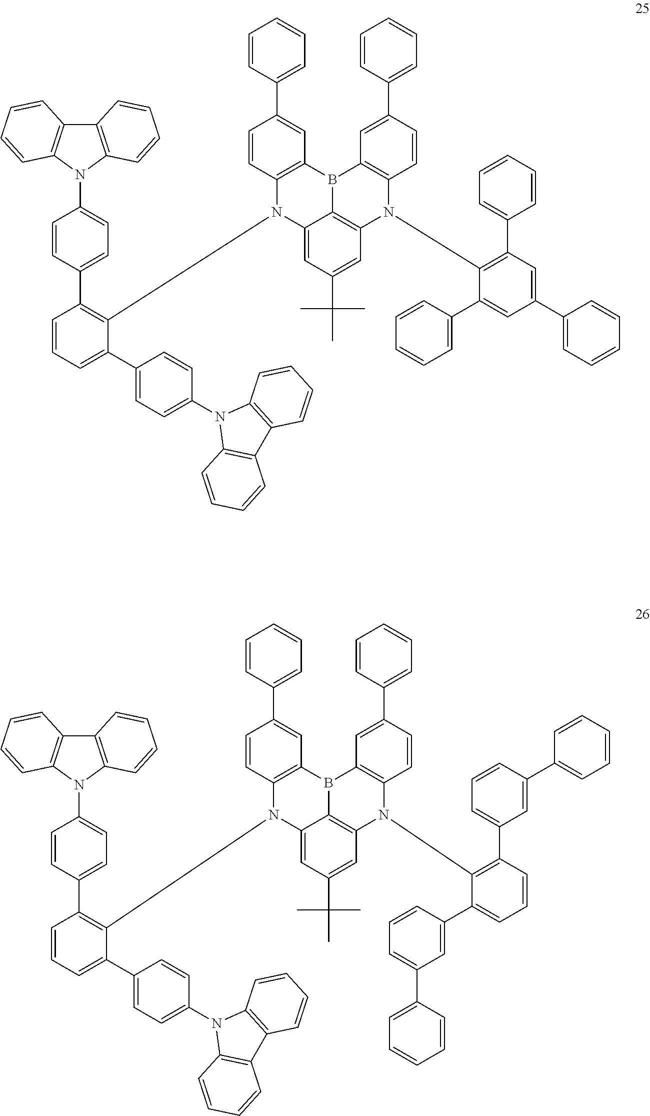 [SMILES: CC(C)(C)c1cc2c3c(c1)N(c1c(-c4ccccc4)cc(-c4ccccc4)cc1-c1ccccc1)c1ccc(-c4ccccc4)cc1B3c1cc(-c3ccccc3)ccc1N2c1c(-c2ccc(-n3c4ccccc4c4ccccc43)cc2)cccc1-c1ccc(-n2c3ccccc3c3ccccc32)cc1 ; CC(C)(C)c1cc2c3c(c1)N(c1c(-c4cccc(-c5ccccc5)c4)cccc1-c1cccc(-c4ccccc4)c1)c1ccc(-c4ccccc4)cc1B3c1cc(-c3ccccc3)ccc1N2c1c(-c2ccc(-n3c4ccccc4c4ccccc43)cc2)cccc1-c1ccc(-n2c3ccccc3c3ccccc32)cc1] 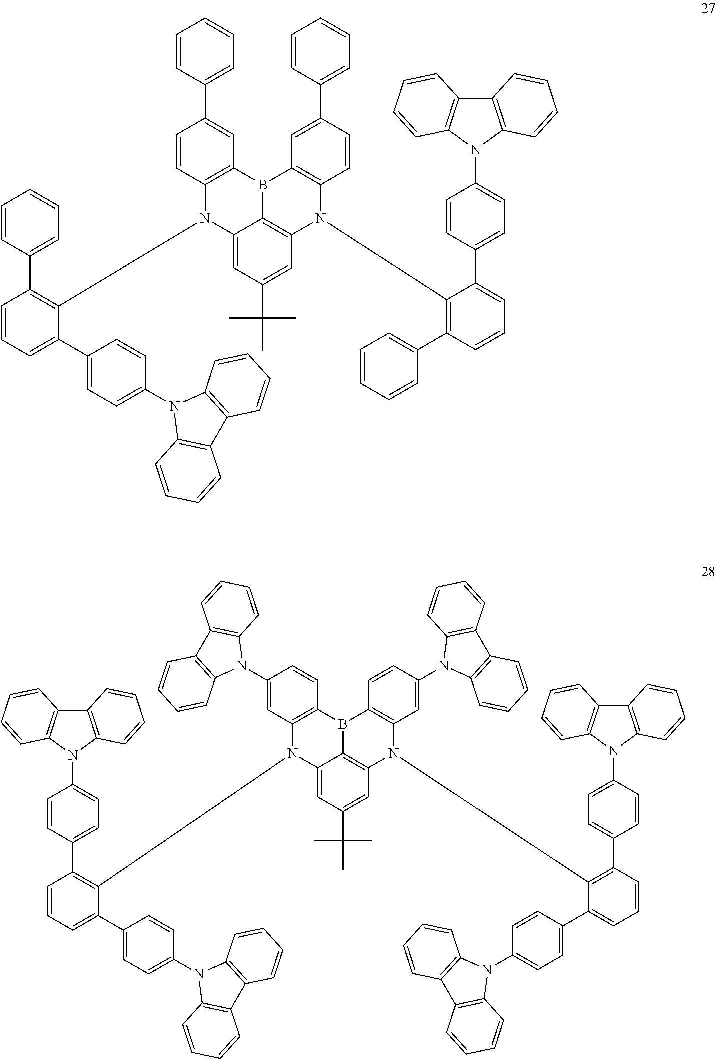 [SMILES: CC(C)(C)c1cc2c3c(c1)N(c1c(-c4ccccc4)cccc1-c1ccc(-n4c5ccccc5c5ccccc54)cc1)c1ccc(-c4ccccc4)cc1B3c1cc(-c3ccccc3)ccc1N2c1c(-c2ccccc2)cccc1-c1ccc(-n2c3ccccc3c3ccccc32)cc1 ; CC(C)(C)c1cc2c3c(c1)N(c1c(-c4ccc(-n5c6ccccc6c6ccccc65)cc4)cccc1-c1ccc(-n4c5ccccc5c5ccccc54)cc1)c1cc(-n4c5ccccc5c5ccccc54)ccc1B3c1ccc(-n3c4ccccc4c4ccccc43)cc1N2c1c(-c2ccc(-n3c4ccccc4c4ccccc43)cc2)cccc1-c1ccc(-n2c3ccccc3c3ccccc32)cc1] 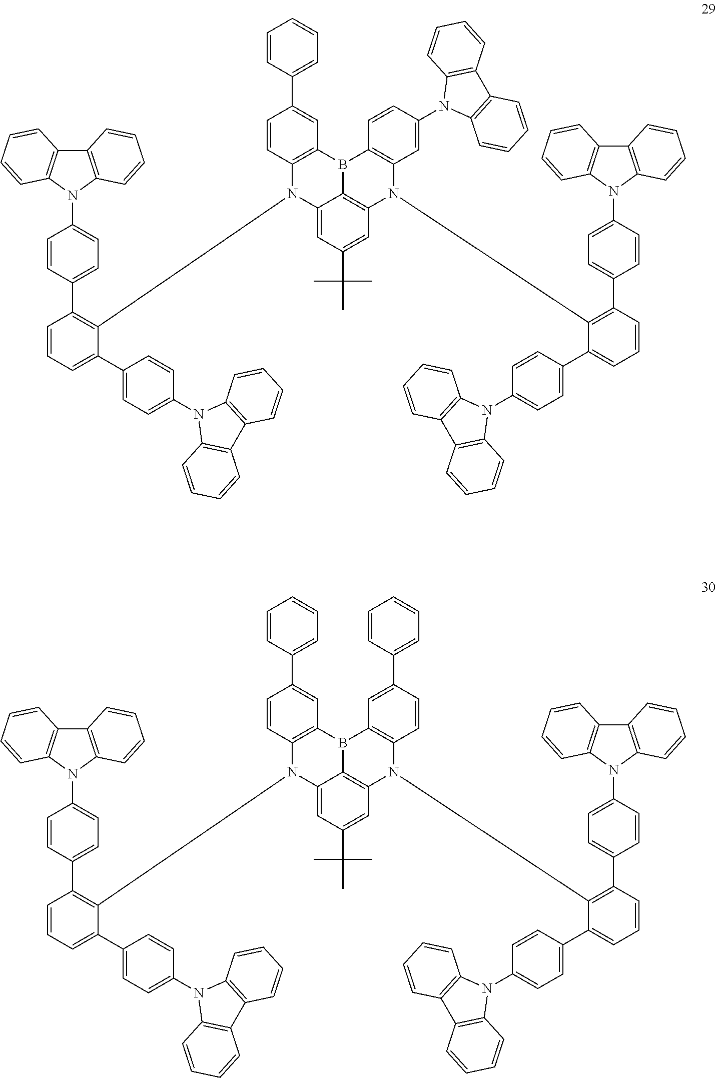 [SMILES: CC(C)(C)c1cc2c3c(c1)N(c1c(-c4ccc(-n5c6ccccc6c6ccccc65)cc4)cccc1-c1ccc(-n4c5ccccc5c5ccccc54)cc1)c1cc(-n4c5ccccc5c5ccccc54)ccc1B3c1cc(-c3ccccc3)ccc1N2c1c(-c2ccc(-n3c4ccccc4c4ccccc43)cc2)cccc1-c1ccc(-n2c3ccccc3c3ccccc32)cc1 ; CC(C)(C)c1cc2c3c(c1)N(c1c(-c4ccc(-n5c6ccccc6c6ccccc65)cc4)cccc1-c1ccc(-n4c5ccccc5c5ccccc54)cc1)c1ccc(-c4ccccc4)cc1B3c1cc(-c3ccccc3)ccc1N2c1c(-c2ccc(-n3c4ccccc4c4ccccc43)cc2)cccc1-c1ccc(-n2c3ccccc3c3ccccc32)cc1] 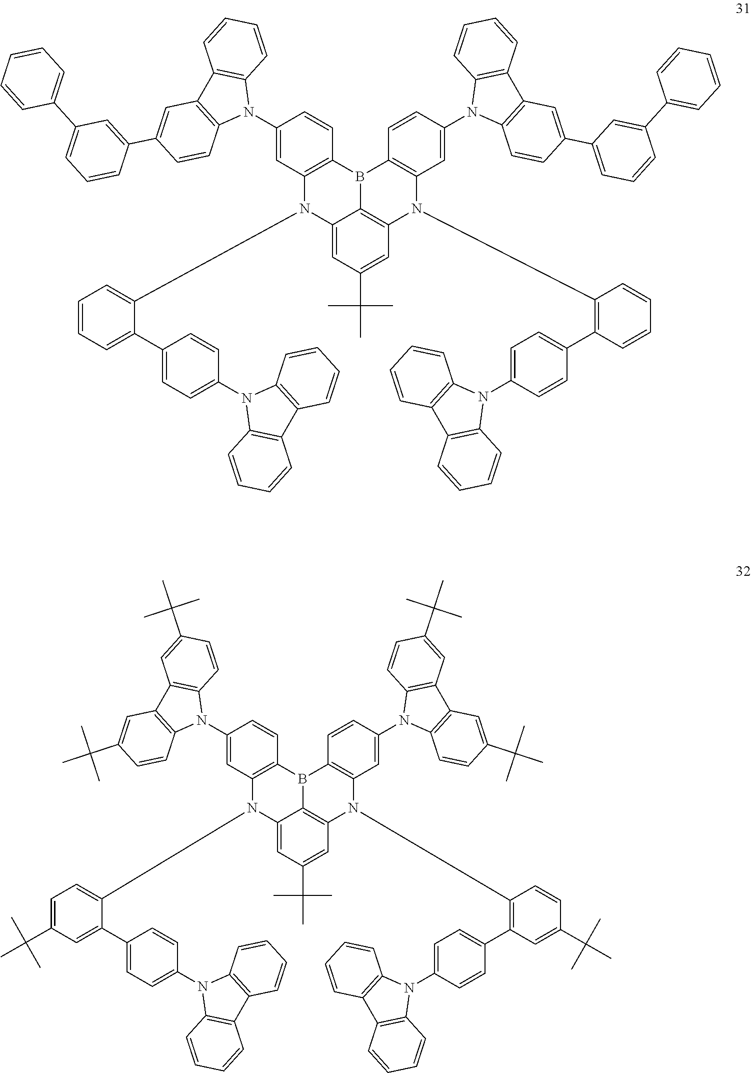 [SMILES: CC(C)(C)c1cc2c3c(c1)N(c1ccccc1-c1ccc(-n4c5ccccc5c5ccccc54)cc1)c1cc(-n4c5ccccc5c5cc(-c6cccc(-c7ccccc7)c6)ccc54)ccc1B3c1ccc(-n3c4ccccc4c4cc(-c5cccc(-c6ccccc6)c5)ccc43)cc1N2c1ccccc1-c1ccc(-n2c3ccccc3c3ccccc32)cc1 ; CC(C)(C)c1ccc(N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4N(c4ccc(C(C)(C)C)cc4-c4ccc(-n5c6ccccc6c6ccccc65)cc4)c4cc(C(C)(C)C)cc2c43)c(-c2ccc(-n3c4ccccc4c4ccccc43)cc2)c1] 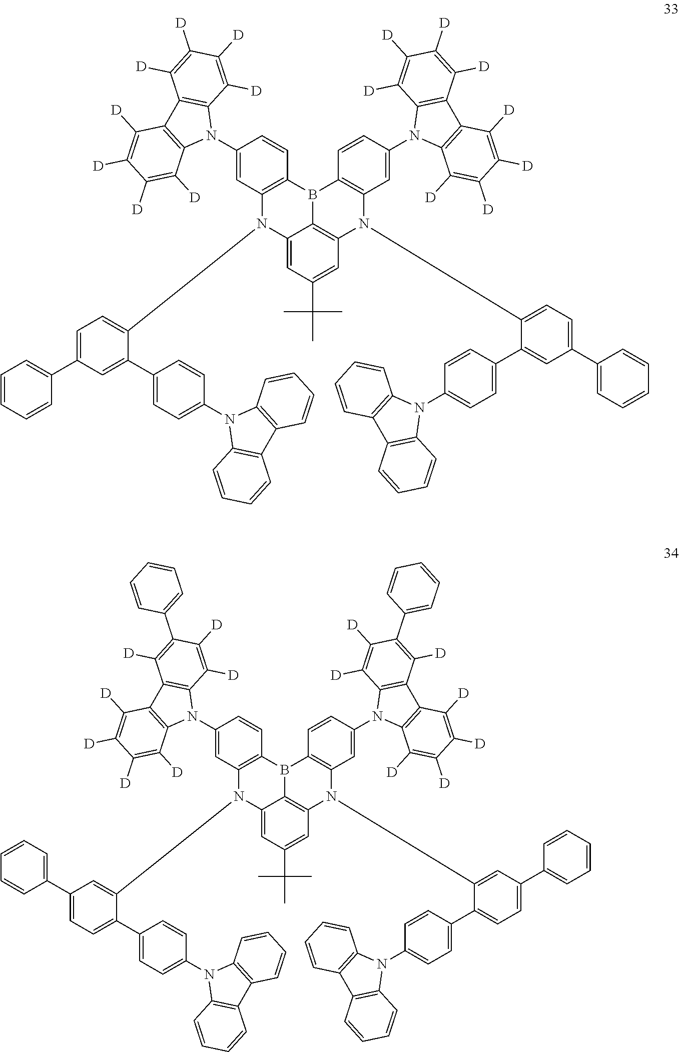 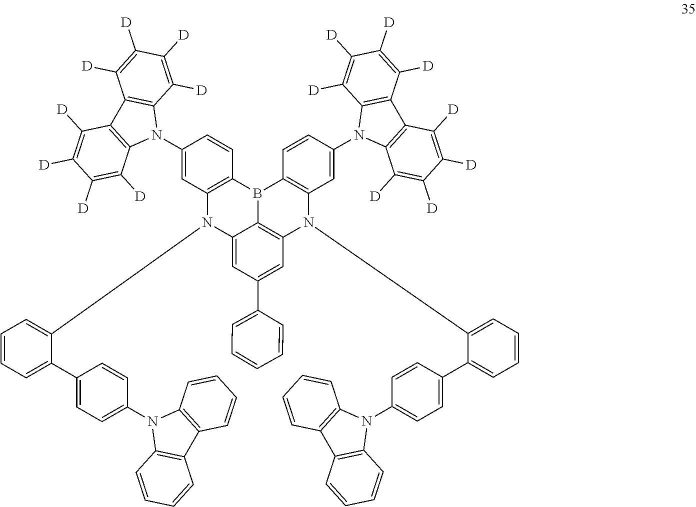 [SMILES: [2H]c1c([2H])c([2H])c2c(c1[2H])c1c([2H])c([2H])c([2H])c([2H])c1n2-c1ccc2c(c1)N(c1ccccc1-c1ccc(-n3c4ccccc4c4ccccc43)cc1)c1cc(-c3ccccc3)cc3c1B2c1ccc(-n2c4c([2H])c([2H])c([2H])c([2H])c4c4c([2H])c([2H])c([2H])c([2H])c42)cc1N3c1ccccc1-c1ccc(-n2c3ccccc3c3ccccc32)cc1] 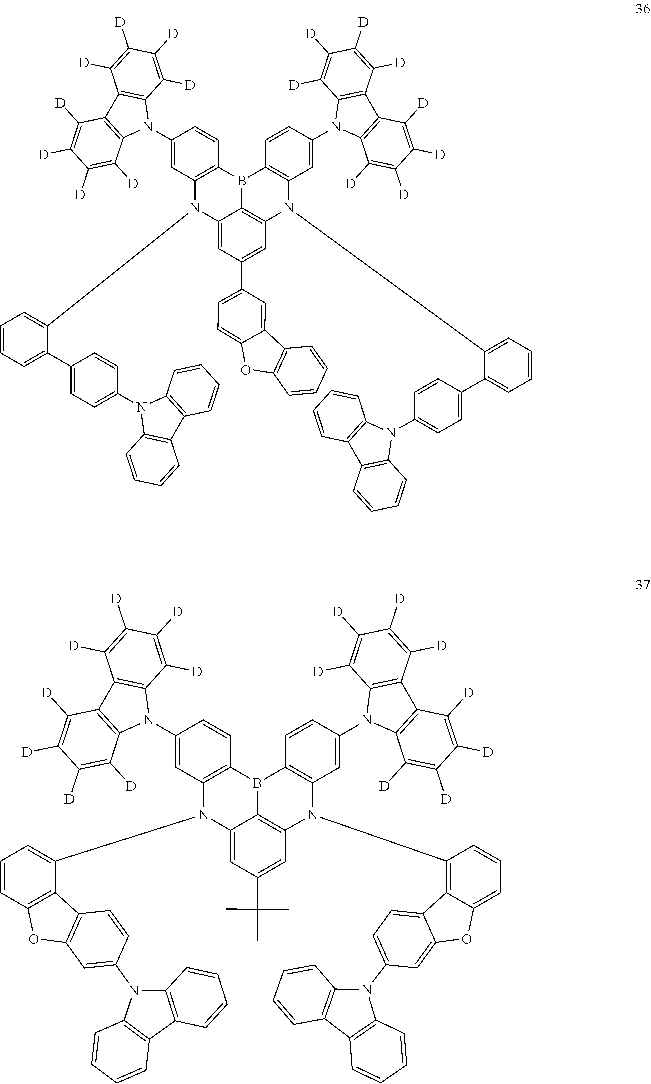 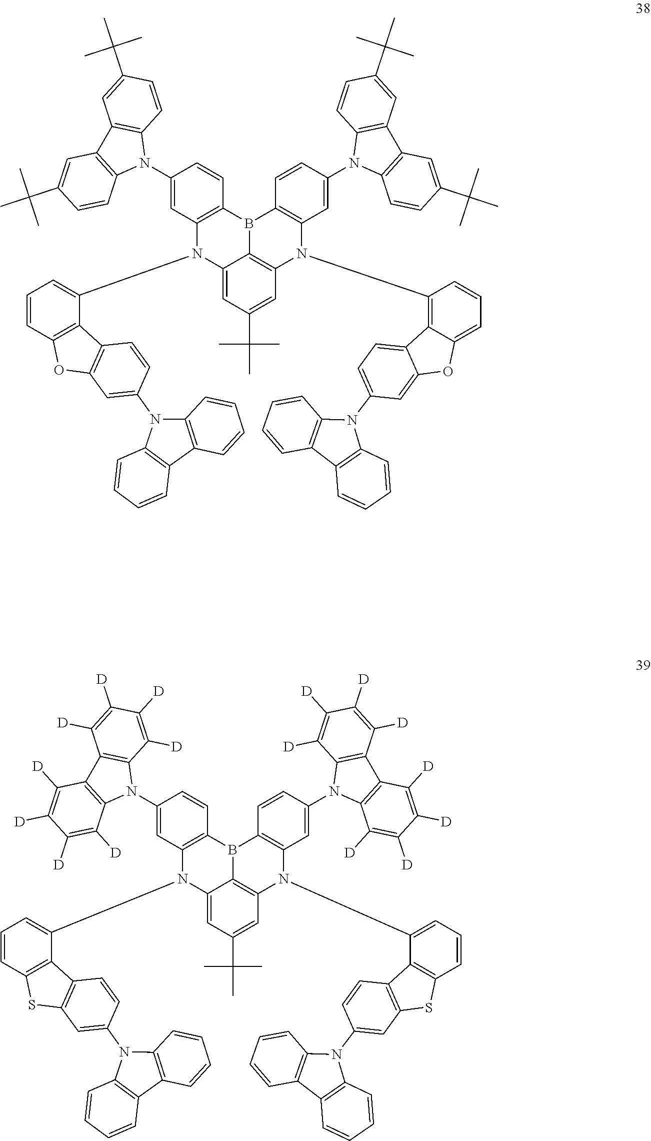 [SMILES: CC(C)(C)c1cc2c3c(c1)N(c1cccc4oc5cc(-n6c7ccccc7c7ccccc76)ccc5c14)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1N2c1cccc2oc3cc(-n4c5ccccc5c5ccccc54)ccc3c12 ; [2H]c1c([2H])c([2H])c2c(c1[2H])c1c([2H])c([2H])c([2H])c([2H])c1n2-c1ccc2c(c1)N(c1cccc3sc4cc(-n5c6ccccc6c6ccccc65)ccc4c13)c1cc(C(C)(C)C)cc3c1B2c1ccc(-n2c4c([2H])c([2H])c([2H])c([2H])c4c4c([2H])c([2H])c([2H])c([2H])c42)cc1N3c1cccc2sc3cc(-n4c5ccccc5c5ccccc54)ccc3c12] 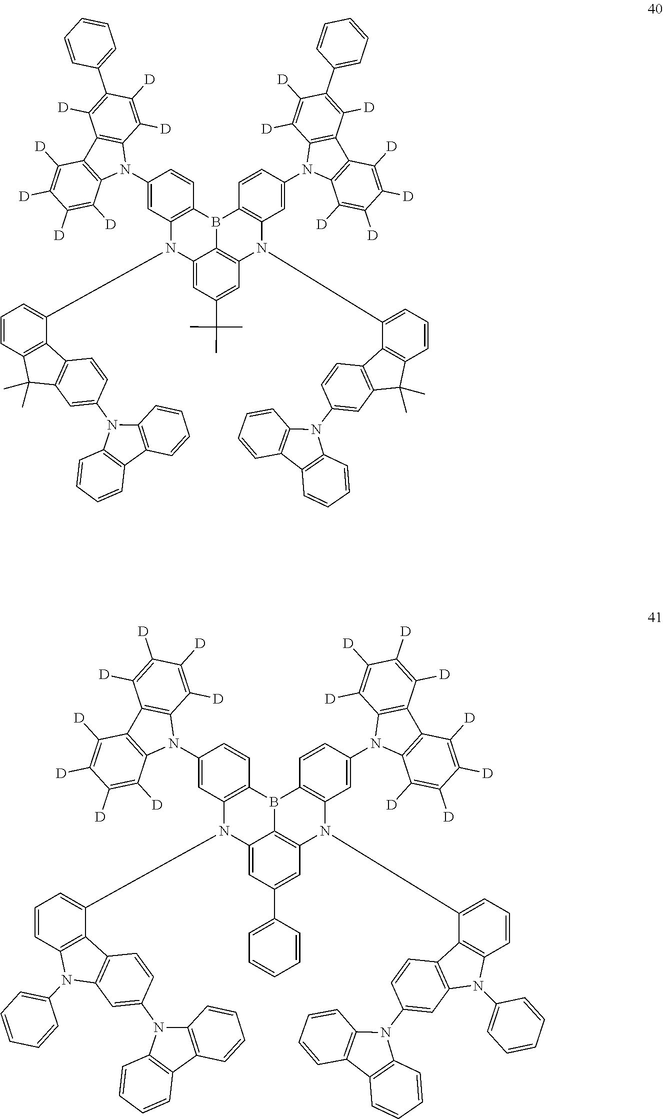 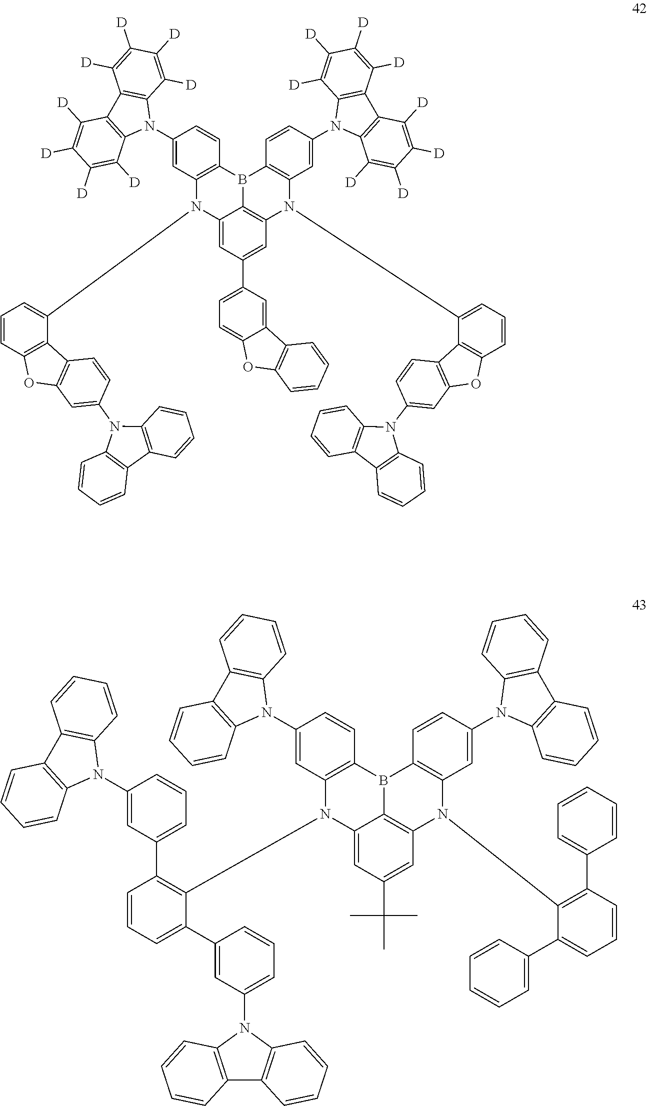 [SMILES: [2H]c1c([2H])c([2H])c2c(c1[2H])c1c([2H])c([2H])c([2H])c([2H])c1n2-c1ccc2c(c1)N(c1cccc3oc4cc(-n5c6ccccc6c6ccccc65)ccc4c13)c1cc(-c3ccc4oc5ccccc5c4c3)cc3c1B2c1ccc(-n2c4c([2H])c([2H])c([2H])c([2H])c4c4c([2H])c([2H])c([2H])c([2H])c42)cc1N3c1cccc2oc3cc(-n4c5ccccc5c5ccccc54)ccc3c12 ; CC(C)(C)c1cc2c3c(c1)N(c1c(-c4cccc(-n5c6ccccc6c6ccccc65)c4)cccc1-c1cccc(-n4c5ccccc5c5ccccc54)c1)c1cc(-n4c5ccccc5c5ccccc54)ccc1B3c1ccc(-n3c4ccccc4c4ccccc43)cc1N2c1c(-c2ccccc2)cccc1-c1ccccc1] 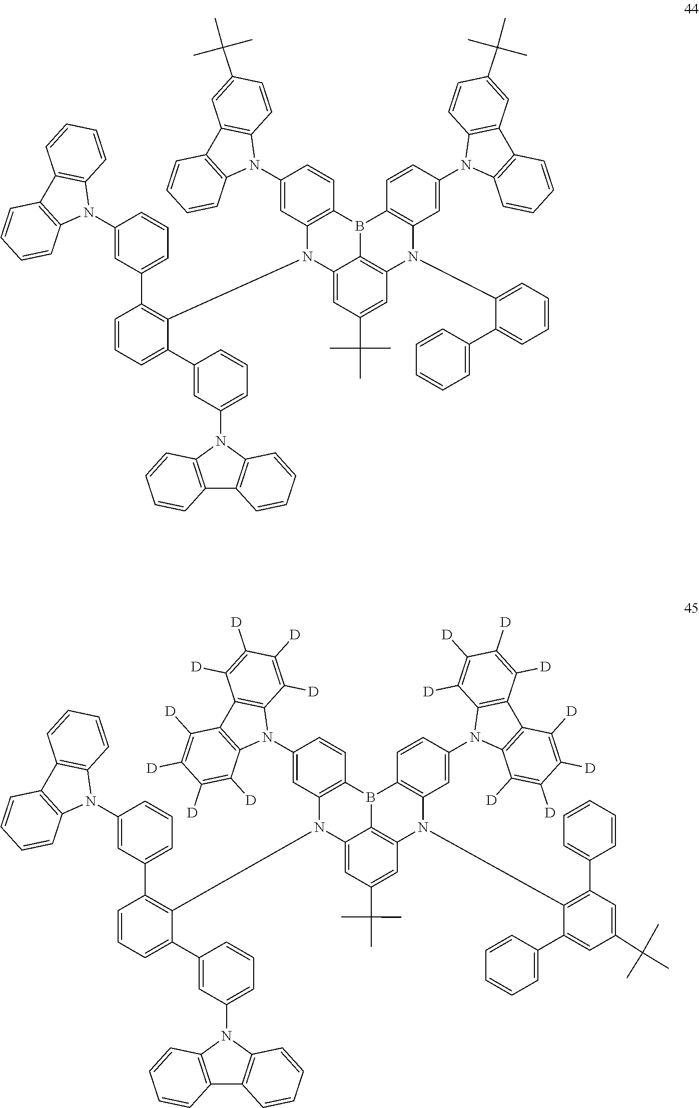 [SMILES: CC(C)(C)c1cc2c3c(c1)N(c1c(-c4cccc(-n5c6ccccc6c6ccccc65)c4)cccc1-c1cccc(-n4c5ccccc5c5ccccc54)c1)c1cc(-n4c5ccccc5c5cc(C(C)(C)C)ccc54)ccc1B3c1ccc(-n3c4ccccc4c4cc(C(C)(C)C)ccc43)cc1N2c1ccccc1-c1ccccc1 ; [2H]c1c([2H])c([2H])c2c(c1[2H])c1c([2H])c([2H])c([2H])c([2H])c1n2-c1ccc2c(c1)N(c1c(-c3cccc(-n4c5ccccc5c5ccccc54)c3)cccc1-c1cccc(-n3c4ccccc4c4ccccc43)c1)c1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2ccccc2)cc(C(C)(C)C)cc1-c1ccccc1] 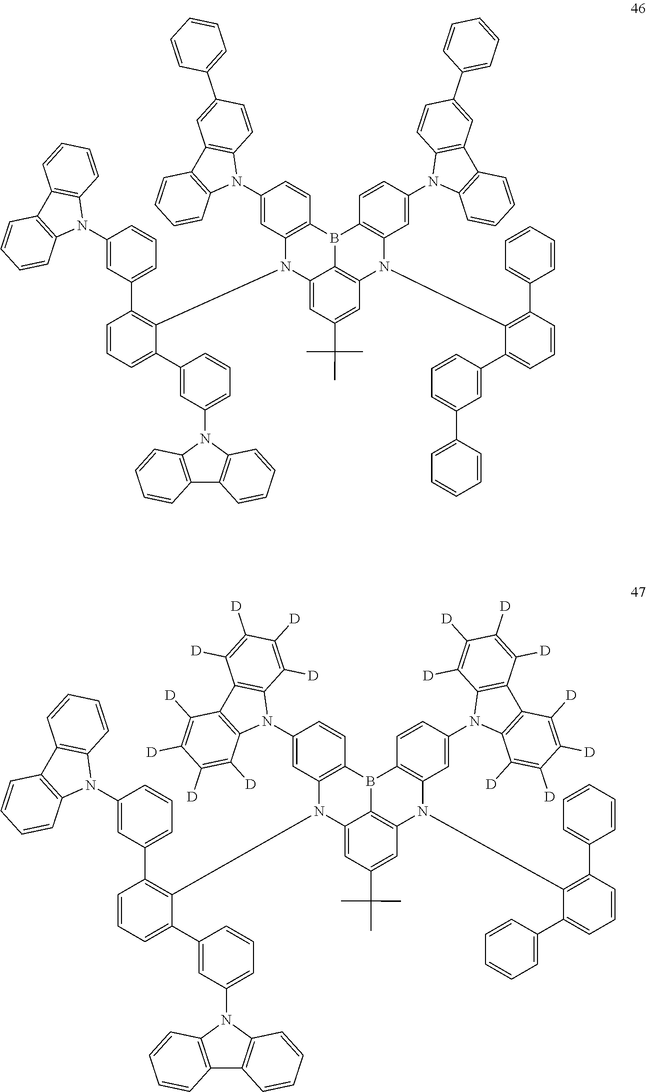 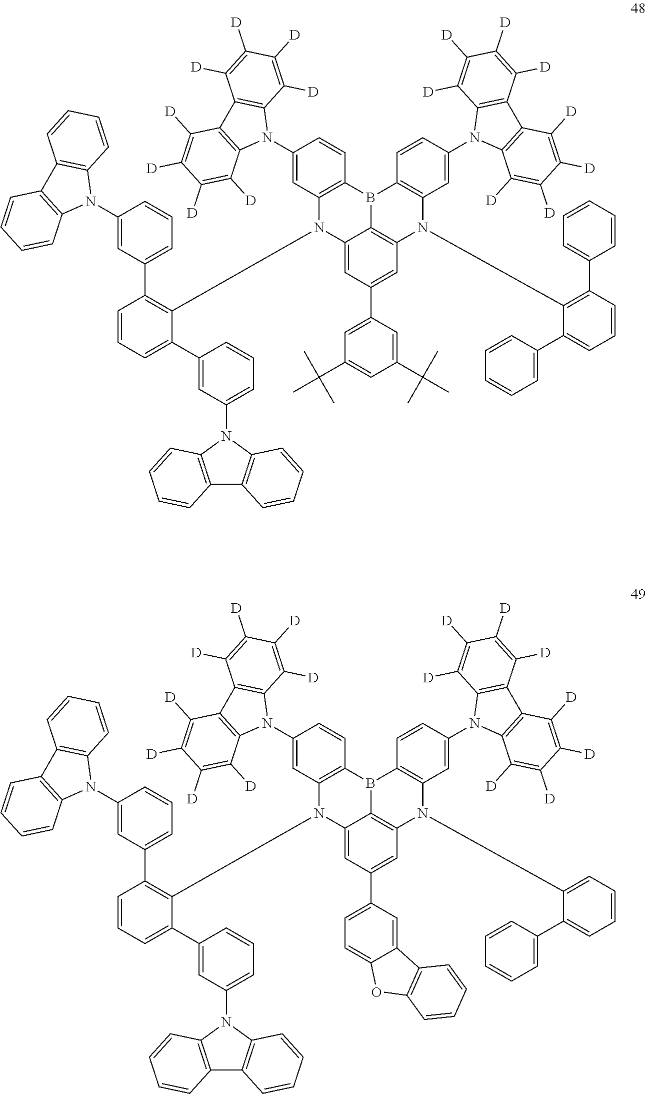 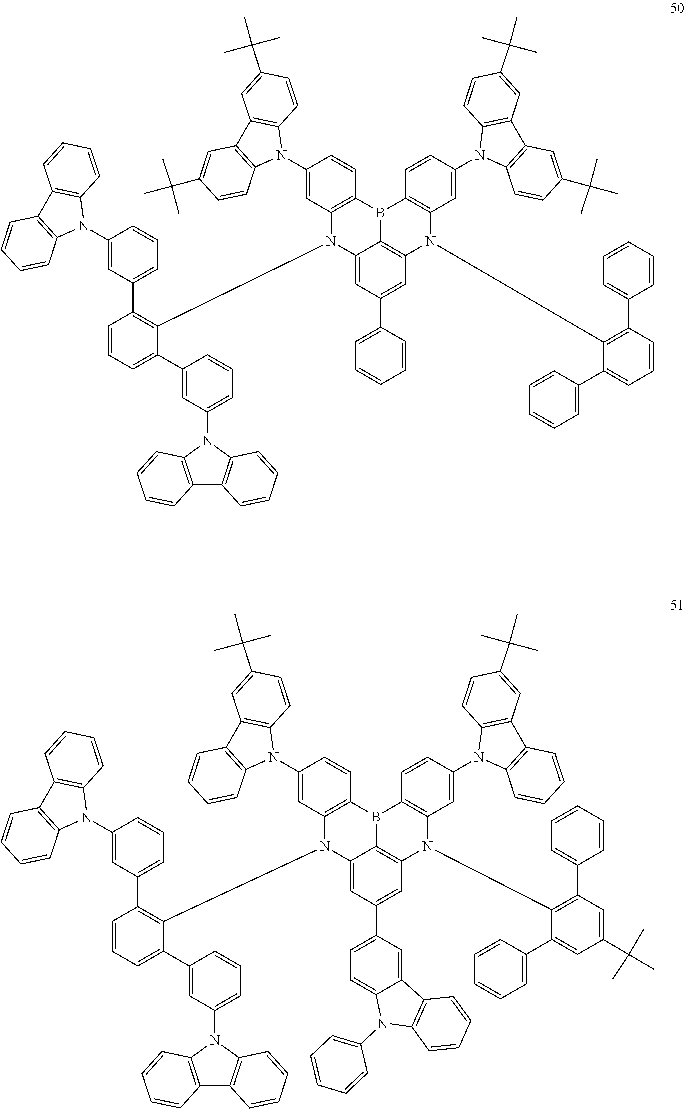 [SMILES: CC(C)(C)c1ccc2c(c1)c1cc(C(C)(C)C)ccc1n2-c1ccc2c(c1)N(c1c(-c3ccccc3)cccc1-c1ccccc1)c1cc(-c3ccccc3)cc3c1B2c1ccc(-n2c4ccc(C(C)(C)C)cc4c4cc(C(C)(C)C)ccc42)cc1N3c1c(-c2cccc(-n3c4ccccc4c4ccccc43)c2)cccc1-c1cccc(-n2c3ccccc3c3ccccc32)c1 ; CC(C)(C)c1cc(-c2ccccc2)c(N2c3cc(-n4c5ccccc5c5cc(C(C)(C)C)ccc54)ccc3B3c4ccc(-n5c6ccccc6c6cc(C(C)(C)C)ccc65)cc4N(c4c(-c5cccc(-n6c7ccccc7c7ccccc76)c5)cccc4-c4cccc(-n5c6ccccc6c6ccccc65)c4)c4cc(-c5ccc6c(c5)c5ccccc5n6-c5ccccc5)cc2c43)c(-c2ccccc2)c1] 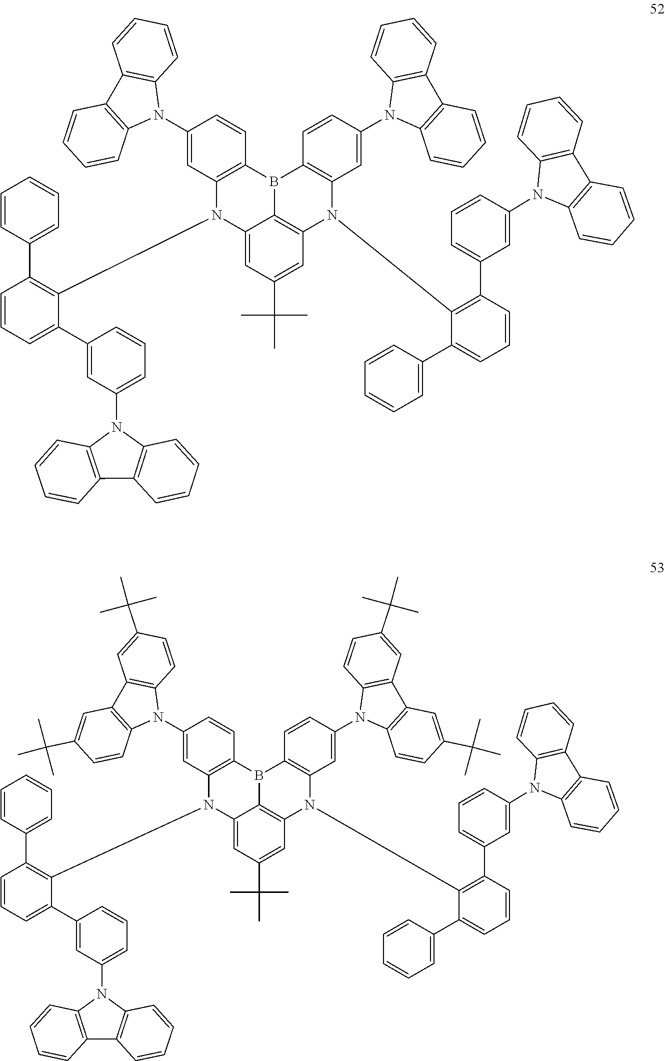 [SMILES: CC(C)(C)c1cc2c3c(c1)N(c1c(-c4ccccc4)cccc1-c1cccc(-n4c5ccccc5c5ccccc54)c1)c1cc(-n4c5ccccc5c5ccccc54)ccc1B3c1ccc(-n3c4ccccc4c4ccccc43)cc1N2c1c(-c2ccccc2)cccc1-c1cccc(-n2c3ccccc3c3ccccc32)c1 ; CC(C)(C)c1cc2c3c(c1)N(c1c(-c4ccccc4)cccc1-c1cccc(-n4c5ccccc5c5ccccc54)c1)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1N2c1c(-c2ccccc2)cccc1-c1cccc(-n2c3ccccc3c3ccccc32)c1] 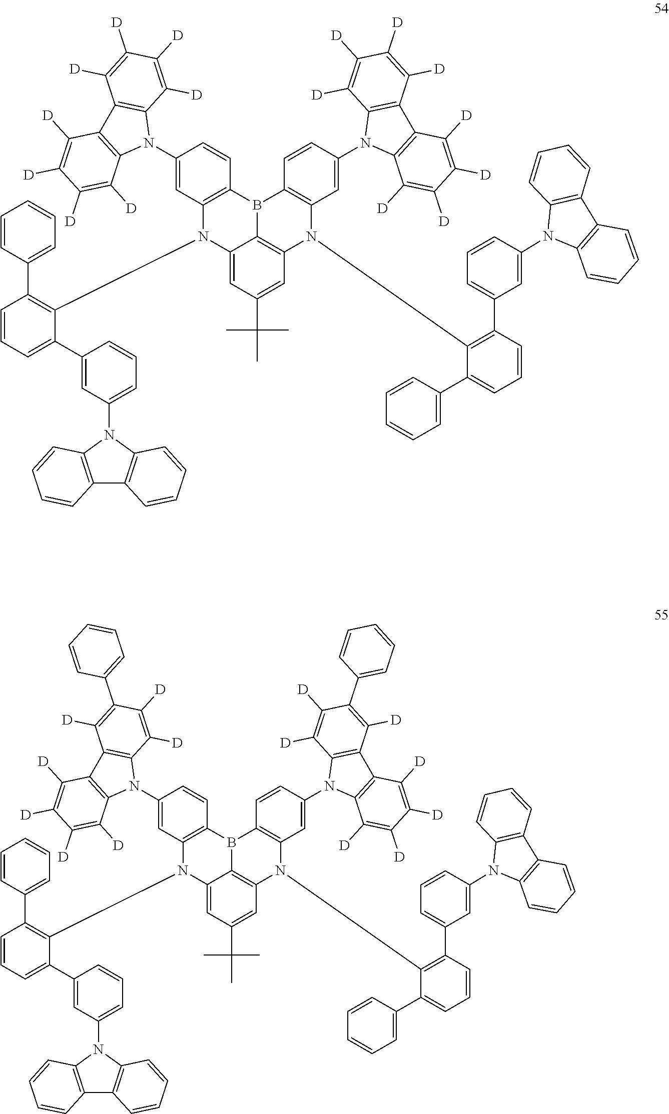 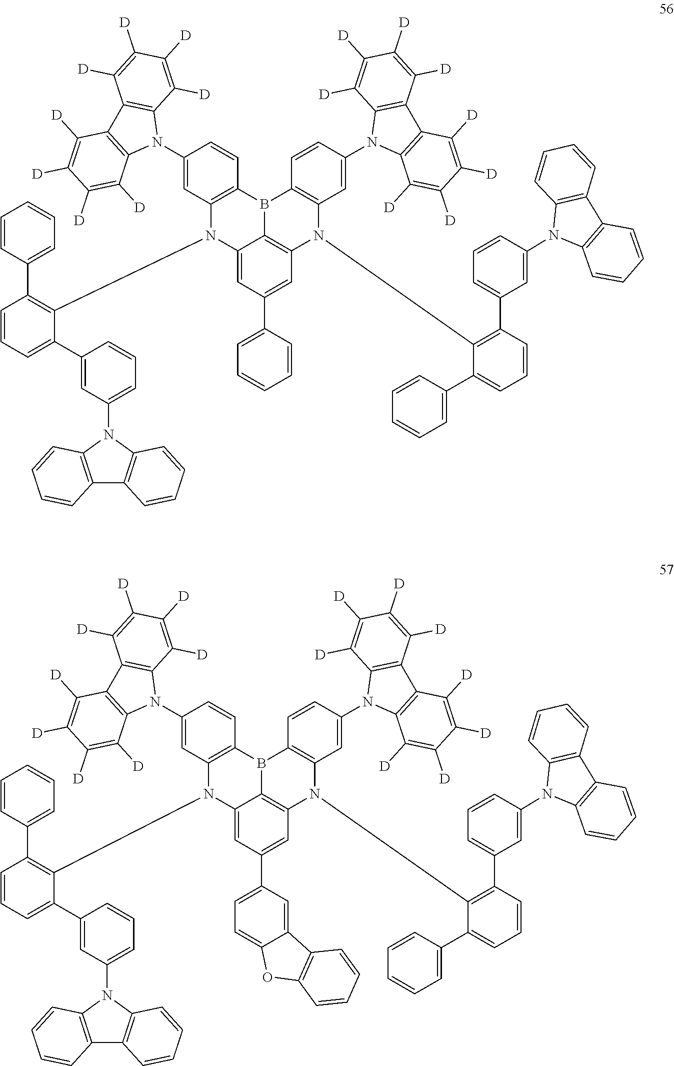 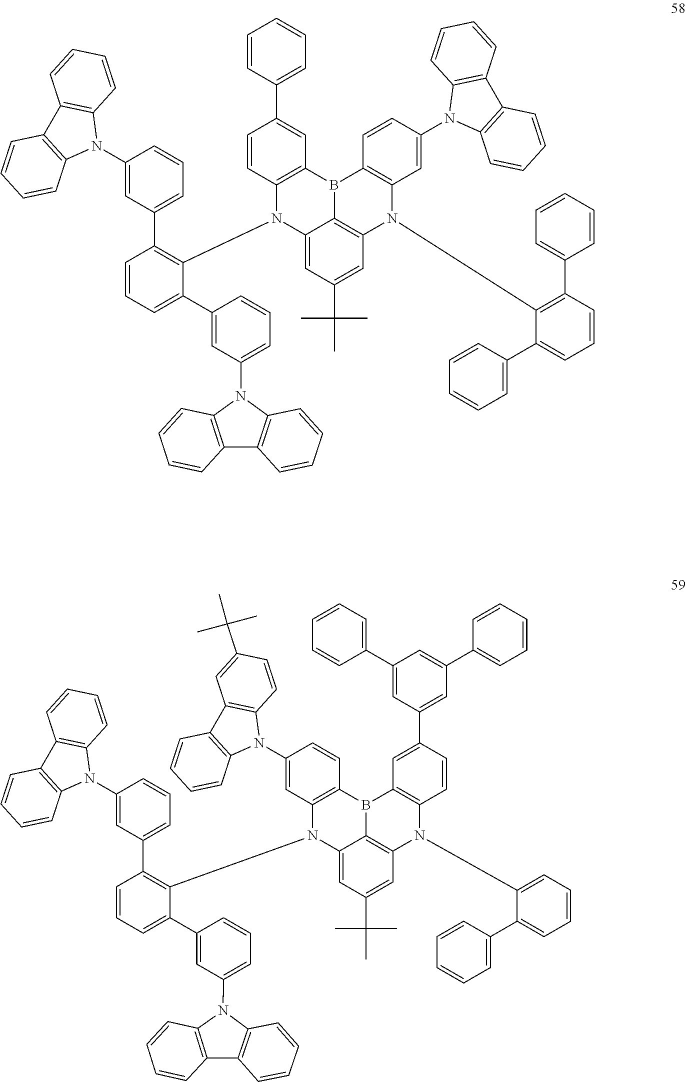 [SMILES: CC(C)(C)c1cc2c3c(c1)N(c1c(-c4ccccc4)cccc1-c1ccccc1)c1cc(-n4c5ccccc5c5ccccc54)ccc1B3c1cc(-c3ccccc3)ccc1N2c1c(-c2cccc(-n3c4ccccc4c4ccccc43)c2)cccc1-c1cccc(-n2c3ccccc3c3ccccc32)c1 ; CC(C)(C)c1cc2c3c(c1)N(c1c(-c4cccc(-n5c6ccccc6c6ccccc65)c4)cccc1-c1cccc(-n4c5ccccc5c5ccccc54)c1)c1cc(-n4c5ccccc5c5cc(C(C)(C)C)ccc54)ccc1B3c1cc(-c3cc(-c4ccccc4)cc(-c4ccccc4)c3)ccc1N2c1ccccc1-c1ccccc1] 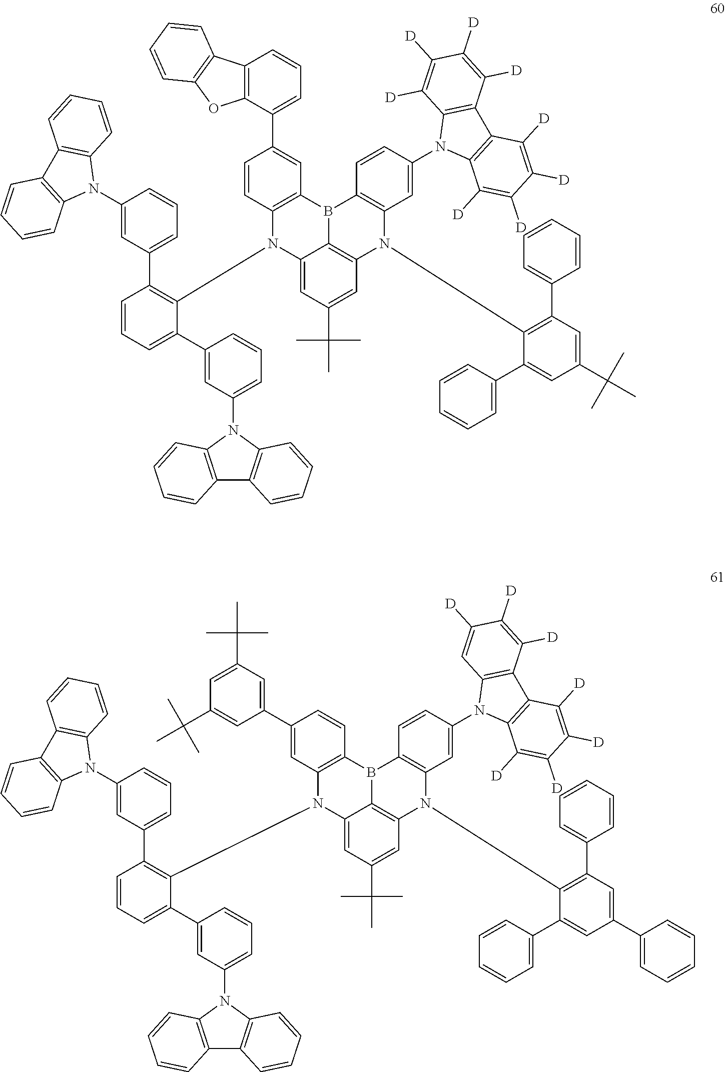 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1cc(-c2cccc4c2oc2ccccc24)ccc1N3c1c(-c2cccc(-n3c4ccccc4c4ccccc43)c2)cccc1-c1cccc(-n2c3ccccc3c3ccccc32)c1 ; [2H]c1cc2c(c([2H])c1[2H])c1c([2H])c([2H])c([2H])c([2H])c1n2-c1ccc2c(c1)N(c1c(-c3ccccc3)cc(-c3ccccc3)cc1-c1ccccc1)c1cc(C(C)(C)C)cc3c1B2c1ccc(-c2cc(C(C)(C)C)cc(C(C)(C)C)c2)cc1N3c1c(-c2cccc(-n3c4ccccc4c4ccccc43)c2)cccc1-c1cccc(-n2c3ccccc3c3ccccc32)c1] 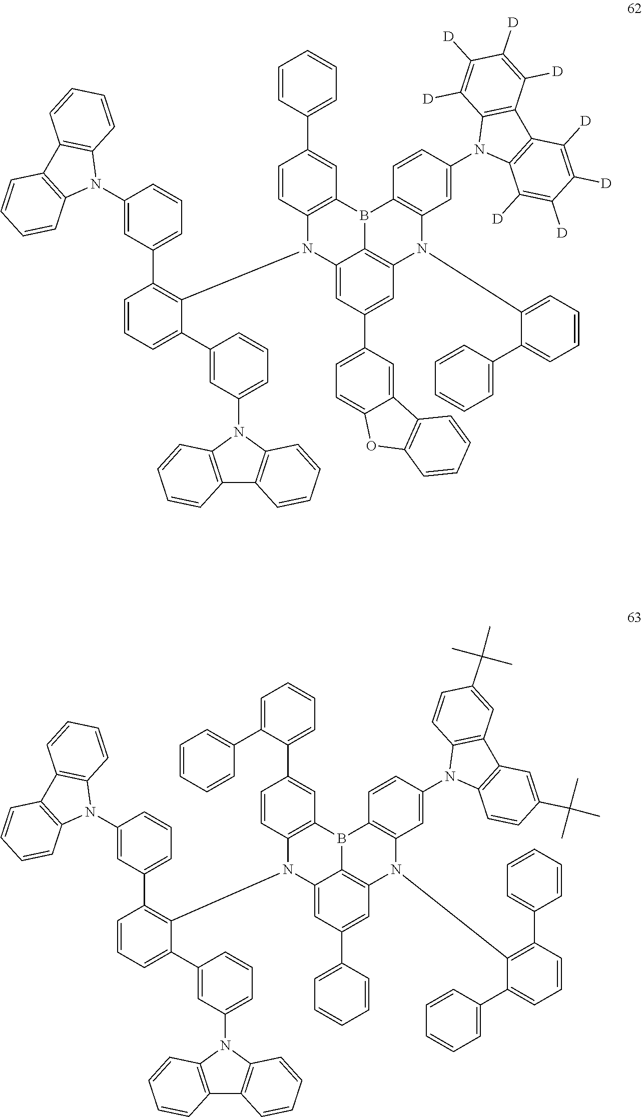 [SMILES: [2H]c1c([2H])c([2H])c2c(c1[2H])c1c([2H])c([2H])c([2H])c([2H])c1n2-c1ccc2c(c1)N(c1ccccc1-c1ccccc1)c1cc(-c3ccc4oc5ccccc5c4c3)cc3c1B2c1cc(-c2ccccc2)ccc1N3c1c(-c2cccc(-n3c4ccccc4c4ccccc43)c2)cccc1-c1cccc(-n2c3ccccc3c3ccccc32)c1 ; CC(C)(C)c1ccc2c(c1)c1cc(C(C)(C)C)ccc1n2-c1ccc2c(c1)N(c1c(-c3ccccc3)cccc1-c1ccccc1)c1cc(-c3ccccc3)cc3c1B2c1cc(-c2ccccc2-c2ccccc2)ccc1N3c1c(-c2cccc(-n3c4ccccc4c4ccccc43)c2)cccc1-c1cccc(-n2c3ccccc3c3ccccc32)c1] 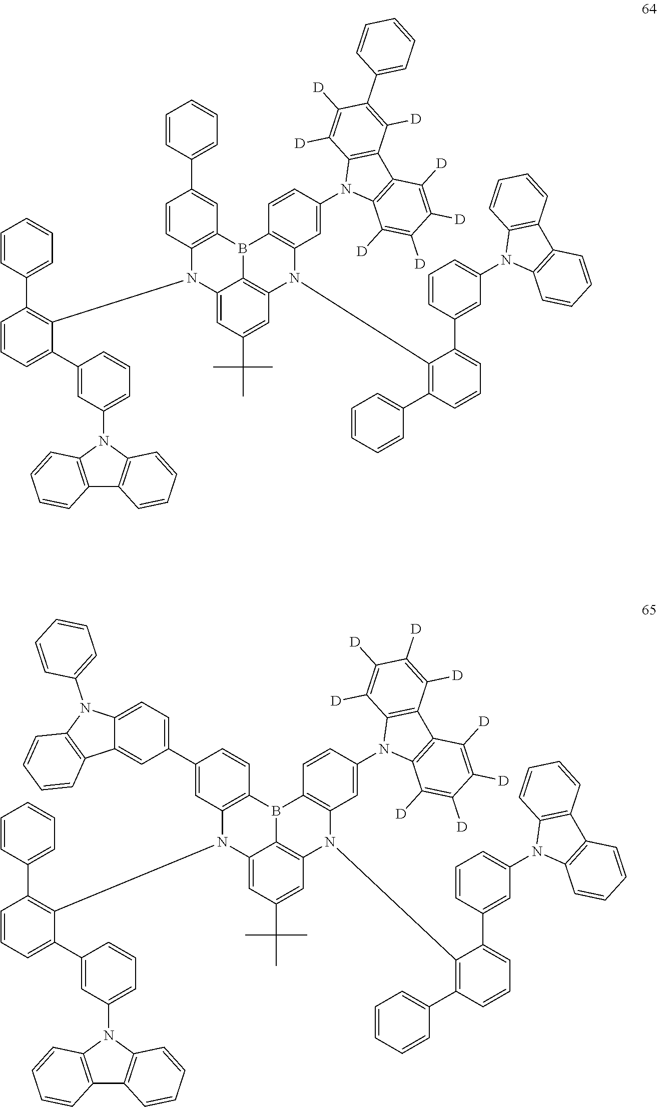 [SMILES: [2H]c1c([2H])c([2H])c2c(c1[2H])c1c([2H])c(-c3ccccc3)c([2H])c([2H])c1n2-c1ccc2c(c1)N(c1c(-c3ccccc3)cccc1-c1cccc(-n3c4ccccc4c4ccccc43)c1)c1cc(C(C)(C)C)cc3c1B2c1cc(-c2ccccc2)ccc1N3c1c(-c2ccccc2)cccc1-c1cccc(-n2c3ccccc3c3ccccc32)c1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1cccc(-n3c4ccccc4c4ccccc43)c1)c1cc(C(C)(C)C)cc3c1B2c1ccc(-c2ccc4c(c2)c2ccccc2n4-c2ccccc2)cc1N3c1c(-c2ccccc2)cccc1-c1cccc(-n2c3ccccc3c3ccccc32)c1] 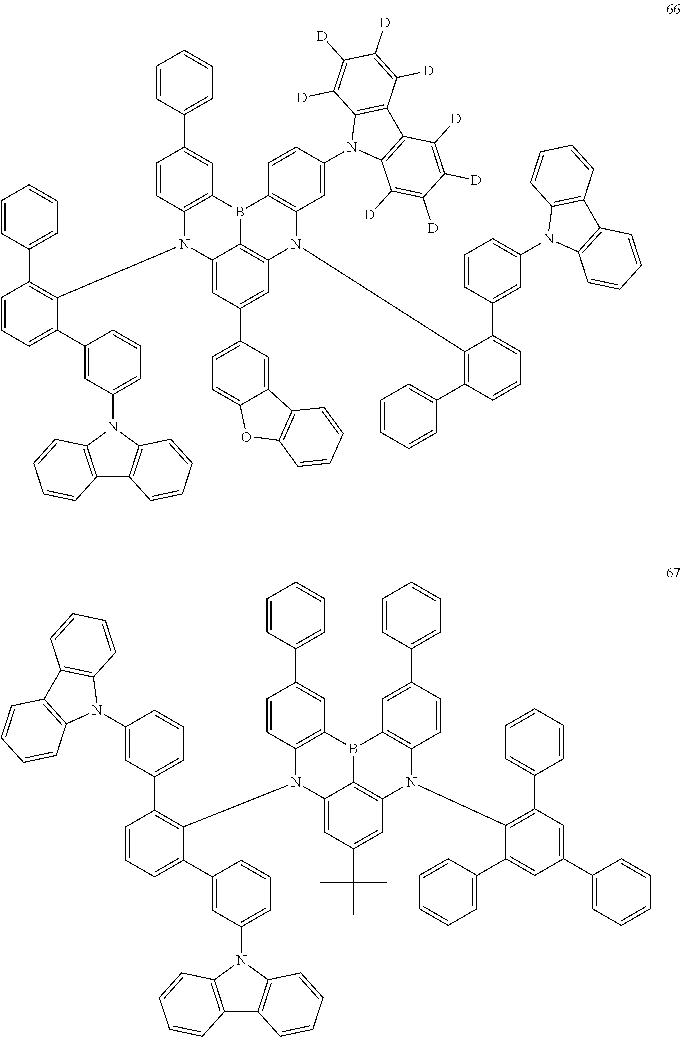 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1cccc(-n3c4ccccc4c4ccccc43)c1)c1cc(-c3ccc4oc5ccccc5c4c3)cc3c1B2c1cc(-c2ccccc2)ccc1N3c1c(-c2ccccc2)cccc1-c1cccc(-n2c3ccccc3c3ccccc32)c1 ; CC(C)(C)c1cc2c3c(c1)N(c1c(-c4ccccc4)cc(-c4ccccc4)cc1-c1ccccc1)c1ccc(-c4ccccc4)cc1B3c1cc(-c3ccccc3)ccc1N2c1c(-c2cccc(-n3c4ccccc4c4ccccc43)c2)cccc1-c1cccc(-n2c3ccccc3c3ccccc32)c1] 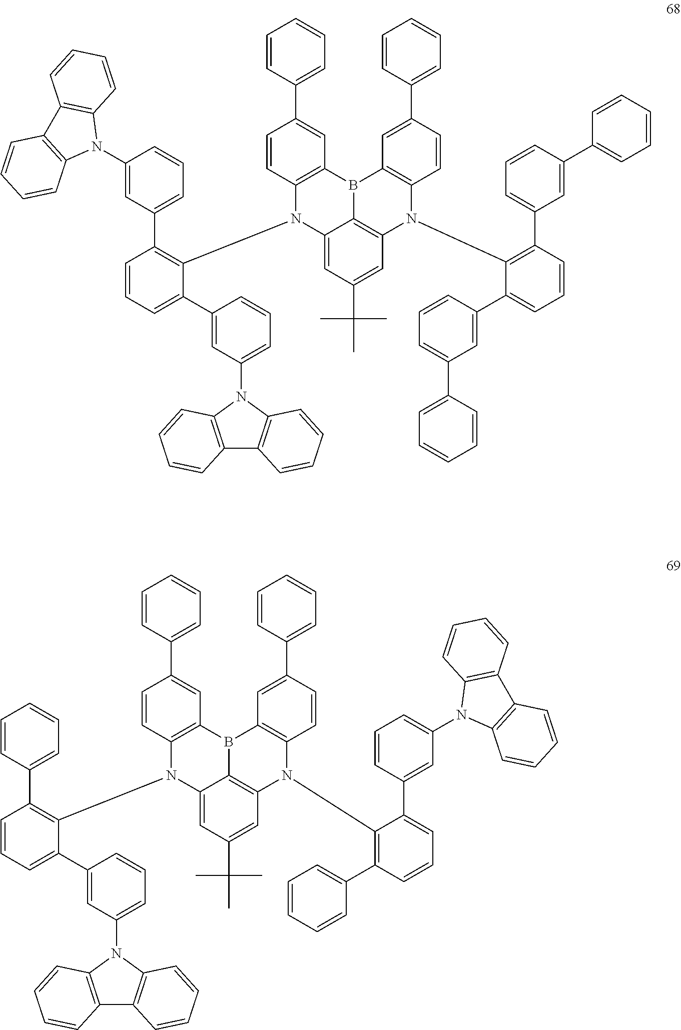 [SMILES: CC(C)(C)c1cc2c3c(c1)N(c1c(-c4cccc(-n5c6ccccc6c6ccccc65)c4)cccc1-c1cccc(-n4c5ccccc5c5ccccc54)c1)c1ccc(-c4ccccc4)cc1B3c1cc(-c3ccccc3)ccc1N2c1c(-c2cccc(-c3ccccc3)c2)cccc1-c1cccc(-c2ccccc2)c1 ; CC(C)(C)c1cc2c3c(c1)N(c1c(-c4ccccc4)cccc1-c1cccc(-n4c5ccccc5c5ccccc54)c1)c1ccc(-c4ccccc4)cc1B3c1cc(-c3ccccc3)ccc1N2c1c(-c2ccccc2)cccc1-c1cccc(-n2c3ccccc3c3ccccc32)c1] 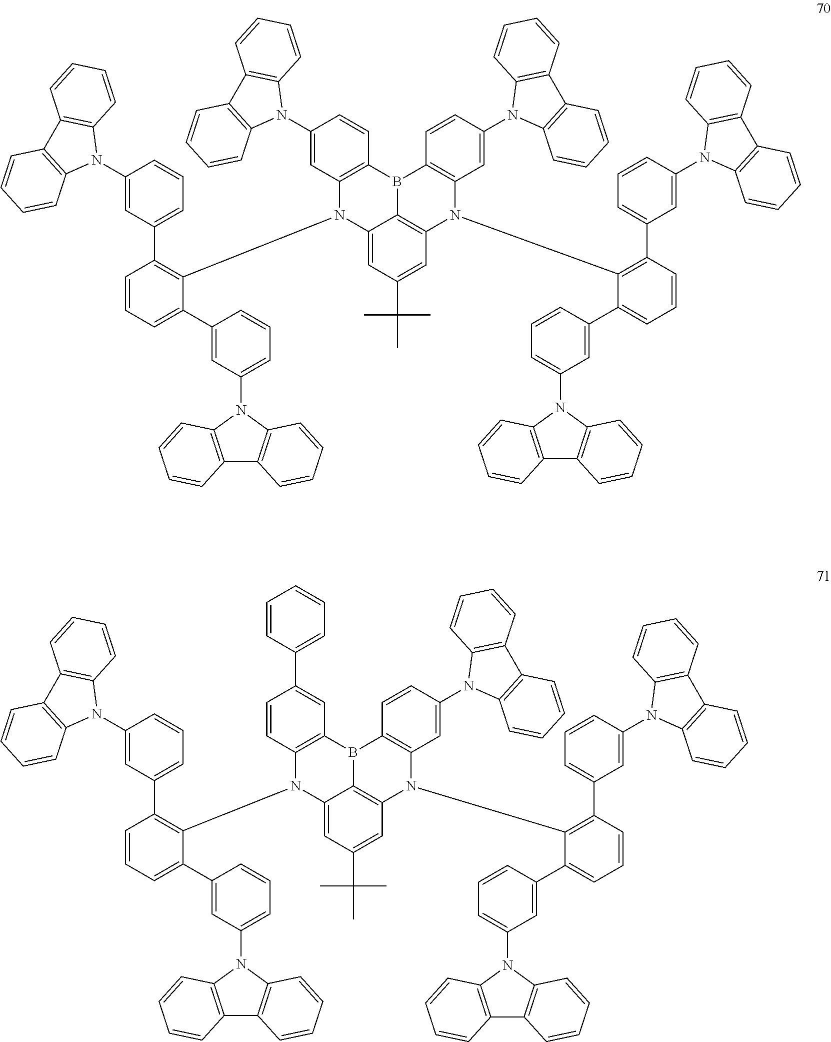 [SMILES: CC(C)(C)c1cc2c3c(c1)N(c1c(-c4cccc(-n5c6ccccc6c6ccccc65)c4)cccc1-c1cccc(-n4c5ccccc5c5ccccc54)c1)c1cc(-n4c5ccccc5c5ccccc54)ccc1B3c1ccc(-n3c4ccccc4c4ccccc43)cc1N2c1c(-c2cccc(-n3c4ccccc4c4ccccc43)c2)cccc1-c1cccc(-n2c3ccccc3c3ccccc32)c1 ; CC(C)(C)c1cc2c3c(c1)N(c1c(-c4cccc(-n5c6ccccc6c6ccccc65)c4)cccc1-c1cccc(-n4c5ccccc5c5ccccc54)c1)c1cc(-n4c5ccccc5c5ccccc54)ccc1B3c1cc(-c3ccccc3)ccc1N2c1c(-c2cccc(-n3c4ccccc4c4ccccc43)c2)cccc1-c1cccc(-n2c3ccccc3c3ccccc32)c1] 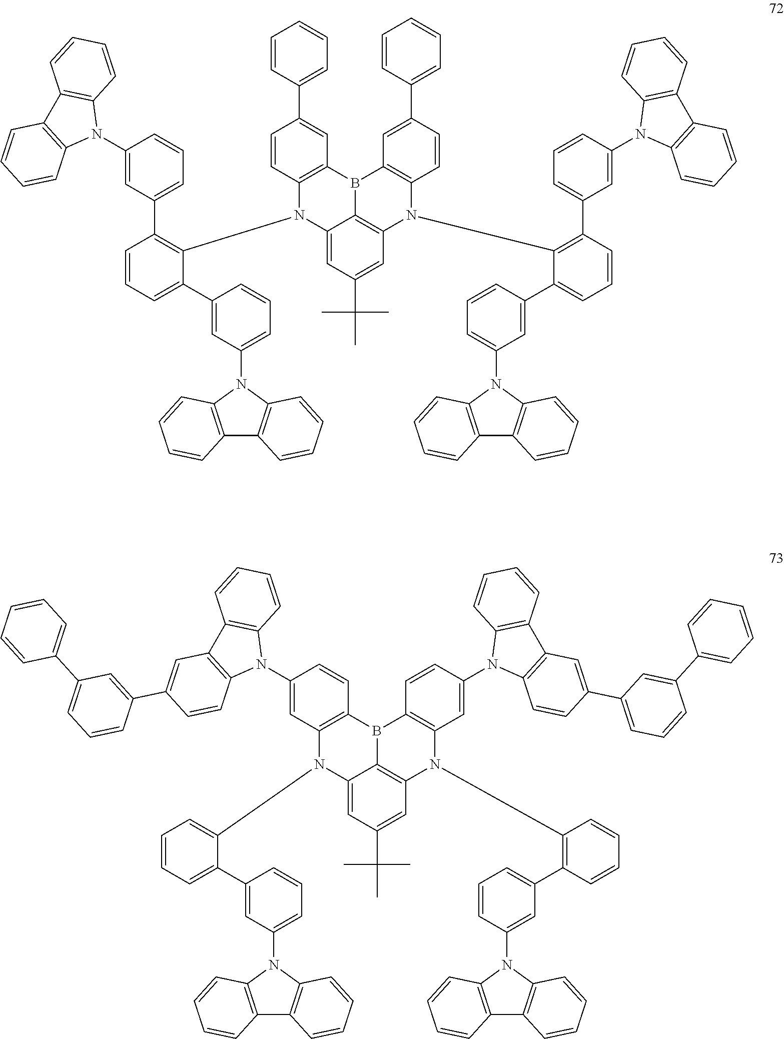 [SMILES: CC(C)(C)c1cc2c3c(c1)N(c1c(-c4cccc(-n5c6ccccc6c6ccccc65)c4)cccc1-c1cccc(-n4c5ccccc5c5ccccc54)c1)c1ccc(-c4ccccc4)cc1B3c1cc(-c3ccccc3)ccc1N2c1c(-c2cccc(-n3c4ccccc4c4ccccc43)c2)cccc1-c1cccc(-n2c3ccccc3c3ccccc32)c1 ; CC(C)(C)c1cc2c3c(c1)N(c1ccccc1-c1cccc(-n4c5ccccc5c5ccccc54)c1)c1cc(-n4c5ccccc5c5cc(-c6cccc(-c7ccccc7)c6)ccc54)ccc1B3c1ccc(-n3c4ccccc4c4cc(-c5cccc(-c6ccccc6)c5)ccc43)cc1N2c1ccccc1-c1cccc(-n2c3ccccc3c3ccccc32)c1] 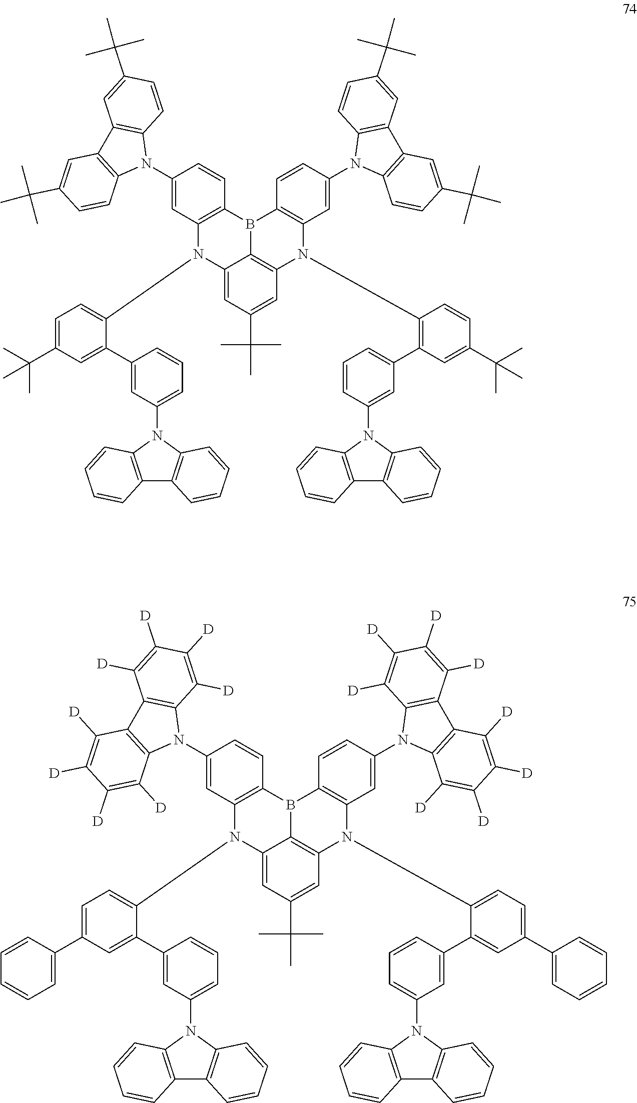 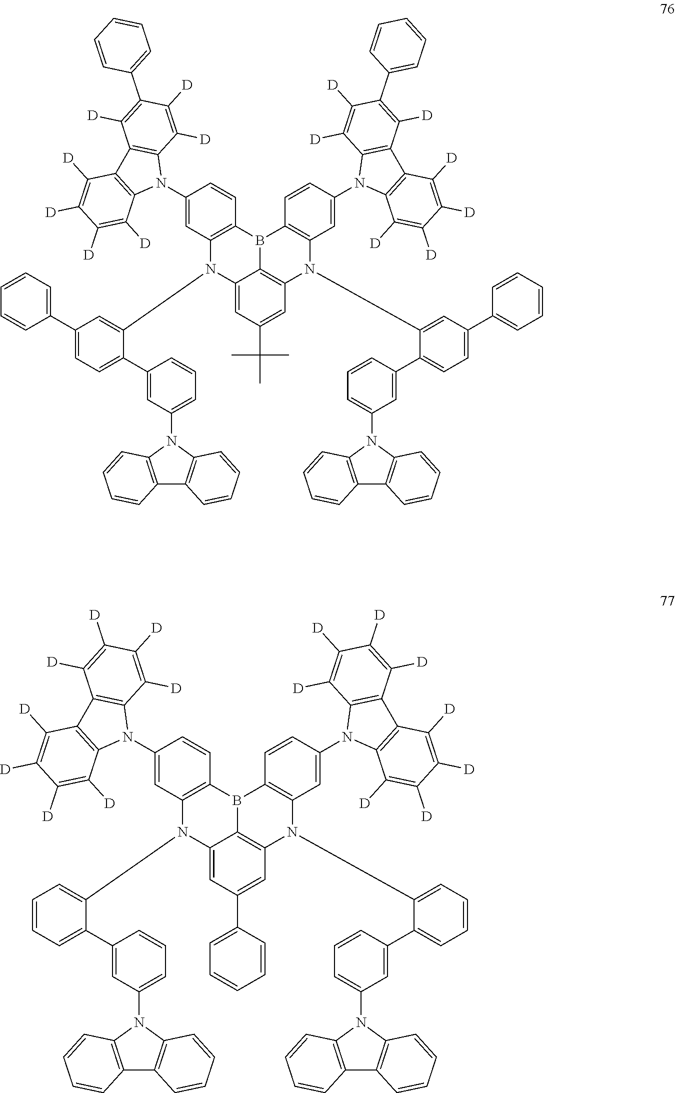 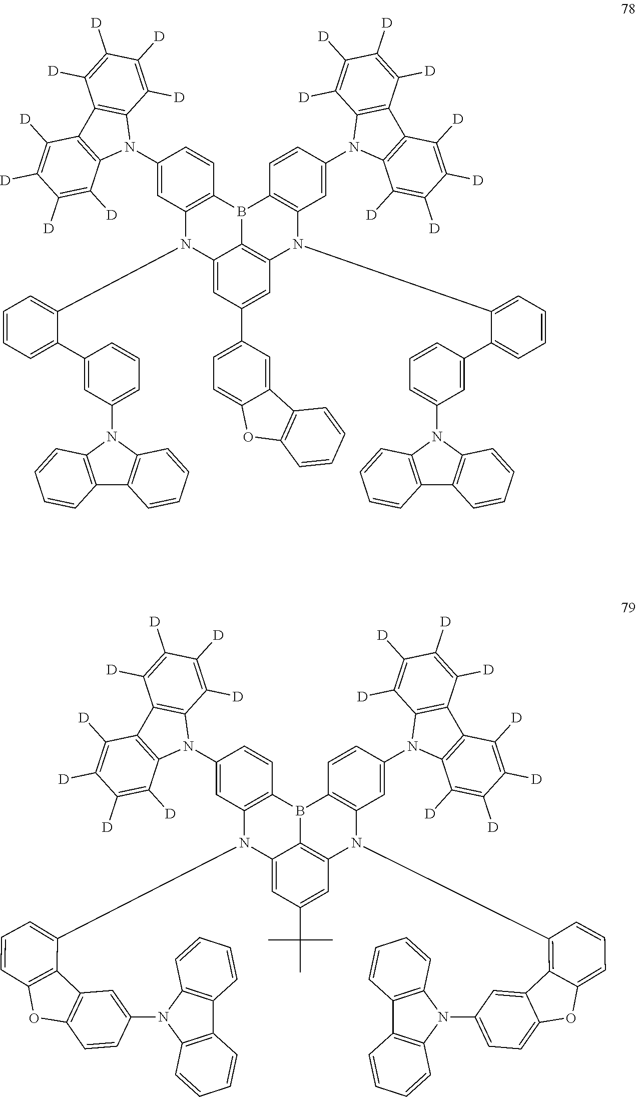 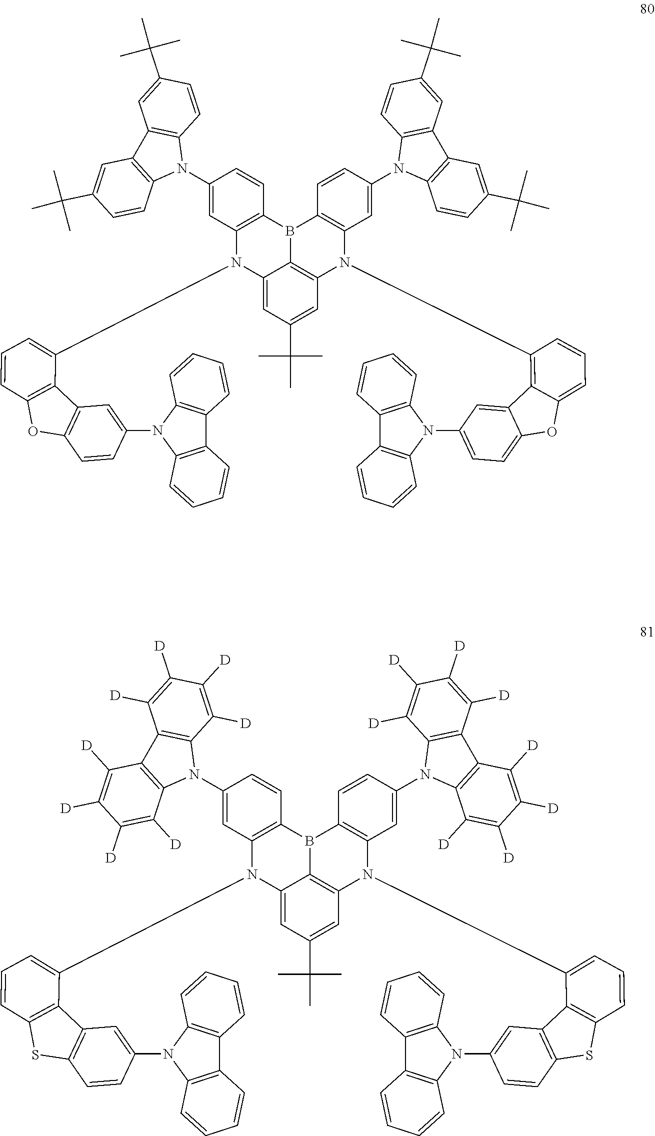 [SMILES: CC(C)(C)c1cc2c3c(c1)N(c1cccc4oc5ccc(-n6c7ccccc7c7ccccc76)cc5c14)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1N2c1cccc2oc3ccc(-n4c5ccccc5c5ccccc54)cc3c12 ; [2H]c1c([2H])c([2H])c2c(c1[2H])c1c([2H])c([2H])c([2H])c([2H])c1n2-c1ccc2c(c1)N(c1cccc3sc4ccc(-n5c6ccccc6c6ccccc65)cc4c13)c1cc(C(C)(C)C)cc3c1B2c1ccc(-n2c4c([2H])c([2H])c([2H])c([2H])c4c4c([2H])c([2H])c([2H])c([2H])c42)cc1N3c1cccc2sc3ccc(-n4c5ccccc5c5ccccc54)cc3c12] 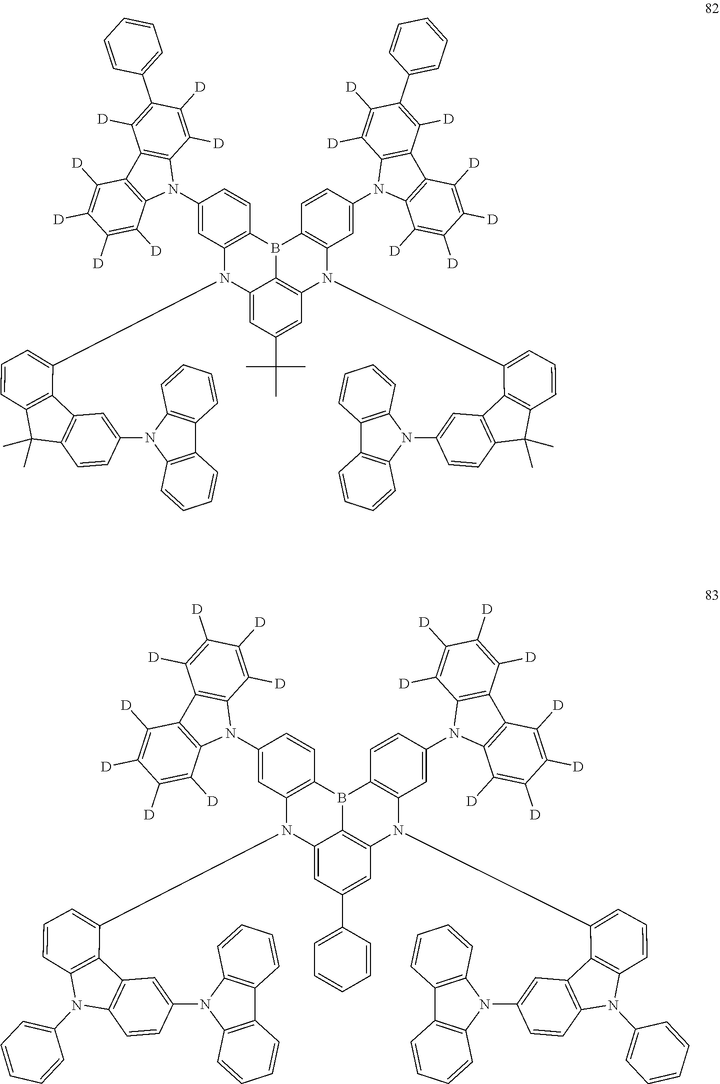 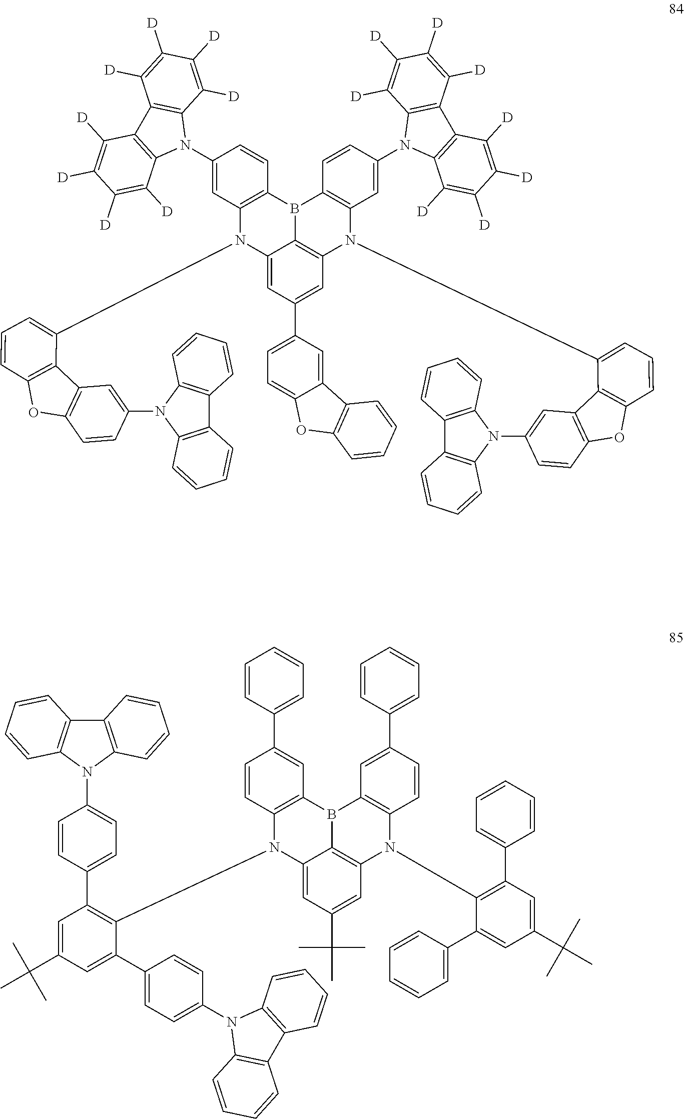 [SMILES: [2H]c1c([2H])c([2H])c2c(c1[2H])c1c([2H])c([2H])c([2H])c([2H])c1n2-c1ccc2c(c1)N(c1cccc3oc4ccc(-n5c6ccccc6c6ccccc65)cc4c13)c1cc(-c3ccc4oc5ccccc5c4c3)cc3c1B2c1ccc(-n2c4c([2H])c([2H])c([2H])c([2H])c4c4c([2H])c([2H])c([2H])c([2H])c42)cc1N3c1cccc2oc3ccc(-n4c5ccccc5c5ccccc54)cc3c12 ; CC(C)(C)c1cc(-c2ccccc2)c(N2c3ccc(-c4ccccc4)cc3B3c4cc(-c5ccccc5)ccc4N(c4c(-c5ccc(-n6c7ccccc7c7ccccc76)cc5)cc(C(C)(C)C)cc4-c4ccc(-n5c6ccccc6c6ccccc65)cc4)c4cc(C(C)(C)C)cc2c43)c(-c2ccccc2)c1] 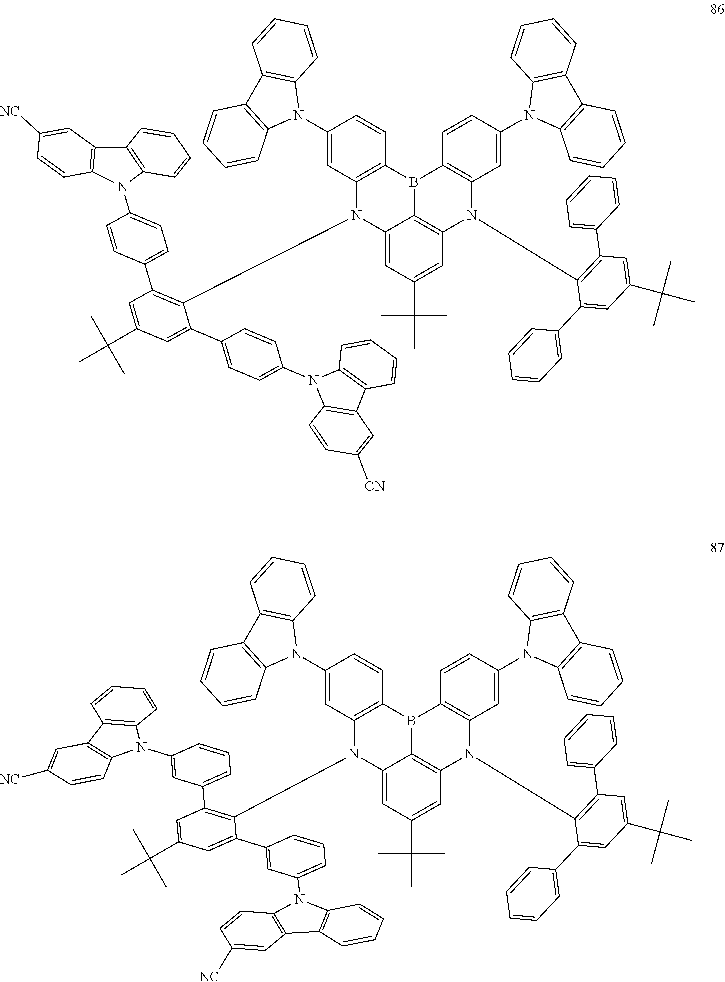 [SMILES: CC(C)(C)c1cc(-c2ccccc2)c(N2c3cc(-n4c5ccccc5c5ccccc54)ccc3B3c4ccc(-n5c6ccccc6c6ccccc65)cc4N(c4c(-c5ccc(-n6c7ccccc7c7cc(C#N)ccc76)cc5)cc(C(C)(C)C)cc4-c4ccc(-n5c6ccccc6c6cc(C#N)ccc65)cc4)c4cc(C(C)(C)C)cc2c43)c(-c2ccccc2)c1 ; CC(C)(C)c1cc(-c2ccccc2)c(N2c3cc(-n4c5ccccc5c5ccccc54)ccc3B3c4ccc(-n5c6ccccc6c6ccccc65)cc4N(c4c(-c5cccc(-n6c7ccccc7c7cc(C#N)ccc76)c5)cc(C(C)(C)C)cc4-c4cccc(-n5c6ccccc6c6cc(C#N)ccc65)c4)c4cc(C(C)(C)C)cc2c43)c(-c2ccccc2)c1] 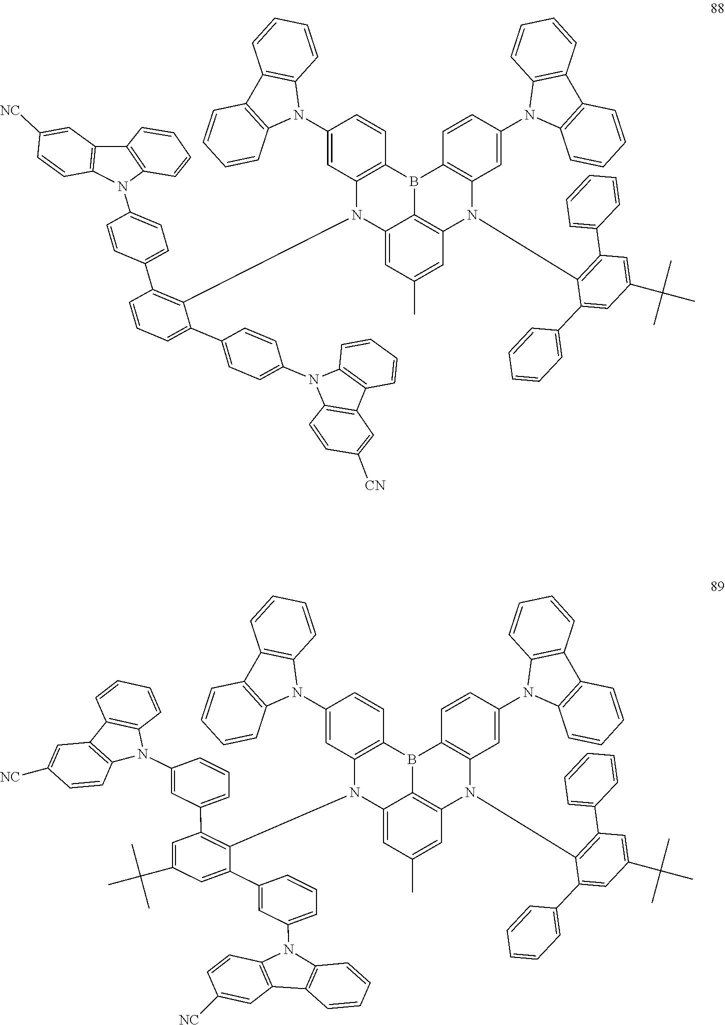 [SMILES: Cc1cc2c3c(c1)N(c1c(-c4ccccc4)cc(C(C)(C)C)cc1-c1ccccc1)c1cc(-n4c5ccccc5c5ccccc54)ccc1B3c1ccc(-n3c4ccccc4c4ccccc43)cc1N2c1c(-c2ccc(-n3c4ccccc4c4cc(C#N)ccc43)cc2)cccc1-c1ccc(-n2c3ccccc3c3cc(C#N)ccc32)cc1 ; Cc1cc2c3c(c1)N(c1c(-c4cccc(-n5c6ccccc6c6cc(C#N)ccc65)c4)cc(C(C)(C)C)cc1-c1cccc(-n4c5ccccc5c5cc(C#N)ccc54)c1)c1cc(-n4c5ccccc5c5ccccc54)ccc1B3c1ccc(-n3c4ccccc4c4ccccc43)cc1N2c1c(-c2ccccc2)cc(C(C)(C)C)cc1-c1ccccc1] 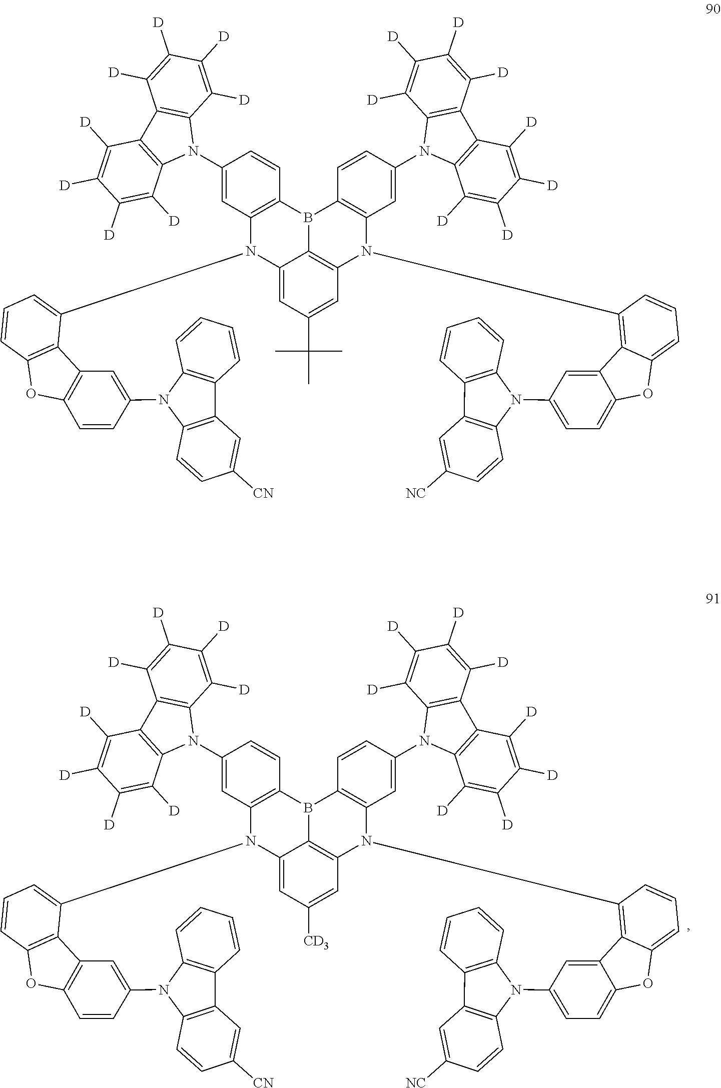
and
wherein, in Compound Group 1, D is a deuterium atom.

18. An electronic device comprising:
a display device, the display device comprising:
a base layer;
a circuit layer on the base layer; and
a display element layer on the circuit layer and comprising a light-emitting element;
wherein the light-emitting element comprises a first electrode, a second electrode opposite to the first electrode, and an emission layer between the first electrode and the second electrode and represented by Formula 1: 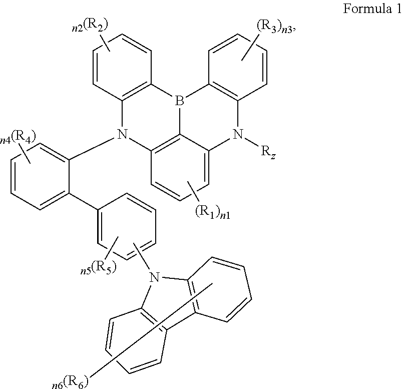
and
wherein, in Formula 1,
R₁ to R₃, R₆ and R_{z} are each independently a hydrogen atom, a deuterium atom, a cyano group, a substituted or unsubstituted alkyl group having 1 to 30 carbons, a substituted or unsubstituted aryl group having 6 to 30 ring-forming carbons, or a substituted or unsubstituted heteroaryl group having 2 to 60 ring-forming carbons,
R₄ and R₅ are each independently a hydrogen atom, a deuterium atom, a cyano group, a hydroxy group, a substituted or unsubstituted thio group, a substituted or unsubstituted oxy group, a substituted or unsubstituted alkyl group having 1 to 30 carbons, a substituted or unsubstituted alkenyl group having 2 to 30 carbons, a substituted or unsubstituted aryl group having 6 to 30 ring-forming carbons, or a substituted or unsubstituted heteroaryl group having 2 to 30 ring-forming carbons, and/or are each bonded to an adjacent group to form a ring,
n1 is an integer of 0 to 3,
n2 and n5 are each independently an integer of 0 to 4, and
n6 is an integer of 0 to 8.

19. The electronic device of claim 18, wherein the light-emitting element is configured to emit blue light.

20. The electronic device of claim 18, further comprising a light control layer comprising a quantum dot.
